(19) United States
(12) Patent Application Publication
(10) Pub. No.: US 2026/0033279 A1
(43) Pub. Date: Jan. 29, 2026

(54) SUBSTRATE PROCESSING APPARATUS

(71) Applicant: SCREEN Holdings Co., Ltd., Kyoto (JP)

(72) Inventor: Hitoshi NAKAI, Kyoto-shi (JP)

(21) Appl. No.: 19/258,341

(22) Filed: Jul. 2, 2025

(30) Foreign Application Priority Data
Jul. 29, 2024 (JP) 2024-122045

(51) Int. Cl. H01L 21/67; B08B 1/12; B08B 1/32; B08B 3/02; B08B 3/08; B08B 3/10

(52) U.S. Cl. CPC H01L 21/6719; B08B 1/12; B08B 1/32; B08B 3/02; B08B 3/08; B08B 3/10; H01L 21/67023

(57) ABSTRACT

A substrate processing apparatus includes a processing block and a transfer block. The processing block has an upper substrate holding portion, a moving mechanism, a processing cup row, and a raising/lowering mechanism. The upper substrate holding portion horizontally holds the substrate. The moving mechanism moves the upper substrate holding portion in a first direction that is a direction parallel to a direction in which the substrate moves between the transfer block and the processing block. The processing cup row includes a plurality of processing cup portions arranged in the first direction. The raising/lowering mechanism raises and lowers at least one of the upper substrate holding portion and the processing cup portion. The plurality of processing cup portions include a first processing cup portion. The first processing cup portion holds a processing liquid in contact with the substrate located inside the first processing cup portion and processes the substrate.

### CROSS REFERENCE TO RELATED APPLICATIONS

This application claims the benefit of priority to Japanese Patent Application No. 2024-122045 filed on Jul. 29, 2024. The entire contents of this application are hereby incorporated herein by reference.

### BACKGROUND OF THE INVENTION

### 1. Field of the Invention

The present invention relates to a substrate processing apparatus.

### 2. Description of Related Art

As that processing a substrate apparatus processes substrates, a batch type apparatus that processes a plurality of substrates at one time and a single substrate processing type apparatus that processes substrates one by one are known. A batch type substrate processing apparatus immerses a plurality of substrates in a processing liquid at one time and processes the plurality of substrates at one time. A single substrate processing type substrate processing apparatus horizontally holds a substrate, rotates the substrate, and supplies a processing liquid to the rotating substrate, thereby processing the substrate (see, for example, JP 2020-126886 A). In general, since the single substrate processing type substrate processing apparatus can be downsized as compared with the batch type substrate processing apparatus, the consumption amount of the processing liquid can be reduced.

However, in the single substrate processing type substrate processing apparatus, the processing liquid is continuously supplied to the substrate, and thus the consumption amount of the processing liquid cannot be reduced much when lengthy processing is required. Therefore, there is room for further improvement in the single substrate processing type substrate processing apparatus.

One of objects of the present invention is to provide a substrate processing apparatus capable of reducing the consumption amount of a processing liquid.

### SUMMARY OF THE INVENTION

According to one aspect of the present invention, a substrate processing apparatus includes a processing block and a transfer block. The processing block processes a substrate. The transfer block is disposed adjacent to the processing block. The transfer block has a transfer device. The transfer device transfers the substrate between the transfer block and the processing block. The processing block has an upper substrate holding portion, a moving mechanism, a processing cup row, and a raising/lowering mechanism. The upper substrate holding portion horizontally holds the substrate. The moving mechanism moves the upper substrate holding portion in a first direction that is a direction parallel to a direction in which the substrate moves between the transfer block and the processing block. The processing cup row includes a plurality of processing cup portions arranged in the first direction. The raising/lowering mechanism raises and lowers at least one of the upper substrate holding portion and the corresponding processing cup portion such that a position of the substrate held by the upper substrate holding portion changes from one of over positions of the plurality of processing cup portions to a position inside the corresponding processing cup portion. The plurality of processing cup portions include a first processing cup portion. The first processing cup portion holds a processing liquid in contact with the substrate located inside the first processing cup portion and processes the substrate.

In a preferred embodiment, the plurality of processing cup portions include a plurality of the first processing cup portions. Each of the plurality of first processing cup portions has a supporting portion that supports the substrate. The upper substrate holding portion transfers the substrate to and from the supporting portion of each of the plurality of first processing cup portions.

In a preferred embodiment, the substrate processing apparatus further includes a draining portion. The processing liquid includes a chemical liquid. The substrate is processed with the chemical liquid in the first processing cup portion. The draining portion drains the chemical liquid from the first processing cup portion. The upper substrate holding portion has an upper nozzle portion. The upper nozzle portion discharges a rinse liquid toward the substrate. The upper nozzle portion discharges the rinse liquid toward the substrate located inside the first processing cup portion from which the chemical liquid has been drained by the draining portion.

In a preferred embodiment, the upper substrate holding portion has an upper holding portion and an upper rotating portion. The upper holding portion horizontally holds the substrate. The upper rotating portion rotates the substrate integrally with the upper holding portion. After the discharge of the rinse liquid is stopped, the upper rotating portion rotates the substrate located inside the first processing cup portion and dry the substrate.

In a preferred embodiment, the upper nozzle portion ejects gas toward the substrate when the substrate is dried.

In a preferred embodiment, the processing cup portion further includes a second processing cup portion. The second processing cup portion receives a rinse liquid drained from the substrate. The raising/lowering mechanism changes a position of a processed substrate, which is the substrate processed in the first processing cup portion, from a position inside the first processing cup portion to an over position of the first processing cup portion. The moving mechanism moves the upper substrate holding portion that holds the processed substrate to a facing position at which the upper substrate holding portion faces the second processing cup portion. The raising/lowering mechanism changes the position of the processed substrate from an over position of the second processing cup portion to a position inside the second processing cup portion.

In a preferred embodiment, the upper substrate holding portion has an upper nozzle portion that discharges the rinse liquid. The upper nozzle portion discharges the rinse liquid toward the processed substrate located inside the second processing cup portion.

In a preferred embodiment, the upper substrate holding portion has an upper holding portion and an upper rotating portion. The upper holding portion horizontally holds the substrate. The upper rotating portion rotates the substrate integrally with the upper holding portion. After the discharge of the rinse liquid is stopped, the upper rotating portion rotates the processed substrate located inside the second processing cup portion and dry the processed substrate.

In a preferred embodiment, the upper nozzle portion ejects gas toward the processed substrate when the processed substrate is dried.

In a preferred embodiment, the plurality of processing cup portions include a plurality of the first processing cup portions and the one second processing cup portion. The processing liquid includes a chemical liquid. The substrate is processed with different types of the chemical liquids in the plurality of first processing cup portions. The moving mechanism moves the upper substrate holding portion according to a processing procedure indicating a procedure of processing the substrate.

In a preferred embodiment, each of the plurality of first processing cup portions has a supporting portion that supports the substrate.

In a preferred embodiment, the plurality of processing cup portions include a plurality of the first processing cup portions and a plurality of the second processing cup portions. The processing liquid includes a chemical liquid. The substrate is processed with different types of the chemical liquids in the plurality of first processing cup portions. The plurality of first processing cup portions and the plurality of second processing cup portions are arranged according to a processing procedure indicating a procedure of processing the substrate.

In a preferred embodiment, each of the plurality of first processing cup portions has a supporting portion that supports the substrate. One of the plurality of second processing cup portions disposed between two first processing cup portions has a supporting portion that supports the substrate.

In a preferred embodiment, the processing procedure includes final rinse processing and drying processing to dry the substrate. The rinse processing indicates processing to wash away the chemical liquid from the substrate processed in the first processing cup portion. The plurality of first processing cup portions include a third processing cup portion in which processing immediately before the final rinse processing is performed. The plurality of second processing cup portions include a fourth processing cup portion in which the final rinse processing and the drying processing are performed. The upper substrate holding portion includes a first upper substrate holding portion and a second upper substrate holding portion. The moving mechanism includes a first moving mechanism and a second moving mechanism. The first moving mechanism moves the first upper substrate holding portion such that the substrate moves between the plurality of processing cup portions other than the fourth processing cup portion. The second moving mechanism moves the second upper substrate holding portion such that the substrate moves between the third processing cup portion and the fourth processing cup portion.

In a preferred embodiment, the substrate processing apparatus further includes a controlling portion. The upper substrate holding portion has an upper holding portion and an upper rotating portion. The upper holding portion holds the substrate. The upper rotating portion rotates the substrate integrally with the upper holding portion. The controlling portion controls rotation of the substrate by the upper rotating portion. The moving mechanism moves the upper substrate holding portion that holds the processed substrate in the first direction. When the raising/lowering mechanism changes a position of the processed substrate from a position inside the first processing cup portion to an over position of the first processing cup portion and the moving mechanism moves the upper substrate holding portion that holds the processed substrate in the first direction, the controlling portion controls a rotational speed of the processed substrate or stops rotation of the processed substrate to maintain a paddle state in which a liquid film of the processing liquid is supported on an upper surface of the processed substrate.

In a preferred embodiment, the substrate processing apparatus further includes a controlling portion. The upper substrate holding portion has an upper holding portion, an upper rotating portion, and an upper nozzle portion. The upper holding portion holds the substrate. The upper rotating portion rotates the substrate integrally with the upper holding portion. The upper nozzle portion discharges a rinse liquid. The controlling portion controls rotation of the substrate by the upper rotating portion. The upper nozzle portion discharges the rinse liquid toward the processed substrate located inside the first processing cup portion and forms a liquid film of the rinse liquid on an upper surface of the processed substrate. The moving mechanism moves the upper substrate holding portion that holds the processed substrate in the first direction. When the raising/lowering mechanism changes a position of the processed substrate from a position inside the first processing cup portion to an over position of the first processing cup portion and the moving mechanism moves the upper substrate holding portion that holds the processed substrate in the first direction, the controlling portion controls a rotational speed of the processed substrate or stops rotation of the processed substrate to maintain a paddle state in which a liquid film of the rinse liquid is supported on an upper surface of the processed substrate.

In a preferred embodiment, the substrate processing apparatus further includes a moving nozzle and a nozzle moving portion. The second processing cup portion includes a lower holding portion, a lower rotating portion, and a guard portion. The lower holding portion horizontally holds the substrate. The lower rotating portion rotates the substrate integrally with the lower holding portion. The guard portion surrounds the substrate held by the lower holding portion and receives a chemical liquid drained from the substrate. The upper substrate holding portion delivers the substrate processed in the first processing cup portion to the lower holding portion. The moving nozzle discharges the chemical liquid toward the substrate held by the lower holding portion. The nozzle moving portion moves the moving nozzle in a horizontal direction. The moving nozzle discharges the chemical liquid while moving in the horizontal direction.

In a preferred embodiment, the first processing cup portion has a supporting portion that horizontally supports a plurality of the substrates. The first processing cup portion holds a processing liquid in contact with the plurality of substrates located inside the first processing cup portion and processes the plurality of substrates.

In a preferred embodiment, the processing block has a plurality of the upper substrate holding portions, a plurality of the moving mechanisms, and a plurality of the raising/lowering mechanisms. The plurality of moving mechanisms correspond to the plurality of upper substrate holding portions. The plurality of raising/lowering mechanisms correspond to the plurality of upper substrate holding portions and/or the plurality of processing cup portions.

In a preferred embodiment, the processing block includes a plurality of the processing cup rows arranged in a direction orthogonal to the first direction, a plurality of the upper substrate holding portions one of which is provided for each of the processing cup rows, a plurality of the moving mechanisms one of which is provided for each of the processing cup rows, and a plurality of the raising/lowering mechanisms one of which is provided for each of the processing cup rows.

In a preferred embodiment, the processing block further has an inter-row transfer device. The inter-row transfer device transfers the substrate between the plurality of processing cup rows.

In a embodiment, the substrate preferred processing apparatus further includes a lid member. The first processing cup portion has an upper surface opening through which the substrate passes. The lid member covers the upper surface opening.

In a preferred embodiment, the substrate processing apparatus further includes a cylindrical member. The upper substrate holding portion has an upper base member and an upper gripping member. The upper gripping member is provided on the upper base member and horizontally grips the substrate. The first processing cup portion has an inner peripheral edge portion. The inner peripheral edge portion forms an upper surface opening through which the substrate passes. When the substrate is located inside the first processing cup portion, a side surface of the upper base member is located at a position at which the side surface faces the inner peripheral edge portion. The cylindrical member is located in a gap between the inner peripheral edge portion and the upper base member when the substrate is located inside the first processing cup portion.

In a preferred embodiment, the upper substrate holding portion has an upper base member and an upper gripping member. The upper gripping member is provided on the upper base member and horizontally grips the substrate. The first processing cup portion has an inner peripheral edge portion and an annular inner wall portion. The inner peripheral edge portion forms an upper surface opening through which the substrate passes. The inner wall portion is positioned under the inner peripheral edge portion. A side surface of the upper base member covers a gap between the inner peripheral edge portion and the inner wall portion when the substrate is located inside the first processing cup portion.

In a preferred embodiment, the first processing cup portion includes an immersion bath. The immersion bath stores the processing liquid. The substrate is immersed in the processing liquid in the immersion bath.

In a preferred embodiment, the upper substrate holding portion has an upper holding portion and an upper rotating portion. The upper holding portion horizontally holds the substrate. The upper rotating portion rotates the substrate integrally with the upper holding portion. The immersion bath has a lower brush member in contact with a lower surface of the substrate. The upper rotating portion rotates the substrate immersed in the processing liquid and being in contact with the lower brush member.

In a preferred embodiment, the substrate processing apparatus further includes a brush processing portion. The brush processing portion performs brush processing on an upper surface of the substrate immersed in the processing liquid. The first processing cup portion has a lower substrate holding portion. The lower substrate holding portion horizontally holds the substrate inside the immersion bath. The upper substrate holding portion delivers the substrate to the lower substrate holding portion. The brush processing portion has an upper brush member and a brush rotating portion. The upper brush member comes into contact with an upper surface of the substrate held by the lower substrate holding portion. The brush rotating portion rotates the upper brush member. The brush rotating portion rotates the upper brush member when the upper brush member is in contact with the upper surface of the substrate immersed in the processing liquid.

In a preferred embodiment, the first processing cup portion has a lower substrate holding portion. The lower substrate holding portion horizontally holds the substrate inside the immersion bath. The upper substrate holding portion has an upper base member, an upper gripping member, an upper brush member, and an upper rotating portion. The upper gripping member is provided on the upper base member to grip the substrate. The upper brush member is provided on the upper base member and comes into contact with an upper surface of the substrate held by the lower substrate holding portion. The upper rotating portion rotates the upper brush member and the upper gripping member integrally with the upper base member. The upper substrate holding portion delivers the substrate from the upper gripping member to the lower substrate holding portion. The upper rotating portion rotates the upper brush member when the upper brush member is in contact with an upper surface of the substrate immersed in the processing liquid.

In a preferred embodiment, the substrate processing apparatus further includes an undiluted liquid supplying portion, and the processing liquid includes a chemical liquid. The immersion bath stores the chemical liquid. The undiluted liquid supplying portion supplies an undiluted liquid of the chemical liquid to the immersion bath.

In a preferred embodiment, the first processing cup portion has a supporting portion and a ring-shaped member. The supporting portion supports the substrate. The ring-shaped member holds a liquid film of the processing liquid in contact with an upper surface of the substrate supported by the supporting portion.

In a preferred embodiment, the first processing cup portion has a supporting portion, a lower base member, and a lower nozzle portion. The supporting portion supports the substrate. The lower base member faces a lower surface of the substrate supported by the supporting portion. The lower nozzle portion is provided in the lower base member. The lower nozzle portion discharges the processing liquid. The processing liquid discharged from the lower nozzle portion is held in a gap between a lower surface of the substrate and the lower base member and comes into contact with a lower surface of the substrate.

According to the substrate processing apparatus according to at least one aspect of the present invention, the consumption amount of the processing liquid can be reduced.

### BRIEF DESCRIPTION OF THE DRAWINGS

FIG. 1 is a schematic plan view of a substrate processing apparatus according to Preferred Embodiment 1.

FIG. 2 is an enlarged schematic plan view of a portion of the substrate processing apparatus according to Preferred Embodiment 1.

FIG. 3 is a block diagram of the substrate processing apparatus according to Preferred Embodiment 1.

FIG. 4 is a cross-sectional view schematically illustrating a portion of a configuration of a first processing block included in the substrate processing apparatus according to Preferred Embodiment 1.

FIG. 5 is an enlarged view schematically illustrating the cross sections of a moving portion and an immersion bath as viewed from the left side.

FIG. 6 is a view illustrating a portion of a configuration of the substrate processing apparatus according to Preferred Embodiment 1.

FIG. 7 is a diagram illustrating an example of the operation flow of the substrate processing apparatus according to Preferred Embodiment 1.

FIG. 8 is a view schematically illustrating an example of the operation of the substrate processing apparatus according to Preferred Embodiment 1.

FIG. 9 is a view illustrating the operation of the first processing block when one substrate is processed in a first processing cup row of the first processing block.

FIG. 10 is a view illustrating the operation of the first processing block when one substrate is processed in the first processing cup row of the first processing block.

FIG. 11 is a view illustrating the operation of the first processing block when one substrate is processed in the first processing cup row of the first processing block.

FIG. 12 is a view illustrating the operation of the first processing block when one substrate is processed in the first processing cup row of the first processing block.

FIG. 13 is a view illustrating the operation of the first processing block when one substrate is processed in the first processing cup row of the first processing block.

FIG. 14 is a view illustrating the operation of the first processing block when one substrate is processed in the first processing cup row of the first processing block.

FIG. 15 is a view illustrating the operation of the first processing block when one substrate is processed in the first processing cup row of the first processing block.

FIG. 16 is a view illustrating the operation of the first processing block when one substrate is processed in the first processing cup row of the first processing block.

FIG. 17 is a view illustrating the operation of the first processing block when one substrate is processed in the first processing cup row of the first processing block.

FIG. 18 is a view illustrating the operation of the first processing block when one substrate is processed in the first processing cup row of the first processing block.

FIG. 19 is a view illustrating the operation of the first processing block when one substrate is processed in the first processing cup row of the first processing block.

FIG. 20 is a view illustrating the operation of the first processing block when one substrate is processed in the first processing cup row of the first processing block.

FIG. 21 is an enlarged schematic plan view of a portion of a substrate processing apparatus according to Modification Example 1.

FIG. 22 is a cross-sectional view schematically illustrating a portion of a configuration of a first processing block included in a substrate processing apparatus according to Modification Example 2.

FIG. 23 is an enlarged schematic plan view of a portion of a substrate processing apparatus according to Preferred Embodiment 2.

FIG. 24 is a cross-sectional view schematically illustrating a portion of a configuration of a first processing block included in the substrate processing apparatus according to Preferred Embodiment 2.

FIG. 25 is an enlarged schematic plan view of a portion of a substrate processing apparatus according to Preferred Embodiment 3.

FIG. 26 is a cross-sectional view schematically illustrating a portion of a configuration of a first processing block included in the substrate processing apparatus according to Preferred Embodiment 3.

FIG. 27 is a view illustrating the processing of immersing a substrate in a first chemical liquid.

FIG. 28 is another cross-sectional view schematically illustrating a portion of the configuration of the first processing block included in the substrate processing apparatus according to Preferred Embodiment 3.

FIG. 29 is still another cross-sectional view schematically illustrating a portion of the configuration of the first processing block included in the substrate processing apparatus according to Preferred Embodiment 3.

FIG. 30 is a diagram illustrating an example of the operation flow of the substrate processing apparatus according to Preferred Embodiment 3.

FIG. 31 is a diagram illustrating an example of the operation flow of the substrate processing apparatus according to Preferred Embodiment 3.

FIG. 32 is a view schematically illustrating an example of the operation of the substrate processing apparatus according to Preferred Embodiment 3.

FIG. 33 is a diagram illustrating another example of the operation flow of the substrate processing apparatus according to Preferred Embodiment 3.

FIG. 34 is a view schematically illustrating another example of the operation of the substrate processing apparatus according to Preferred Embodiment 3.

FIG. 35 is a view illustrating the processing of pulling up the substrate from the first chemical liquid.

FIG. 36 is a view illustrating the processing of pulling up the substrate from the first chemical liquid.

FIG. 37 is an enlarged schematic plan view of a portion of a substrate processing apparatus according to Modification Example 3.

FIG. 38 is a diagram illustrating an example of the operation flow of the substrate processing apparatus according to Modification Example 3.

FIG. 39 is a view schematically illustrating an example of the operation f the substrate processing apparatus according to Modification Example 3.

FIG. 40 is a view schematically illustrating an example of the operation of a substrate processing apparatus according to Modification Example 4.

FIG. 41 is a view schematically illustrating an example of the operation of a substrate processing apparatus according to Modification Example 5.

FIG. 42 is an enlarged schematic plan view of a portion of a substrate processing apparatus according to Modification Example 6.

FIG. 43 is a cross-sectional view schematically illustrating a portion of a configuration of a first processing block included in the substrate processing apparatus according to Modification Example 6.

FIG. 44 is a view schematically illustrating an example of the operation of the substrate processing apparatus according to Modification Example 6.

FIG. 45 is an enlarged schematic plan view of a portion of a substrate processing apparatus according to Modification Example 7.

FIG. 46 is an enlarged schematic plan view of a portion of a substrate processing apparatus according to Modification Example 8.

FIG. 47 is a block diagram of the substrate processing apparatus according to Modification Example 8.

FIG. 48 is a cross-sectional view schematically illustrating a portion of a configuration of a first processing block included in a substrate processing apparatus according to Modification Example 9.

FIG. 49 is an enlarged schematic plan view of a portion of a substrate processing apparatus according to Modification Example 10.

FIG. 50 is a block diagram of the substrate processing apparatus according to Modification Example 10.

FIG. 51 is a cross-sectional view schematically illustrating a portion of a configuration of a first processing block included in the substrate processing apparatus according to Modification Example 10.

FIG. 52 is a cross-sectional view schematically illustrating a portion of a configuration of a first processing block included in a substrate processing apparatus according to Modification Example 11.

FIG. 53 is a cross-sectional view schematically illustrating a portion of a configuration of a first processing block included in a substrate processing apparatus according to Modification Example 12.

FIG. 54 is a cross-sectional view schematically illustrating a portion of a configuration of a first processing block included in a substrate processing apparatus according to Modification Example 13.

FIG. 55 is a cross-sectional view schematically illustrating a configuration of an immersion bath included in a substrate processing apparatus according to Modification Example 14.

FIG. 56 is a cross-sectional view schematically illustrating a portion of a configuration of a first processing block included in a substrate processing apparatus according to Preferred Embodiment 4.

FIG. 57 is another cross-sectional view schematically illustrating a portion of the configuration of the first processing block included in the substrate processing apparatus according to Preferred Embodiment 4.

FIG. 58 is still another cross-sectional view schematically illustrating a portion of the configuration of the first processing block included in the substrate processing apparatus according to Preferred Embodiment 4.

FIG. 59 is still another cross-sectional view schematically illustrating a portion of the configuration of the first processing block included in the substrate processing apparatus according to Preferred Embodiment 4.

FIG. 60 is a view illustrating another example of the paddle processing.

FIG. 61 is a view illustrating another example of the paddle processing.

FIG. 62 is a view illustrating another example of the paddle processing.

FIG. 63 is an enlarged schematic plan view of a portion of a substrate processing apparatus according to Preferred Embodiment 5.

FIG. 64 is a block diagram of the substrate processing apparatus according to Preferred Embodiment 5.

FIG. 65 is a view schematically illustrating an example of the operation of the substrate processing apparatus according to Preferred Embodiment 5.

FIG. 66 is a cross-sectional view schematically illustrating a portion of a configuration of a first processing block included in the substrate processing apparatus according to Preferred Embodiment 5.

FIG. 67 is an enlarged schematic plan view of a portion of a substrate processing apparatus according to Preferred Embodiment 6.

FIG. 68 is a block diagram of the substrate processing apparatus according to Preferred Embodiment 6.

FIG. 69 is a cross-sectional view schematically illustrating a portion of a configuration of a first processing block included in the substrate processing apparatus according to Preferred Embodiment 6.

FIG. 70 is a cross-sectional view schematically illustrating a portion of a configuration of a first processing block included in a substrate processing apparatus according to Preferred Embodiment 7.

FIG. 71 is a cross-sectional view schematically illustrating a portion of a configuration of a first processing block included in a substrate processing apparatus according to Preferred Embodiment 8.

FIG. 72 is a cross-sectional view schematically illustrating a portion of a configuration of a first processing block included in a substrate processing apparatus according to Preferred Embodiment 9.

FIG. 73 is a cross-sectional view schematically illustrating a portion of a configuration of a first processing block included in a substrate processing apparatus according to Preferred Embodiment 10.

### DETAILED DESCRIPTION OF PREFERRED EMBODIMENTS

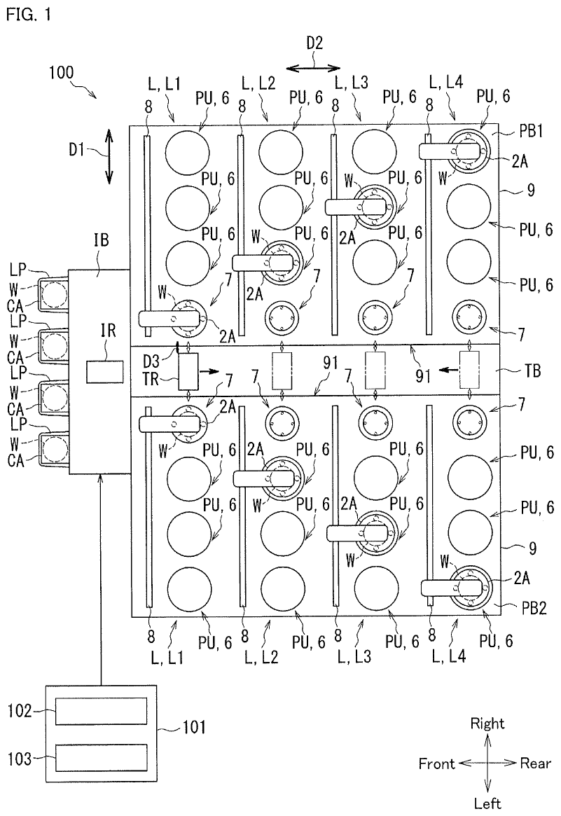

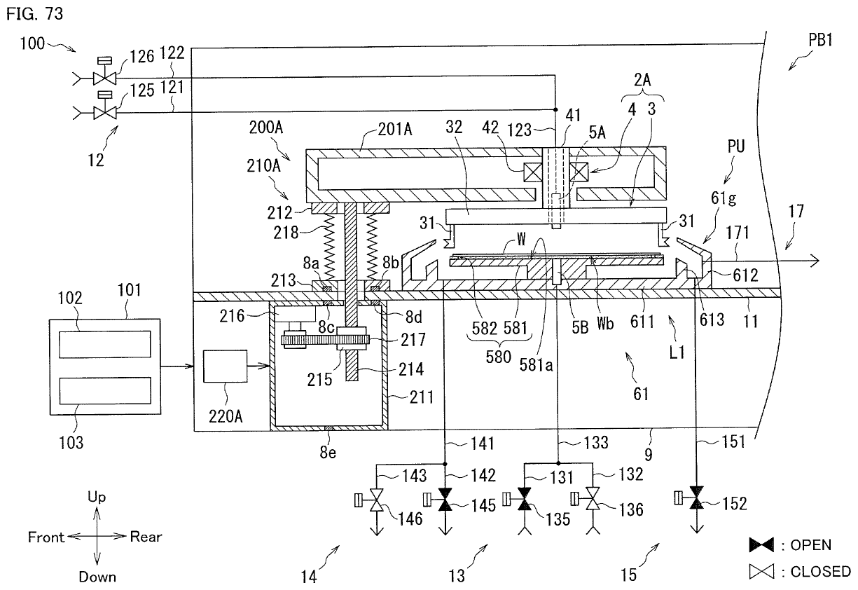

Hereinafter, preferred embodiments according to a substrate processing apparatus of the present invention will be described with reference to the drawings (FIGS. 1 to 73). However, the present invention is not restricted to the preferred embodiments described below and can be implemented in various modes within a scope not deviating from its gist. Regarding portions for which description is redundant, the description is at times omitted as appropriate. Also, in the figures, same or corresponding portions are provided with the same reference sign and description will not be repeated.

As a “substrate” to be subjected to substrate processing in the substrate processing apparatus according to the present invention, any of various substrates such as semiconductor wafers, glass substrates for photomasks, glass substrates for liquid crystal displays, glass substrates for plasma displays, substrates for field emission displays (FEDs), substrates for optical discs, substrates for magnetic disks, and substrates for magneto-optical disks is applicable. Hereinafter, the preferred embodiments of the present invention will be mainly described by taking a case where a disk-shaped semiconductor wafer is to be subjected to substrate processing as an example, but the substrate processing apparatus according to the present invention is similarly applicable to various substrates other than the above-described semiconductor wafer. Also, the shape of the substrate is not limited to a disk shape, and the substrate processing apparatus according to the present invention can be applied to substrates having various shapes.

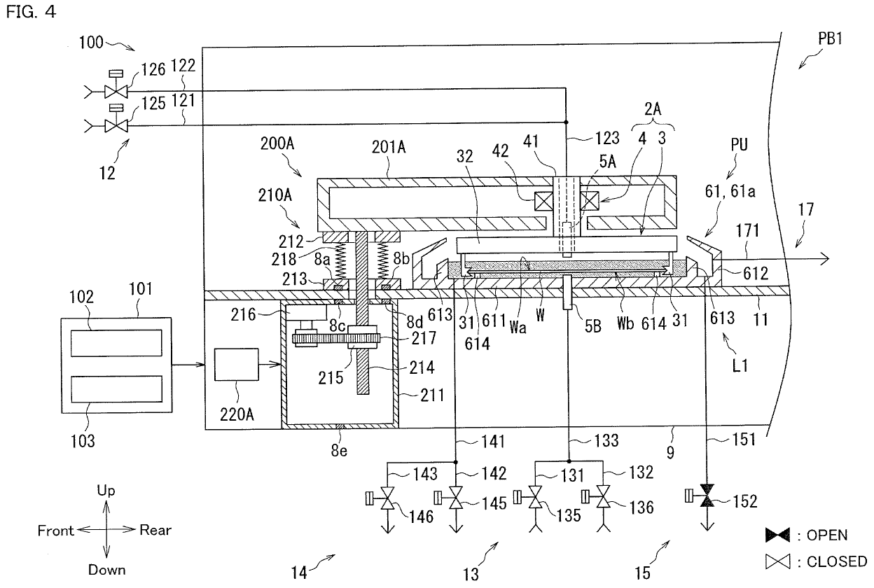

In the present specification, a: front-rear direction, a left-right direction, and an up-down direction are defined for easy understanding. The front-rear direction and the left-right direction are parallel to a horizontal direction, and the up-down direction is parallel to a vertical direction. In the present preferred embodiment, for example, a side on which a plurality of load ports LP are disposed with respect to a carry-in/carry-out block IB is a front side, and a side on which a transfer block TB is disposed with respect to the carry-in/carry-out block IB is a rear side (see FIG. 1). Also, a side on which a first processing block PB1 is disposed with respect to the transfer block TB is a right side, and a side on which a second processing block PB2 is disposed with respect to the transfer block TB is a left side (see FIG. 1). Also, a side on which a supporting arm 201A is disposed with respect to an upper substrate holding portion 2A is an upper side, and a side on which a supporting plate 11 is disposed with respect to an immersion bath 61a is a lower side (see FIG. 4).

### Preferred Embodiment 1

First, Preferred Embodiment 1 of the present invention will be described with reference to FIGS. 1 to 22. FIG. 1 is a schematic plan view of a substrate processing apparatus 100 according to Preferred Embodiment 1.

The substrate processing apparatus 100 is a single substrate processing type apparatus and processes substrates W one by one with a processing liquid. For example, the substrate processing apparatus 100 executes at least one of etching, surface processing, property imparting, film forming, removal of at least a portion of a film, and cleaning on each of the substrates W. The processing liquid includes a chemical liquid and a rinse liquid.

The chemical liquid for example, dilute hydrofluoric acid (DHF), hydrofluoric acid (HF), nitric hydrofluoric acid (mixed liquid of hydrofluoric acid and nitric acid (HNO3)), buffered hydrofluoric acid (BHF), ammonium fluoride, HFEG (mixed liquid of hydrofluoric acid and ethylene glycol), phosphoric acid (H3PO4), sulfuric acid, acetic acid, nitric acid, hydrochloric acid, ammonia water, hydrogen peroxide water, an organic acid (for example, citric acid, oxalic acid), an organic alkali (for example, TMAH: tetramethylammonium hydroxide), sulfuric acid/hydrogen peroxide water mixture (SPM), ammonia/hydrogen peroxide water mixture (SC1), hydrochloric acid/hydrogen peroxide water mixture (SC2), isopropyl alcohol (IPA), a surfactant, or a corrosion inhibitor.

The rinse liquid is water such as pure water. The pure water may be, for example, deionized water (DIW). More specifically, DIW may be ultrapure water. In the present preferred embodiment, the rinse liquid is DIW.

As illustrated in FIG. 1, the substrate processing apparatus 100 includes a plurality of load ports LP, a carry-in/carry-out block IB, a transfer block TB, a first processing block PB1, a second processing block PB2, and a controller 101.

A cassette CA is placed on each of the load ports LP. One or more substrates W are stacked and accommodated in the cassette CA. The cassette CA may be, for example, a front opening unified pod (FOUP), a standard mechanical inter face pod (SMIF), or an open cassette (OC).

The plurality of load ports LP are disposed adjacent to a front side of the carry-in/carry-out block IB. The substrate W is carried into the carry-in/carry-out block IB from the cassette CA. Further, the substrate W is carried out from the carry-in/carry-out block IB to the cassette CA.

The transfer block TB is disposed adjacent to a rear side of the carry-in/carry-out block IB. The substrate W is carried into the transfer block TB from the carry-in/carry-out block IB. In addition, the substrate W is carried out from the transfer block TB to the carry-in/carry-out block IB.

In the present preferred embodiment, the carry-in/carry-out block IB has an indexer robot IR. The transfer block TB has a transfer robot TR.

The indexer robot IR transfers the substrate W between the cassette CA and the carry-in/carry-out block IB. The indexer robot IR transfers the substrate W between the carry-in/carry-out block IB and the transfer block TB. Specifically, the indexer robot IR transfers the substrate W between the cassette CA and the transfer robot TR.

The transfer robot TR transfers the substrate W between the carry-in/carry-out block IB and the transfer block TB. The transfer robot TR transfers the substrate W between the transfer block TB and the first processing block PB1 and the second processing block PB2. Specifically, the transfer robot TR transfers the substrate W between the indexer robot IR, the first processing block PB1, and the second processing block PB2. The transfer robot TR is an example of a “transfer device.”

A placing table (path) on which the substrate W is temporarily placed may be provided between the indexer robot IR and the transfer robot TR, and the substrate W may be indirectly transferred between the indexer robot IR and the transfer robot TR through the placing table.

The first processing block PB1 is disposed adjacent to a right side of the transfer block TB. The second processing block PB2 is disposed adjacent to a left side of the transfer block TB. In other words, the transfer block TB is disposed adjacent to the first processing block PB1 and the second processing block PB2. The transfer block TB is disposed between the first processing block PB1 and the second processing block PB2. The substrate processing apparatus 100 may include a plurality of first processing blocks PB1 stacked in the up-down direction and a plurality of second processing blocks PB2 stacked in the up-down direction.

The transfer robot TR carries the substrate W received from the indexer robot IR into the first processing block PB1 or the second processing block PB2. The first processing block PB1 and the second processing block PB2 process the substrate W using the processing liquid. The transfer robot TR carries out the substrate W processed in the first processing block PB1 from the first processing block PB1 and transfers the substrate W to the indexer robot IR. Similarly, the transfer robot TR carries out the substrate W processed in the second processing block PB2 from the second processing block PB2 and transfers the substrate W to the indexer robot IR.

In the present preferred embodiment, the first processing block PB1 has a plurality of processing cup rows L. In Preferred Embodiment 1, the first processing block PB1 has four processing cup rows L (first processing cup row L1, second processing cup row L2, third processing cup row L3, and fourth processing cup row L4).

Each processing cup row L includes a plurality of processing cup portions 6 arranged in a first direction D1. In Preferred Embodiment 1, each processing cup row L includes three processing cup portions 6. The first direction D1 indicates a direction parallel to a direction D3 in which the substrate W moves between the transfer block TB and the first processing block PB1. Hereinafter, the direction D3 in which the substrate W moves between the transfer block TB and the first processing block PB1 may be referred to as a “moving direction D3.” In the present preferred embodiment, the moving direction D3 is parallel to the left-right direction. The first direction D1 is parallel to the left-right direction.

The moving direction D3 includes a direction (carry-in direction) in which the substrate W moves from the transfer block TB to the inside of the first processing block PB1 and a direction (carry-out direction) in which the substrate W moves from the first processing block PB1 to the inside of the transfer block TB. The first direction D1 includes a direction approaching the transfer block TB and a direction moving away from the transfer block TB.

The plurality of processing cup rows L are arranged in a second direction D2. The second direction D2 indicates a direction orthogonal to the first direction D1. In other words, the second direction D2 indicates a direction orthogonal to the direction D3 (moving direction D3) in which the substrate W moves between the transfer block TB and the first processing block PB1. In the present preferred embodiment, the second direction D2 is parallel to the front-rear direction. The second direction D2 includes a direction approaching the carry-in/carry-out block IB and a direction away from the carry-in/carry-out block IB. In other words, the second direction D2 includes a direction approaching the load port LP and a direction away from the load port LP.

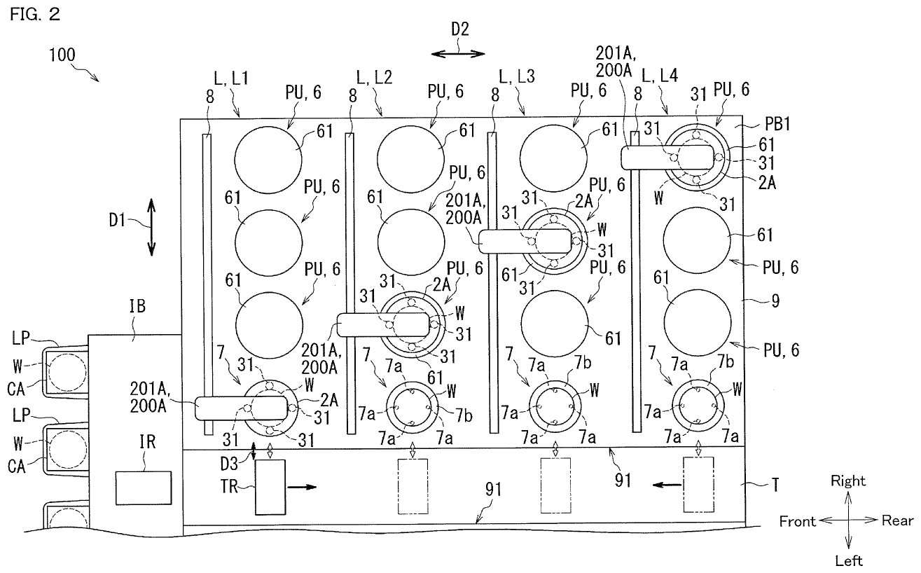

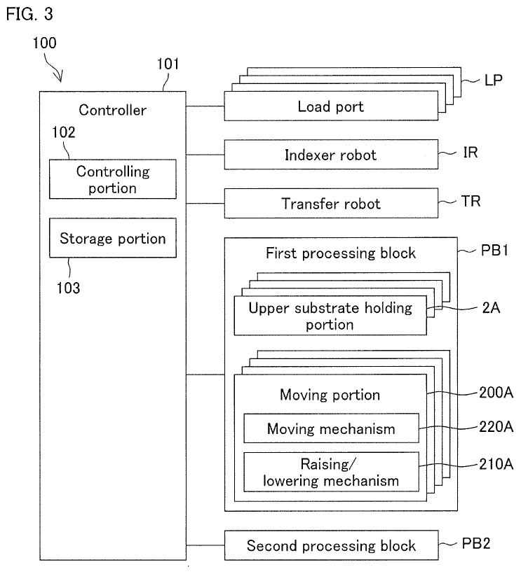

More specifically, the first processing block PB1 has a processing chamber 9, a plurality of upper substrate holding portions 2A, a plurality of substrate processing units PU, and a plurality of rail members 8. As will be described below with reference to FIGS. 2 and 3, the first processing block PB1 includes a plurality of moving portions 200A. The rail member 8 and the moving portion 200A are provided for each processing cup row L. Each of the plurality of substrate processing units PU includes a processing cup portion 6. In Preferred Embodiment 1, the first processing block PB1 further has a plurality of placing tables 7. The placing table 7 is provided for each processing cup row L.

Similarly to the first processing block PB1, the second processing block PB2 has a plurality of processing cup rows L. Specifically, similarly to the first processing block PB1, the second processing block PB2 includes a processing chamber 9, a plurality of upper substrate holding portions 2A, a plurality of substrate processing units PU, a plurality of rail members 8, a plurality of moving portions 200A, and a plurality of placing tables 7. The configuration of the second processing block PB2 is substantially similar to the configuration of the first processing block PB1. Therefore, hereinafter, the configuration of the first processing block PB1 will be described, and the description of the second processing block PB2 will be appropriately omitted.

The controller 101 controls the operation of each portion of the substrate processing apparatus 100. For example, the controller 101 controls the load port LP, the indexer robot IR, the transfer robot TR, the plurality of substrate processing units PU, and the plurality of upper substrate holding portions 2A. In addition, the controller 101 further controls the plurality of moving portions 200A which will be described later with reference to FIGS. 2 and 3. The controller 101 includes a controlling portion 102 and a storage portion 103.

The controlling portion 102 controls the operation of each portion of the substrate processing apparatus 100 on the basis of various types of information stored in the storage portion 103. The controlling portion 102 has, for example, a processor. The controlling portion 102 includes a central processing unit (CPU) or a micro processing unit (MPU) as the processor. Alternatively, the controlling portion 102 may have a general-purpose computing unit or a specialized computing unit.

The storage portion 103 stores various types of information for controlling the operation of the substrate processing apparatus 100. For example, the storage portion 103 stores data and a computer program. The data includes various recipe data. The recipe data includes a process recipe. The process recipe is data defining a processing procedure. The processing procedure indicates a procedure of processing the substrate W. The controlling portion 102 controls the operation of each portion of the substrate processing apparatus 100 according to the processing procedure. The processing of the substrate W includes chemical liquid processing, rinse processing, and drying processing. For example, in a case where the substrate W is processed using one type of chemical liquid, the chemical liquid processing, the rinse processing, and the drying processing are executed on one substrate W in that order.

The storage portion 103 has a main storage. The main storage includes, for example, a semiconductor memory. The storage portion 103 may further have an auxiliary storage. The auxiliary storage includes, for example, at least one of a semiconductor memory and a hard disk drive. The storage portion 103 may include a removable medium.

Subsequently, the substrate processing apparatus 100 according to Preferred Embodiment 1 will be described with reference to FIGS. 1 to 3. FIG. 2 is an enlarged schematic plan view of a portion of the substrate processing apparatus 100 according to Preferred Embodiment 1. FIG. 3 is a block diagram of the substrate processing apparatus 100 according to Preferred Embodiment 1.

As illustrated in FIG. 2, the first processing block PB1 further has the moving portion 200A provided for each processing cup row L. Each moving portion 200A has the supporting arm 201A. The processing chamber 9 has substantially a box shape. In Preferred Embodiment 1, the processing chamber 9 accommodates the plurality of upper substrate holding portions 2A, the plurality of processing cup portions 6 included in each processing cup row L, the plurality of supporting arms 201A, the plurality of placing tables 7, and the plurality of rail members 8.

Each placing table 7 supports the substrate W. Each placing table 7 may horizontally support the substrate W. Specifically, each placing table 7 has a plurality of supporting portions 7a and a supporting table 7b. Each of the supporting portions 7a protrudes from an upper surface of the supporting table 7b. The supporting portion 7a may have, for example, a circular columnar shape. Specifically, the plurality of supporting portions 7a are disposed on the same circumference and support the peripheral edge portion of the substrate W.

Each placing table 7 is arranged in a line in the first direction D1 (left-right direction) together with the plurality of processing cup portions 6 included in the corresponding processing cup row L. Specifically, in the first processing block PB1, each placing table 7 is disposed on the left side of the corresponding processing cup row L. That is, each placing table 7 is disposed at a position closer to the transfer block TB than the corresponding processing cup row L. Similarly, in the second processing block PB2 illustrated in FIG. 1, each placing table 7 is disposed at a position closer to the transfer block TB than the corresponding processing cup row L.

The processing chamber 9 has a side wall 91. The side wall 91 indicates a wall on a side of the transfer block TB among walls constituting the processing chamber 9. Specifically, the side wall 91 of the first processing block PB1 is a left side wall. The side wall 91 of the second processing block PB2 illustrated in FIG. 1 is a right side wall. Each placing table 7 is positioned between the corresponding processing cup row L and the side wall 91. Therefore, each placing table 7 is disposed at a position closer to the side wall 91 than the corresponding processing cup row L.

The side wall 91 has a plurality of carry-in/carry-out ports (not illustrated). Each carry-in/carry-out port is an opening formed in the side wall 91. The carry-in/carry-out port is provided for each processing cup row L. In Preferred Embodiment 1, the carry-in/carry-out port is provided for each placing table 7. Specifically, each carry-in/carry-out port is provided at a position adjacent to the corresponding placing table 7 in the left-right direction.

The transfer robot TR accesses the inside of the first processing block PB1 through each carry-in/carry-out port. For example, the transfer robot TR carries the substrate W into the first processing block PB1 through the carry-in/carry-out port corresponding to the first processing cup row L1 and places the substrate W on the placing table 7 corresponding to the first processing cup row L1. Specifically, the transfer robot TR places the substrate W on the plurality of supporting portions 7a. As a result, the substrate W is supported by the plurality of supporting portions 7a.

Specifically, the transfer robot TR is movable in the second direction D2 (front-rear direction). The substrate processing apparatus 100 further includes a moving mechanism (not illustrated) that moves the transfer robot TR in the second direction D2 (front-rear direction).

The moving mechanism that moves the transfer robot TR may have, for example, a ball screw mechanism and an electric motor capable of rotating forward and backward. The controlling portion 102 controls the moving mechanism such that the transfer robot TR is moved between positions adjacent to the carry-in/carry-out ports in the left-right direction. In other words, the controlling portion 102 controls the moving mechanism such that the transfer robot TR is moved between positions corresponding to the placing tables 7. That is, the controlling portion 102 controls the moving mechanism such that the transfer robot TR is moved between positions corresponding to the processing cup rows L.

The upper substrate holding portion 2A is provided for each processing cup row L. Each upper substrate holding portion 2A horizontally holds the substrate W. Specifically, each upper substrate holding portion 2A has a plurality of upper chuck members 31. The plurality of upper chuck members 31 grip the substrate W. When the plurality of upper chuck members 31 grip the substrate W, the substrate W is horizontally held. Specifically, the plurality of upper chuck members 31 are disposed on the same circumference and grip the peripheral edge portion of the substrate W. The upper chuck member 31 is an example of an “upper gripping member.”

Each moving portion 200A moves the corresponding upper substrate holding portion 2A in the first direction D1 (left-right direction). Each supporting arm 201A supports the corresponding upper substrate holding portion 2A. Each rail member 8 guides a raising/lowering mechanism 210A (see FIG. 3) coupled to the corresponding supporting arm 201A in the first direction D1 (left-right direction). Therefore, each upper substrate holding portion 2A is movable in the first direction D1 (left-right direction).

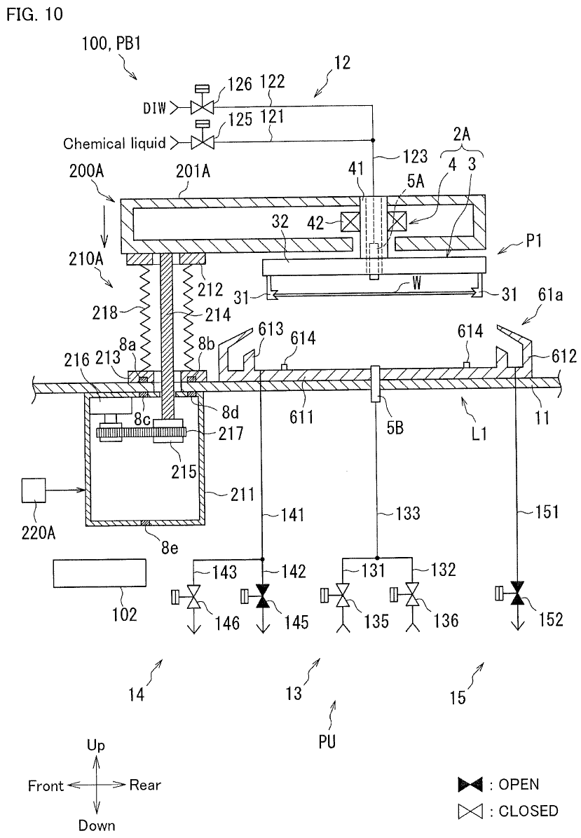

Each upper substrate holding portion 2A moves in the first direction D1 (left-right direction) in the space over the corresponding placing table 7 and the space over the corresponding processing cup row L. In Preferred Embodiment 1, the upper substrate holding portion 2A corresponding to the first processing cup row L1 moves in a facing position group including a facing position at which the upper substrate holding portion 2A faces the placing table 7 corresponding to the first processing cup row L1 and each facing position P1 (see FIG. 10) at which the upper substrate holding portion 2A faces each of the plurality of processing cup portions 6 included in the first processing cup row L1. The same applies to the upper substrate holding portions 2A corresponding to the second processing cup row L2 to the fourth processing cup row L4.

The facing position at which the upper substrate holding portion 2A faces the placing table 7 indicates a position at which the upper substrate holding portion 2A faces the placing table 7 in the up-down direction. Specifically, the facing position at which the upper substrate holding portion 2A faces the placing table 7 is a position over the placing table 7. Similarly, the facing position P1 at which the upper substrate holding portion 2A faces the processing cup portion 6 indicates a position at which the upper substrate holding portion 2A faces the processing cup portion 6 in the up-down direction. Specifically, the facing position P1 at which the upper substrate holding portion 2A faces the processing cup portion 6 is a position over the processing cup portion 6. Hereinafter, the facing position at which the upper substrate holding portion 2A faces the placing table 7 may be referred to as a “facing position of the placing table 7.” Similarly, the facing position P1 at which the upper substrate holding portion 2A faces the processing cup portion 6 may be referred to as a “facing position P1 of the processing cup portion 6.”

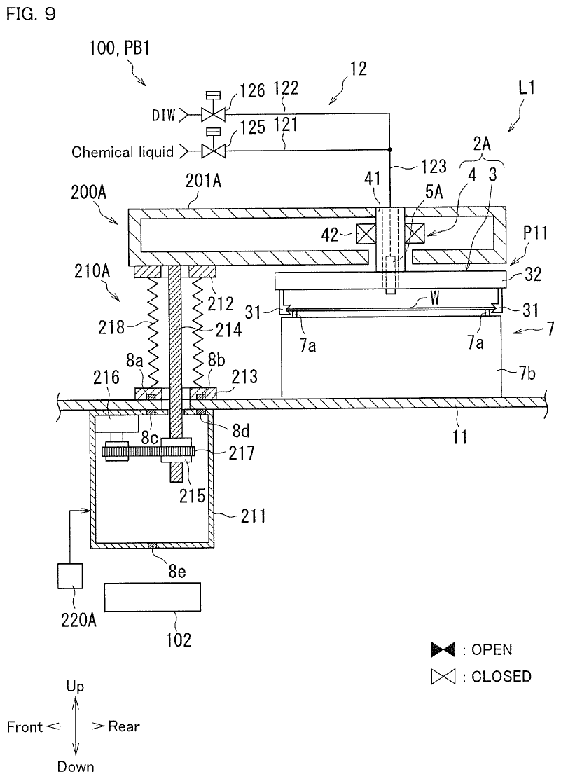

In the present preferred embodiment, each upper substrate holding portion 2A is able to be raised and lowered. Each upper substrate holding portion 2A is lowered from the facing position of the corresponding placing table 7 to a transfer position P11 (see FIG. 9) and grips the substrate W supported by the corresponding placing table 7. In addition, the upper substrate holding portion 2A corresponding to the first processing cup row L1 is lowered from the facing position P1 (see FIG. 10) of one processing cup portion 6 among the processing cup portions 6 included in the first processing cup row L1 and moves the substrate W to a position inside the one processing cup portion 6. The same applies to the upper substrate holding portions 2A corresponding to the second processing cup row L2 to the fourth processing cup row L4. The transfer position P11 indicates a position in the up-down direction.

The plurality of processing cup portions 6 included in each processing cup row L include a first processing cup portion 61. In Preferred Embodiment 1, all the processing cup portions 6 are the first processing cup portions 61. The substrate W is processed inside the first processing cup portion 61. In other words, the substrate processing is performed inside the first processing cup portion 61. Specifically, the first processing cup portion 61 holds the processing liquid in contact with the substrate W located inside the first processing cup portion 61 and processes the substrate W. Specifically, the substrate processing unit PU and the upper substrate holding portion 2A cooperate with each other to process the substrate W.

Each moving portion 200A is controlled by the controlling portion 102 such that the corresponding upper substrate holding portion 2A is moved. In the present preferred embodiment, each moving portion 200A has a moving mechanism 220A and a raising/lowering mechanism 210A. The moving mechanism 220A and the raising/lowering mechanism 210A are controlled by the controlling portion 102.

Each raising/lowering mechanism 210A raises and lowers the corresponding upper substrate holding portion 2A by raising and lowering the corresponding supporting arm 201A. For example, each raising/lowering mechanism 210A raises and lowers the corresponding upper substrate holding portion 2A between the facing position of the corresponding placing table 7 and the transfer position P11 (see FIG. 9) by raising and lowering the corresponding supporting arm 201A. The transfer position P11 is a position at which the substrate W is transferred between the placing table 7 and the upper substrate holding portion 2A. In addition, the raising/lowering mechanism 210A corresponding to the first processing cup row L1 lowers the corresponding upper substrate holding portion 2A by lowering the corresponding supporting arm 201A such that a position of the substrate W held by the corresponding upper substrate holding portion 2A changes from an over position of one processing cup portion 6 among the plurality of processing cup portions 6 included in the first processing cup row L1 to a position inside the one processing cup portion 6. The same applies to the raising/lowering mechanisms 210A corresponding to the second processing cup row L2 to the fourth processing cup row L4.

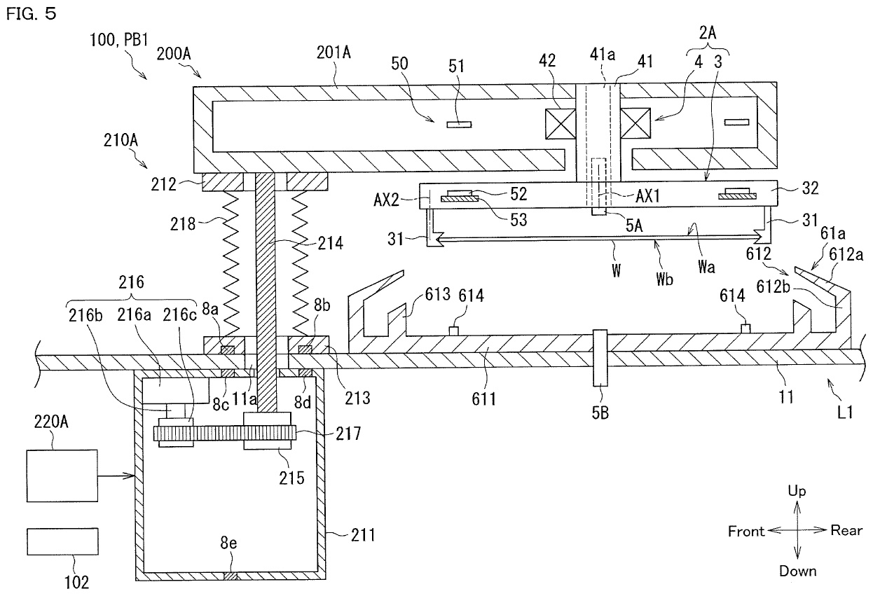

Each moving mechanism 220A moves the corresponding supporting arm 201A in the first direction D1 (left-right direction) by moving the corresponding raising/lowering mechanism 210A along the corresponding rail member 8. As a result, the corresponding upper substrate holding portion 2A moves in the first direction D1 (left-right direction). In Preferred Embodiment 1, each moving mechanism 220A moves the corresponding upper substrate holding portion 2A in the facing position group including the facing position of the corresponding placing table 7 and the facing position P1 (see FIG. 10) of each of the plurality of corresponding processing cup portions 6. Subsequently, the substrate processing apparatus 100 according to Preferred Embodiment 1 will be described with reference to FIGS. 1 to 5. FIG. 4 is a cross-sectional view schematically illustrating a portion of a configuration of the first processing block PB1 included in the substrate processing apparatus 100 according to Preferred Embodiment 1. FIG. 4 schematically illustrates the cross sections of the moving portion 200A and the immersion bath 61a as viewed from the left side. FIG. 5 is an enlarged view schematically illustrating the cross sections of the moving portion 200A and the immersion bath 61a as viewed from the left side. FIG. 4 illustrates the moving portion 200A, the upper substrate holding portion 2A, a first liquid supplying portion 12, and the substrate processing unit PU which correspond to the first processing cup row L1 of the first processing block PB1. FIG. 5 illustrates the moving portion 200A, the upper substrate holding portion 2A, and the immersion bath 61a which correspond to the first processing cup row L1 of the first processing block PB1.

As illustrated in FIG. 4, in Preferred Embodiment 1, the first processing block PB1 further has a supporting plate 11, a first liquid supplying portion 12, a second liquid supplying portion 13, a first draining portion 14, a second draining portion 15, and an exhaust portion 17 in addition to the plurality of upper substrate holding portions 2A, the plurality of placing tables 7, the plurality of rail members 8, the processing chamber 9, the plurality of processing cup rows L, and the plurality of moving portions 200A which are described with reference to FIGS. 1 to 3. Specifically, each of the substrate processing units PU described with reference to FIGS. 1 and 2 includes the first processing cup portion 61, the second liquid supplying portion 13, the first draining portion 14, the second draining portion 15, and the exhaust portion 17. In other words, the first processing block PB1 has the second liquid supplying portion 13, the first draining portion 14, the second draining portion 15, and the exhaust portion 17 for each first processing cup portion 61.

The processing chamber 9 further accommodates the plurality of moving portions 200A, the supporting plate 11, a portion of each first liquid supplying portion 12, a portion of each second liquid supplying portion 13, a portion of each first draining portion 14, a portion of each second draining portion 15, and a portion of each exhaust portion 17 in addition to the plurality of upper substrate holding portions 2A, the plurality of processing cup rows L, the plurality of placing tables 7, and the plurality of rail members 8.

The supporting plate 11 supports the plurality of processing cup portions 6 (see FIGS. 1 and 2) included in each processing cup row L. In Preferred Embodiment 1, the supporting plate 11 further supports the plurality of placing tables 7 (see FIGS. 1 and 2). Specifically, each of the processing cup portions 6 is horizontally supported by the supporting plate 11. Similarly, each placing table 7 is horizontally supported by the supporting plate 11. For example, the supporting plate 11 may be fixed to the side wall of the processing chamber 9 or may be supported by a column. The supporting plate 11 partitions the inside of the processing chamber 9 into an upper space and a lower space.

Each upper substrate holding portion 2A is located under the corresponding supporting arm 201A. Each upper substrate holding portion 2A has an upper holding portion 3, an upper rotating portion 4, and an upper nozzle portion 5A.

The upper holding portion 3 horizontally holds the substrate W. Specifically, the upper holding portion 3 further has an upper spin base 32 in addition to the plurality of upper chuck members 31 described with reference to FIG. 2. The upper spin base 32 is an example of an “upper base member.”

The plurality of upper chuck members 31 described with reference to FIG. 2 are provided on the upper spin base 32. Specifically, the upper spin base 32 has substantially a disk shape and supports the plurality of upper chuck members 31 in the horizontal posture. The plurality of upper chuck members 31 are disposed in a peripheral edge portion of the upper spin base 32 and protrudes downward from the upper spin base 32. The plurality of upper chuck members 31 grip the substrate W under the upper spin base 32. Therefore, the substrate W is horizontally held by the plurality of upper chuck members 31 under the upper spin base 32. The operation of the plurality of upper chuck members 31 is controlled by the controlling portion 102.

The upper rotating portion 4 rotates the substrate W integrally with the upper holding portion 3. The operation of the upper rotating portion 4 is controlled by the controlling portion 102. The upper rotating portion 4 has, for example, an upper shaft 41 and an upper motor body 42.

The lower end of the upper shaft 41 is coupled to the upper spin base 32. The upper shaft 41 protrudes upward from the upper spin base 32. The upper end of the upper shaft 41 is rotatably supported by the supporting arm 201A. A portion of the upper shaft 41 may be accommodated inside the supporting arm 201A.

The upper motor body 42 rotates the upper shaft 41. As a result, the upper spin base 32 rotates. The operation of the upper motor body 42 is controlled by the controlling portion 102. The upper motor body 42 is, for example, an electric motor. The upper motor body 42 may be accommodated inside the supporting arm 201A.

The upper nozzle portion 5A discharges the processing liquid downward. Specifically, the upper nozzle portion 5A has a tip end. The upper nozzle portion 5A discharges the processing liquid from the tip end surface of the upper nozzle portion 5A. In the present preferred embodiment, the tip end of the upper nozzle portion 5A protrudes from the lower surface of the upper spin base 32. The tip end surface of the upper nozzle portion 5A may be coplanar with the lower surface of the upper spin base 32. Alternatively, the tip end of the upper nozzle portion 5A may be located inside the upper spin base 32.

In Preferred Embodiment 1, the first processing cup portion 61 includes the immersion bath 61a. The immersion bath stores 61a the processing liquid. Specifically, the immersion bath 61a has a container shape with an open upper surface, and the processing liquid is stored in an inner space of the immersion bath 61a. The substrate W is immersed in the processing liquid stored in the immersion bath 61a in the horizontal posture. Specifically, the immersion bath 61a stores at least the chemical liquid out of the chemical liquid and the rinse liquid. When the substrate W is immersed in the chemical liquid in the immersion bath 61a, an upper surface Wa and a lower surface Wb of the substrate W are processed with the chemical liquid.

The outer shape of the immersion bath 61a may be, for example, a substantially circular shape in a plan view. The upper surface of the immersion bath 61a has an opening. The immersion bath 61a may have, for example, a bottomed cylindrical shape. Specifically, the immersion bath 61a has a bottom wall portion 611, a side wall portion 612, and an inner wall portion 613.

The bottom wall portion 611 may have, for example, substantially a disk shape. The side wall portion 612 protrudes upward from the bottom wall portion 611. The side wall portion 612 has an annular shape. The side wall portion 612 may have, for example, a circular annular shape. The side wall portion 612 may be connected to a peripheral edge portion of the bottom wall portion 611. The upper end of the side wall portion 612 forms an upper surface opening of the immersion bath 61a. In other words, the upper end of the side wall portion 612 constitutes an edge portion (inner peripheral edge portion) of the upper surface opening of the immersion bath 61a. The substrate W passes through the upper surface opening of the immersion bath 61a and moves to the inside of the immersion bath 61a. In addition, the substrate W passes through the upper surface opening of the immersion bath 61a and moves to the outside of the immersion bath 61a.

The inner wall portion 613 is provided inside the side wall portion 612 and protrudes upward from the bottom wall portion 611. The inner wall portion 613 is provided at a position away from the side wall portion 612. The upper end of the inner wall portion 613 is located at a position lower than that of the upper end of the side wall portion 612. The inner wall portion 613 has an annular shape. The inner wall portion 613 may have, for example, a circular annular shape. The processing liquid is stored inside the inner wall portion 613. Therefore, the substrate W is immersed in the processing liquid inside the inner wall portion 613. The processing liquid having overflowed from the inner wall portion 613 flows out between the inner wall portion 613 and the side wall portion 612.

The immersion bath 61a has a lower nozzle portion 5B. The lower nozzle portion 5B discharges the processing liquid upward. Specifically, the lower nozzle portion 5B has a tip end. The lower nozzle portion 5B discharges the processing liquid from the tip end surface of the lower nozzle portion 5B. In the present preferred embodiment, the tip end of the lower nozzle portion 5B protrudes from the bottom wall portion 611 of the immersion bath 61a. The tip end surface of the lower nozzle portion 5B may be coplanar with the upper surface of the bottom wall portion 611. Alternatively, the tip end of the lower nozzle portion 5B may be located inside the bottom wall portion 611.

The first liquid supplying portion 12 supplies the processing liquid to the upper nozzle portion 5A. In Preferred Embodiment 1, the first liquid supplying portion 12 selectively supplies one of the chemical liquid and the rinse liquid (in the present preferred embodiment, DIW) to the upper nozzle portion 5A. Specifically, the first liquid supplying portion 12 has a chemical liquid pipe portion 121, a rinse liquid pipe portion 122, a common pipe portion 123, a first opening/closing valve 125, and a second opening/closing valve 126.

The chemical liquid pipe portion 121, the rinse liquid pipe portion 122, and the common pipe portion 123 are tubular members through which a fluid flows. The first opening/closing valve 125 is provided in the chemical liquid pipe portion 121. The second opening/closing valve 126 is provided in the rinse liquid pipe portion 122. The first opening/closing valve 125 and the second opening/closing valve 126 are openable and closable. The opening and closing operations of the first opening/closing valve 125 and the second opening/closing valve 126 are controlled by the controlling portion 102.

The chemical liquid is supplied to the upstream end of the chemical liquid pipe portion 121. The downstream end of the chemical liquid pipe portion 121 is connected to the common pipe portion 123. The first opening/closing valve 125 opens and closes a flow path in the chemical liquid pipe portion 121. When the first opening/closing valve 125 is opened, the chemical liquid flows to the common pipe portion 123 through the chemical liquid pipe portion 121. As a result, the chemical liquid is supplied to the common pipe portion 123. When the first opening/closing valve 125 is closed, the flow of the chemical liquid through the chemical liquid pipe portion 121 is stopped. As a result, the supply of the chemical liquid to the common pipe portion 123 is stopped.

The rinse liquid is supplied to the upstream end of the rinse liquid pipe portion 122. The downstream end of the rinse liquid pipe portion 122 is connected to the common pipe portion 123. The second opening/closing valve 126 opens and closes a flow path in the rinse liquid pipe portion 122. When the second opening/closing valve 126 is opened, the rinse liquid flows to the common pipe portion 123 through the rinse liquid pipe portion 122. As a result, the rinse liquid is supplied to the common pipe portion 123. When the second opening/closing valve 126 is closed, the flow of the rinse liquid through the rinse liquid pipe portion 122 is stopped. As a result, the supply of the rinse liquid to the common pipe portion 123 is stopped.

The downstream end of the common pipe portion 123 is connected to the upper nozzle portion 5A. The controlling portion 102 controls the first opening/closing valve 125 and the second opening/closing valve 126 such that one of the chemical liquid and the rinse liquid selectively flows into the common pipe portion 123. Therefore, the common pipe portion 123 selectively supplies one of the chemical liquid and the rinse liquid to the upper nozzle portion 5A. When the chemical liquid is supplied to the upper nozzle portion 5A through the common pipe portion 123, the chemical liquid is discharged from the upper nozzle portion 5A. Similarly, when the rinse liquid is supplied to the upper nozzle portion 5A through the common pipe portion 123, the rinse liquid is discharged from the upper nozzle portion 5A.

The second liquid supplying portion 13 supplies the processing liquid to the lower nozzle portion 5B. In Preferred Embodiment 1, the second liquid supplying portion 13 selectively supplies one of the chemical liquid and the rinse liquid (in the present preferred embodiment, DIW) to the lower nozzle portion 5B. Specifically, the second liquid supplying portion 13 has a chemical liquid pipe portion 131, a rinse liquid pipe portion 132, a common pipe portion 133, a first opening/closing valve 135, and a second opening/closing valve 136. Since the configuration of the second liquid supplying portion 13 is similar to that of the first liquid supplying portion 12, the detailed description thereof will be omitted.

The first draining portion 14 drains the processing liquid stored in the immersion bath 61a to the outside of the immersion bath 61a. In the present preferred embodiment, the first draining portion 14 drains the processing liquid stored inside the inner wall portion 613 to the outside of the first processing block PB1.

Specifically, the first draining portion 14 has a common pipe portion 141, a drainage pipe portion 142, a recovery pipe portion 143, a first opening/closing valve 145, and a second opening/closing valve 146.

The common pipe portion 141, the drainage pipe portion 142, and the recovery pipe portion 143 are tubular members through which a fluid flows. The first opening/closing valve 145 is provided in the drainage pipe portion 142. The second opening/closing valve 146 is provided in the recovery pipe portion 143. The first opening/closing valve 145 and the second opening/closing valve 146 are openable and closable. The opening and closing operations of the first opening/closing valve 145 and the second opening/closing valve 146 are controlled by the controlling portion 102.

The upstream end of the common pipe portion 141 is connected to the bottom wall portion 611 of the immersion bath 61a inside the inner wall portion 613 and communicates with the inner space of the immersion bath 61a. The processing liquid stored inside the inner wall portion 613 flows into the upstream end of the common pipe portion 141. The upstream end of the drainage pipe portion 142 is connected to a downstream end of the common pipe portion 141. The downstream end of the drainage pipe portion 142 is connected to a drain tank (not illustrated). The drain tank is installed outside the first processing block PB1.

The first opening/closing valve 145 opens and closes a flow path in the drainage pipe portion 142. When the first opening/closing valve 145 is opened, the processing liquid stored inside the inner wall portion 613 is drained to the drainage pipe portion 142 through the common pipe portion 141. The processing liquid flowing into the drainage pipe portion 142 from the immersion bath 61a through the common pipe portion 141 is collected in the drain tank (not illustrated) through the drainage pipe portion 142. The drain tank stores the processing liquid drained from the immersion bath 61a. The processing liquid drained from the immersion bath 61a may be guided to waste liquid facilities of a factory where the substrate processing apparatus 100 is installed through the drainage pipe portion 142.

The upstream end of the recovery pipe portion 143 is connected to the downstream end of the common pipe portion 141. The downstream end of the recovery pipe portion 143 is connected to a chemical liquid tank 18 which will be described below with reference to FIG. 5. The second opening/closing valve 146 opens and closes a flow path in the recovery pipe portion 143. When the second opening/closing valve 146 is opened, the processing liquid stored inside the inner wall portion 613 is drained to the recovery pipe portion 143 through the common pipe portion 141. The processing liquid flowing into the recovery pipe portion 143 from the immersion bath 61a through the common pipe portion 141 is recovered in the chemical liquid tank 18 through the recovery pipe portion 143.

When the processing liquid stored inside the inner wall portion 613 is drained from the immersion bath 61a, the controlling portion 102 opens one of the first opening/closing valve 145 and the second opening/closing valve 146 and closes the other. In addition, when the processing liquid is stored inside the inner wall portion 613, the controlling portion 102 closes both of the first opening/closing valve 145 and the second opening/closing valve 146.

The second draining portion 15 drains the processing liquid collected between the inner wall portion 613 and the side wall portion 612 of the immersion bath 61a from the immersion bath 61a. Specifically, the second draining portion 15 has a drainage pipe portion 151 and an opening/closing valve 152. The drainage pipe portion 151 is a tubular member through which a fluid flows. The opening/closing valve 152 is provided in the drainage pipe portion 151. The opening/closing valve 152 is openable and closable. The opening and closing operations of the opening/closing valve 152 are controlled by the controlling portion 102.

The upstream end of the drainage pipe portion 151 is connected to the bottom wall portion 611 of the immersion bath 61a between the inner wall portion 613 and the side wall portion 612 and communicates with the inner space of the immersion bath 61a. The processing liquid collected between the inner wall portion 613 and the side wall portion 612 flows into the drainage pipe portion 151. The downstream end of the drainage pipe portion 151 is connected to a drain tank (not illustrated). Therefore, the processing liquid collected between the inner wall portion 613 and the side wall portion 612 of the immersion bath 61a is drained to the outside of the first processing block PB1.

The opening/closing valve 152 opens and closes a flow path in the drainage pipe portion 151. When the opening/closing valve 152 is opened, the processing liquid collected between the inner wall portion 613 and the side wall portion 612 is drained to the drain tank (not illustrated) through the drainage pipe portion 151.

The exhaust portion 17 exhausts gas from a space inside the immersion bath 61a to the outside of the first processing block PB1. Specifically, the exhaust portion 17 has an exhaust pipe portion 171. The exhaust pipe portion 171 is a tubular member through which a fluid flows.

The upstream end of the exhaust pipe portion 171 is connected to the side wall portion 612 of the immersion bath 61a and communicates with the space inside the immersion bath 61a. The downstream end of the exhaust pipe portion 171 may be connected to, for example, an exhaust device (not illustrated) provided in a factory where the substrate processing apparatus 100 is installed. The exhaust device constantly suctions the gas in the exhaust pipe portion 171 from the downstream end of the exhaust pipe portion 171. As a result, the gas is suctioned from the space inside the immersion bath 61a to the upstream end of the exhaust pipe portion 171.

The gas suctioned to the upstream end of the exhaust pipe portion 171 flows through the exhaust pipe portion 171 and is suctioned by an exhaust device (not illustrated). As a result, the gas inside the immersion bath 61a is exhausted to the outside of the first processing block PB1.

As illustrated in FIG. 5, in the present preferred embodiment, each rail member 8 includes a first rail member 8a, a second rail member 8b, a third rail member 8c, a fourth rail member 8d, and a fifth rail member 8e.

The first rail member 8a and the second rail member 8b are fixed to the upper surface of the supporting plate 11. The third rail member 8c and the fourth rail member 8d are fixed to the lower surface of the supporting plate 11. The fifth rail member 8e is fixed to a floor surface of the processing chamber 9 (see FIG. 4).

Each of the moving portions 200A has the supporting arm 201A, the raising/lowering mechanism 210A, and the moving mechanism 220A. The raising/lowering mechanism 210A has a housing 211, an upper plate 212, a lower plate 213, a screw shaft 214, a nut 215, an electric motor 216, a driving belt 217, and an elastic member 218.

The housing 211 is disposed under the supporting plate 11. The corresponding third rail member 8c and fourth rail member 8d are engaged with the upper wall portion of the housing 211. The corresponding fifth rail member 8e is engaged with the lower wall portion of the housing 211. Therefore, the housing 211 is guided in the first direction D1 (see FIG. 1) by the corresponding third rail member 8c, fourth rail member 8d, and fifth rail member 8e.

The lower plate 213 is disposed on the upper surface of the supporting plate 11. The lower plate 213 is engaged with the corresponding first rail member 8a and second rail member 8b. Therefore, the lower plate 213 is guided in the first direction D1 (see FIG. 1) by the corresponding first rail member 8a and second rail member 8b.

A through hole through which the screw shaft 214 is inserted is formed in the upper wall portion of the housing 211. The screw shaft 214 extends in the up-down direction and protrudes upward from the inside of the housing 211.

An elongated hole 11a extending in the first direction D1 (see FIG. 1) is formed in the supporting plate 11. The screw shaft 214 protruding from the housing 211 is inserted into the elongated hole 11a of the supporting plate 11.

The lower plate 213 is a plate-shaped member having a through hole in a central portion thereof. In other words, the lower plate 213 has an annular shape in a plan view. The lower plate 213 is disposed at a position at which the through hole of the lower plate 213 overlaps the elongated hole 11a of the supporting plate 11. The screw shaft 214 protruding from the elongated hole 11a of the supporting plate 11 is inserted into the through hole of the lower plate 213. The first rail member 8a is disposed in front of the elongated hole 11a of the supporting plate 11. The second rail member 8b is disposed behind the elongated hole 11a of the supporting plate 11.

The upper plate 212 is fixed to the lower surface of the supporting arm 201A. Similarly to the lower plate 213, the upper plate 212 is a plate-shaped member having a through hole in a central portion thereof. In other words, the upper plate 212 has an annular shape in a plan view. The upper plate 212 is disposed at a position at which the through hole of the upper plate 212 overlaps the through hole of the lower plate 213 in a plan view. The upper end of the screw shaft 214 protruding from the through hole of the lower plate 213 is inserted into the through hole of the upper plate 212 and fixed to the supporting arm 201A.

The screw shaft 214 is covered with the elastic member 218 between the supporting plate 11 and the supporting arm 201A. Specifically, the upper end of the elastic member 218 is fixed to the upper plate 212. The lower end of the elastic member 218 is fixed to the lower plate 213. The screw shaft 214 protruding from the supporting plate 11 is accommodated inside the elastic member 218. As a result, the screw shaft 214 protruding from the supporting plate 11 is covered with the elastic member 218. The elastic member 218 is able to be elastic in the up-down direction. The elastic member 218 is, for example, a bellows.

The screw shaft 214 and the nut 215 constitute a ball screw mechanism. Specifically, a screw groove is formed in the outer peripheral surface of the screw shaft 214. The nut 215 is accommodated in the housing 211. The nut 215 has a plurality of balls in contact with the screw groove of the screw shaft 214. When the nut 215 rotates about the center axis of the screw shaft 214, the screw shaft 214 moves in the up-down direction. As a result, the supporting arm 201A is raised and lowered, and the upper substrate holding portion 2A is raised and lowered.

The electric motor 216 is accommodated in the housing 211. The electric motor 216 generates a driving force for rotating the nut 215. In other words, the electric motor 216 generates a driving force for moving the screw shaft 214 in the up-down direction. Specifically, the electric motor 216 has a motor body 216a capable of rotating forward and backward, a motor shaft 216b, and a motor pulley 216c. The motor body 216a may be fixed to, for example, an inner wall surface of the housing 211. The motor body 216a rotates the motor shaft 216b. The motor pulley 216c is fixed to the tip end of the motor shaft 216b, for example.

The driving belt 217 is accommodated in the housing 211. The driving belt 217 is stretched around the outer peripheral surfaces of the motor pulley 216c and the nut 215. The driving belt 217 transmits a rotational force of the motor pulley 216c to the nut 215. When the motor pulley 216c rotates, the nut 215 rotates.

Each moving mechanism 220A moves the corresponding raising/lowering mechanism 210A in the first direction D1 (see FIG. 1). When the moving mechanism 220A moves the raising/lowering mechanism 210A in the first direction D1 (see FIG. 1), the upper substrate holding portion 2A moves in the first direction D1 (see FIG. 1). The moving mechanism 220A may have, for example, a ball screw mechanism and an electric motor that drives the ball screw mechanism, similarly to the raising/lowering mechanism 210A.

Subsequently, the upper substrate holding portion 2A will be described with reference to FIG. 5. As illustrated in FIG. 5, the plurality of upper chuck members 31 are disposed such that the center of the substrate W faces the center of the upper spin base 32. Therefore, when the upper holding portion 3 (plurality of upper chuck members 31) holds the substrate W, the center of the substrate W faces the center of the upper spin base 32.

The upper rotating portion 4 integrally rotates the substrate W and the upper holding portion 3 about a first rotational axis AX1 extending in the up-down direction. Specifically, the first rotational axis AX1 passes through the center of the upper spin base 32. Therefore, the upper spin base 32 rotates about the center of the upper spin base 32 as a rotational center. As a result, the substrate W rotates about the center of the substrate W as a rotational center.

The tip end surface of the upper nozzle portion 5A faces the center of the substrate W held by the upper holding portion 3. Therefore, the processing liquid is discharged from the upper nozzle portion 5A toward the center of the substrate W. Specifically, the upper substrate holding portion 2A has a through hole 41a. The through hole 41a passes through the upper shaft 41 and the upper spin base 32 along the first rotational axis AX1 in the up-down direction. The upper nozzle portion 5A is accommodated in the through hole 41a.

The upper substrate holding portion 2A further has an upper chuck driving mechanism 50 that rotates the plurality of upper chuck members 31. For example, the upper chuck driving mechanism 50 has a driving magnet 51, a driven magnet 52, and a raising/lowering plate 53.

The driving magnet 51 is disposed inside the supporting arm 201A. The driving magnet 51 may have an annular shape in a plan view. In this case, the driving magnet 51 is disposed to surround the first rotational axis AX1. Alternatively, the upper chuck driving mechanism 50 may have a plurality of driving magnets 51. In this case, the plurality of driving magnets 51 are disposed over one circumference to surround the first rotational axis AX1.

The driven magnet 52 and the raising/lowering plate 53 are disposed inside the upper spin base 32. The raising/lowering plate 53 has an annular shape in a plan view. The raising/lowering plate 53 is disposed to surround the first rotational axis AX1. The raising/lowering plate 53 is biased upward by a biasing member (not illustrated).

The driven magnet 52 is fixed to the raising/lowering plate 53. The driven magnet 52 is disposed at a position directly below the driving magnet 51. The driven magnet 52 may have an annular shape in a plan view. In this case, the driven magnet 52 is disposed to surround the first rotational axis AX1. Alternatively, the upper chuck driving mechanism 50 may have a plurality of driven magnets 52. In this case, the plurality of driven magnets 52 are disposed over one circumference to surround the first rotational axis AX1.

The driving magnet 51 moves in the up-down direction by a raising/lowering mechanism (not illustrated). The raising/lowering mechanism that raises and lowers the driving magnet 51 is controlled by the controlling portion 102. When the driving magnet 51 is raised and lowered, the driven magnet 52 and the raising/lowering plate 53 are raised and lowered.

The raising/lowering plate 53 is provided with a cam or a link mechanism that rotates each of the upper chuck members 31 between a holding position and a non-holding position. Therefore, when the raising/lowering plate 53 is raised and lowered, each of the upper chuck members 31 rotates between the holding position and the non-holding position. When each of the plurality of upper chuck members 31 rotates from the non-holding position to the holding position, the substrate W is gripped by the plurality of upper chuck members 31. Further, when each of the plurality of upper chuck members 31 rotates from the holding position to the non-holding position, the gripping of the substrate W by the plurality of upper chuck members 31 is released.

Subsequently, the immersion bath 61a will be described with reference to FIG. 5. As illustrated in FIG. 5, the side wall portion 612 includes an upper wall portion 612a and a lower wall portion 612b. The lower wall portion 612b extends upward from the bottom wall portion 611. The upper wall portion 612a is inclined inward from the upper end of the lower wall portion 612b in an up direction.

In the present preferred embodiment, the upper wall portion 612a (inclined portion) extends to a position at which the upper wall portion 612a faces the inner wall portion 613 in the up-down direction. The upper end of the upper wall portion 612a (upper end of the side wall portion 612) is located at a position higher than that of the upper end of the inner wall portion 613. The upper end of the upper wall portion 612a (upper end of the side wall portion 612) faces the inner wall portion 613 in the up-down direction. Therefore, a gap (space) is formed between the upper end of the upper wall portion 612a (upper end of the side wall portion 612) and the upper end of the inner wall portion 613.

The immersion bath 61a further has a plurality of supporting portions 614. The plurality of supporting portions 614 protrude from the bottom wall portion 611 of the immersion bath 61a. Specifically, the plurality of supporting portions 614 are disposed inside the inner wall portion 613. Each of the supporting portion 614 may have, for example, a circular columnar shape. The plurality of supporting portions 614 horizontally support the substrate W. Specifically, the plurality of supporting portions 614 are disposed on the same circumference and support the peripheral edge portion of the substrate W.

The upper end of each supporting portion 614 is located at a position lower than that of the upper end of the inner wall portion 613. In other words, the height of each supporting portion 614 from the bottom wall portion 611 is lower than the height of the inner wall portion 613 from the bottom wall portion 611. The substrate W supported by the plurality of supporting portions 614 is immersed in the processing liquid stored inside the inner wall portion 613.

The upper substrate holding portion 2A (upper holding portion 3) transfers the substrate W to and from the plurality of supporting portions 614. Specifically, the upper substrate holding portion 2A (upper holding portion 3) places the substrate W on the plurality of supporting portions 614. As a result, the substrate W is supported by the plurality of supporting portions 614. In addition, the upper substrate holding portion 2A (upper holding portion 3) grips the peripheral edge portion of the substrate W supported by the plurality of supporting portions 614 using the plurality of upper chuck members 31. As a result, the substrate W is held by the upper substrate holding portion 2A (upper holding portion 3).

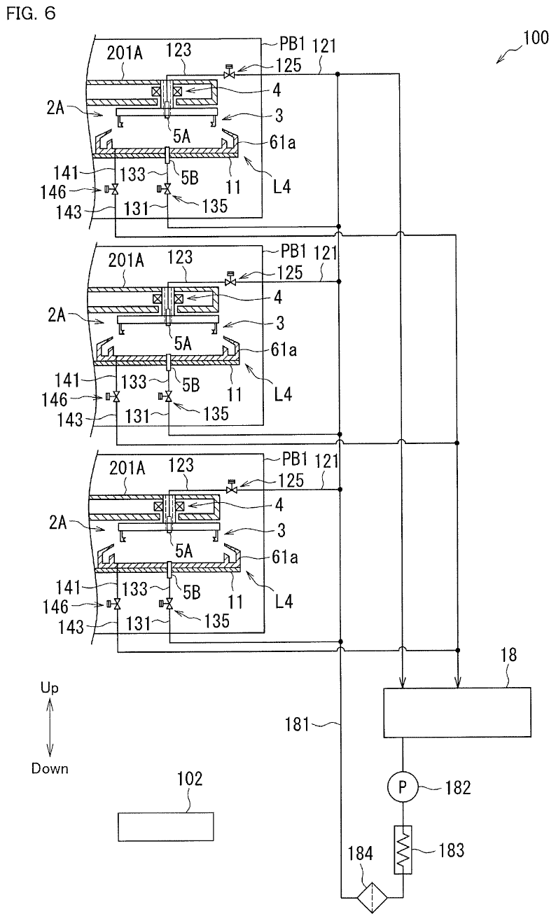

Subsequently, the substrate processing apparatus 100 according to Preferred Embodiment 1 will be described with reference to FIG. 6. FIG. 6 is a view illustrating a portion of a configuration of the substrate processing apparatus 100 according to Preferred Embodiment 1. FIG. 6 illustrates the supporting arm 201A, the upper substrate holding portion 2A, and the immersion bath 61a which correspond to the fourth processing cup row L4 of the first processing block PB1. As illustrated in FIG. 6, the substrate processing apparatus 100 further includes a chemical liquid tank 18, a circulation pipe 181, a circulation pump 182, a circulation heater 183, and a circulation filter 184.

A chemical liquid is stored in the chemical liquid tank 18. The circulation pipe 181 is a tubular member through which a fluid flows. One end and the other end of the circulation pipe 181 are connected to the chemical liquid tank 18. The circulation pump 182 is provided in the circulation pipe 181. The circulation pump 182 feeds the chemical liquid such that the chemical liquid flows in the circulation pipe 181 from one end toward the other end of the circulation pipe 181. As a result, the chemical liquid circulates through the circulation pipe 181 via the chemical liquid tank 18. The circulation pump 182 is controlled by the controlling portion 102.

One end of the recovery pipe portion 143 is further connected to the chemical liquid tank 18. The other end of the recovery pipe portion 143 is connected to the bottom wall portion 611 of the immersion bath 61a through the common pipe portion 141. Therefore, when the second opening/closing valve 146 is opened, the chemical liquid drained from the immersion bath 61a is recovered into the chemical liquid tank 18 through the common pipe portion 141 and the recovery pipe portion 143.

The circulation heater 183 is provided in the circulation pipe 181. The circulation heater 183 heats the chemical liquid flowing through the circulation pipe 181 to a target temperature. The circulation filter 184 is provided in the circulation pipe 181. The circulation filter 184 removes foreign matters from the chemical liquid flowing through the circulation pipe 181.

One end of the chemical liquid pipe portion 121 is connected to the circulation pipe 181. The other end of the chemical liquid pipe portion 121 is connected to the upper nozzle portion 5A through the common pipe portion 123. When the first opening/closing valve 125 is opened, the chemical liquid flowing into the chemical liquid pipe portion 121 from the circulation pipe 181 flows through the chemical liquid pipe portion 121 and the common pipe portion 123 toward the upper nozzle portion 5A. As a result, the chemical liquid is discharged from the upper nozzle portion 5A.

Similarly, one end of the chemical liquid pipe portion 131 is connected to the circulation pipe 181. The other end of the chemical liquid pipe portion 131 is connected to the lower nozzle portion 5B through the common pipe portion 133. When the first opening/closing valve 135 is opened, the chemical liquid flowing into the chemical liquid pipe portion 131 from the circulation pipe 181 flows through the chemical liquid pipe portion 131 and the common pipe portion 133 toward the lower nozzle portion 5B. As a result, the chemical liquid is discharged from the lower nozzle portion 5B.

The chemical liquid drained from the immersion bath 61a may not be recovered in the chemical liquid tank 18. In this case, the recovery pipe portion 143 and the second opening/closing valve 146 of the first draining portion 14 can be omitted.

As described above with reference to FIGS. 1 to 6, according to Preferred Embodiment 1, the chemical liquid can be supplied from the same circulation pipe 181 to the upper nozzle portion 5A and the lower nozzle portion 5B. Specifically, the substrate processing apparatus 100 according to Preferred Embodiment 1 processes the substrate W by immersing one substrate W in the chemical liquid in a horizontal posture. Therefore, it is not necessary to continuously supply the chemical liquid to the substrate W in a continuous flow. Therefore, the flow rate of the chemical liquid to be supplied to the upper nozzle portion 5A and the lower nozzle portion 5B (amount of the chemical liquid flowing per unit time) can be reduced as compared with the configuration in which the chemical liquid is continuously supplied to the substrate W in a continuous flow. As a result, the chemical liquid can be supplied from the same circulation pipe 181 to the upper nozzle portion 5A and the lower nozzle portion 5B.

According to Preferred Embodiment 1, since the chemical liquid can be supplied from the same circulation pipe 181 to the upper nozzle portion 5A and the lower nozzle portion 5B, the apparatus can be downsized.

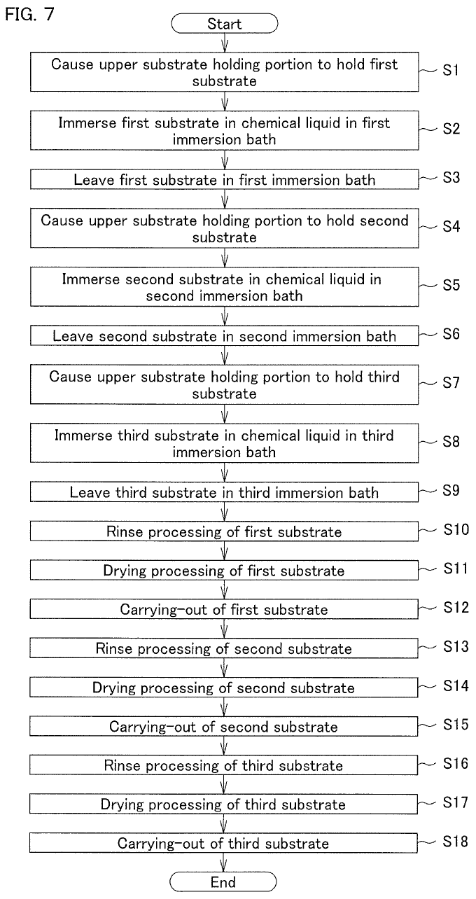

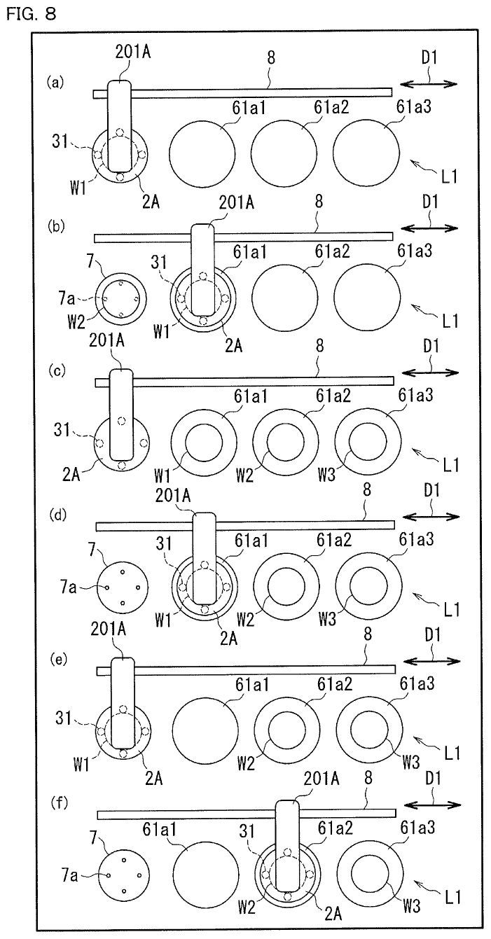

Subsequently, an example of the operation of the substrate processing apparatus 100 according to Preferred Embodiment 1 will be described with reference to FIGS. 1 to 7 and 8A to 8F using the first processing cup row L1 of the first processing block PB1 as an example. FIG. 7 is a diagram illustrating an example of the operation flow of the substrate processing apparatus 100 according to Preferred Embodiment 1. Specifically, FIG. 7 illustrates an example of the flow of processing executed by the controlling portion 102 when three substrates W (first substrate W1, second substrate W2, and third substrate W3) are processed in the first processing cup row L1 of the first processing block PB1. FIGS. 8A to 8F are views schematically illustrating an example of the operation of the substrate processing apparatus 100 according to Preferred Embodiment 1. Specifically, FIGS. 8A to 8F illustrate an example of the operation of the first processing block PB1 when three substrates W (first substrate W1, second substrate W2, and third substrate W3) are processed in the first processing cup row L1 of the first processing block PB1. Hereinafter, three immersion baths 61a included in the first processing cup row L1 of the first processing block PB1 may be referred to as a “first immersion bath 61al,” a “second immersion bath 61a2,” and a “third immersion bath 61a3” in order from the left side (in order from the placing table 7).

The processing illustrated in FIG. 7 includes steps S1 to S18. The processing illustrated in FIG. 7 starts when the transfer robot TR places the first substrate W1 on the placing table 7. As illustrated in FIGS. 7 and 8A, when the transfer robot TR is controlled such that the first substrate W1 is placed on the placing table 7, the controlling portion 102 controls the moving portion 200A (raising/lowering mechanism 210A and moving mechanism 220A) and the upper substrate holding portion 2A (upper chuck driving mechanism 50) such that the first substrate W1 placed on the placing table 7 is gripped by the plurality of upper chuck members 31. As a result, the first substrate W1 is horizontally held by the upper substrate holding portion 2A (upper holding portion 3) (step S1).

As illustrated in FIGS. 7 and 8B, when the first substrate W1 is held by the upper substrate holding portion 2A (upper holding portion 3), the controlling portion 102 controls the moving portion 200A (raising/lowering mechanism 210A and moving mechanism 220A) such that the first substrate W1 horizontally held by the upper substrate holding portion 2A (upper holding portion 3) is immersed in the chemical liquid stored in the first immersion bath 61a1 (step S2). As a result, an upper surface Wa and a lower surface Wb of the first substrate W1 are processed with the chemical liquid. Specifically, the moving portion 200A moves the first substrate W1 held by the upper substrate holding portion 2A (upper holding portion 3) to a position in contact with the upper surfaces of the plurality of supporting portions 614 provided in the first immersion bath 61a1.

When the first substrate W1 held by the upper substrate holding portion 2A (upper holding portion 3) is immersed in the chemical liquid in the first immersion bath 61al, the controlling portion 102 controls the upper substrate holding portion 2A (upper chuck driving mechanism 50) such that the gripping of the first substrate W1 by the plurality of upper chuck members 31 is released. As a result, the first substrate W1 is supported by the supporting portions 614 of the first immersion bath 61al, and the first substrate W1 is left in the first immersion bath 61a1 (step S3). The first substrate W1 left in the first immersion bath 61al is immersed in the chemical liquid.

While the first substrate W1 moves from the placing table 7 to the inside of the first immersion bath 61al, or after the first substrate W1 moves to the inside of the first immersion bath 61a1, the controlling portion 102 controls the transfer robot TR such that the second substrate W2 is placed on the placing table 7.

After the transfer robot TR places the second substrate W2 on the placing table 7, the controlling portion 102 causes the upper substrate holding portion 2A (upper holding portion 3) to hold the second substrate W2 as in step S1 (step S4).

When the second substrate W2 is held by the upper substrate holding portion 2A (upper holding portion 3), the controlling portion 102 immerses the second substrate W2 in the chemical liquid stored in the second immersion bath 61a2 as in step S2 (step S5). As a result, an upper surface Wa and a lower surface Wb of the second substrate W2 are processed with the chemical liquid.

When the second substrate W2 held by the upper substrate holding portion 2A (upper holding portion 3) is immersed in the chemical liquid in the second immersion bath 61a2, the controlling portion 102 leaves the second substrate W2 in the second immersion bath 61a2 as in step S3 (step S6).

While the second substrate W2 moves from the placing table 7 to the inside of the second immersion bath 61a2, or after the second substrate W2 moves to the inside of the second immersion bath 61a2, the controlling portion 102 controls the transfer robot TR such that the third substrate W3 is placed on the placing table 7.

After the transfer robot TR places the third substrate W3 on the placing table 7, the controlling portion 102 causes the upper substrate holding portion 2A (upper holding portion 3) to hold the third substrate W3 as in steps S1 and S4 (step S7).

When the third substrate W3 is held by the upper substrate holding portion 2A (upper holding portion 3), the controlling portion 102 immerses the third substrate W3 in the chemical liquid stored in the third immersion bath 61a3 as in steps S2 and S5 (step S8). As a result, an upper surface Wa and a lower surface Wb of the third substrate W3 are processed with the chemical liquid.

When the third substrate W3 held by the upper substrate holding portion 2A (upper holding portion 3) is immersed in the chemical liquid in the third immersion bath 61a3, the controlling portion 102 leaves the third substrate W3 in the third immersion bath 61a3 as in steps S3 and S6 (step S9). As a result, as illustrated in FIG. 8C, the first substrate W1, the second substrate W2, and the third substrate W3 are immersed in the chemical liquids in the first immersion bath 61al, the second immersion bath 61a2, and the third immersion bath 61a3, respectively, and operations of the chemical liquid processing for the first substrate W1, the second substrate W2, and the third substrate W3 are performed in parallel.

As illustrated in FIGS. 7 and 8D, when the time elapsed after the first substrate W1 is immersed in the chemical liquid becomes greater than or equal to a predetermined time (predetermined chemical liquid processing time), the controlling portion 102 controls the moving portion 200A (raising/lowering mechanism 210A and moving mechanism 220A) and the upper substrate holding portion 2A (upper chuck driving mechanism 50) such that the plurality of upper chuck members 31 grip the first substrate W1 supported by the plurality of supporting portions 614 of the first immersion bath 61a1. Then, the controlling portion 102 controls the first processing block PB1 such that the rinse processing of the first substrate W1 is executed inside the first immersion bath 61al (step S10).

The rinse processing indicates the processing of washing away the chemical liquid from the upper surface Wa and the lower surface Wb of the substrate W. In Preferred Embodiment 1, the controlling portion 102 discharges the rinse liquid from the upper nozzle portion 5A and the lower nozzle portion 5B toward the upper surface Wa and the lower surface Wb of the substrate W and washes away the chemical liquid from the upper surface Wa and the lower surface Wb of the substrate W. Specifically, the controlling portion 102 controls the moving portion 200A (raising/lowering mechanism 210A), the upper substrate holding portion 2A (upper motor body 42), the first liquid supplying portion 12 (second opening/closing valve 126), the second liquid supplying portion 13 (second opening/closing valve 136), and the first draining portion 14 (first opening/closing valve 145 or second opening/closing valve 146) such that the rinse processing is executed.

When the time elapsed from the start of the rinse processing of the first substrate W1 becomes greater than or equal to a predetermined time (predetermined rinse processing time), the controlling portion 102 controls the first processing block PB1 such that the drying processing of the first substrate W1 is executed inside the first immersion bath 61al (step S11).

The drying processing indicates processing for drying the substrate W. In Preferred Embodiment 1, the controlling portion 102 controls the upper rotating portion 4 (upper motor body 42) such that the substrate W is rotated at a high speed, thereby drying the substrate W.

As illustrated in FIGS. 7 and 8E, when the time elapsed from the start of the drying processing of the first substrate W1 becomes greater than or a equal to predetermined time (predetermined drying processing time), the controlling portion 102 controls the upper rotating portion 4 (upper motor body 42) such that the rotation of the first substrate W1 is stopped. Then, the controlling portion 102 controls the moving portion 200A (raising/lowering mechanism 210A and moving mechanism 220A) and the upper substrate holding portion 2A (upper chuck driving mechanism 50) such that the first substrate W1 is placed on the placing table 7. When the first substrate W1 is placed on the placing table 7, the controlling portion 102 controls the transfer robot TR such that the first substrate W1 is carried out from the first processing block PB1 (step S12).

As illustrated in FIGS. 7 and 8F, when the time elapsed after the second substrate W2 is immersed in the chemical liquid becomes greater than or equal to a predetermined time (predetermined chemical liquid processing time), the controlling portion 102 controls the first processing block PB1 such that the rinse processing of the second substrate W2 is executed inside the second immersion bath 61a2 as in step S10 (step S13).

When the time elapsed from the start of the rinse processing of the second substrate W2 becomes greater than or equal to a predetermined time (predetermined rinse processing time), the controlling portion 102 controls the first processing block PB1 such that the drying processing of the second substrate W2 is executed inside the second immersion bath 61a2 as in step S11 (step S14).

When the time elapsed from the start of the drying processing of the second substrate W2 becomes greater than or equal to a predetermined time (predetermined drying processing time), the controlling portion 102 carries out the second substrate W2 from the first processing block PB1 as in step S12 (step S15).

When the time elapsed after the third substrate W3 is immersed in the chemical liquid becomes greater than or equal to a predetermined time (predetermined chemical liquid processing time), the controlling portion 102 controls the first processing block PB1 such that the rinse processing of the third substrate W3 is executed inside the third immersion bath 61a3 as in steps S10 and S13 (step S16).

When the time elapsed from the start of the rinse processing of the third substrate W3 becomes greater than or equal to a predetermined time (predetermined rinse processing time), the controlling portion 102 controls the first processing block PB1 such that the drying processing of the third substrate W3 is executed inside the third immersion bath 61a3 as in steps S11 and S14 (step S17).

When the time elapsed from the start of the drying processing of the third substrate W3 becomes greater than or equal to a predetermined time (predetermined drying processing time), the controlling portion 102 carries out the third substrate W3 from the first processing block PB1 as in steps S12 and S15 (step S18). As a result, the operation illustrated in FIG. 7 ends.

As described above with reference to FIGS. 1 to 7 and 8A to 8F, according to Preferred Embodiment 1, the first processing block PB1 has a plurality of immersion baths 61a. Therefore, operations of the chemical liquid processing for the plurality of substrates W can be executed in parallel.

Subsequently, the operation of the substrate processing apparatus 100 according to Preferred Embodiment 1 will be described with reference to FIGS. 1 to 20. FIGS. 9 to 20 are views illustrating the operation of the first processing block PB1 when one substrate W is processed in the first processing cup row L1 of the first processing block PB1. FIG. 9 schematically illustrates a cross section of the moving portion 200A as viewed from the left side. FIGS. 10 to 20 schematically illustrate the cross sections of the moving portion 200A and the immersion bath 61a as viewed from the left side.

FIG. 9 illustrates the upper chuck member 31 that grips the substrate W placed on the placing table 7. As illustrated in FIG. 9, when the substrate W is placed on the placing table 7, the controlling portion 102 controls the moving mechanism 220A such that the upper substrate holding portion 2A is moved to the facing position of the placing table 7 and then controls the raising/lowering mechanism 210A such that the upper substrate holding portion 2A is lowered to the transfer position P11. Then, the controlling portion 102 controls the upper chuck driving mechanism 50 such that the plurality of upper chuck members 31 grip the substrate W. When the substrate W placed on the placing table 7 is held by the upper substrate holding portion 2A, the first opening/closing valve 125 and the second opening/closing valve 126 of the first liquid supplying portion 12 are in the closed state.

FIG. 10 illustrates the upper substrate holding portion 2A moved to the facing position P1 of one immersion bath 61a among the plurality of immersion baths 61a included in the first processing cup row L1. As illustrated in FIG. 10, after the plurality of upper chuck members 31 grip the substrate W placed on the placing table 7, the controlling portion 102 controls the raising/lowering mechanism 210A and the moving mechanism 220A such that the upper substrate holding portion 2A is moved to the facing position P1 of the immersion bath 61a. When the upper substrate holding portion 2A is located at the facing position P1 of the immersion bath 61a, the substrate W held by the upper substrate holding portion 2A is located over the immersion bath 61a. At this time, the first opening/closing valve 125 and the second opening/closing valve 126 of the first liquid supplying portion 12 and the first opening/closing valve 135 and the second opening/closing valve 136 of the second liquid supplying portion 13 are in the closed state, and the first opening/closing valve 145 of the first draining portion 14 and the opening/closing valve 152 of the second draining portion 15 are in the open state.

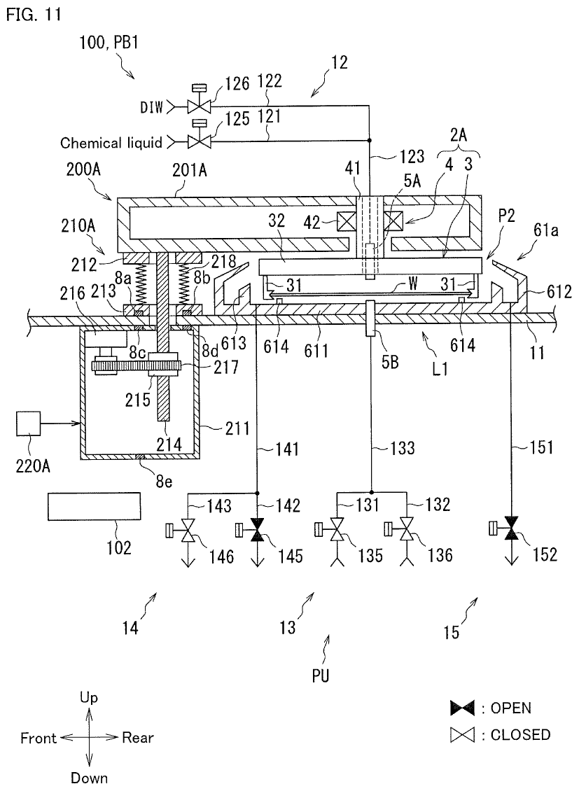

FIG. 11 illustrates the upper substrate holding portion 2A lowered from the facing position P1 of the immersion bath 61a to a first processing position P2. The first processing position P2 indicates a position in the up-down direction.

As illustrated in FIG. 11, after the upper substrate holding portion 2A is moved to the facing position P1 of the immersion bath 61a, the controlling portion 102 controls the raising/lowering mechanism 210A such that the upper substrate holding portion 2A is lowered from the facing position P1 of the immersion bath 61a to the first processing position P2. When the upper substrate holding portion 2A is lowered to the first processing position P2, the substrate W is lowered from the position over the immersion bath 61a to the position inside the immersion bath 61a. Therefore, when the upper substrate holding portion 2A is located at the first processing position P2, the substrate W is located inside the inner wall portion 613. When the upper substrate holding portion 2A is located at the first processing position P2, the substrate W is located at a position higher than those of the plurality of supporting portions 614.

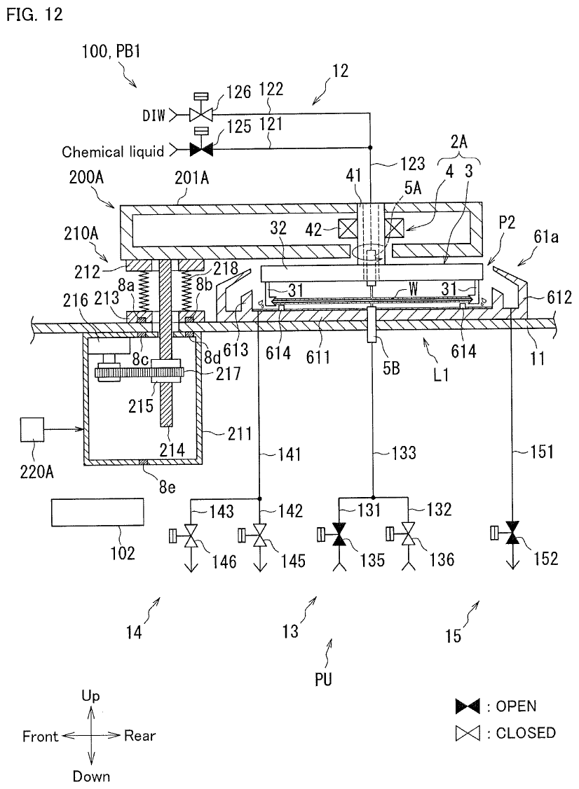

FIG. 12 illustrates the first processing block PB1 when the chemical liquid is stored in the immersion bath 61a. As illustrated in FIG. 12, after the upper substrate holding portion 2A is moved to the first processing position P2, the controlling portion 102 switches the first opening/closing valve 125 of the first liquid supplying portion 12 and the first opening/closing valve 135 of the second liquid supplying portion 13 from the closed state to the open state and closes the first opening/closing valve 145 and the second opening/closing valve 146 of the first draining portion 14. The controlling portion 102 controls the upper rotating portion 4 (upper motor body 42) such that the substrate W is rotated. As a result, the chemical liquid is discharged from the upper nozzle portion 5A toward the center of the upper surface Wa of the substrate W, the chemical liquid is discharged from the lower nozzle portion 5B toward the center of the lower surface Wb of the substrate W, and the chemical liquid flowing down from the upper surface Wa and the lower surface Wb of the substrate W is stored inside the inner wall portion 613.

By discharging the chemical liquid from the upper nozzle portion 5A and the lower nozzle portion 5B toward the rotating substrate W, the chemical liquid immediately wets and spreads over the entire upper surface Wa and the entire lower surface Wb of the substrate W. As a result, for example, it is possible to suppress a difference in processing time with the chemical liquid between the central portion and the outer peripheral portion of the substrate W. Further, by discharging the chemical liquid from the upper nozzle portion 5A and the lower nozzle portion 5B, it is possible to suppress a difference in processing time with the chemical liquid between the upper surface Wa and the lower surface Wb of the substrate W.

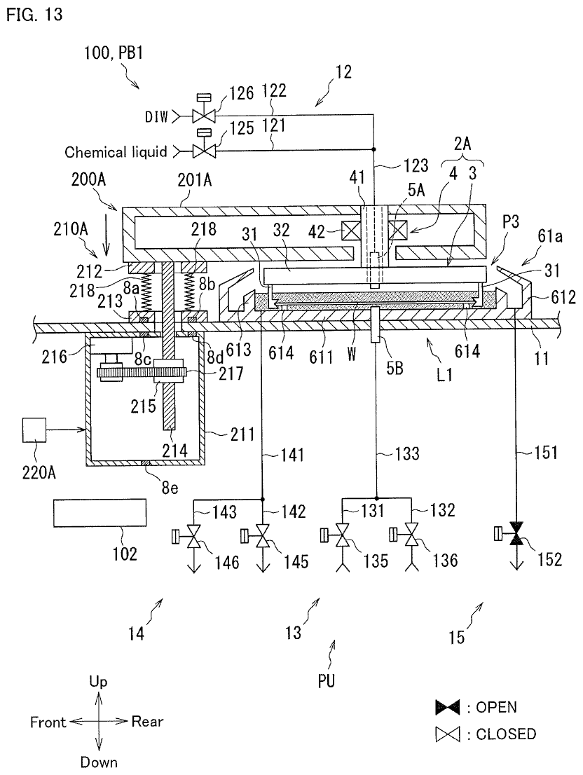

FIG. 13 illustrates the substrate W immersed in the chemical liquid stored in the immersion bath 61a. As illustrated in FIG. 13, the substrate W is immersed in the chemical liquid stored inside the inner wall portion 613. Specifically, when a liquid level of the chemical liquid rises to a position higher than that of the upper surface Wa of the substrate W, the controlling portion 102 switches the first opening/closing valve 125 of the first liquid supplying portion 12 and the first opening/closing valve 135 of the second liquid supplying portion 13 from the open state to the closed state to stop the discharge of the chemical liquid from the upper nozzle portion 5A and the lower nozzle portion 5B. As a result, the substrate W is immersed in the chemical liquid inside the immersion bath 61a. For example, when a predetermined time has elapsed from the start of the discharge of the chemical liquid from the upper nozzle portion 5A and the lower nozzle portion 5B, the controlling portion 102 may stop the discharge of the chemical liquid.

When the discharge of the chemical liquid is stopped, the controlling portion 102 controls the upper rotating portion 4 (upper motor body 42) such that the rotation of the substrate W is stopped. Then, the controlling portion 102 controls the raising/lowering mechanism 210A such that the upper substrate holding portion 2A is lowered from the first processing position P2 to a second processing position P3. The second processing position P3 indicates a position in the up-down direction. The second processing position P3 is a position at which the substrate W is in contact with the upper surfaces of the plurality of supporting portions 614.

The timing to stop the discharge of the chemical liquid is not particularly limited as long as it is the timing at which the liquid level of the chemical liquid rises to a position higher than that of the upper surface Wa of the substrate W. For example, the discharge of the chemical liquid may be stopped after the chemical liquid overflows the inner wall portion 613. The timing to stop the rotation of the substrate W is not particularly limited as long as it is before the upper substrate holding portion 2A reaches the second processing position P3 (before the substrate W comes into contact with the upper surfaces of the plurality of supporting portions 614).

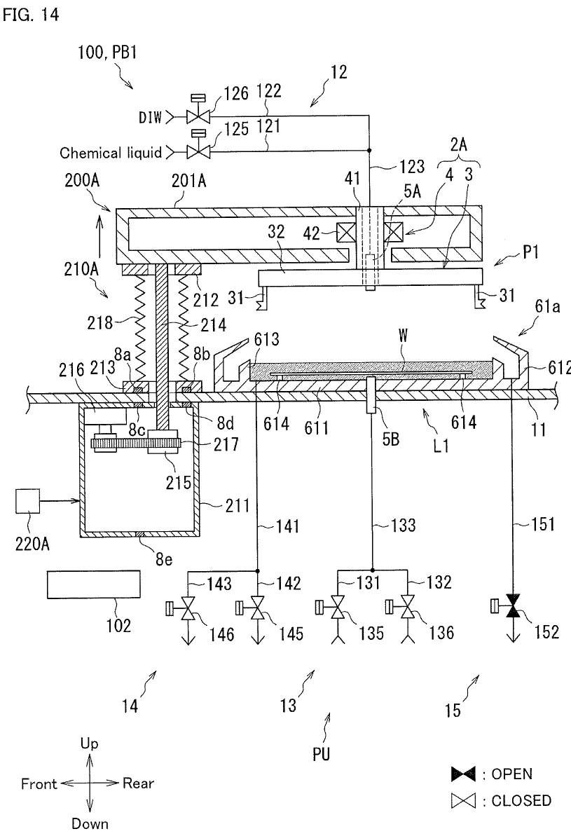

FIG. 14 illustrates the substrate W left in the immersion bath 61a. As illustrated in FIG. 14, after the upper substrate holding portion 2A is moved from the first processing position P2 to the second processing position P3, the controlling portion 102 controls the upper chuck driving mechanism 50 such that the gripping of the substrate W by the plurality of upper chuck members 31 is released. When the gripping of the substrate W by the plurality of upper chuck members 31 is released, the controlling portion 102 controls the raising/lowering mechanism 210A such that the upper substrate holding portion 2A is raised from the second processing position P3 to the facing position P1 of the immersion bath 61a.

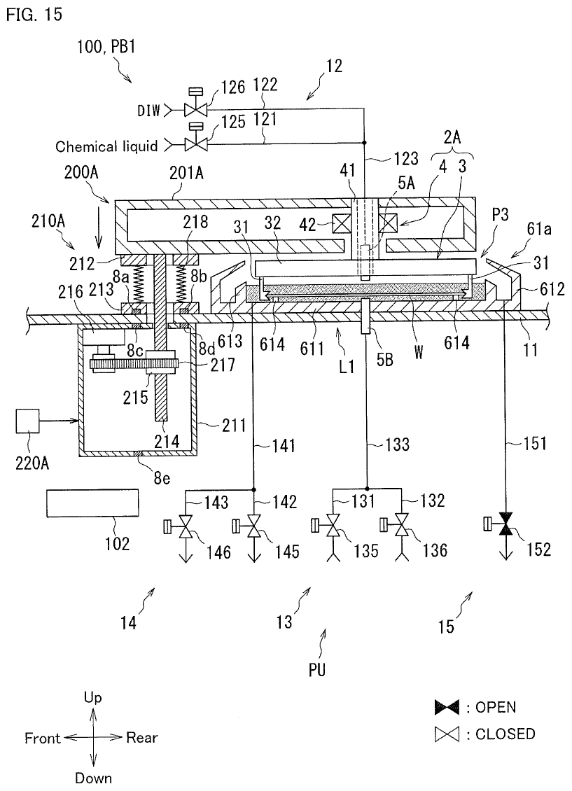

FIG. 15 illustrates the first processing block PB1 before starting the drainage of the chemical liquid. As illustrated in FIG. 15, before starting the drainage of the chemical liquid, the controlling portion 102 controls the moving portion 200A (raising/lowering mechanism 210A and moving mechanism 220A) such that the upper substrate holding portion 2A is moved to the second processing position P3. Then, the controlling portion 102 controls the upper chuck driving mechanism 50 such that the plurality of upper chuck members 31 grip the substrate W supported by the plurality of supporting portions 614.

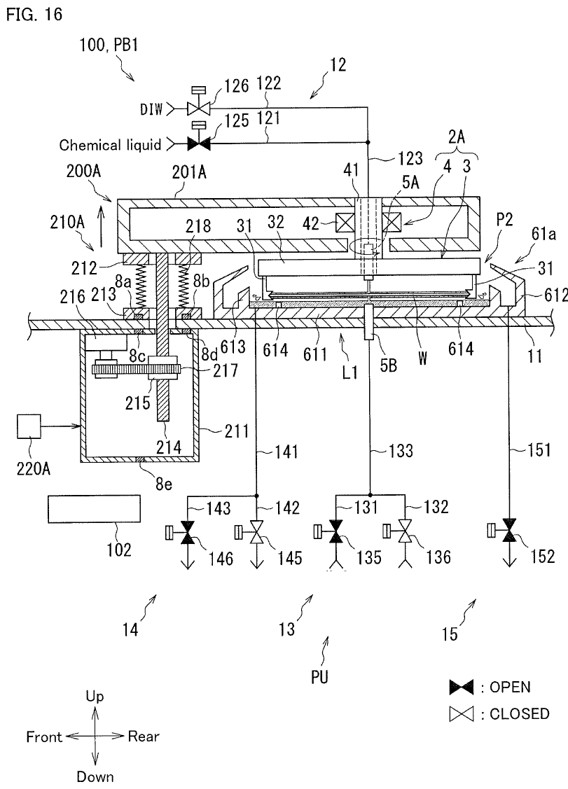

FIG. 16 illustrates the first processing block PB1 when the chemical liquid is drained. As illustrated in FIG. 16, when the plurality of upper chuck members 31 grip the substrate W, the controlling portion 102 controls the raising/lowering mechanism 210A such that the upper substrate holding portion 2A is raised from the second processing position P3 to the first processing position P2. Then, the controlling portion 102 switches one of the first opening/closing valve 145 and the second opening/closing valve 146 of the first draining portion 14 from the closed state to the open state. As a result, the chemical liquid is drained from the immersion bath 61a.

When the chemical liquid is drained, the controlling portion 102 controls the upper rotating portion 4 (upper motor body 42) such that the substrate W is rotated and switches the first opening/closing valve 125 of the first liquid supplying portion 12 and the first opening/closing valve 135 of the second liquid supplying portion 13 from the closed state to the open state. As a result, when the chemical liquid is drained, the chemical liquid is discharged from the upper nozzle portion 5A and the lower nozzle portion 5B toward the upper surface Wa and the lower surface Wb of the rotating substrate W, and the chemical liquid wets and spreads over the upper surface Wa and the lower surface Wb of the substrate W. Therefore, it is possible to suppress the substrate W from being dried, and thus it is possible to suppress collapse of a pattern and generation of particles. The total flow rate at which the chemical liquid is discharged from the upper nozzle portion 5A and the lower nozzle portion 5B is smaller than the flow rate at which the chemical liquid is discharged through the first draining portion 14.

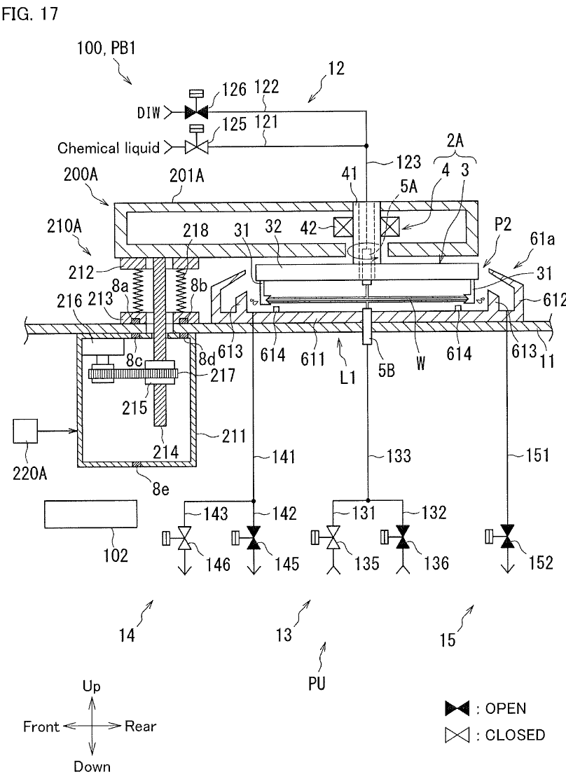

FIG. 17 is a view illustrating a first step of the rinse processing. As illustrated in FIG. 17, when a predetermined time has elapsed from the start of the drainage of the chemical liquid, the controlling portion 102 switches the first opening/closing valve 125 of the first liquid supplying portion 12 and the first opening/closing valve 135 of the second liquid supplying portion 13 from the open state to the closed state and switches the second opening/closing valve 126 of the first liquid supplying portion 12 and the second opening/closing valve 136 of the second liquid supplying portion 13 from the closed state to the open state. As a result, the rinse liquid is discharged from the upper nozzle portion 5A and the lower nozzle portion 5B toward the upper surface Wa and the lower surface Wb of the rotating substrate W, the rinse liquid wets and spreads over the upper surface Wa and the lower surface Wb of the substrate W, and the chemical liquid adhering to the upper surface Wa and the lower surface Wb of the substrate W is washed away from the substrate W with the rinse liquid.

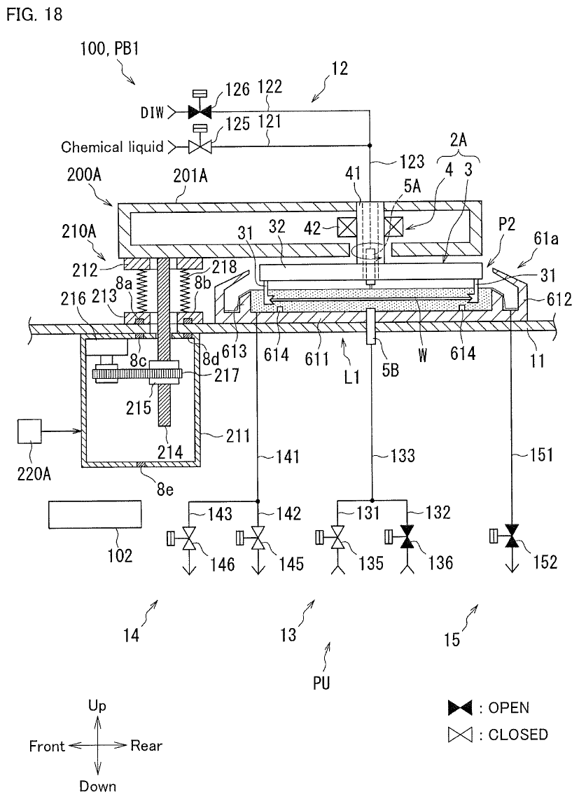

FIG. 18 is a view illustrating a second step of the rinse processing. As illustrated in FIG. 18, when a predetermined time has elapsed from the start of the discharge of the rinse liquid, the controlling portion 102 closes the first opening/closing valve 145 and the second opening/closing valve 146 of the first draining portion 14. As a result, the rinse liquid is stored inside the inner wall portion 613, and the substrate W is immersed in the rinse liquid. The controlling portion 102 continues the rotation of the substrate W from the first step to the second step of the rinse processing.

In the present preferred embodiment, even after a space inside the inner wall portion 613 is filled with the rinse liquid, the discharge of the rinse liquid from the upper nozzle portion 5A and the lower nozzle portion 5B is continued. Therefore, the rinse liquid overflows the inner wall portion 613, and the rinse liquid flows into a space between the side wall portion 612 and the inner wall portion 613. As a result, the surface constituting the space between the side wall portion 612 and the inner wall portion 613 is cleaned with the overflowing rinse liquid. The rinse liquid collected in the space between the side wall portion 612 and the inner wall portion 613 is drained from the immersion bath 61a through the second draining portion 15.

When a predetermined time has elapsed from the start of the storage of the rinse liquid, the controlling portion 102 switches the first opening/closing valve 145 of the first draining portion 14 from the closed state to the open state. As a result, the rinse liquid is drained from the immersion bath 61a.

Similarly to the drainage of the chemical liquid, when the rinse liquid is drained, the controlling portion 102 rotates the substrate W and discharges the rinse liquid from the upper nozzle portion 5A and the lower nozzle portion 5B. Through this processing, the drying of the substrate W can be suppressed, and pattern collapse and generation of particles can be suppressed.

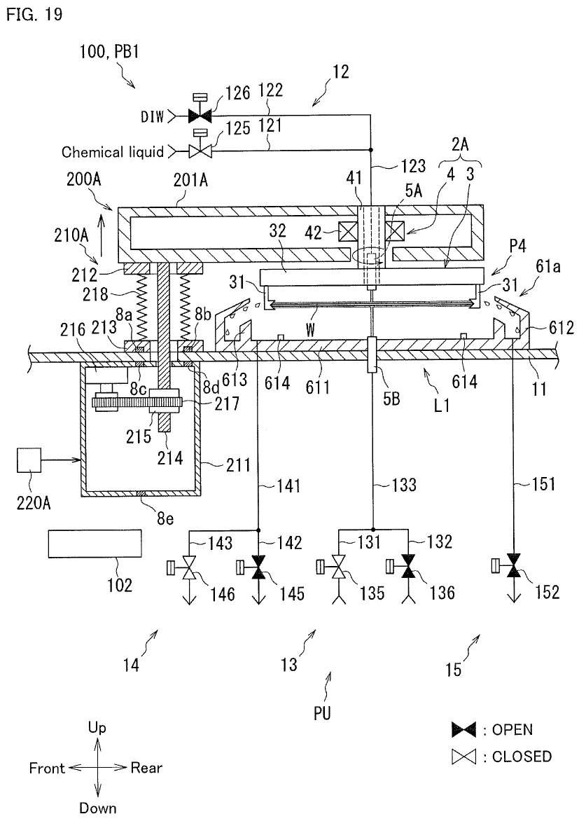

FIG. 19 is a view illustrating a third step of the rinse processing. As illustrated in FIG. 19, after the rinse liquid is drained, the controlling portion 102 controls the raising/lowering mechanism 210A such that the upper substrate holding portion 2A is raised from the first processing position P2 to a third processing position P4. The third processing position P4 indicates a position in the up-down direction.

Specifically, the controlling portion 102 raises the upper substrate holding portion 2A to the third processing position P4 while continuing the discharge of the rinse liquid from the upper nozzle portion 5A and the lower nozzle portion 5B and the rotation of the substrate W. Through this processing, the drying of the substrate W can be suppressed, and pattern collapse and generation of particles can be suppressed. The timing at which the upper substrate holding portion 2A starts to rise is not particularly limited as long as it is after the liquid level of the rinse liquid is lowered to a position lower than the lower surface Wb of the substrate W.

When the upper substrate holding portion 2A rises from the first processing position P2 to the third processing position P4, the substrate W rises to a position at which the side surface of the substrate W faces the side wall portion 612 in the horizontal direction. Specifically, the side surface of the substrate W faces a position between the upper end of the inner wall portion 613 and the upper end of the side wall portion 612 in the horizontal direction. Therefore, the rinse liquid scattered from the substrate W in the third step of the rinse processing is received by the side wall portion 612. As a result, the rinse liquid is collected in the space between the side wall portion 612 and the inner wall portion 613. The rinse liquid collected in the space between the side wall portion 612 and the inner wall portion 613 is drained from the immersion bath 61a through the second draining portion 15.

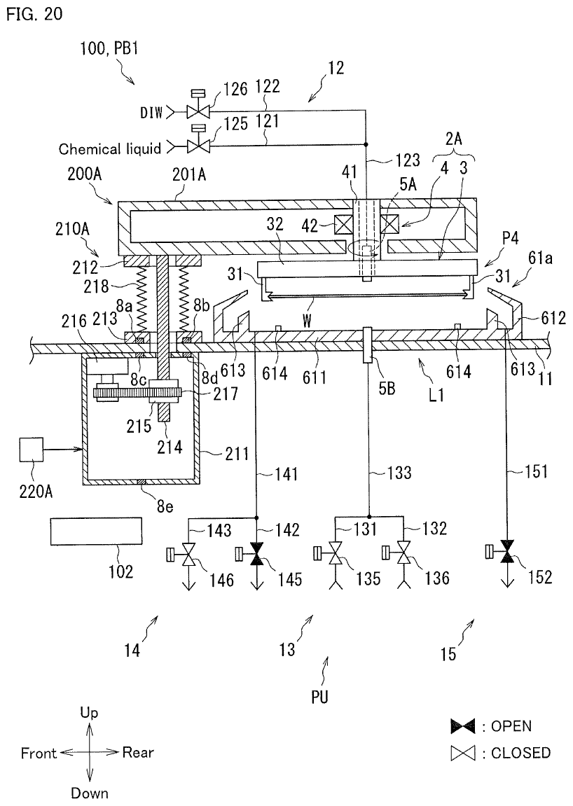

FIG. 20 is a diagram illustrating the drying processing. As illustrated in FIG. 20, when a predetermined time has elapsed after the upper substrate holding portion 2A is moved to the third processing position P4, the controlling portion 102 switches the second opening/closing valve 126 of the first liquid supplying portion 12 and the second opening/closing valve 136 of the second liquid supplying portion 13 from the open state to the closed state. Then, the controlling portion 102 controls the upper rotating portion 4 (upper motor body 42) such that the rotational speed of the substrate W is increased. As a result, the rinse liquid is blown off from the substrate W by a centrifugal force, and the substrate W is dried. After a predetermined time has elapsed from the increase in the rotational speed of the substrate W, the controlling portion 102 controls the upper rotating portion 4 (upper motor body 42) such that the rotation of the substrate W is stopped.

As described above with reference to FIGS. 9 to 20, in Preferred Embodiment 1, the chemical liquid processing, the rinse processing, and the drying processing are performed on one substrate W inside one immersion bath 61a. Specifically, the upper nozzle portion 5A and the lower nozzle portion 5B discharge the rinse liquid toward the substrate W located inside the immersion bath 61a from which the chemical liquid has been drained by the first draining portion 14. After the discharge of the rinse liquid is stopped, the upper rotating portion 4 increases the rotational speed of the substrate W located inside the immersion bath 61a to dry the substrate W.

Preferred Embodiment 1 has been described above with reference to FIGS. 1 to 20. According to Preferred Embodiment 1, since one substrate W in the horizontal posture is immersed in the chemical liquid stored in the immersion bath 61a and the substrate W is processed, the consumption amount of the chemical liquid can be reduced. In addition, according to Preferred Embodiment 1, since the substrates W are immersed in the chemical liquid one by one, generation of particles can be suppressed as compared with a batch type apparatus in which a plurality of substrates W are simultaneously immersed in the chemical liquid in one processing bath.

Furthermore, according to Preferred Embodiment 1, since the substrate W is supported by the supporting portions 614 of the immersion bath 61a and the substrate W is immersed in the chemical liquid, operations of the chemical liquid processing can be executed for the plurality of substrates W in parallel. Therefore, the waiting time for waiting for the timing to start the chemical liquid processing can be reduced.

In Preferred Embodiment 1, the upper substrate holding portion 2A is raised and lowered, but the processing cup portion 6 may be raised and lowered, or the upper substrate holding portion 2A and the processing cup portion 6 may be raised and lowered. Similarly, the placing table 7 may be raised and lowered, or the placing table 7 and the upper substrate holding portion 2A may be raised and lowered. That is, each of the first processing block PB1 and the second processing block PB2 may have a raising/lowering mechanism that individually raises and lowers the processing cup portion 6 and a raising/lowering mechanism that raises and lowers the placing table 7 for each processing cup row L.

Specifically, in Preferred Embodiment 1, the upper substrate holding portion 2A is raised and lowered such that the position of the substrate W held by the upper substrate holding portion 2A changes from one over position among the over positions of the corresponding processing cup portions 6 to the position inside the one processing cup portion 6, but the one processing cup portion 6 may be raised and lowered or the one processing cup portion 6 and the upper substrate holding portion 2A may be raised and lowered such that the position of the substrate W held by the upper substrate holding portion 2A changes from one over position among the over positions of the corresponding processing cup portions 6 to the position inside the one processing cup portion 6. The same applies to the placing table 7.

In Preferred Embodiment 1, the substrate W is immersed in the rinse liquid in the second step (see FIG. 18) of the rinse processing, but the second step of the rinse processing may be omitted. Alternatively, the second step and the third step of the rinse processing may be omitted, or the first step and the second step of the rinse processing may be omitted.

In Preferred Embodiment 1, the first draining portion 14 has the recovery pipe portion 143 and the second opening/closing valve 146, but the recovery pipe portion 143 and the second opening/closing valve 146 may be omitted.

In Preferred Embodiment 1, the substrate W is indirectly transferred between each upper substrate holding portion 2A and the transfer robot TR through the placing table 7, but the substrate W may be directly transferred between each upper substrate holding portions 2A and the transfer robot TR.

In Preferred Embodiment 1, three processing cup portions 6 are provided in one processing cup row L, but the number of processing cup portions 6 provided in one processing cup row L is not limited to three. Two or four or more processing cup portions 6 may be provided in one processing cup row L.

### Modification Example 1

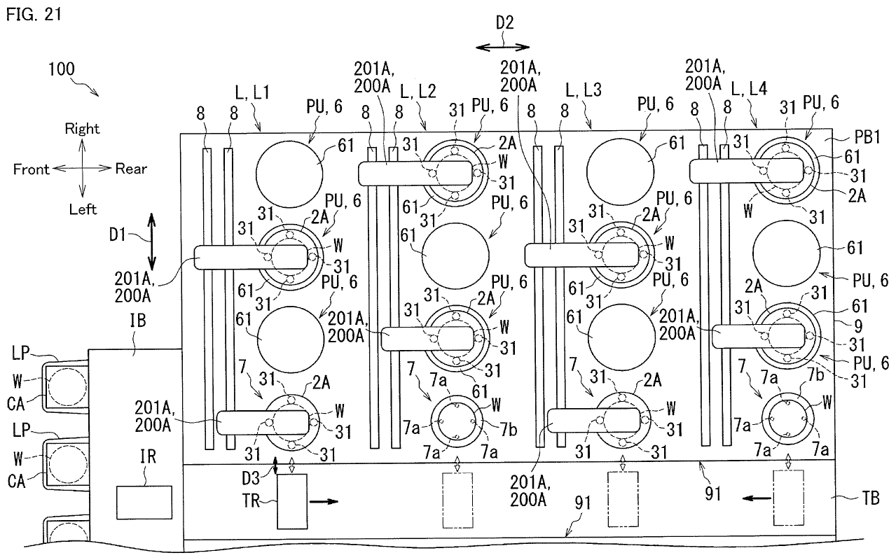

Subsequently, a substrate processing apparatus 100 according to Modification Example 1 will be described with reference to FIG. 21. However, matters differing from the preferred embodiments described with reference to FIGS. 1 to 20 will be described, and the description of matters that are the same as in the preferred embodiments described with reference to FIGS. 1 to 20 will be omitted.

FIG. 21 is an enlarged schematic plan view of a portion of the substrate processing apparatus 100 according to Modification Example 1. Specifically, FIG. 21 illustrates a configuration of the first processing block PB1 included in the substrate processing apparatus 100 according to Modification Example 1. Although not illustrated, the configuration of the second processing block PB2 is similar to the configuration of the first processing block PB1.

In the preferred embodiment described with reference to FIGS. 1 to 20, each of the first processing block PB1 and the second processing block PB2 has one upper substrate holding portion 2A for each processing cup row L, but the number of upper substrate holding portions 2A is not limited to one. Each of the first processing block PB1 and the second processing block PB2 may have a plurality of upper substrate holding portions 2A for each processing cup row L. For example, as illustrated in FIG. 21, two upper substrate holding portions 2A may be provided for each processing cup row L. Alternatively, three or more upper substrate holding portions 2A may be provided for each processing cup row L.

Specifically, each of the first processing block PB1 and the second processing block PB2 may have the plurality of upper substrate holding portions 2A, the plurality of rail members 8 corresponding to each of the upper substrate holding portions 2A, and the moving portions 200A corresponding to each of the upper substrate holding portions 2A for each processing cup row L. Each of the raising/lowering mechanisms 210A of the moving portions 200A raises and lowers the corresponding upper substrate holding portion 2A. In addition, each of the moving mechanisms 220A of the moving portions 200A moves the corresponding upper substrate holding portion 2A in the facing position group including the facing position of the corresponding placing table 7 and the facing position P1 of each of the plurality of corresponding processing cup portions 6.

When one of the plurality of upper substrate holding portions 2A corresponding to the first processing cup row L1 is moved in the first direction D1, the vertical positions of the upper substrate holding portion 2A to be moved and the supporting arm 201A are different from the vertical positions of the other upper substrate holding portion 2A and supporting arm 201A corresponding to the first processing cup row L1. Therefore, it is possible to avoid the plurality of upper substrate holding portions 2A corresponding to the first processing cup row L1 from interfering with each other. Similarly, it is possible to avoid the plurality of supporting arms 201A corresponding to the first processing cup row L1 from interfering with each other. The same applies to the case of moving the plurality of upper substrate holding portions 2A corresponding to each of the second processing cup row L2, the third processing cup row L3, and the fourth processing cup row L4.

According to Modification Example 1, operations of the rinse processing and the drying processing can be executed on the plurality of substrates W in parallel for each processing cup row L. Therefore, the waiting time for waiting for the timing to start the rinse processing and the drying processing can be reduced.

### Modification Example 2

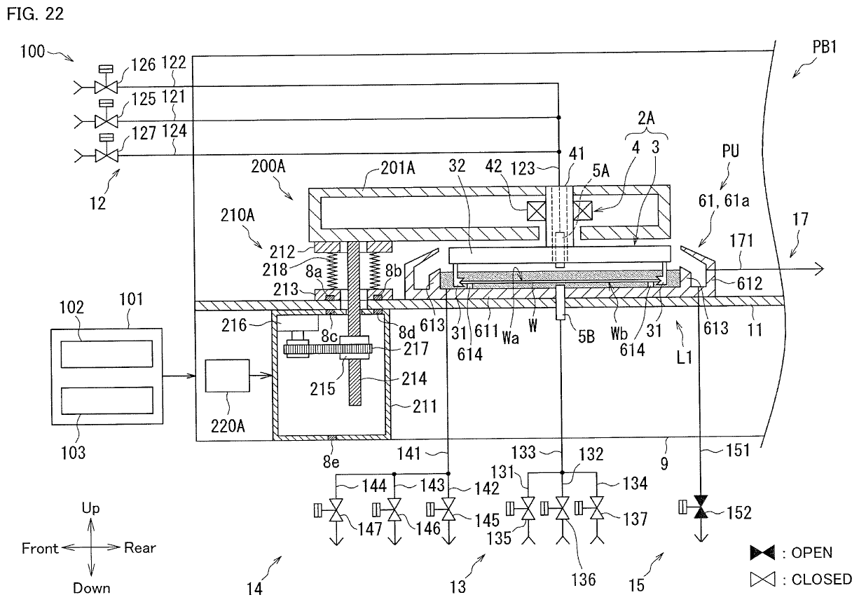

Subsequently, a substrate processing apparatus 100 according to Modification Example 2 will be described with reference to FIG. 22. However, matters differing from the preferred embodiments described with reference to FIGS. 1 to 21 will be described, and the description of matters that are the same as in the preferred embodiments described with reference to FIGS. 1 to 21 will be omitted. FIG. 22 is a cross-sectional view schematically illustrating a portion of a configuration of the first processing block PB1 included in the substrate processing apparatus 100 according to Modification Example 2. FIG. 22 schematically illustrates the cross sections of the moving portion 200A and the immersion bath 61a as viewed from the left side.

In the preferred embodiments described with reference to FIGS. 1 to 21, the same type of chemical liquid is stored in the plurality of immersion baths 61a included in each processing cup row L, but different types of chemical liquids may be stored in one immersion bath 61a and another immersion bath 61a in the plurality of immersion baths 61a included in the same processing cup row L. For example, different types of chemical liquids may be stored in the plurality of immersion baths 61a included in the same processing cup row L.

Specifically, the substrate processing apparatus 100 illustrated in FIG. 22 is different from the substrate processing apparatuses 100 described with reference to FIGS. 1 to 21 in that the first liquid supplying portion 12 can supply two types of chemical liquids to the upper nozzle portion 5A. In addition, the substrate processing apparatus 100 illustrated in FIG. 22 is different from the substrate processing apparatuses 100 described with reference to FIGS. 1 to 21 in that the second liquid supplying portion 13 can supply two types of chemical liquids to the lower nozzle portion 5B.

In the example illustrated in FIG. 22, the first liquid supplying portion 12 selectively supplies any one of a first chemical liquid, a second chemical liquid, and the rinse liquid to the upper nozzle portion 5A. Specifically, as illustrated in FIG. 22, the first liquid supplying portion 12 further has a chemical liquid pipe portion 124 and a third opening/closing valve 127. Hereinafter, the chemical liquid pipe portion 121 may be referred to as a “first chemical liquid pipe portion 121,” and the chemical liquid pipe portion 124 may be referred to as a “second chemical liquid pipe portion 124.” The second chemical liquid pipe portion 124 is a tubular member through which a fluid flows. The third opening/closing valve 127 is openable and closable similarly to the first opening/closing valve 125 and the second opening/closing valve 126.

In the example illustrated in FIG. 22, the first chemical liquid is supplied to the upstream end of the first chemical liquid pipe portion 121. A second chemical liquid different in type from the first chemical liquid is supplied to the upstream end of the second chemical liquid pipe portion 124. The downstream end of the second chemical liquid pipe portion 124 is connected to the common pipe portion 123 similarly to the first chemical liquid pipe portion 121. The third opening/closing valve 127 is provided in the second chemical liquid pipe portion 124. The third opening/closing valve 127 is controlled by the controlling portion 102 such that a flow path inside the second chemical liquid pipe portion 124 is opened and closed.

In the example illustrated in FIG. 22, the second liquid supplying portion 13 selectively supplies any one of the first chemical liquid, the second chemical liquid, and the rinse liquid to the lower nozzle portion 5B. Specifically, the second liquid supplying portion 13 further has a chemical liquid pipe portion 134 and a third opening/closing valve 137. Since the configuration of the second liquid supplying portion 13 is similar to that of the first liquid supplying portion 12, the detailed description thereof will be omitted.

According to Modification Example 2, the chemical liquid processing using the first chemical liquid and the chemical liquid processing using the second chemical liquid can be executed in parallel. Further, according to Modification Example 2, one of the first chemical liquid and the second chemical liquid can be selectively stored in one immersion bath 61a. Therefore, the chemical liquid processing executed in one immersion bath 61a can be selected between the chemical liquid processing using the first chemical liquid and the chemical liquid processing using the second chemical liquid.

Although the configuration in which the first liquid supplying portion 12 can supply two types of chemical liquids to the upper nozzle portion 5A has been exemplified with reference to FIG. 22, the first liquid supplying portion 12 may be able to supply three or more types of chemical liquids to the upper nozzle portion 5A. Similarly, the second liquid supplying portion 13 may be able to supply three or more types of chemical liquids to the lower nozzle portion 5B.

### Preferred Embodiment 2

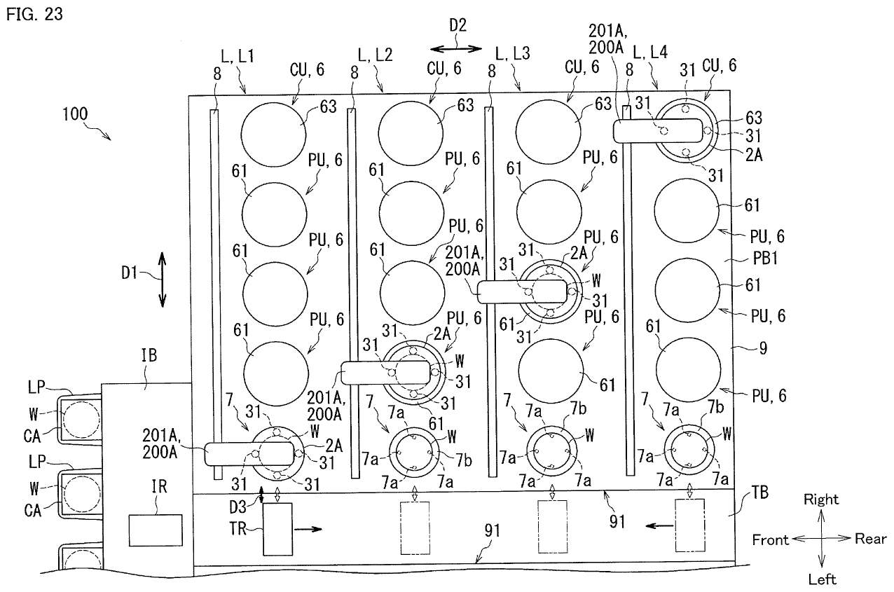

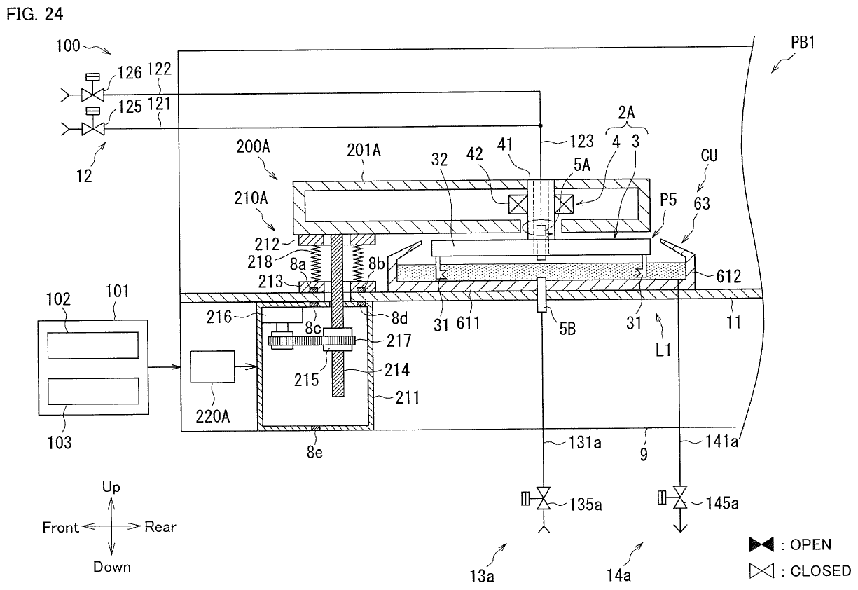

Subsequently, Preferred Embodiment 2 of the present invention will be described with reference to FIGS. 23 and 24. However, matters differing from the preferred embodiments described with reference to FIGS. 1 to 22 will be described, and the description of matters that are the same as in the preferred embodiments described with reference to FIGS. 1 to 22 will be omitted. Preferred Embodiment 2 is different from the preferred embodiments described with reference to FIGS. 1 to 22 in that a cleaning bath 63 is included in the plurality of processing cup portions 6 of each processing cup row L.

FIG. 23 is an enlarged schematic plan view of a portion of a substrate processing apparatus 100 according to Preferred Embodiment 2. Specifically, FIG. 23 illustrates a configuration of the first processing block PB1 included in the substrate processing apparatus 100 according to Preferred Embodiment 2. Although not illustrated, the configuration of the second processing block PB2 is similar to the configuration of the first processing block PB1.

As illustrated in FIG. 23, the plurality of processing cup portions 6 of each processing cup row L include a cleaning bath 63. For example, the cleaning bath 63 may be disposed on the most right side among the plurality of corresponding processing cup portions 6. However, the position of the cleaning bath 63 is not particularly limited. For example, the cleaning bath 63 may be disposed on the most left side among the plurality of corresponding processing cup portions 6. That is, the cleaning bath 63 may be disposed next to (on the right of) the corresponding placing table 7.

Specifically, each of the first processing block PB1 and the second processing block PB2 further has a cleaning unit CU for each processing cup row L. The cleaning unit CU cleans the plurality of upper chuck members 31. The cleaning bath 63 is included in the cleaning unit CU. The cleaning bath 63 is a bath in which the upper chuck member 31 of the upper substrate holding portion 2A is cleaned. A rinse liquid (here, DIW) is stored in the cleaning bath 63.

FIG. 24 is a cross-sectional view schematically illustrating a portion of the configuration of the first processing block PB1 included in the substrate processing apparatus 100 according to Preferred Embodiment 2. Specifically, FIG. 24 illustrates the first liquid supplying portion 12, the upper substrate holding portion 2A, the moving portion 200A, the cleaning unit CU, and the first rail member 8a to the fifth rail member 8e which correspond to the first processing cup row L1 of the first processing block PB1. FIG. 24 schematically illustrates the cross sections of the moving portion 200A and the cleaning bath 63 as viewed from the left side. As illustrated in FIG. 24, the cleaning unit CU further has a liquid supplying portion 13a and a draining portion 14a in addition to the cleaning bath 63.

The cleaning bath 63 has a container shape with an open upper surface. The upper chuck member 31 is immersed in the rinse liquid stored in the cleaning bath 63 in a state of not holding the substrate W. As a result, the upper chuck member 31 is cleaned with the rinse liquid. In the present preferred embodiment, the controlling portion 102 rotates the upper spin base 32 in a state where the upper chuck member 31 is immersed in the rinse liquid. Through this processing, the cleaning effect on the upper chuck member 31 can be improved.

The cleaning bath 63 has a bottom wall portion 611, a side wall portion 612, and a lower nozzle portion 5B. Since the cleaning bath 63 has the same structure as the immersion bath 61a described with reference to FIGS. 1 to 22 except that the cleaning bath 63 does not have the inner wall portion 613 and the plurality of supporting portions 614, the detailed description thereof will be omitted.

The liquid supplying portion 13a is controlled by the controlling portion 102 such that the rinse liquid is supplied to the lower nozzle portion 5B of the cleaning bath 63. Specifically, the liquid supplying portion 13a has a rinse liquid pipe portion 131a and an opening/closing valve 135a.

The rinse liquid pipe portion 131a is a tubular member through which a fluid flows. The opening/closing valve 135a is provided in the rinse liquid pipe portion 131a. The opening/closing valve 135a is openable and closable. The opening and closing operations of the opening/closing valve 135a are controlled by the controlling portion 102.

The rinse liquid is supplied to the upstream end of the rinse liquid pipe portion 131a. A downstream end of the rinse liquid pipe portion 131a is connected to the lower nozzle portion 5B of the cleaning bath 63. The opening/closing valve 135a opens and closes a flow path in the rinse liquid pipe portion 131a. When the opening/closing valve 135a is opened, the rinse liquid flows through the rinse liquid pipe portion 131a, and the rinse liquid is supplied to the cleaning bath 63. As a result, the rinse liquid is stored in the cleaning bath 63. When the opening/closing valve 135a is closed, the flow of the rinse liquid through the rinse liquid pipe portion 131a is stopped. As a result, the supply of the rinse liquid to the cleaning bath 63 is stopped.

The draining portion 14a drains the rinse liquid stored in the cleaning bath 63 to the outside of the cleaning bath 63. In the present preferred embodiment, the draining portion 14a drains the rinse liquid stored in the cleaning bath 63 to the outside of the first processing block PB1. Specifically, the draining portion 14a has a drainage pipe portion 141a and an opening/closing valve 145a.

The drainage pipe portion 141a is a tubular member through which a fluid flows. The opening/closing valve 145a is provided in the drainage pipe portion 141a. The opening/closing valve 145a is openable and closable. The opening and closing operations of the opening/closing valve 145a are controlled by the controlling portion 102.

The upstream end of the drainage pipe portion 141a is connected to the bottom wall portion 611 of the cleaning bath 63 and communicates with an inner space of the cleaning bath 63. The downstream end of the drainage pipe portion 141a is connected to a drain tank (not illustrated). The opening/closing valve 145a opens and closes a flow path in the drainage pipe portion 141a. When the opening/closing valve 145 is opened, the rinse liquid stored in the cleaning bath 63 is drained to the drain tank (not illustrated) through the drainage pipe portion 141a.

Here, the flow of processing executed by the controlling portion 102 when cleaning the plurality of upper chuck members 31 will be described.

The controlling portion 102 controls the moving mechanism 220A such that the upper substrate holding portion 2A is moved to a facing position P1 of the cleaning bath 63 and then controls the raising/lowering mechanism 210A such that the upper substrate holding portion 2A is lowered from the facing position P1 of the cleaning bath 63 to a cleaning position P5. As a result, the plurality of upper chuck members 31 of the upper substrate holding portion 2A are immersed in the rinse liquid in the cleaning bath 63. The cleaning position P5 indicates a position in the up-down direction.

After the upper substrate holding portion 2A is lowered from the facing position P1 of the cleaning bath 63 to the cleaning position P5, the controlling portion 102 controls the upper rotating portion 4 (upper motor body 42) such that the upper spin base 32 is rotated. As a result, the plurality of upper chuck members 31 rotate in the rinse liquid.

When a predetermined time has elapsed from the start of the rotation of the plurality of upper chuck members 31, the controlling portion 102 controls the upper rotating portion 4 (upper motor body 42) such that the rotation of the upper spin base 32 (plurality of upper chuck members 31) is stopped. Then, the controlling portion 102 controls the raising/lowering mechanism 210A such that the upper substrate holding portion 2A is raised from the cleaning position P5 to the facing position P1 of the cleaning bath 63.

Preferred Embodiment 2 of the present invention has been described above with reference to FIGS. 23 and 24. According to Preferred Embodiment 2, similarly to the preferred embodiments described with reference to FIGS. 1 to 22, the consumption amount of the chemical liquid can be reduced. Further, according to Preferred Embodiment 2, since the upper chuck member 31 can be cleaned, the chemical liquid, etc., adhering to the upper chuck member 31 can be removed from the upper chuck member 31. Therefore, the substrate W can be gripped by the clean upper chuck member 31.

For example, as described with reference to FIG. 22, in a case where a chemical liquid of a type different from that of the other immersion baths 61a is stored in at least one of the plurality of immersion baths 61a, when the next substrate W is immersed in the second chemical liquid after the substrate W is immersed in the first chemical liquid, the first chemical liquid adhering to the upper chuck member 31 may be mixed with the second chemical liquid. On the other hand, according to Preferred Embodiment 2, after the substrate W is immersed in the first chemical liquid, the upper chuck member 31 can be cleaned in the cleaning bath 63. Therefore, the next substrate W can be gripped by the cleaned upper chuck member 31, and the next substrate W can be immersed in the second chemical liquid. Therefore, the possibility that the first chemical liquid is mixed with the second chemical liquid can be reduced. As a result, the possibility that the substrate W is contaminated can be reduced.

In Preferred Embodiment 2, the plurality of upper chuck members 31 are immersed in the rinse liquid stored in the cleaning bath 63, and the plurality of upper chuck members 31 are cleaned, but the configuration in which the plurality of upper chuck members 31 are cleaned is not limited to this configuration. For example, a spray cleaning nozzle may be provided in the cleaning bath 63. In this case, the rinse liquid is discharged from the spray cleaning nozzle toward the plurality of upper chuck members 31 located inside the cleaning bath 63 to clean the plurality of upper chuck members 31. For example, when cleaning the plurality of upper chuck members 31, the upper spin base 32 may be rotated, and the rinse liquid may be discharged from one spray cleaning nozzle toward the plurality of rotating upper chuck members 31.

### Preferred Embodiment 3

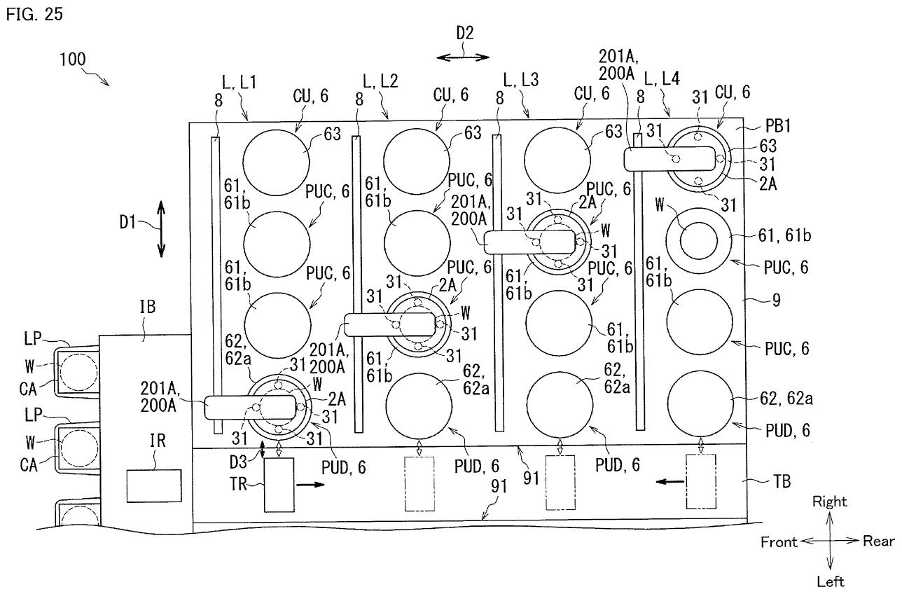

Subsequently, Preferred Embodiment 3 of the present invention will be described with reference to FIGS. 25 to 55. However, matters differing from the preferred embodiments described with reference to FIGS. 1 to 24 will be described, and the description of matters that are the same as in the preferred embodiments described with reference to FIGS. 1 to 24 will be omitted. Preferred Embodiment 3 is different from the preferred embodiments described with reference to FIGS. 1 to 24 in that a second processing cup portion 62 is included in the plurality of processing cup portions 6 of each processing cup row L.

FIG. 25 is an enlarged schematic plan view of a portion of a substrate processing apparatus 100 according to Preferred Embodiment 3. Specifically, FIG. 25 illustrates a configuration of the first processing block PB1 included in the substrate processing apparatus 100 according to Preferred Embodiment 3. Although not illustrated, the configuration of the second processing block PB2 is similar to the configuration of the first processing block PB1.

As illustrated in FIG. 25, in Preferred Embodiment 3, the plurality of processing cup portions 6 of each processing cup row L include a plurality of first processing cup portions 61, one second processing cup portion 62, and one cleaning bath 63. The second processing cup portion 62 receives the processing liquid drained from the substrate W held by the corresponding upper substrate holding portion 2A.

The plurality of first processing cup portions 61, the second processing cup portion 62, and the cleaning bath 63 are arranged in the first direction D1 (left-right direction). The second processing cup portion 62 is located on the most left side among the plurality of processing cup portions 6. In other words, the second processing cup portion 62 is located at a position closest to the corresponding placing table 7 among the plurality of processing cup portions 6. The cleaning bath 63 is located on the most right side among the plurality of processing cup portions 6. In other words, the cleaning bath 63 is located at a position farthest from the corresponding placing table 7 among the plurality of processing cup portions 6.

Specifically, the plurality of first processing cup portions 61 include two immersion baths 61b. The second processing cup portion 62 includes a rinse drying cup portion 62a. Hereinafter, one of the two immersion baths 61b may be referred to as a “first immersion bath 61b1.” In addition, the other of the two immersion baths 61b may be referred to as a “second immersion bath 61b2.” The placing table 7, two immersion baths 61b (first immersion bath 61b1 and second immersion bath 61b2), one rinse drying cup portion 62a, and one cleaning bath 63 are disposed in the order of the placing table 7, the rinse drying cup portion 62a, the first immersion bath 61b1, the second immersion bath 61b2, and the cleaning bath 63 from the left side.

The chemical liquid is stored in the immersion bath 61b. The substrate W is immersed in the chemical liquid in the immersion bath 61b. Therefore, the chemical liquid processing is performed in the immersion bath 61b. For example, different types of chemical liquids are stored in the two immersion baths 61b. The rinse drying cup portion 62a receives the rinse liquid drained from the substrate W held by the upper substrate holding portion 2A.

Specifically, the first processing block PB1 and the second processing block PB2 each have a rinse drying processing unit PUD, two chemical liquid processing units PUC, and the cleaning unit CU for each processing cup row L. The rinse drying processing unit PUD has the rinse drying cup portion 62a. The chemical liquid processing unit PUC has the immersion bath 61b.

The rinse drying processing unit PUD cooperates with the upper substrate holding portion 2A to execute the rinse processing and the drying processing inside the rinse drying cup portion 62a. Therefore, the rinse drying cup portion 62a receives the rinse liquid drained from the substrate W held by the upper substrate holding portion 2A.

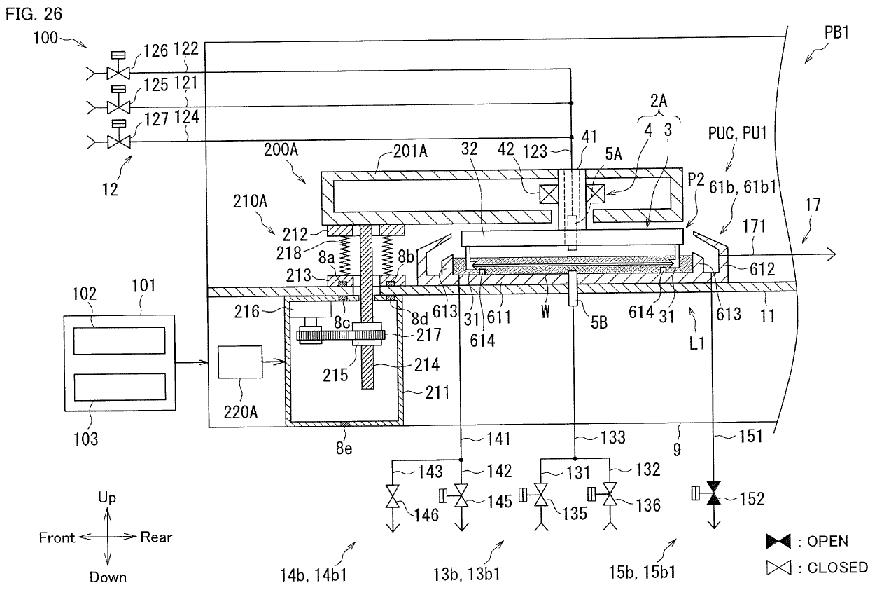

Subsequently, the first liquid supplying portion 12 and the chemical liquid processing unit PUC included in the substrate processing apparatus 100 according to Preferred Embodiment 3 will be described with reference to FIG. 26. FIG. 26 is a cross-sectional view schematically illustrating a portion of the configuration of the first processing block PB1 included in the substrate processing apparatus 100 according to Preferred Embodiment 3. Specifically, FIG. 26 illustrates the first liquid supplying portion 12, the upper substrate holding portion 2A, the moving portion 200A, the chemical liquid processing unit PUC, and the first rail member 8a to the fifth rail member 8e which correspond to the first processing cup row L1 of the first processing block PB1. FIG. 26 schematically illustrates the cross sections of the moving portion 200A and the immersion bath 61b as viewed from the left side.

As illustrated in FIG. 26, in Preferred Embodiment 3, the first liquid supplying portion 12 selectively supplies any one of the first chemical liquid, the second chemical liquid, and the rinse liquid (here, DIW) to the upper nozzle portion 5A. Since the configuration of the first liquid supplying portion 12 illustrated in FIG. 26 is similar to the configuration of the first liquid supplying portion 12 described with reference to FIG. 22, the detailed description thereof will be omitted.

The chemical liquid processing unit PUC has a second liquid supplying portion 13b, a first draining portion 14b, a second draining portion 15b, and an exhaust portion 17 in addition to the immersion bath 61b.

Since the immersion bath 61b has the same structure as the immersion bath 61a described with reference to FIGS. 4 and 5, the detailed description thereof will be omitted.

The second liquid supplying portion 13b selectively supplies one of the chemical liquid and the rinse liquid (here, DIW) to the lower nozzle portion 5B of the immersion bath 61b. Since the configuration of the second liquid supplying portion 13b is similar to the configuration of the second liquid supplying portion 13 described with reference to FIG. 4, the detailed description thereof will be omitted.

The first draining portion 14b drains the processing liquid (chemical liquid) stored in the immersion bath 61b to the outside of the immersion bath 61b. Since the configuration of the first draining portion 14b is similar to the configuration of the first draining portion 14 described with reference to FIG. 4, the detailed description thereof will be omitted. The chemical liquid drained from the immersion bath 61b may not be recovered in the chemical liquid tank. In this case, the recovery pipe portion 143 and the second opening/closing valve 146 of the first draining portion 14b can be omitted.

Since the configuration of the second draining portion 15b is similar to the configuration of the second draining portion 15 described with reference to FIG. 4, the detailed description thereof will be omitted.

The substrate W may or may not be left in the immersion bath 61b. When the chemical liquid processing is performed while the substrate W is not left in the immersion bath 61b, the upper substrate holding portion 2A (upper holding portion 3) is located at the first processing position P2 while holding the substrate W until a predetermined time (predetermined chemical liquid processing time) has elapsed after the substrate W is immersed in the chemical liquid. In addition, in a case where the substrate W is not left in the immersion bath 61b, when the substrate W is immersed in the chemical liquid, the controlling portion 102 may control the upper rotating portion 4 (upper motor body 42) such that the substrate W is rotated.

As illustrated in FIG. 26, the chemical liquid processing unit PUC includes a first chemical liquid processing unit PU1. The first chemical liquid processing unit PU1 has the first immersion bath 61b1 (immersion bath 61b). The first chemical liquid is stored in the first immersion bath 61b1. Therefore, the chemical liquid processing (first chemical liquid processing) with the first chemical liquid is performed in the first immersion bath 61b1. Specifically, the first chemical liquid processing unit PU1 has a second liquid supplying portion 13b1 (second liquid supplying portion 13b), a first draining portion 14b1 (first draining portion 14b), a second draining portion 15b1 (second draining portion 15b), and an exhaust portion 17 in addition to the first immersion bath 61b1.

The second liquid supplying portion 13b1 selectively supplies one of the first chemical liquid and the rinse liquid to the lower nozzle portion 5B of the first immersion bath 61b1. The first chemical liquid is supplied to the upstream end of the chemical liquid pipe portion 131 of the second liquid supplying portion 13b1. The downstream end of the recovery pipe portion 143 of the first draining portion 14b1 is connected to a first chemical liquid tank.

At the time of the first chemical liquid processing, the substrate W may or may not be left in the first immersion bath 61b1. In a case where the substrate W is not left in the first immersion bath 61b1, when the substrate W is immersed in the first chemical liquid, the controlling portion 102 may control the upper rotating portion 4 (upper motor body 42) such that the substrate W is rotated.

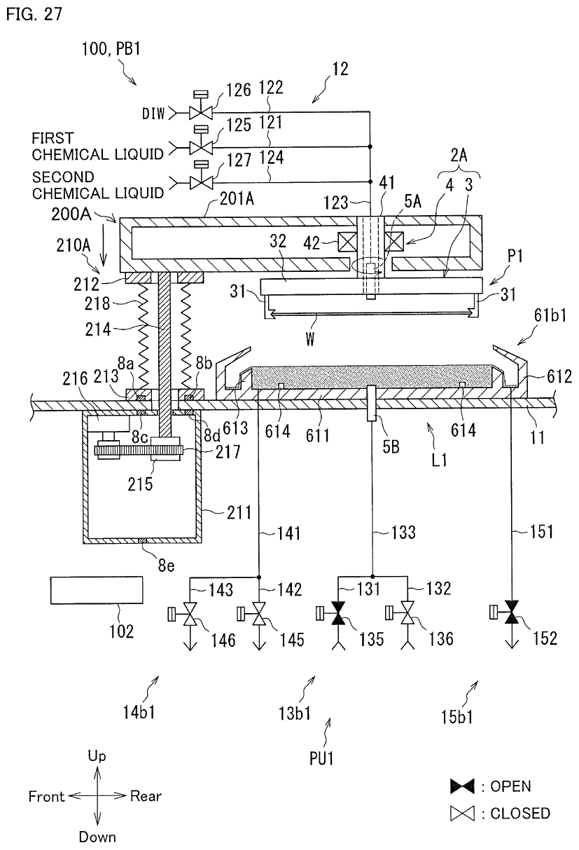

Subsequently, the processing of immersing the substrate W in the chemical liquid will be described with reference to FIG. 27 using the processing of immersing the substrate W in the first chemical liquid as an example. FIG. 27 is a view illustrating the processing of immersing the substrate W in the first chemical liquid. FIG. 27 illustrates the first liquid supplying portion 12, the upper substrate holding portion 2A, a portion of the moving portion 200A, the first chemical liquid processing unit PU1, and the first rail member 8a to the fifth rail member 8e which correspond to the first processing cup row L1 of the first processing block PB1. FIG. 27 schematically illustrates the cross sections of the moving portion 200A and the first immersion bath 61b1 as viewed from the left side.

In Preferred Embodiment 1, after the substrate W is moved to the inside of the immersion bath 61a, the chemical liquid is discharged from the upper nozzle portion 5A and the lower nozzle portion 5B, the chemical liquid is stored in the immersion bath 61a, and the substrate W is immersed in the chemical liquid, but, in Preferred Embodiment 3, the first chemical liquid is stored in the first immersion bath 61b1 before the substrate W is immersed in the first chemical liquid. Therefore, the substrate W is immersed in the first chemical liquid by submerging the substrate W in the first chemical liquid stored in the first immersion bath 61b1.

Specifically, as illustrated in FIG. 27, before the substrate W is immersed in the first chemical liquid, the upper substrate holding portion 2A is located at the facing position P1 of the first immersion bath 61b1. Therefore, before the substrate W is immersed in the first chemical liquid, the substrate W is located at an over position of the first immersion bath 61b1 and faces the liquid level of the first chemical liquid in the first immersion bath 61b1.

When the substrate W is immersed in the first chemical liquid, the controlling portion 102 controls the upper rotating portion 4 (upper motor body 42) such that the substrate W is rotated. Also, the controlling portion 102 switches the first opening/closing valve 135 of the second liquid supplying portion 13b1 from the closed state to the open state and discharges the first chemical liquid from the lower nozzle portion 5B of the first immersion bath 61b1. Therefore, the first chemical liquid overflows from the inner wall portion 613.

The controlling portion 102 controls the raising/lowering mechanism 210A such that the upper substrate holding portion 2A is lowered from the facing position P1 of the first immersion bath 61b1 to the first processing position P2 (see FIG. 26). As a result, the substrate W is immersed in the first chemical liquid. As described above, the substrate W can be submerged in the first chemical liquid by discharging the first chemical liquid from the lower nozzle portion 5B while rotating the substrate W.

When the substrate W is immersed in the first chemical liquid, the first chemical liquid may be discharged from the upper nozzle portion 5A. Specifically, when the substrate W moves to the position inside the first immersion bath 61b1, the controlling portion 102 may switch the first opening/closing valve 125 of the first liquid supplying portion 12 from the closed state to the open state and discharge the first chemical liquid from the upper nozzle portion 5A.

When the substrate W is left in the first immersion bath 61b1, the controlling portion 102 controls the raising/lowering mechanism 210A such that the upper substrate holding portion 2A is moved from the first processing position P2 to the second processing position P3 and then controls the upper chuck driving mechanism 50 such that the gripping of the substrate W by the plurality of upper chuck members 31 is released. Then, the controlling portion 102 controls the raising/lowering mechanism 210A such that the upper substrate holding portion 2A is raised from the second processing position P3 to the facing position P1 of the first immersion bath 61b1. As a result, the substrate W is supported by the plurality of supporting portions 614 of the first immersion bath 61b1, and the substrate W is left in the first immersion bath 61b1.

Subsequently, the processing of pulling up the substrate W from the chemical liquid will be described using the processing of pulling up the substrate W from the first chemical liquid as an example. In Preferred Embodiment 1, after the substrate W is processed with the chemical liquid, the chemical liquid is drained from the immersion bath 61a, and the rinse processing and the drying processing are executed in the immersion bath 61a from which the chemical liquid has been drained, but, in Preferred Embodiment 3, the first chemical liquid is not drained from the first immersion bath 61b1, and the substrate W is pulled up from the first chemical liquid. For example, the first chemical liquid is drained from the first immersion bath 61b1 when the first immersion bath 61b1 is cleaned.

Specifically, in a case where the first chemical liquid processing is performed without leaving the substrate W in the first immersion bath 61b1, when the substrate W is pulled up from the first chemical liquid, the controlling portion 102 controls the upper rotating portion 4 (upper motor body 42) such that the substrate W is rotated. Also, the controlling portion 102 switches the first opening/closing valve 135 of the second liquid supplying portion 13b1 from the closed state to the open state and discharges the first chemical liquid from the lower nozzle portion 5B of the first immersion bath 61b1. Then, the controlling portion 102 controls the raising/lowering mechanism 210A such that the upper substrate holding portion 2A is raised from the first processing position P2 (see FIG. 26) to the facing position P1 of the first immersion bath 61b1. As described above, when the first chemical liquid is discharged from the lower nozzle portion 5B of the first immersion bath 61b1 while the substrate W is rotated, the substrate W can be pulled up from the first chemical liquid. When the substrate W is pulled up from the first chemical liquid, the first chemical liquid overflows from the inner wall portion 613.

In addition, in a case where the first chemical liquid processing is performed while the substrate W is left in the first immersion bath 61b1, as described with reference to FIG. 15, the controlling portion 102 moves the upper substrate holding portion 2A to the second processing position P3 and causes the plurality of upper chuck members 31 to grip the substrate W supported by the plurality of supporting portions 614 of the first immersion bath 61b1. Then, as described with reference to FIG. 16, the controlling portion 102 raises the upper substrate holding portion 2A from the second processing position P3 to the first processing position P2. Thereafter, the controlling portion 102 executes the pulling-up processing described above.

When the substrate W is pulled up from the first chemical liquid, the controlling portion 102 may switch the first opening/closing valve 125 of the first liquid supplying portion 12 from the closed state to the open state and discharge the first chemical liquid from the upper nozzle portion 5A. In this case, before the substrate W moves to the outside (upward) of the first immersion bath 61b1, the controlling portion 102 may switch the first opening/closing valve 125 of the first liquid supplying portion 12 from the closed state to the open state and stop the discharge of the first chemical liquid from the upper nozzle portion 5A.

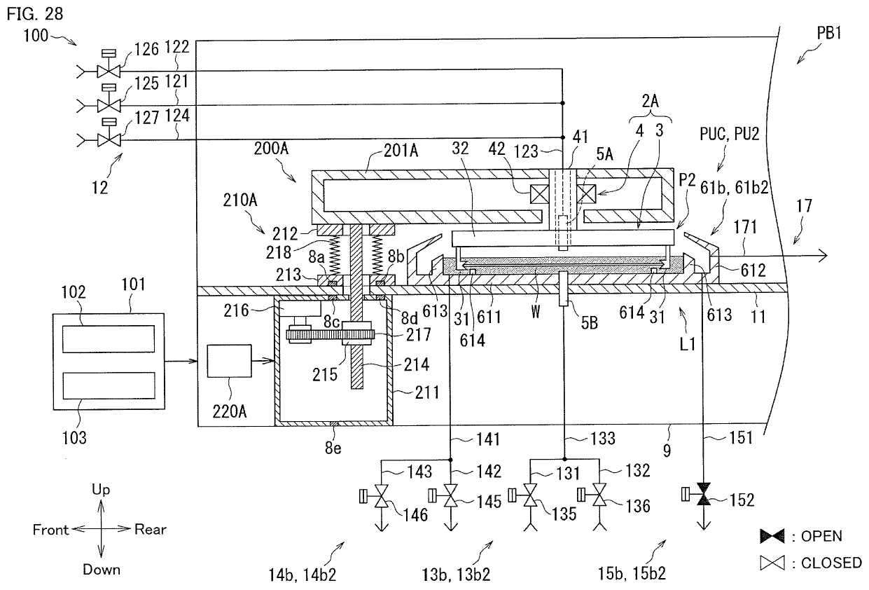

Subsequently, a second chemical liquid processing unit PU2 included in the substrate processing apparatus 100 according to Preferred Embodiment 3 will be described with reference to FIG. 28. FIG. 28 is another cross-sectional view schematically illustrating a portion of the configuration of the first processing block PB1 included in the substrate processing apparatus 100 according to Preferred Embodiment 3. Specifically, FIG. 28 illustrates the first liquid supplying portion 12, the upper substrate holding portion 2A, the moving portion 200A, the second chemical liquid processing unit PU2, and the first rail member 8a to the fifth rail member 8e which correspond to the first processing cup row L1 of the first processing block PB1. FIG. 28 schematically illustrates the cross sections of the moving portion 200A and the immersion bath 61b (second immersion bath 61b2) as viewed from the left side.

As illustrated in FIG. 28, the chemical liquid processing unit PUC includes the second chemical liquid processing unit PU2. The second chemical liquid processing unit PU2 has the second immersion bath 61b2 (immersion bath 61b). The second chemical liquid is stored in the second immersion bath 61b2. Therefore, the chemical liquid processing (second chemical liquid processing) with the second chemical liquid is performed in the second immersion bath 61b2. Specifically, the second chemical liquid processing unit PU2 has a second liquid supplying portion 13b2 (second liquid supplying portion 13b), a first draining portion 14b2 (first draining portion 14b), a second draining portion 15b2 (second draining portion 15b), and an exhaust portion 17 in addition to the second immersion bath 61b2.

The second liquid supplying portion 13b2 selectively supplies one of the second chemical liquid and the rinse liquid (here, DIW) to the lower nozzle portion 5B of the second immersion bath 61b2. The second chemical liquid is supplied to the upstream end of the chemical liquid pipe portion 131 of the second liquid supplying portion 13b2. The downstream end of the recovery pipe portion 143 of the first draining portion 14b2 is connected to a second chemical liquid tank.

In Preferred Embodiment 3, the second chemical liquid is stored in the second immersion bath 61b2 before the substrate W is immersed in the second chemical liquid. Therefore, the substrate W is immersed in the second chemical liquid by submerging the substrate W in the second chemical liquid stored in the second immersion bath 61b2. Since the processing of immersing the substrate W in the second chemical liquid is similar to the processing of immersing the substrate W in the first chemical liquid, the detailed description thereof will be omitted.

In Preferred Embodiment 3, after the substrate W is processed with the second chemical liquid, the second chemical liquid is not drained from the second immersion bath 61b2. Therefore, the substrate W is pulled up from the second chemical liquid. Since the processing of pulling up the substrate W from the second chemical liquid is similar to the processing of pulling up the substrate W from the first chemical liquid, the detailed description thereof will be omitted.

Similarly to the first chemical liquid processing, the substrate W may or may not be left in the second immersion bath 61b2. In a case where the substrate W is not left in the second immersion bath 61b2, when the substrate W is immersed in the second chemical liquid, the controlling portion 102 may control the upper rotating portion 4 (upper motor body 42) such that the substrate W is rotated.

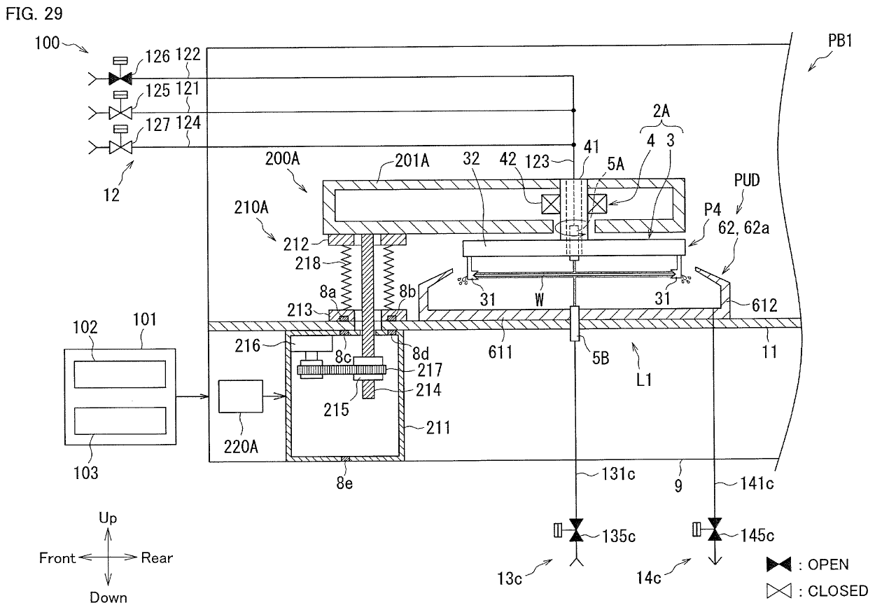

Subsequently, the rinse drying processing unit PUD included in the substrate processing apparatus 100 according to Preferred Embodiment 3 will be described with reference to FIG. 29. FIG. 29 is still another cross-sectional view schematically illustrating a portion of the configuration of the first processing block PB1 included in the substrate processing apparatus 100 according to Preferred Embodiment 3. Specifically, FIG. 29 illustrates the first liquid supplying portion 12, the upper substrate holding portion 2A, the moving portion 200A, the rinse drying processing unit PUD, and the first rail member 8a to the fifth rail member 8e which correspond to the first processing cup row L1 of the first processing block PB1. FIG. 29 schematically illustrates the cross sections of the moving portion 200A and the rinse drying cup portion 62a as viewed from the left side.

As illustrated in FIG. 29, the rinse drying processing unit PUD has a second liquid supplying portion 13c, a draining portion 14c, and an exhaust portion 17 in addition to the rinse drying cup portion 62a. The rinse drying cup portion 62a has a bottom wall portion 611, a side wall portion 612, and a lower nozzle portion 5B. Since the rinse drying cup portion 62a has the same structure as the immersion bath 61b except that the rinse drying cup portion 62a does not have the inner wall portion 613 and the plurality of supporting portions 614, the detailed description thereof will be omitted.

The second liquid supplying portion 13c supplies the rinse liquid (here, DIW) to the lower nozzle portion 5B of the rinse drying cup portion 62a. Specifically, the second liquid supplying portion 13c has a rinse liquid pipe portion 131c and an opening/closing valve 135c. Since the configuration of the second liquid supplying portion 13c is similar to the configuration of the liquid supplying portion 13a described with reference to FIG. 24, the detailed description thereof will be omitted.

The draining portion 14c drains the rinse liquid collected in the rinse drying cup portion 62a to the outside of the rinse drying cup portion 62a. In Preferred Embodiment 3, the draining portion 14c drains the rinse liquid collected in the rinse drying cup portion 62a to the outside of the first processing block PB1. Specifically, the draining portion 14c has a drainage pipe portion 141c and an opening/closing valve 145c. Since the configuration of the draining portion 14c is similar to the configuration of the draining portion 14a described with reference to FIG. 24, the detailed description thereof will be omitted.

In Preferred Embodiment 3, in the rinse drying cup portion 62a, the rinse processing is performed on the substrate W immersed in the first chemical liquid (substrate W subjected to the first chemical liquid processing).

Specifically, when a predetermined time (predetermined first chemical liquid processing time) has elapsed after the substrate W is immersed in the first chemical liquid, the controlling portion 102 moves the substrate W from the first immersion bath 61b1 to the rinse drying cup portion 62a.

Specifically, the controlling portion 102 executes the pulling-up processing such that the upper substrate holding portion 2A that holds the substrate W is raised from the first processing position P2 (see FIG. 26) or the second processing position P3 (see FIG. 15) to the facing position P1 of the first immersion bath 61b1. As a result, the substrate W after being processed in the first immersion bath 61b1 rises from the position inside the first immersion bath 61b1 to the over position of the first immersion bath 61b1.

After the upper substrate holding portion 2A is raised to the facing position P1 of the first immersion bath 61b1, the controlling portion 102 controls the moving mechanism 220A such that the upper substrate holding portion 2A is moved from the facing position P1 of the first immersion bath 61b1 to the facing position P1 of the rinse drying cup portion 62a. Then, the controlling portion 102 controls the raising/lowering mechanism 210A such that the upper substrate holding portion 2A is lowered from the facing position P1 of the rinse drying cup portion 62a to the third processing position P4. As a result, the substrate W subjected to the first chemical liquid processing moves to a position inside the rinse drying cup portion 62a.

When the substrate W moves to the position inside the rinse drying cup portion 62a, the controlling portion 102 controls the upper rotating portion 4 (upper motor body 42) such that the substrate W is rotated. In addition, the controlling portion 102 switches the second opening/closing valve 126 of the first liquid supplying portion 12 and the opening/closing valve 135c of the second liquid supplying portion 13c from the closed state to the open state and discharges the rinse liquid from the upper nozzle portion 5A and the lower nozzle portion 5B of the rinse drying cup portion 62a toward the upper surface Wa and the lower surface Wb of the rotating substrate W. As a result, the rinse processing is executed on the substrate W subjected to the first chemical liquid processing inside the rinse drying cup portion 62a. Specifically, the rinse liquid wets and spreads over the upper surface Wa and the lower surface Wb of the substrate W, and the first chemical liquid adhering to the upper surface Wa and the lower surface Wb of the substrate W is washed away from the substrate W with the rinse liquid.

The first chemical liquid and the rinse liquid drained from the rotating substrate W are received by the rinse drying cup portion 62a and collected in the rinse drying cup portion 62a. The processing liquid collected in the rinse drying cup portion 62a is drained from the rinse drying cup portion 62a through the draining portion 14c.

In Preferred Embodiment 3, in the rinse drying cup portion 62a, the rinse processing is performed on the substrate W immersed in the second chemical liquid (substrate W subjected to the second chemical liquid processing). Since the rinse processing on the substrate W subjected to the second chemical liquid processing is similar to the rinse processing on the substrate W subjected to the first chemical liquid processing, the description thereof will be omitted.

In Preferred Embodiment 3, the drying processing of the substrate W is performed in the rinse drying cup portion 62a. Since the drying processing is similar to the drying processing described with reference to FIG. 20, the description thereof will be omitted.

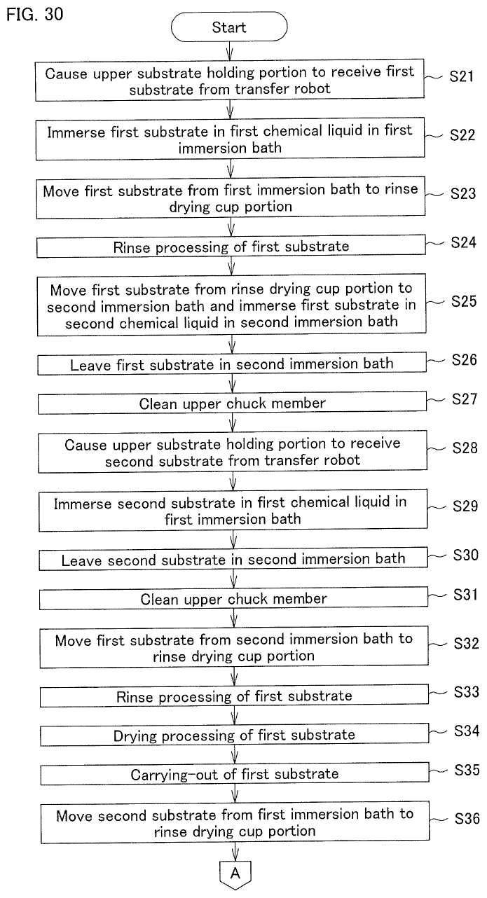

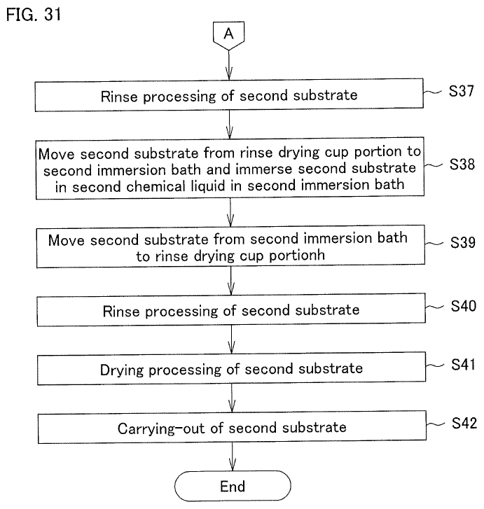

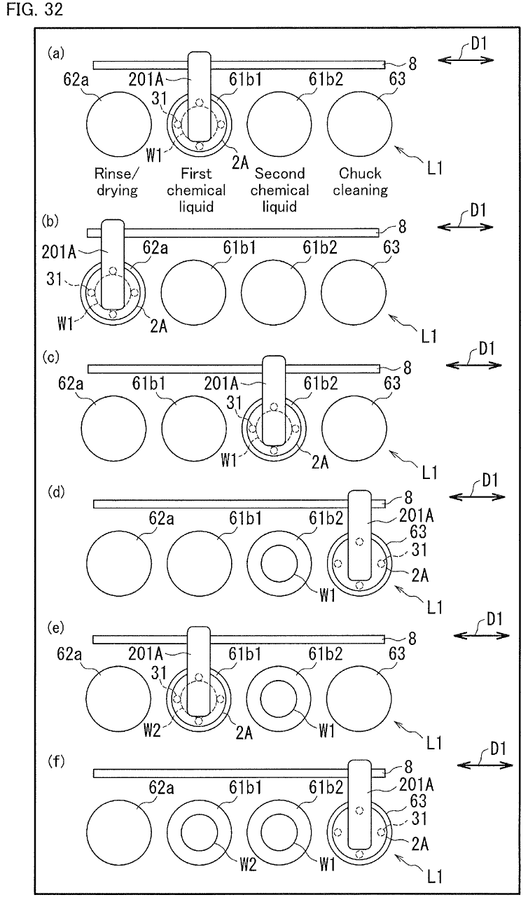

Subsequently, an example of the operation of the substrate processing apparatus 100 according to Preferred Embodiment 3 will be described with reference to FIGS. 25 to 31 and 32A to 32F using the first processing cup row L1 of the first processing block PB1 as an example. FIGS. 30 and 31 are diagrams illustrating an example of the operation flow of the substrate processing apparatus 100 according to Preferred Embodiment 3. Specifically, FIGS. 30 and 31 illustrate an example of the flow of processing executed by the controlling portion 102 when two substrates W (first substrate W1 and second substrate W2) are processed in the first processing cup row L1 of the first processing block PB1. FIGS. 32A to 32F are views schematically illustrating an example of the operation of the substrate processing apparatus 100 according to Preferred Embodiment 3. Specifically, FIGS. 32A to 32F illustrate an example of the operation of the first processing block PB1 when two substrates W (first substrate W1 and second substrate W2) are processed in the first processing cup row L1 of the first processing block PB1.

The processing illustrated in FIGS. 30 and 31 includes steps S21 to S42. Through the processing illustrated in FIGS. 30 and 31, each substrate W is processed according to the processing procedure. Specifically, the first chemical liquid processing, the rinse processing, the second chemical liquid processing, the rinse processing, and the drying processing are executed on each substrate W in that order.

The processing illustrated in FIGS. 30 and 31 starts when the transfer robot TR carries the first substrate W1 into the first processing block PB1 through the carry-in/carry-out port corresponding to the first processing cup row L1 of the first processing block PB1.

As illustrated in FIG. 30, when the transfer robot TR is controlled such that the first substrate W1 is carried into the first processing block PB1, the controlling portion 102 controls the upper substrate holding portion 2A (upper chuck driving mechanism 50) such that the first substrate W1 supported by the hand of the transfer robot TR is gripped by the plurality of upper chuck members 31. As a result, the upper substrate holding portion 2A receives the first substrate W1 from the transfer robot TR (step S21). When the plurality of upper chuck members 31 grip the first substrate W1, the first substrate W1 is horizontally held by the upper substrate holding portion 2A (upper holding portion 3). In Preferred Embodiment 3, the upper substrate holding portion 2A receives the first substrate W1 from the transfer robot TR over the rinse drying cup portion 62a. Before the first substrate W1 is carried into the first processing block PB1, the upper substrate holding portion 2A stands by at the facing position P1 of the rinse drying cup portion 62a.

When the upper substrate holding portion 2A holds the first substrate W1, the controlling portion 102 controls the moving portion 200A (moving mechanism 220A) such that the upper substrate holding portion 2A is moved to the facing position P1 of the first immersion bath 61b1 (FIG. 32A). Then, as described with reference to FIG. 27, the controlling portion 102 immerses the first substrate W1 in the first chemical liquid by submerging the first substrate W1 in the first chemical liquid in the first immersion bath 61b1 (step S22). By immersing the first substrate W1 in the first chemical liquid, the first chemical liquid processing is executed on the first substrate W1.

When the time elapsed after the first substrate W1 is immersed in the first chemical liquid becomes greater than or equal to a predetermined time (predetermined first chemical liquid processing time), the controlling portion 102 moves the first substrate W1 subjected to the first chemical liquid processing from the first immersion bath 61b1 to the rinse drying cup portion 62a (step S23).

Specifically, the upper substrate holding portion 2A holds the first substrate W1 during execution of the first chemical liquid processing on the first substrate W1. Therefore, the upper substrate holding portion 2A holds the first substrate W1 at the end of the first chemical liquid processing on the first substrate W1. Therefore, when the time elapsed after the first substrate W1 is immersed in the first chemical liquid becomes greater than or equal to a predetermined time (predetermined first chemical liquid processing time), the controlling portion 102 executes the pulling-up processing. As a result, the upper substrate holding portion 2A rises to the facing position P1 of the first immersion bath 61b1, and the first substrate W1 subjected to the first chemical liquid processing moves to the over position of the first immersion bath 61b1.

Before the upper substrate holding portion 2A is raised to the facing position P1 of the first immersion bath 61b1, the controlling portion 102 may raise the upper substrate holding portion 2A to the third processing position P4 (see FIG. 19) and execute shaking-off processing. The shaking-off processing indicates the processing of draining the processing liquid from the substrate W to such an extent that the substrate W is not dried by rotating the substrate W.

As illustrated in FIG. 32B, when the upper substrate holding portion 2A is raised to the facing position P1 of the first immersion bath 61b1, the controlling portion 102 controls the moving mechanism 220A such that the upper substrate holding portion 2A is moved from the facing position P1 of the first immersion bath 61b1 to the facing position P1 of the rinse drying cup portion 62a. Then, the controlling portion 102 controls the raising/lowering mechanism 210A such that the upper substrate holding portion 2A is lowered from the facing position P1 of the rinse drying cup portion 62a to the third processing position P4 (see FIG. 29). As a result, the first substrate W1 moves from above the rinse drying cup portion 62a to the inside of the rinse drying cup portion 62a.

When the first substrate W1 is moved to the inside of the rinse drying cup portion 62a, the controlling portion 102 executes the rinse processing as described with reference to FIG. 29 (step S24). In addition, the controlling portion 102 discharges the rinse liquid from the upper nozzle portion 5A and the lower nozzle portion 5B of the rinse drying cup portion 62a toward the upper surface Wa and the lower surface Wb of the first substrate W1 located inside the rinse drying cup portion 62a while rotating the first substrate W1.

When the time elapsed from the start of the rinse processing becomes greater than or equal to a predetermined portion 102 moves the first substrate W1 subjected to the rinse processing from the rinse drying cup portion 62a to the second immersion bath 61b2 and immerses the first substrate W1 subjected to the rinse processing in the second chemical liquid in the second immersion bath 61b2 (step S25). By immersing the first substrate W1 in the second chemical liquid, the second chemical liquid processing is executed on the first substrate W1.

Specifically, as illustrated in FIG. 32C, the controlling portion 102 controls the raising/lowering mechanism 210A such that the upper substrate holding portion 2A is raised from the third processing position P4 (see FIG. 29) to the facing position P1 of the rinse drying cup portion 62a and then controls the moving mechanism 220A such that the upper substrate holding portion 2A is moved from the facing position P1 of the rinse drying cup portion 62a to the facing position P1 of the second immersion bath 61b2. Then, the controlling portion 102 immerses the first substrate W1 in the second chemical liquid by submerging the first substrate W1 in the second chemical liquid in the second immersion bath 61b2 as in step S22.

The controlling portion 102 may execute the shaking-off processing before raising the upper substrate holding portion 2A to the facing position P1 of the rinse drying cup portion 62a.

In the example described with reference to FIGS. 30, 31, and 32A to 32F, when the first substrate W1 is immersed in the second chemical liquid, the controlling portion 102 leaves the first substrate W1 in the second immersion bath 61b2 as described with reference to FIG. 27 (step S26).

When the first substrate W1 is left in the second immersion bath 61b2, the controlling portion 102 cleans the plurality of upper chuck members 31 of the upper substrate holding portion 2A (step S27). Specifically, as illustrated in FIG. 32D, when the first substrate W1 is left in the second immersion bath 61b2, the controlling portion 102 controls the raising/lowering mechanism 210A such that the upper substrate holding portion 2A is raised from the second processing position P3 to the facing position P1 of the second immersion bath 61b2 and then controls the moving mechanism 220A such that the upper substrate holding portion 2A is moved to the facing position P1 of the cleaning bath 63. Then, the controlling portion 102 controls the raising/lowering mechanism 210A such that the upper substrate holding portion 2A is lowered to the cleaning position P5 (see FIG. 24) and immerses the plurality of upper chuck members 31 of the upper substrate holding portion 2A in the rinse liquid in the cleaning bath 63. In the present preferred embodiment, the controlling portion 102 rotates the upper spin base 32 in a state where the upper chuck member 31 is immersed in the rinse liquid.

When a predetermined time (predetermined cleaning time) has elapsed after the upper chuck member 31 is immersed in the rinse liquid in the cleaning bath 63, the controlling portion 102 controls the upper rotating portion 4 (upper motor body 42) such that the rotation of the upper spin base 32 is stopped and then controls the raising/lowering mechanism 210A such that the upper substrate holding portion 2A is raised from the cleaning position P5 to the facing position P1 of the cleaning bath 63. Then, the controlling portion 102 controls the moving mechanism 220A such that the upper substrate holding portion 2A is moved from the facing position P1 of the cleaning bath 63 to the facing position P1 of the rinse drying cup portion 62a.

When the upper substrate holding portion 2A is moved to the facing position P1 of the rinse drying cup portion 62a, the controlling portion 102 controls the transfer robot TR such that the second substrate W2 is carried into the first processing block PB1. Then, as in step S21, the controlling portion 102 causes the plurality of upper chuck members 31 to grip the second substrate W2 supported by the hand of the transfer robot TR. As a result, the upper substrate holding portion 2A receives the second substrate W2 from the transfer robot TR (step S28).

As illustrated in FIG. 32E, when the upper substrate holding portion 2A holds the second substrate W2, the controlling portion 102 controls the moving portion 200A (moving mechanism 220A) such that the upper substrate holding portion 2A is moved to the facing position P1 of the first immersion bath 61b1. Then, the controlling portion 102 immerses the second substrate W2 in the first chemical liquid by submerging the second substrate W2 in the first chemical liquid in the first immersion bath 61b1 as in step S22 (step S29).

When the second substrate W2 is immersed in the first chemical liquid, the controlling portion 102 leaves the second substrate W2 in the first immersion bath 61b1 as in step S26 (step S30). As illustrated in FIG. 32F, when the second substrate W2 is left in the first immersion bath 61b1, the controlling portion 102 immerses the upper chuck member 31 in the rinse liquid in the cleaning bath 63 to clean the upper chuck member 31 as in step S27 (step S31).

When a predetermined time (predetermined cleaning time) has elapsed after the upper chuck member 31 is immersed in the rinse liquid in the cleaning bath 63, the controlling portion 102 controls the upper rotating portion 4 (upper motor body 42) such that the rotation of the upper spin base 32 is stopped and then controls the raising/lowering mechanism 210A such that the upper substrate holding portion 2A is raised from the cleaning position P5 to the facing position P1 of the cleaning bath 63. Then, the controlling portion 102 controls the moving mechanism 220A such that the upper substrate holding portion 2A is moved from the facing position P1 of the cleaning bath 63 to the facing position P1 of the second immersion bath 61b2.

When the time elapsed after the first substrate W1 is immersed in the second chemical liquid becomes greater than or equal to a predetermined time (predetermined second chemical liquid processing time), the controlling portion 102 controls the raising/lowering mechanism 210A such that the upper substrate holding portion 2A is lowered from the facing position P1 of the second immersion bath 61b2 to the second processing position P3 and then controls the upper chuck driving mechanism 50 such that the plurality of upper chuck members 31 grip the first substrate W1 supported by the plurality of supporting portions 614 of the second immersion bath 61b2 (first substrate W1 subjected to the second chemical liquid processing). When the first substrate W1 is gripped by the plurality of upper chuck members 31, the controlling portion 102 moves the first substrate W1 subjected to the second chemical liquid processing from the second immersion bath 61b2 to the rinse drying cup portion 62a as in step S23 (step S32).

The controlling portion 102 may execute the shaking-off processing before raising the upper substrate holding portion 2A to the facing position P1 of the second immersion bath 61b2.

When the first substrate W1 is moved to the inside of the rinse drying cup portion 62a, the controlling portion 102 executes the rinse processing as in step S24 (step S33).

When the time elapsed from the start of the rinse processing of the first substrate W1 becomes greater than or equal to a predetermined time (predetermined rinse processing time), the controlling portion 102 executes the drying processing as described with reference to FIG. 20 (step S34). Specifically, after stopping the discharge of the rinse liquid, the controlling portion 102 increases the rotational speed of the first substrate W1 located inside the rinse drying cup portion 62a.

When the time elapsed from the start of the drying processing becomes greater than or equal to a predetermined time (predetermined drying time), the controlling portion 102 stops the rotation of the first substrate W1 and ends the drying processing. As a result, the first substrate W1 is dried.

When the drying processing ends, the controlling portion 102 controls the raising/lowering mechanism 210A such that the upper substrate holding portion 2A is raised to the facing position P1 of the rinse drying cup portion 62a. When the upper substrate holding portion 2A is raised to the facing position P1 of the rinse drying cup portion 62a, the controlling portion 102 causes the hand of the transfer robot TR to enter the inside of the first processing block PB1 through the carry-in/carry-out port corresponding to the first processing cup row L1. Then, the controlling portion 102 controls the upper chuck driving mechanism 50 such that the holding of the first substrate W1 by the plurality of upper chuck members 31 is released and the first substrate W1 is supported by the hand of the transfer robot TR and then controls the transfer robot TR such that the hand of the transfer robot TR is taken out to the outside of the first processing block PB1. As a result, the first substrate W1 processed by the first processing block PB1 is carried out from the first processing block PB1 (step S35).

After the first substrate W1 is carried out from the first processing block PB1, the controlling portion 102 controls the moving mechanism 220A such that the upper substrate holding portion 2A is moved from the facing position P1 of the rinse drying cup portion 62a to the facing position P1 of the first immersion bath 61b1.

When the time elapsed after the second substrate W2 is immersed in the first chemical liquid becomes greater than or equal to a predetermined time (predetermined first chemical liquid processing time), the controlling portion 102 controls the raising/lowering mechanism 210A such that the upper substrate holding portion 2A is lowered from the facing position P1 of the first immersion bath 61b1 to the second processing position P3 and then controls the upper chuck driving mechanism 50 such that the plurality of upper chuck members 31 grip the second substrate W2 supported by the plurality of supporting portions 614 of the first immersion bath 61b1 (second substrate W2 subjected to the first chemical liquid processing). When the second substrate W2 is gripped by the plurality of upper chuck members 31, the controlling portion 102 moves the second substrate W2 subjected to the first chemical liquid processing from the first immersion bath 61b1 to the rinse drying cup portion 62a as in step S23 (step S36).

The controlling portion 102 may execute the shaking-off processing before raising the upper substrate holding portion 2A to the facing position P1 of the first immersion bath 61b1.

As illustrated in FIG. 31, when the second substrate W2 is moved to the inside of the rinse drying cup portion 62a, the controlling portion 102 executes the rinse processing as in step S24 (step S37).

When the time elapsed from the start of the rinse processing becomes greater than or equal to a predetermined time (predetermined rinse processing time), the controlling portion 102 moves the second substrate W2 subjected to the rinse processing from the rinse drying cup portion 62a to the second immersion bath 61b2 and immerses the second substrate W2 subjected to the rinse processing in the second chemical liquid in the second immersion bath 61b2 as in step S25 (step S38). By immersing the second substrate W2 in the second chemical liquid, the second chemical liquid processing is executed on the second substrate W2. The upper substrate holding portion 2A holds the second substrate W2 during execution of the second chemical liquid processing on the second substrate W2.

The controlling portion 102 may execute the shaking-off processing before raising the upper substrate holding portion 2A to the facing position P1 of the rinse drying cup portion 62a.

When the time elapsed after the second substrate W2 is immersed in the second chemical liquid becomes greater than or equal to a predetermined time (predetermined second chemical liquid processing time), the controlling portion 102 moves the second substrate W2 subjected to the second chemical liquid processing from the second immersion bath 61b2 to the rinse drying cup portion 62a as in step S23 (step S39).

The controlling portion 102 may execute the shaking-off processing before raising the upper substrate holding portion 2A to the facing position P1 of the second immersion bath 61b2.

When the second substrate W2 is moved to the inside of the rinse drying cup portion 62a, the controlling portion 102 executes the rinse processing as in step S24 (step S40).

When the time elapsed from the start of the rinse processing of the second substrate W2 becomes greater than or equal to a predetermined time (predetermined rinse processing time), the controlling portion 102 executes the drying processing as in step S34 (step S41). As a result, the second substrate W2 is dried. When the drying processing ends, the controlling portion 102 carries out the second substrate W2 from the first processing block PB1 as in step S35 (step S42). As a result, the processing illustrated in FIGS. 30 and 31 ends.

As described above with reference to FIGS. 30, 31, and 32A to 32F, since the first immersion bath 61b1 and the second immersion bath 61b2 each have the supporting portion 614, two substrates W can be immersed in the chemical liquid in parallel.

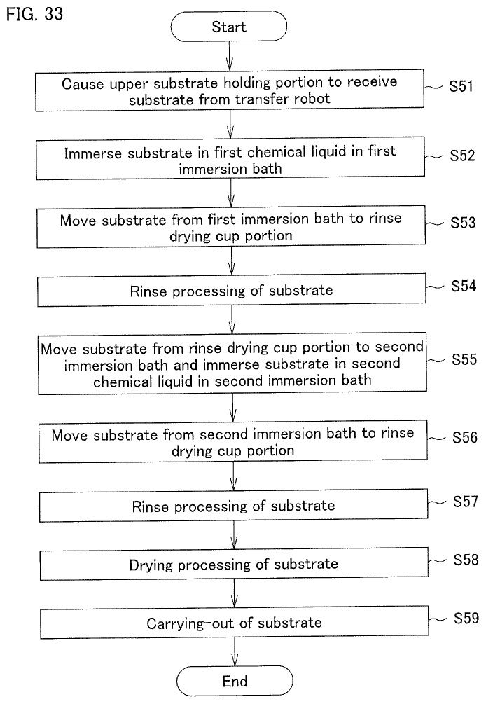

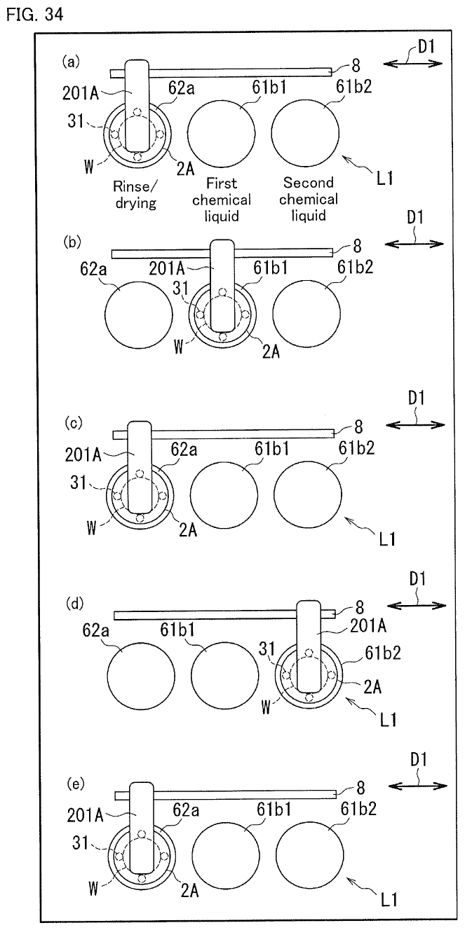

Subsequently, another example of the operation of the substrate processing apparatus 100 according to Preferred Embodiment 3 will be described with reference to FIGS. 25 to 29, 33, and 34A to 34E using the first processing cup row L1 of the first processing block PB1 as an example. FIG. 33 is a diagram illustrating another example of the operation flow of the substrate processing apparatus 100 according to Preferred Embodiment 3. Specifically, FIG. 33 illustrates an example of the flow of processing executed by the controlling portion 102 when one substrate W is processed in the first processing cup row L1 of the first processing block PB1. FIGS. 34A to 34E are views schematically illustrating another example of the operation of the substrate processing apparatus 100 according to Preferred Embodiment 3. Specifically, FIGS. 34A to 34E illustrate an example of the operation of the first processing block PB1 when one substrate W is processed in the first processing cup row L1 of the first processing block PB1. In FIGS. 34A to 34E, the cleaning bath 63 is omitted for easy understanding.

The processing illustrated in FIG. 33 includes steps S51 to S59. Through the processing illustrated in FIG. 33, one substrate W is processed according to the processing procedure. Specifically, the first chemical liquid processing, the rinse processing, the second chemical liquid processing, the rinse processing, and the drying processing are executed on one substrate W in that order.

The processing illustrated in FIG. 33 starts when the transfer robot TR carries the substrate W into the first processing block PB1 through the carry-in/carry-out port corresponding to the first processing cup row L1 of the first processing block PB1.

As illustrated in FIGS. 33 and 34A, when the transfer robot TR is controlled such that the substrate W is carried into the first processing block PB1, the controlling portion 102 causes the plurality of upper chuck members 31 to grip the first substrate W1 supported by the hand of the transfer robot TR as in step S21 in FIG. 30. As a result, the upper substrate holding portion 2A receives the substrate W from the transfer robot TR (step S51).

As illustrated in FIGS. 33 and 34B, when the upper substrate holding portion 2A holds the substrate W, the controlling portion 102 immerses the substrate W in the first chemical liquid by submerging the substrate W in the first chemical liquid in the first immersion bath 61b1 as in step S22 in FIG. 30 (step S52).

As illustrated in FIGS. 33 and 34C, when the time elapsed after the substrate W is immersed in the first chemical liquid becomes greater than or equal to a predetermined time (predetermined first chemical liquid processing time), the controlling portion 102 moves the substrate W subjected to the first chemical liquid processing from the first immersion bath 61b1 to the rinse drying cup portion 62a as in step S23 in FIG. 30 (step S53).

As illustrated in FIG. 33, when the substrate W is moved to the inside of the rinse drying cup portion 62a, the controlling portion 102 executes the rinse processing as in step S24 in FIG. 30 (step S54).

As illustrated in FIGS. 33 and 34D, when the time elapsed from the start of the rinse processing becomes greater than or equal to a predetermined time (predetermined rinse processing time), the controlling portion 102 moves the substrate W subjected to the rinse processing from the rinse drying cup portion 62a to the second immersion bath 61b2 and immerses the substrate W subjected to the rinse processing in the second chemical liquid in the second immersion bath 61b2 as in step S25 in FIG. 30 (step S55). In the example described with reference to FIGS. 33 and 34A to 34E, the upper substrate holding portion 2A holds the substrate W during the second chemical liquid processing.

As illustrated in FIGS. 33 and 34E, when the time elapsed after the substrate W is immersed in the second chemical liquid becomes greater than or equal to a predetermined time (predetermined second chemical liquid processing time), the controlling portion 102 moves the substrate W subjected to the second chemical liquid processing from the second immersion bath 61b2 to the rinse drying cup portion 62a as in step S32 in FIG. 30 (step S56).

When the substrate W is moved to the inside of the rinse drying cup portion 62a, the controlling portion 102 executes the rinse processing as in step S33 in FIG. 30 (step S57).

When the time elapsed from the start of the rinse processing of the substrate W becomes greater than or equal to a predetermined time (predetermined rinse processing time), the controlling portion 102 executes the drying processing as in step S34 in FIG. 30 (step S58). As a result, the substrate W is dried.

When the drying processing ends, the controlling portion 102 carries out the substrate W from the first processing block PB1 as in step S35 in FIG. 30 (step S59). As a result, the processing illustrated in FIG. 33 ends.

As described above with reference to FIGS. 33 and 34A to 34E, the controlling portion 102 controls the moving portion 200A such that the upper substrate holding portion 2A is moved according to the processing procedure.

As described with reference to FIGS. 33 and 34A to 34E, when the substrates W are processed one by one in one processing cup row L, the upper chuck member 31 may not be cleaned during the substrate processing. Therefore, when the substrates W are processed one by one in one processing cup row L, the cleaning unit CU may be omitted. However, the upper chuck member 31 may be cleaned during the substrate processing.

In addition, as described with reference to FIGS. 33 and 34A to 34E, when the substrates W are processed one by one in one processing cup row L, the processing of leaving the substrate W can be omitted. Therefore, when the substrates W are processed one by one in one processing cup row L, the supporting portion 614 may be omitted. However, the processing of leaving the substrate W may be performed.

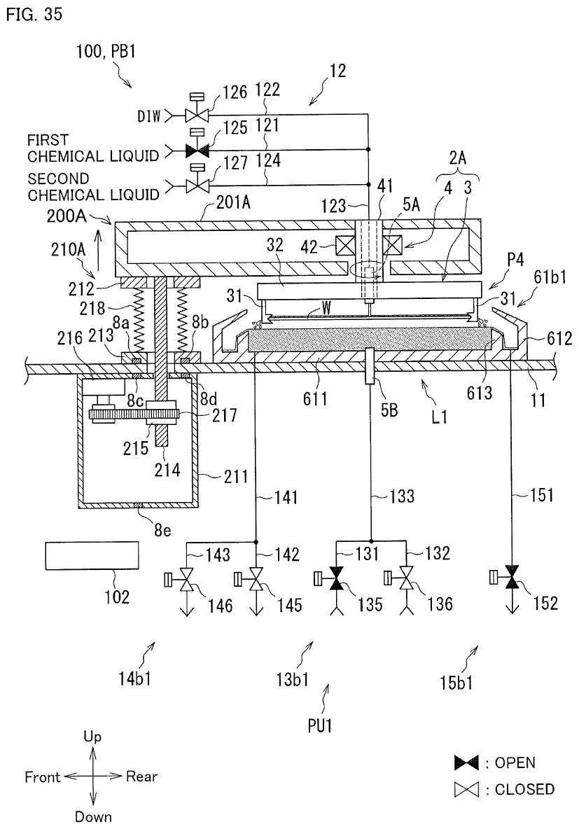

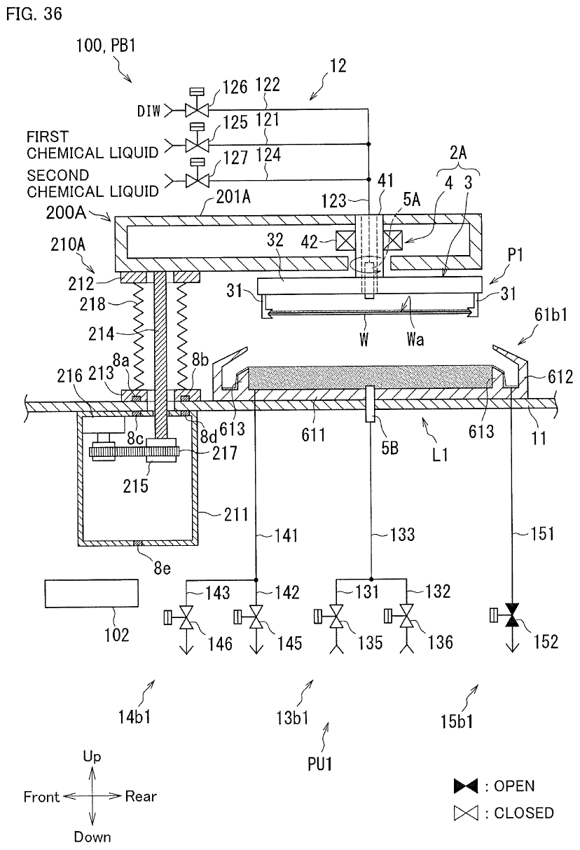

Subsequently, an example of the processing of moving the substrate W from a certain processing cup portion 6 to another processing cup portion 6 will be described by taking a case of moving the substrate W from the first immersion bath 61b1 to the rinse drying cup portion 62a as an example with reference to FIGS. 35 and 36. FIGS. 35 and 36 are views illustrating the processing of pulling up the substrate W from the first chemical liquid. FIGS. 35 and 36 illustrate the first liquid supplying portion 12, the upper substrate holding portion 2A, a portion of the moving portion 200A, the first chemical liquid processing unit PU1, and the first rail member 8a to the fifth rail member 8e which correspond to the first processing cup row L1 of the first processing block PB1. FIGS. 35 and 36 schematically illustrate the cross sections of the moving portion 200A and the first immersion bath 61b1 as viewed from the left side.

As illustrated in FIG. 35, when the substrate W is pulled up from the first chemical liquid through the pulling-up processing, the controlling portion 102 switches the first opening/closing valve 125 of the first liquid supplying portion 12 from the closed state to the open state and discharges the first chemical liquid from the upper nozzle portion 5A.

When the upper substrate holding portion 2A is raised to the third processing position P4, the controlling portion 102 switches the first opening/closing valve 125 of the first liquid supplying portion 12 from the open state to the closed state, stops the discharge of the first chemical liquid from the upper nozzle portion 5A, and executes the paddle processing of supporting a liquid film of the first chemical liquid on the upper surface Wa of the substrate W.

Specifically, the controlling portion 102 controls the upper rotating portion 4 (upper motor body 42) such that the rotational speed of the substrate W is reduced to a rotational speed at which the first chemical liquid is not drained from the substrate W. For example, the controlling portion 102 may reduce the rotational speed of the substrate W to 10 rpm. As a result, the liquid film of the first chemical liquid is supported on the upper surface Wa of the substrate W. Hereinafter, the state in which the processing liquid is supported on the upper surface Wa of the substrate W may be referred to as a “paddle state.”

When the liquid film of the first chemical liquid is supported on the upper surface Wa of the substrate W, as illustrated in FIG. 36, the controlling portion 102 controls the raising/lowering mechanism 210A such that the upper substrate holding portion 2A is moved from the third processing position P4 to the facing position P1 of the first immersion bath 61b1 while maintaining the paddle state. That is, the controlling portion 102 raises the substrate W from the inside of the first immersion bath 61b1 to the over position of the first immersion bath 61b1 while rotating the substrate W at a rotational speed at which the liquid film of the first chemical liquid is held on the upper surface Wa of the substrate W.

Thereafter, while maintaining the paddle state, the controlling portion 102 controls the moving portion 200A such that the substrate W is moved from the over position of the first immersion bath 61b1 to the position inside the rinse drying cup portion 62a.

The timing at which the discharge of the first chemical liquid from the upper nozzle portion 5A is started is not particularly limited as long as it is before the substrate W moves upward (outward) from the first immersion bath 61b1. For example, the controlling portion 102 may cause the upper nozzle portion 5A to start the discharge of the first chemical liquid when the substrate W is immersed in the first chemical liquid.

Further, in the paddle processing described with reference to FIGS. 35 and 36, the paddle state is formed by reducing the rotational speed of the substrate W to the rotational speed at which the first chemical liquid is not drained from the substrate W, but the controlling portion 102 may stop the rotation of the substrate W and support the liquid film of the first chemical liquid on the upper surface Wa of the substrate W.

As described with reference to FIGS. 35 and 36, by supporting the liquid film of the first chemical liquid on the upper surface Wa of the substrate W, it is possible to suppress the upper surface Wa of the substrate W from being dried while the substrate W is moved from the first immersion bath 61b1 to the rinse drying cup portion 62a. As a result, it is possible to suppress collapse of a pattern and generation of particles.

In the example illustrated in FIGS. 35 and 36, the substrate W is moved from the first immersion bath 61b1 to the rinse drying cup portion 62a in a state where the liquid film of the first chemical liquid is supported (held) on the upper surface Wa of the substrate W, but the substrate W may be moved from the first immersion bath 61b1 to the rinse drying cup portion 62a in a state where the liquid film of the rinse liquid is supported (held) on the upper surface Wa of the substrate W.

Similarly, when the substrate W is moved from the rinse drying cup portion 62a to the second immersion bath 61b2, the liquid film of the rinse liquid or the second chemical liquid may be supported (held) on the upper surface Wa of the substrate W, or when the substrate W is moved from the second immersion bath 61b2 to the rinse drying cup portion 62a, the liquid film of the second chemical liquid or the rinse liquid may be supported (held) on the upper surface Wa of the substrate W.

Preferred Embodiment 3 of the present invention has been described above with reference to FIGS. 25 to 36. According to Preferred Embodiment 3, similarly to the preferred embodiments described with reference to FIGS. 1 to 24, since one substrate W in the horizontal posture is immersed in the chemical liquid stored in the immersion bath 61b and the substrate W is processed, the consumption amount of the chemical liquid can be reduced.

Furthermore, according to Preferred Embodiment 3, the substrate W can be immersed in the chemical liquid by submerging the substrate W in the chemical liquid stored in the immersion bath 61b. Therefore, it is not necessary to drain the chemical liquid from the immersion bath 61b every time the substrate W is processed, and thus the consumption amount of the chemical liquid can be further reduced. However, the chemical liquid may be drained from the immersion bath 61b every time the substrate W is processed.

In Preferred Embodiment 3, each of the first processing block PB1 and the second processing block PB2 has one upper substrate holding portion 2A for each processing cup row L, but the number of upper substrate holding portions 2A is not limited to one. As described with reference to FIG. 21, each of the first processing block PB1 and the second processing block PB2 may have a plurality of upper substrate holding portions 2A for each processing cup row L.

Further, in Preferred Embodiment 3, although the configuration in which the first liquid supplying portion 12 can supply two types of chemical liquids to the upper nozzle portion 5A has been exemplified, the first liquid supplying portion 12 may have a configuration in which three or more types of chemical liquids can be supplied to the upper nozzle portion 5A. Similarly, the second liquid supplying portions 13b1 and 13b2 may have a configuration in which two or three or more types of chemical liquids can be supplied to the lower nozzle portion 5B.

In Preferred Embodiment 3, the two first processing cup portions 61 are included in the plurality of processing cup portions 6 of each processing cup row L, but the number of the first processing cup portions 61 is not limited to two. For example, one first processing cup portion 61 may be included in the plurality of processing cup portions 6 of each processing cup row L, or three or more first processing cup portions 61 may be included therein. Specifically, in Preferred Embodiment 3, the two immersion baths 61b are included in the plurality of processing cup portions 6 of each processing cup row L, but one immersion bath 61b may be included in the plurality of processing cup portions 6 of each processing cup row L, or three or more immersion baths 61b may be included therein.

Further, in Preferred Embodiment 3, the first immersion bath 61b1 has the inner wall portion 613, but the inner wall portion 613 of the first immersion bath 61b1 may be omitted. In this case, one of the first draining portion 14b1 and the second draining portion 15b1 may be omitted.

Similarly, in Preferred Embodiment 3, the second immersion bath 61b2 has the inner wall portion 613, but the inner wall portion 613 of the second immersion bath 61b2 may be omitted. In this case, one of the first draining portion 14b2 and the second draining portion 15b2 may be omitted.

In Preferred Embodiment 3, the substrate W is not immersed in the rinse liquid when the rinse processing is executed inside the rinse drying cup portion 62a, but, as described with reference to FIG. 18, the rinse processing may include a step of immersing the substrate W in the rinse liquid.

In Preferred Embodiment 3, the inner wall portion 613 is not provided in the rinse drying cup portion 62a, but the rinse drying cup portion 62a may have the inner wall portion 613.

In Preferred Embodiment 3, the plurality of supporting portions 614 are not provided in the rinse drying cup portion 62a, but the rinse drying cup portion 62a may have the plurality of supporting portions 614.

In Preferred Embodiment 3, the cleaning bath 63 is disposed on the most right side among the plurality of corresponding processing cup portions 6, but the position of the cleaning bath 63 is not particularly limited. For example, the cleaning bath 63 may be disposed on the most left side among the plurality of corresponding processing cup portions 6.

In Preferred Embodiment 3, the placing table 7 is not provided, but the placing table 7 may be provided for each processing cup row L as in the preferred embodiments described with reference to FIGS. 1 to 24.

### Modification Example 3

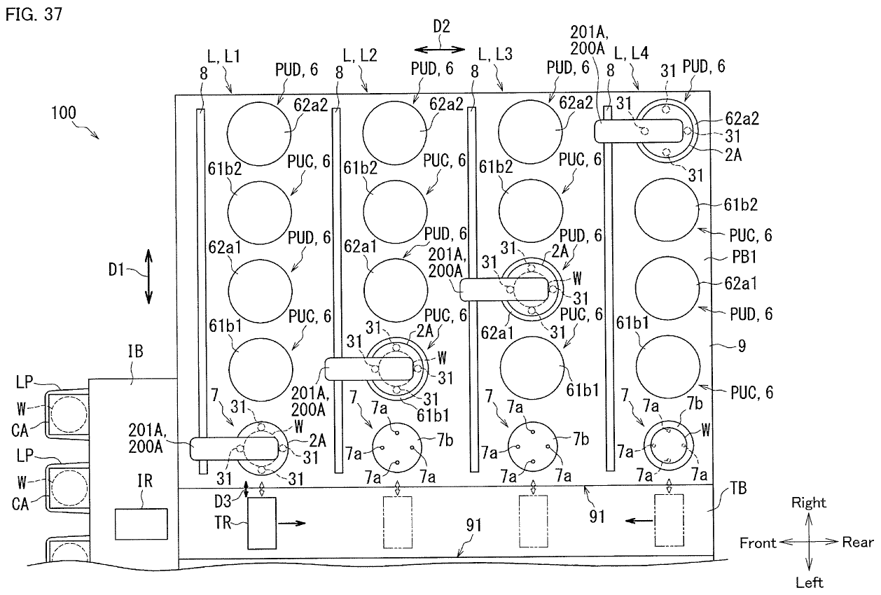

Subsequently, a substrate processing apparatus 100 according to Modification Example 3 will be described with reference to FIGS. 37, 38, and 39A to 39D. However, matters differing from the preferred embodiments described with reference to FIGS. 1 to 36 will be described, and the description of matters that are the same as in the preferred embodiments described with reference to FIGS. 1 to 36 will be omitted.

In the preferred embodiment described with reference to FIGS. 25 to 36, the one second processing cup portion 62 is included in the plurality of processing cup portions 6 of each processing cup row L, but a plurality of second processing cup portions 62 may be included in the plurality of processing cup portions 6 of each processing cup row L. Modification Example 3 is different from the preferred embodiments described with reference to FIGS. 1 to 36 in that a plurality of second processing cup portions 62 are included in the plurality of processing cup portions 6 of each processing cup row L.

FIG. 37 is an enlarged schematic plan view of a portion of the substrate processing apparatus 100 according to Modification Example 3. Specifically, FIG. 37 illustrates a configuration of the first processing block PB1 included in the substrate processing apparatus 100 according to Modification Example 3. Although not illustrated, the configuration of the second processing block PB2 is similar to the configuration of the first processing block PB1.

As illustrated in FIG. 37, in Modification Example 3, the plurality of processing cup portions 6 of each processing cup row L include the plurality of first processing cup portions 61 and a plurality of second processing cup portions 62. In the example illustrated in FIG. 37, the placing table 7 is provided for each processing cup row L.

The first processing cup portions 61 and the second processing cup portions 62 are alternately arranged in the first direction D1 (left-right direction). One of the second processing cup portions 62 may be disposed on the most right side among the plurality of processing cup portions 6.

Specifically, the plurality of first processing cup portions 61 include two immersion baths 61b (first immersion bath 61b1 and second immersion bath 61b2). The plurality of second processing cup portion 62 include two rinse drying cup portions 62a. Hereinafter, one of the two rinse drying cup portions 62a may be referred to as a “first rinse drying cup portion 62al.” The other of the two rinse drying cup portions 62a may be referred to as a “second rinse drying cup portion 62a2.” The two immersion baths 61b (first immersion bath 61b1 and second immersion bath 61b2) and the two rinse drying cup portions 62a (first rinse drying cup portion 62al and second rinse drying cup portion 62a2) are disposed in the order of the first immersion bath 61b1, the first rinse drying cup portion 62al, the second immersion bath 61b2, and the second rinse drying cup portion 62a2 from the left side.

Specifically, the first processing block PB1 and the second processing block PB2 each have two rinse drying processing units PUD and two chemical liquid processing units PUC for each processing cup row L.

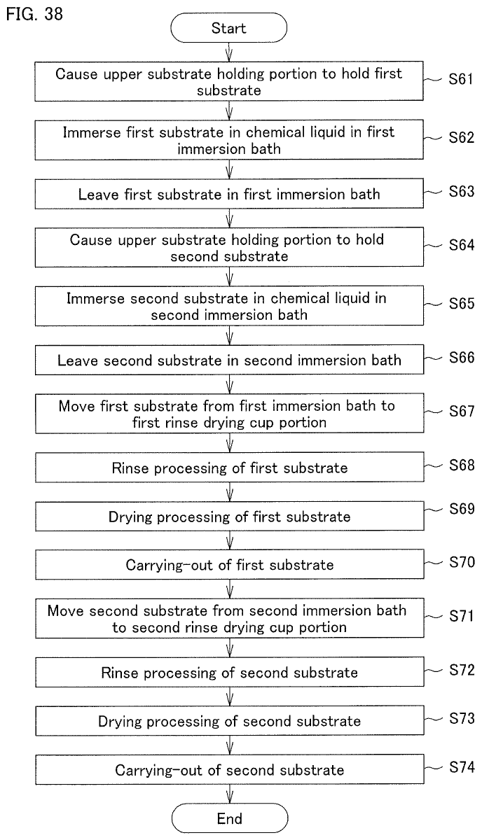

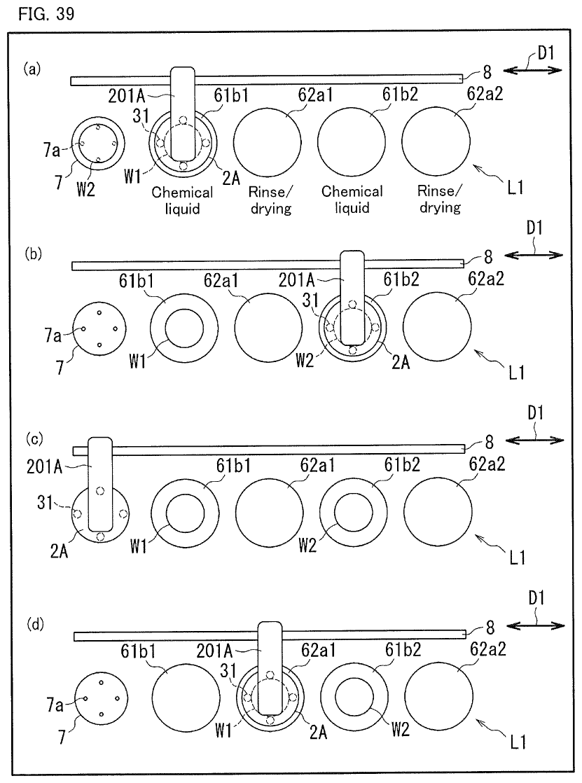

Subsequently, an example of the operation of the substrate processing apparatus 100 according to Modification Example 3 will be described with reference to FIGS. 37, 38, and 39A to 39D using the first processing cup row L1 of the first processing block PB1 as an example. FIG. 38 is a diagram illustrating an example of the operation flow of the substrate processing apparatus 100 according to Modification Example 3. Specifically, FIG. 38 illustrates an example of the flow of processing executed by the controlling portion 102 when two substrates W (first substrate W1 and second substrate W2) are processed in the first processing cup row L1 of the first processing block PB1. FIGS. 39A to 39D are views schematically illustrating an example of the operation of the substrate processing apparatus 100 according to Modification Example 3. Specifically, FIGS. 39A to 39D illustrate an example of the operation of the first processing block PB1 when two substrates W (first substrate W1 and second substrate W2) are processed in the first processing cup row L1 of the first processing block PB1.

The processing illustrated in FIG. 38 includes steps S61 to S74. Through the processing illustrated in FIG. 38, each substrate W is processed according to the processing procedure. In Modification Example 3, the same type of chemical liquid is stored in each of the first immersion bath 61b1 and the second immersion bath 61b2, and the chemical liquid processing, the rinse processing, and the drying processing are executed on each substrate W in that order.

The processing illustrated in FIG. 38 starts when the first substrate W1 is placed on the placing table 7 corresponding to the first processing cup row L1. As illustrated in FIG. 38, when the first substrate W1 is placed on the placing table 7, the controlling portion 102 causes the upper substrate holding portion 2A to hold the first substrate W1 (step S61).

As illustrated in FIG. 39A, when the first substrate W1 is held by the upper substrate holding portion 2A, the controlling portion 102 immerses the first substrate W1 in the chemical liquid in the first immersion bath 61b1 (step S62). Then, the controlling portion 102 leaves the first substrate W1 in the first immersion bath 61b1 (step S63).

When the second substrate W2 is placed on the placing table 7 before the chemical liquid processing on the first substrate W1 is ended, the controlling portion 102 causes the upper substrate holding portion 2A to hold the second substrate W2 (step S64).

As illustrated in FIG. 39B, when the second substrate W2 is held by the upper substrate holding portion 2A, the controlling portion 102 immerses the second substrate W2 in the chemical liquid in the second immersion bath 61b2 (step S65). Then, the controlling portion 102 leaves the second substrate W2 in the second immersion bath 61b2 (step S66). As a result, as illustrated in FIG. 39C, operations of the chemical liquid processing are performed on two substrates W (first substrate W1 and second substrate W2) in parallel.

As illustrated in FIG. 39D, when a predetermined time (predetermined chemical liquid processing time) has elapsed after the first substrate W1 is immersed in the chemical liquid, the controlling portion 102 moves the first substrate W1 from the first immersion bath 61b1 to the first rinse drying cup portion 62al (step S67). Then, the controlling portion 102 executes the rinse processing on the first substrate W1 subjected to the chemical liquid processing inside the first rinse drying cup portion 62a1 (step S68).

When a predetermined time (predetermined rinse processing time) has elapsed from the start of the rinse processing on the first substrate W1, the controlling portion 102 ends the rinse processing and executes the drying processing inside the first rinse drying cup portion 62al (step S69). As a result, the first substrate W1 is dried. When the drying processing ends, the controlling portion 102 carries out the first substrate W1 from the first processing block PB1 (step S70).

When a predetermined time (predetermined chemical liquid processing time) has elapsed after the second substrate W2 is immersed in the chemical liquid, the controlling portion 102 moves the second substrate W2 from the second immersion bath 61b2 to the second rinse drying cup portion 62a2 (step S71). Then, the controlling portion 102 executes the rinse processing on the second substrate W2 subjected to the chemical liquid processing inside the second rinse drying cup portion 62a2 (step S72).

When a predetermined time (predetermined rinse processing time) has elapsed from the start of the rinse processing on the second substrate W2, the controlling portion 102 ends the rinse processing and executes the drying processing inside the second rinse drying cup portion 62a2 (step S73). As a result, the second substrate W2 is dried. When the drying processing ends, the controlling portion 102 carries out the second substrate W2 from the first processing block PB1 (step S74).

The substrate processing apparatus 100 according to Modification Example 3 has been described above with reference to FIGS. 37, 38, and 39A to 39D. According to Modification Example 3, operations of the chemical liquid processing can be performed on the plurality of substrates W in parallel.

In Modification Example 3, the same type of chemical liquid is stored in the two immersion baths 61b, but different types of chemical liquids may be stored in the two immersion baths 61b. In this case, each of the first processing block PB1 and the second processing block PB2 may have the cleaning unit CU (cleaning bath 63) for each processing cup row L.

In Modification Example 3, the placing table 7 is provided for each processing cup row L, but the placing table 7 may be omitted.

### Modification Example 4

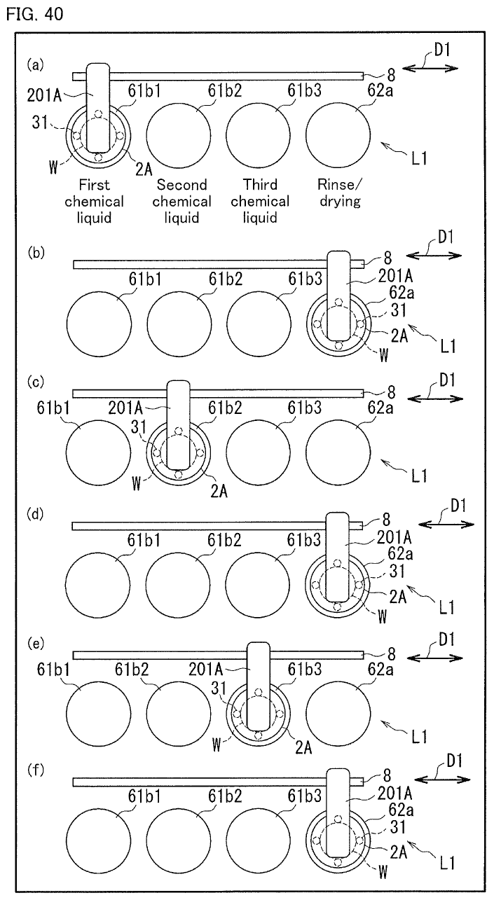

Subsequently, a substrate processing apparatus 100 according to Modification Example 4 will be described with reference to FIGS. 40A to 40F. However, matters differing from the preferred embodiments described with reference to FIGS. 1 to 39 will be described, and the description of matters that are the same as in the preferred embodiments described with reference to FIGS. 1 to 39 will be omitted.

FIGS. 40A to 40F are views schematically illustrating an example of the operation of the substrate processing apparatus 100 according to Modification Example 4. Specifically, FIGS. 40A to 40F illustrate an example of the operation of the first processing block PB1 when one substrate W is processed in the first processing cup row L1 of the first processing block PB1.

Further, in the preferred embodiments described with reference to FIGS. 25 to 39, the plurality of processing cup portions 6 include two immersion baths 61b, but the plurality of processing cup portions 6 may include three or more immersion baths 61b. In Modification Example 4, as illustrated in FIG. 40A, the plurality of processing cup portions 6 include three immersion baths 61b (first immersion bath 61b1 to third immersion bath 61b3) and one rinse drying cup portion 62a. In addition, different types of chemical liquids (first chemical liquid to third chemical liquid) are stored in the three immersion baths 61b (first immersion bath 61b1 to third immersion bath 61b3). Hereinafter, an example of the operation of the substrate processing apparatus 100 in a case where three or more immersion baths 61b are included in the plurality of processing cup portions 6 will be described using the configuration illustrated in FIGS. 40A to 40F as an example.

First, as illustrated in FIG. 40A, the controlling portion 102 causes the upper substrate holding portion 2A to hold the substrate W carried into the first processing block PB1 by the transfer robot TR. Then, the controlling portion 102 immerses the substrate W in the first chemical liquid in the first immersion bath 61b1.

As illustrated in FIG. 40B, when a predetermined time (predetermined first chemical liquid processing time) has elapsed after the substrate W is immersed in the first chemical liquid, the controlling portion 102 moves the substrate W from the first immersion bath 61b1 to the rinse drying cup portion 62a. Then, the controlling portion 102 executes the rinse processing on the substrate W subjected to the first chemical liquid processing inside the rinse drying cup portion 62a.

As illustrated in FIG. 40C, when a predetermined time (predetermined rinse processing time) has elapsed from the start of the rinse processing on the substrate W subjected to the first chemical liquid processing, the controlling portion 102 ends the rinse processing and immerses the substrate W subjected to the rinse processing in the second chemical liquid in the second immersion bath 61b2.

As illustrated in FIG. 40D, when a predetermined time (predetermined second chemical liquid processing time) has elapsed after the substrate W is immersed in the second chemical liquid, the controlling portion 102 moves the substrate W from the second immersion bath 61b2 to the rinse drying cup portion 62a. Then, the controlling portion 102 executes the rinse processing on the substrate W subjected to the second chemical liquid processing inside the rinse drying cup portion 62a.

As illustrated in FIG. 40E, when a predetermined time (predetermined rinse processing time) has elapsed from the start of the rinse processing on the substrate W subjected to the second chemical liquid processing, the controlling portion 102 ends the rinse processing and immerses the substrate W subjected to the rinse processing in the third chemical liquid in the third immersion bath 61b3.

As illustrated in FIG. 40F, when a predetermined time (predetermined third chemical liquid processing time) has elapsed after the substrate W is immersed in the third chemical liquid, the controlling portion 102 moves the substrate W from the third immersion bath 61b3 to the rinse drying cup portion 62a. Then, the controlling portion 102 executes the rinse processing on the substrate W subjected to the third chemical liquid processing inside the rinse drying cup portion 62a.

When a predetermined time (predetermined rinse processing time) has elapsed from the start of the rinse processing on the substrate W subjected to the third chemical liquid processing, the controlling portion 102 ends the rinse processing and executes the drying processing inside the rinse drying cup portion 62a.

The substrate processing apparatus 100 according to Modification Example 4 has been described above with reference to FIGS. 40A to 40F. According to Modification Example 4, a greater number of immersion baths 61b can be disposed in a restricted space. Therefore, the substrate W can be processed using three or more types of chemical liquids.

In Modification Example 4, the placing table 7 is not provided, but the placing table 7 may be provided for each processing cup row L as in the preferred embodiments described with reference to FIGS. 1 to 24.

### Modification Example 5

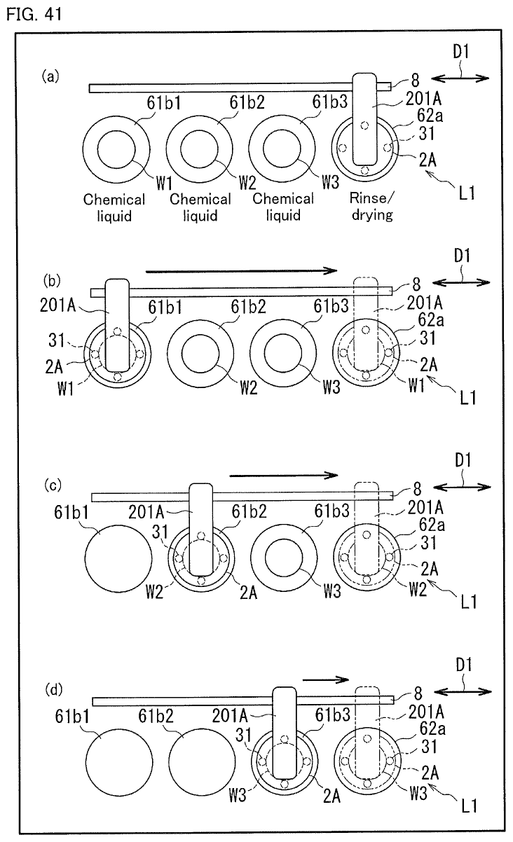

Subsequently, a substrate processing apparatus 100 according to Modification Example 5 will be described with reference to FIGS. 41A to 41D. However, matters differing from the preferred embodiments described with reference to FIGS. 1 to 39 and 40A to 40F will be described, and the description of matters that are the same as in the preferred embodiments described with reference to FIGS. 1 to 39 and 40A to 40F will be omitted.

FIGS. 41A to 41D are views schematically illustrating an example of the operation of the substrate processing apparatus 100 according to Modification Example 5. Specifically, FIGS. 41A to 41D illustrate an example of the operation of the first processing block PB1 when three substrates W (first substrate W1 to third substrate W3) are processed in the first processing cup row L1 of the first processing block PB1.

In Modification Example 5, similarly to Modification Example 4, the plurality of processing cup portions 6 include three immersion baths 61b (first immersion bath 61b1 to third immersion bath 61b3) and one rinse drying cup portion 62a. In Modification Example 5, the same type of chemical liquid is stored in the three immersion baths 61b (first immersion bath 61b1 to third immersion bath 61b3).

As illustrated in FIG. 41A, in Modification Example 5, the first substrate W1 to the third substrate W3 are left in the first immersion bath 61b1 to the third immersion bath 61b3, respectively. Therefore, the first substrate W1 to the third substrate W3 are subjected to chemical liquid processing in parallel.

As illustrated in FIG. 41B, for example, when the time elapsed after the first substrate W1 is immersed in the chemical liquid in the first immersion bath 61b1 becomes greater than or equal to a predetermined time (predetermined chemical liquid processing time), the controlling portion 102 moves the first substrate W1 from the first immersion bath 61b1 to the rinse drying cup portion 62a, executes the rinse processing and the drying processing on the first substrate W1, and then carries out the first substrate W1 from the first processing block PB1.

Similarly, when the time elapsed after the second substrate W2 is immersed in the chemical liquid in the second immersion bath 61b2 becomes greater than or equal to a predetermined time (predetermined chemical liquid processing time), as illustrated in FIG. 41C, the controlling portion 102 moves the second substrate W2 from the second immersion bath 61b2 to the rinse drying cup portion 62a, executes the rinse processing and the drying processing on the second substrate W2, and then carries out the second substrate W2 from the first processing block PB1. In addition, when the time elapsed after the third substrate W3 is immersed in the chemical liquid in the third immersion bath 61b3 becomes greater than or equal to a predetermined time (predetermined chemical liquid processing time), as illustrated in FIG. 41D, the controlling portion 102 moves the third substrate W3 from the third immersion bath 61b3 to the rinse drying cup portion 62a, executes the rinse processing and the drying processing on the third substrate W3, and then carries out the third substrate W3 from the first processing block PB1.

Modification Example 5 has been described above with reference to FIGS. 41A to 41D. According to Modification Example 5, operations of the chemical liquid processing can be executed on the plurality of substrates W in parallel. Therefore, the waiting time for waiting for the timing to start the chemical liquid processing can be reduced.

In Modification Example 5, the same type of chemical liquid is stored in the first immersion bath 61b1 to the third immersion bath 61b3, but different types of chemical liquids may be stored in the first immersion bath 61b1 to the third immersion bath 61b3. In this case, each of the first processing block PB1 and the second processing block PB2 may have the cleaning unit CU (cleaning bath 63) for each processing cup row L.

In Modification Example 5, the placing table 7 is not provided, but the placing table 7 may be provided for each processing cup row L as in the preferred embodiments described with reference to FIGS. 1 to 24.

### Modification Example 6

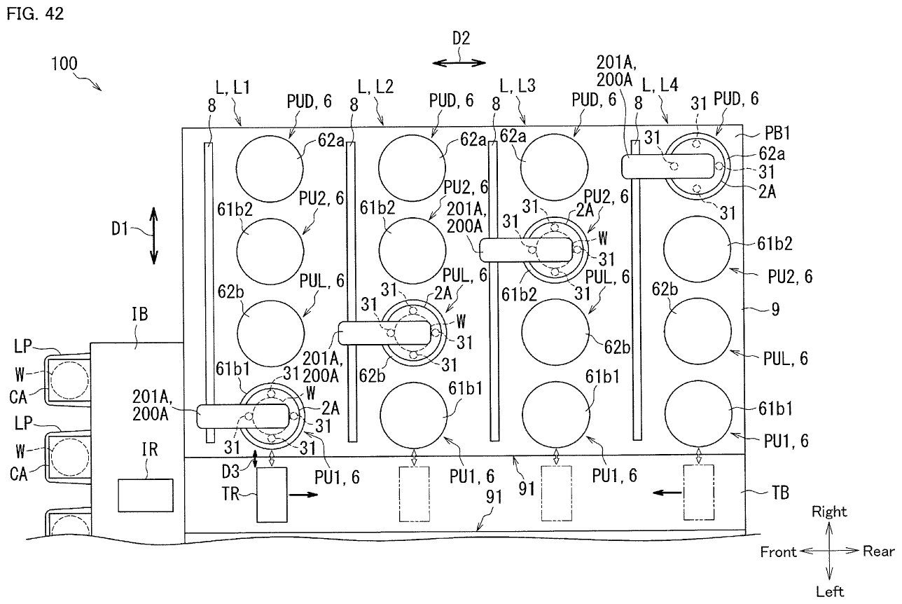

Subsequently, a substrate processing apparatus 100 according to Modification Example 6 will be described with reference to FIGS. 42, 43, and 44A to 44F. However, matters differing from the preferred embodiments described with reference to FIGS. 1 to 39, 40A to 40F, and 41A to 41D will be described, and the description of matters that are the same as in the preferred embodiments described with reference to FIGS. 1 to 39, 40A to 40F, and 41A to 41D will be omitted. Modification Example 6 is different from the preferred embodiments described with reference to FIGS. 25 to 39, 40A to 40F, and 41A to 41D in that a rinse cup portion 62b is included in each processing cup row L.

FIG. 42 is an enlarged schematic plan view of a portion of the substrate processing apparatus 100 according to Modification Example 6. Specifically, FIG. 42 illustrates a configuration of the first processing block PB1 included in the substrate processing apparatus 100 according to Modification Example 6. Although not illustrated, the configuration of the second processing block PB2 is similar to the configuration of the first processing block PB1.

As illustrated in FIG. 42, in Modification Example 6, the plurality of processing cup portions 6 of each processing cup row L include the plurality of first processing cup portions 61 and the plurality of second processing cup portions 62. In the example illustrated in FIG. 42, the plurality of processing cup portions 6 of each processing cup row L include two first processing cup portions 61 and two second processing cup portions 62.

Specifically, the plurality of first processing cup portions 61 include two immersion baths 61b (first immersion bath 61b1 and second immersion bath 61b2). The plurality of second processing cup portions 62 include one rinse drying cup portion 62a and one rinse cup portion 62b.

The two immersion baths 61b (first immersion bath 61b1 and second immersion bath 61b2), the one rinse drying cup portion 62a, and the one rinse cup portion 62b are arranged in accordance with the processing procedure. Specifically, the first immersion bath 61b1, the second immersion bath 61b2, the rinse drying cup portion 62a, and the rinse cup portion 62b are disposed in the order of the first immersion bath 61b1, the rinse cup portion 62b, the second immersion bath 61b2, and the rinse drying cup portion 62a from the left side. The rinse drying cup portion 62a is disposed on the most right side among the plurality of processing cup portions 6. The rinse cup portion 62b is disposed between the two immersion baths 61b (two first processing cup portions 61).

Specifically, the first chemical liquid processing, the rinse processing, the second chemical liquid processing, the rinse processing, and the drying processing are executed on the substrate W in that order. The first chemical liquid is stored in the first immersion bath 61b1. The second chemical liquid is stored in the second immersion bath 61b2. The rinse cup portion 62b is used for the rinse processing after the first chemical liquid processing. The rinse cup portion 62b receives the rinse liquid drained from the substrate W held by the upper substrate holding portion 2A.

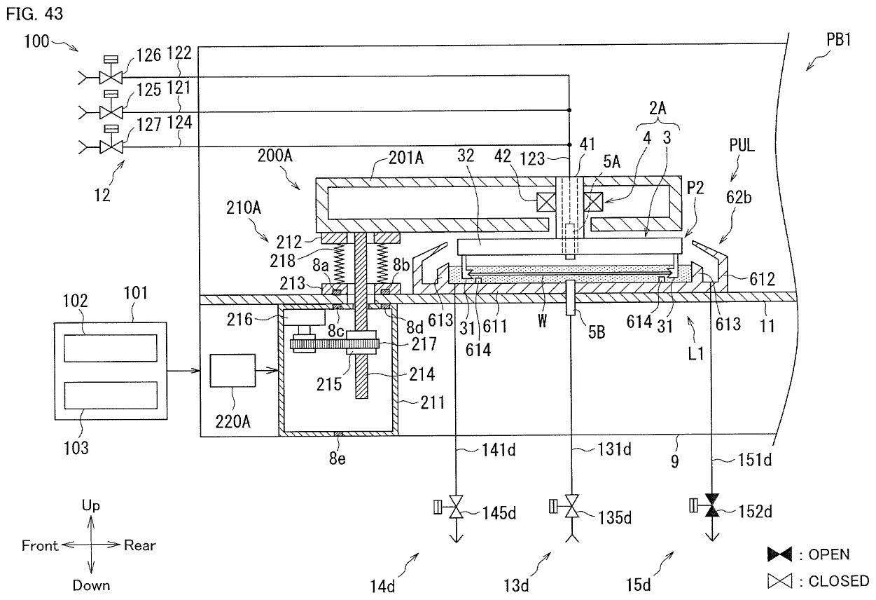

FIG. 43 is a cross-sectional view schematically illustrating a portion of the configuration of the first processing block PB1 included in the substrate processing apparatus 100 according to Modification Example 6. Specifically, FIG. 43 illustrates the first liquid supplying portion 12, the upper substrate holding portion 2A, the moving portion 200A, a rinse processing unit PUL, and the first rail member 8a to the fifth rail member 8e which correspond to the first processing cup row L1 of the first processing block PB1. FIG. 43 schematically illustrates the cross sections of the moving portion 200A and the rinse cup portion 62b as viewed from the left side.

As illustrated in FIG. 43, the rinse processing unit PUL has the rinse cup portion 62b, a second liquid supplying portion 13d, a first draining portion 14d, and a second draining portion 15. In Modification Example 6, the rinse cup portion 62b has a bottom wall portion 611, a side wall portion 612, an inner wall portion 613, a plurality of supporting portions 614, and a lower nozzle portion 5B. Since the rinse cup portion 62b illustrated in FIG. 43 has the same structure as the immersion bath 61b, the detailed description thereof will be omitted.

The second liquid supplying portion 13d supplies the rinse liquid (here, DIW) to the lower nozzle portion 5B of the rinse cup portion 62b. Specifically, the second liquid supplying portion 13d has a rinse liquid pipe portion 131d and an opening/closing valve 135d. Since the configuration of the second liquid supplying portion 13d is similar to the configuration of the second liquid supplying portion 13 illustrated in FIG. 29, the detailed description thereof will be omitted.

The first draining portion 14d drains the rinse liquid stored inside the inner wall portion 613 from the rinse cup portion 62b. Specifically, the first draining portion 14d has a drainage pipe portion 141d and an opening/closing valve 145d. The second draining portion 15d drains the rinse liquid collected between the inner wall portion 613 and the side wall portion 612 from the rinse cup portion 62b. Specifically, the second draining portion 15d has a drainage pipe portion 151d and an opening/closing valve 152d. Since the configuration of each of the first draining portion 14d and the second draining portion 15d is similar to the configuration of the draining portion 14c illustrated in FIG. 29, the detailed description thereof will be omitted.

In Modification Example 6, the rinse processing is executed on the substrate W subjected to the first chemical liquid processing inside the rinse cup portion 62b. Hereinafter, the rinse processing executed inside the rinse cup portion 62b will be described.

The controlling portion 102 controls the moving portion 200A such that the upper substrate holding portion 2A that holds the substrate W subjected to the first chemical liquid processing is moved to the facing position P1 of the rinse cup portion 62b. Then, the controlling portion 102 controls the raising/lowering mechanism 210A such that the upper substrate holding portion 2A is lowered from the facing position P1 of the rinse cup portion 62b to the first processing position P2.

In Modification Example 6, the rinse liquid is not stored in the rinse cup portion 62b at the start of the rinse processing on the substrate W subjected to the first chemical liquid processing. When the upper substrate holding portion 2A is lowered from the facing position P1 of the rinse cup portion 62b to the first processing position P2, the controlling portion 102 controls the upper rotating portion 4 (upper motor body 42) such that the substrate W is rotated. Thereafter, as described with reference to FIG. 17, the controlling portion 102 switches the second opening/closing valve 126 of the first liquid supplying portion 12 and the opening/closing valve 135d of the second liquid supplying portion 13d from the closed state to the open state and discharges the rinse liquid from the upper nozzle portion 5A and the lower nozzle portion 5B toward the upper surface Wa and the lower surface Wb of the rotating substrate W (first step of the rinse processing).

When a predetermined time has elapsed from the start of the discharge of the rinse liquid, the controlling portion 102 closes the first opening/closing valve 145d of the first draining portion 14d. As a result, as described with reference to FIG. 18, the rinse liquid is stored inside the inner wall portion 613, and the substrate W is immersed in the rinse liquid (second step of the rinse processing). The controlling portion 102 continues the rotation of the substrate W from the first step to the second step of the rinse processing.

In Modification Example 6, after the substrate W is immersed in the rinse liquid, the substrate W is left in the rinse cup portion 62b. Specifically, the controlling portion 102 stops the rotation of the substrate W after the substrate W is immersed in the rinse liquid. In addition, the controlling portion 102 switches the second opening/closing valve 126 of the first liquid supplying portion 12 and the opening/closing valve 135d of the second liquid supplying portion 13d from the open state to the closed state and stops the discharge of the rinse liquid. Then, the controlling portion 102 controls the raising/lowering mechanism 210A such that the upper substrate holding portion 2A is moved from the first processing position P2 to the second processing position P3 and then controls the upper chuck driving mechanism 50 such that the gripping of the substrate W by the upper chuck member 31 is released. As a result, the substrate W is supported by the plurality of supporting portions 614 of the rinse cup portion 62b.

The controlling portion 102 may stop the discharge of the rinse liquid after a predetermined time has elapsed after the substrate W is immersed in the rinse liquid. Specifically, the controlling portion 102 may continue discharging the rinse liquid until a predetermined time elapses after the space inside the inner wall portion 613 is filled with the rinse liquid to cause the rinse liquid to overflow from the inner wall portion 613 (overflow processing).

When the substrate W is moved from the rinse cup portion 62b to the other processing cup portion 6, the controlling portion 102 causes the upper chuck member 31 to grip the substrate W and raises the upper substrate holding portion 2A from the second processing position P3 to the first processing position P2. Then, the controlling portion 102 switches the opening/closing valve 145d of the first draining portion 14d from the closed state to the open state and causes the rinse liquid to be drained from the rinse cup portion 62b. When the rinse liquid is drained from the rinse cup portion 62b, the controlling portion 102 controls the first liquid supplying portion 12, the second liquid supplying portion 13d, and the upper substrate holding portion 2A such that the third step of the rinse processing described with reference to FIG. 19 is executed inside the rinse cup portion 62b.

When the rinse liquid is drained, the controlling portion 102 may rotate the substrate W and discharge the rinse liquid from the upper nozzle portion 5A and the lower nozzle portion 5B. Through this processing, the drying of the substrate W can be suppressed, and pattern collapse and generation of particles can be suppressed.

Also, the controlling portion 102 may execute the processing of causing the rinse liquid to overflow from the inner wall portion 613 before draining the rinse liquid. In this case, the controlling portion 102 causes the upper chuck member 31 to hold the substrate W, raises the upper substrate holding portion 2A from the second processing position P3 to the first processing position P2, then discharges the rinse liquid from the upper nozzle portion 5A and the lower nozzle portion 5B, and causes the rinse liquid to overflow from the inner wall portion 613. When a predetermined time has elapsed from the start of the discharge of the rinse liquid, the controlling portion 102 stops the discharge of the rinse liquid and then drains the rinse liquid from the rinse cup portion 62b. The controlling portion 102 may rotate the substrate W when the rinse liquid overflows from the inner wall portion 613.

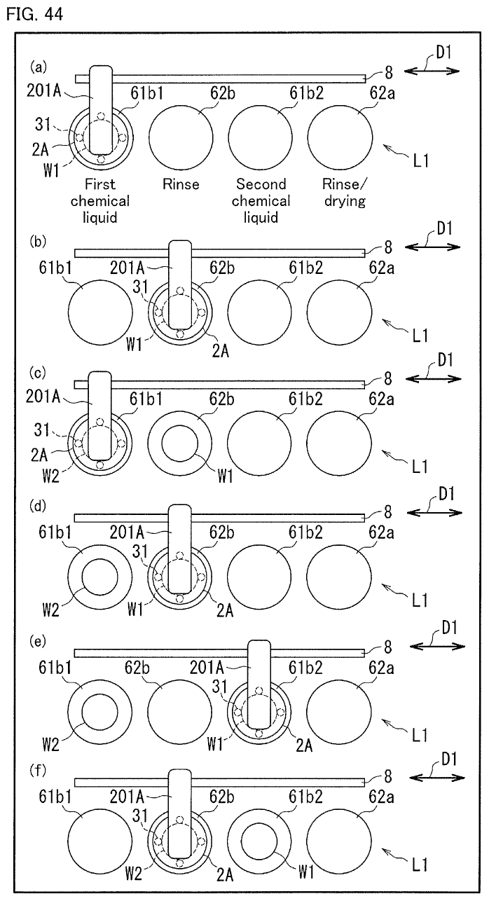

Subsequently, an example of the operation of the substrate processing apparatus 100 according to Modification Example 6 will be described with reference to FIGS. 42, 43, and 44A to 44F using the first processing cup row L1 of the first processing block PB1 as an example. FIGS. 44A to 44F are views schematically illustrating an example of the operation f the substrate processing apparatus 100 according to Modification Example 6. Specifically, FIGS. 44A to 44F illustrate an example of the operation of the first processing block PB1 when two substrates W (first substrate W1 and second substrate W2) are processed in the first processing cup row L1 of the first processing block PB1.

As illustrated in FIG. 44A, the controlling portion 102 causes the upper substrate holding portion 2A to hold the first substrate W1 carried into the first processing block PB1 by the transfer robot TR. Then, the controlling portion 102 immerses the first substrate W1 in the first chemical liquid in the first immersion bath 61b1.

As illustrated in FIG. 44B, when a predetermined time (predetermined first chemical liquid processing time) has elapsed after the first substrate W1 is immersed in the first chemical liquid, the controlling portion 102 moves the first substrate W1 from the first immersion bath 61b1 to the rinse cup portion 62b. Then, as described with reference to FIG. 43, the controlling portion 102 immerses the first substrate W1 in the rinse liquid and then leaves the first substrate W1 in the rinse cup portion 62b.

As illustrated in FIG. 44C, the controlling portion 102 leaves the first substrate W1 in the rinse cup portion 62b and then causes the upper substrate holding portion 2A to hold the second substrate W2 carried into the first processing block PB1 by the transfer robot TR. Then, the controlling portion 102 leaves the second substrate W2 in the first chemical liquid in the first immersion bath 61b1.

As illustrated in FIG. 44D, when the second substrate W2 is left in the first chemical liquid in the first immersion bath 61b1, the controlling portion 102 controls the moving portion 200A and the upper chuck driving mechanism 50 such that the upper substrate holding portion 2A holds the first substrate W1 left in the rinse liquid in the rinse cup portion 62b. Then, as described with reference to FIG. 43, the controlling portion 102 executes the third step of the rinse processing after draining the rinse liquid from the rinse cup portion 62b.

As illustrated in FIG. 44E, the controlling portion 102 moves the first substrate W1 from the rinse cup portion 62b to the second immersion bath 61b2 after end of the third step of the rinse processing. Then, the controlling portion 102 leaves the first substrate W1 in the second chemical liquid in the second immersion bath 61b2.

As illustrated in FIG. 44F, when a predetermined time (predetermined first chemical liquid processing time) has elapsed after the second substrate W2 is immersed in the first chemical liquid, the controlling portion 102 moves the second substrate W2 from the first immersion bath 61b1 to the rinse cup portion 62b. Then, similarly to the first substrate W1, the controlling portion 102 leaves the second substrate W2 in the rinse liquid in the rinse cup portion 62b.

When the time elapsed after the second substrate W2 is left in the rinse cup portion 62b and then the first substrate W1 is immersed in the second chemical liquid becomes greater than or equal to a predetermined time (predetermined second chemical liquid processing time), the controlling portion 102 moves the first substrate W1 from the second immersion bath 61b2 to the rinse drying cup portion 62a and executes the rinse processing and the drying processing on the first substrate W1. After the first substrate W1 is dried, the controlling portion 102 carries out the first substrate W1 from the first processing block PB1. Thereafter, the controlling portion 102 processes the second substrate W2 similarly to the first substrate W1 and carries out the second substrate W2 from the first processing block PB1.

The operation at the time of processing two substrates W has been described with reference to FIGS. 44A to 44F, and the third and subsequent substrates W are also similarly processed. Specifically, the controlling portion 102 leaves the second substrate W2 in the rinse cup portion 62b and then causes the upper substrate holding portion 2A to hold the third substrate W3 (substrate W of the third) carried into the first processing block PB1 by the transfer robot TR. Then, the controlling portion 102 leaves the third substrate W3 in the first chemical liquid in the first immersion bath 61b1.

Modification Example 6 has been described above with reference to FIGS. 42, 43, and 44A to 44F. According to Modification Example 6, before the processing on one substrate W is completed, the processing on the next substrate W can be started. Therefore, the waiting time for waiting for the timing to start the chemical liquid processing can be reduced. In Modification Example 6, the plurality of processing cup portions 6 are arranged according to the processing procedure. Therefore, the movement sequence of the upper substrate holding portion 2A is less likely to be complicated.

The rinse drying cup portion 62a may have the same structure as the immersion bath 61b. Since the rinse drying cup portion 62a has the same structure as the immersion bath 61b, the rinse liquid can be stored in the rinse drying cup portion 62a, and the substrate W can be left in the rinse drying cup portion 62a. Therefore, the number of substrates W that can be continuously processed can be increased.

In Modification Example 6, the two second processing cup portions 62 are included in the plurality of processing cup portions 6 of each processing cup row L, but the number of the second processing cup portions 62 is not limited to two. For example, three or more second processing cup portions 62 may be included in the plurality of processing cup portions 6 of each processing cup row L. Specifically, the plurality of processing cup portions 6 of each processing cup row L may include three or more immersion baths 61b, two or more rinse cup portions 62b, and one rinse drying cup portion 62a.

In Modification Example 6, the placing table 7 is not provided, but the placing table 7 may be provided for each processing cup row L as in the preferred embodiments described with reference to FIGS. 1 to 24.

### Modification Example 7

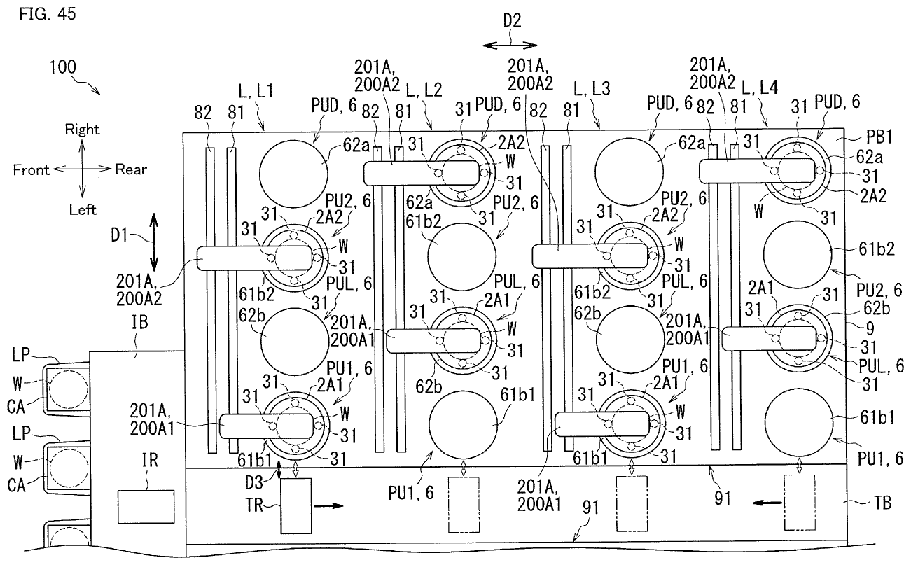

Subsequently, a substrate processing apparatus 100 according to Modification Example 7 will be described with reference to FIG. 45. However, matters differing from the preferred embodiments described with reference to FIGS. 1 to 43 and 44A to 44F will be described, and the description of matters that are the same as in the preferred embodiments described with reference to FIGS. 1 to 43 and 44A to 44F will be omitted.

FIG. 45 is an enlarged schematic plan view of a portion of the substrate processing apparatus 100 according to Modification Example 7. Specifically, FIG. 45 illustrates a configuration of the first processing block PB1 included in the substrate processing apparatus 100 according to Modification Example 7. Although not illustrated, the configuration of the second processing block PB2 is similar to the configuration of the first processing block PB1.

As illustrated in FIG. 45, in Modification Example 7, similarly to Modification Example 6, the plurality of first processing cup portions 61 and the plurality of second processing cup portions 62 are arranged in the first direction D1 (left-right direction) according to the processing procedure of the substrate W. Specifically, the plurality of processing cup portions 6 of each processing cup row L include two immersion baths 61b (first immersion bath 61b1 and second immersion bath 61b2), one rinse drying cup portion 62a, and one rinse cup portion 62b. The first immersion bath 61b1, the second immersion bath 61b2, the rinse drying cup portion 62a, and the rinse cup portion 62b are disposed in the order of the first immersion bath 61b1, the rinse cup portion 62b, the second immersion bath 61b2, and the rinse drying cup portion 62a from the left side. The first chemical liquid and the second chemical liquid are stored in the first immersion bath 61b1 and the second immersion bath 61b2, respectively.

In Modification Example 7, the first chemical liquid processing, the rinse processing, the second chemical liquid processing, the rinse processing, and the drying processing are performed on the substrate W in that order. In the second immersion bath 61b2, processing (second chemical liquid processing) immediately before the final rinse processing is performed. In the rinse drying cup portion 62a, the final rinse processing and the drying processing are performed. The second immersion bath 61b2 is an example of a “third processing cup portion.” The rinse drying cup portion 62a is an example of a “fourth processing cup portion.”

In Modification Example 7, similarly to Modification Example 1 (FIG. 21), two upper substrate holding portions 2A are provided for each processing cup row L. Specifically, a first upper substrate holding portion 2A1 and a second upper substrate holding portion 2A2 are provided for each processing cup row L. The second upper substrate holding portion 2A2 holds the substrate W when executing the final rinse processing and drying processing included in the processing procedure of the substrate W.

Specifically, each of the first processing block PB1 and the second processing block PB2 has the first upper substrate holding portion 2A1, a rail member 81 corresponding to the first upper substrate holding portion 2A1, a first moving portion 200A1 corresponding to the first upper substrate holding portion 2A1, a second upper substrate holding portion 2A2, a rail member 82 corresponding to the second upper substrate holding portion 2A2, and a second moving portion 200A2 corresponding to the second upper substrate holding portion 2A2 for each processing cup row L.

Similarly to the moving portion 200A, the first moving portion 200A1 includes the supporting arm 201A, the raising/lowering mechanism 210A, and the moving mechanism 220A. The supporting arm 201A and the raising/lowering mechanism 210A of the first moving portion 200A1 are guided in the first direction D1 (left-right direction) by the rail member 81. Since the configuration of the first moving portion 200A1 is similar to the configuration of the moving portion 200A described with reference to FIGS. 1, 2, 4, and 5, the detailed description thereof will be omitted. Similarly, since the configuration of the rail member 81 is similar to the configuration of the rail member 8 described with reference to FIGS. 1, 2, 4, and 5, the detailed description thereof will be omitted. The moving mechanism 200A of the first moving portion 220A1 is an example of a “first moving mechanism.”

Similarly to the moving portion 200A, the second moving portion 200A2 includes the supporting arm 201A, the raising/lowering mechanism 210A, and the moving mechanism 220A. The supporting arm 201A and the raising/lowering mechanism 210A of the second moving portion 200A2 are guided in the first direction D1 (left-right direction) by the rail member 82. Since the configuration of the second moving portion 200A2 is similar to the configuration of the moving portion 200A described with reference to FIGS. 1, 2, 4, and 5, the detailed description thereof will be omitted. Similarly, since the configuration of the rail member 82 is similar to the configuration of the rail member 8 described with reference to FIGS. 1, 2, 4, and 5, the detailed description thereof will be omitted. The moving mechanism 200A of the second moving portion 220A2 is an example of a “second moving mechanism.”

When the first upper substrate holding portion 2A1 is moved in the first direction D1, the vertical positions of the first upper substrate holding portion 2A1 and the supporting arm 201A of the first moving portion 200A1 and the second upper substrate holding portion 2A2 and the supporting arm 201A of the second moving portion 200A2 are different from each other. Similarly, when the second upper substrate holding portion 2A2 is moved in the first direction D1, the vertical positions of the first upper substrate holding portion 2A1 and the supporting arm 201A of the first moving portion 200A1 and the second upper substrate holding portion 2A2 and the supporting arm 201A of the second moving portion 200A2 are different from each other. Therefore, it is possible to avoid the first upper substrate holding portion 2A1 and the second upper substrate holding portion 2A2 from interfering with each other. Further, it is possible to avoid the supporting arms 201A from interfering with each other.

Subsequently, an example of the operation of the first processing block PB1 when one substrate W is processed will be described with reference to FIG. 45 using the first processing cup row L1 as an example.

The controlling portion 102 controls the first moving portion 200A1 and the first upper substrate holding portion 2A1 such that the first upper substrate holding portion 2A1 holds the substrate W carried into the first processing block PB1 by the transfer robot TR. Then, the controlling portion 102 controls the first moving portion 200A1, the first upper substrate holding portion 2A1, and the first chemical liquid processing unit PU1 such that the substrate W is immersed in the first chemical liquid in the first immersion bath 61b1 (first chemical liquid processing).

When the time elapsed after the substrate W is immersed in the first chemical liquid becomes greater than or equal to a predetermined time (predetermined first chemical liquid processing time), the controlling portion 102 controls the first moving portion 200A1, the first upper substrate holding portion 2A1, and the first chemical liquid processing unit PU1 such that the first upper substrate holding portion 2A1 is raised to the facing position P1 of the first immersion bath 61b1, thereby pulling up the substrate W from the first chemical liquid. Then, the controlling portion 102 controls the first moving portion 200A1 such that the first upper substrate holding portion 2A1 is moved to the facing position P1 of the rinse cup portion 62b and then the first upper substrate holding portion 2A1 is lowered from the facing position P1 of the rinse cup portion 62b to the first processing position P2. As a result, the substrate W subjected to the first chemical liquid processing moves to the inside of the rinse cup portion 62b. When the substrate W subjected to the first chemical liquid processing moves to the inside of the rinse cup portion 62b, the controlling portion 102 executes the rinse processing on the substrate W subjected to the first chemical liquid processing.

After end of the rinse processing, the controlling portion 102 controls the first moving portion 200A1 such that the first upper substrate holding portion 2A1 is moved to the facing position P1 of the rinse cup portion 62b and then the first upper substrate holding portion 2A1 is moved from the facing position P1 of the rinse cup portion 62b to the facing position P1 of the second immersion bath 61b2. Then, the controlling portion 102 controls the first moving portion 200A1, the first upper substrate holding portion 2A1, and the second chemical liquid processing unit PU2 such that the substrate W is left in the second chemical liquid in the second immersion bath 61b2 (second chemical liquid processing).

When the time elapsed after the substrate W is immersed in the second chemical liquid becomes greater than or equal to a predetermined time (predetermined second chemical liquid processing time), the controlling portion 102 controls the second moving portion 200A2 and the second upper substrate holding portion 2A2 such that the second upper substrate holding portion 2A2 holds the substrate W immersed in the second chemical liquid. Then, the controlling portion 102 controls the second moving portion 200A2, the second chemical liquid processing unit PU2, and the second upper substrate holding portion 2A2 such that the second upper substrate holding portion 2A2 is raised to the facing position P1 of the second immersion bath 61b2, thereby pulling up the substrate W from the second chemical liquid.

When the substrate W is pulled up from the second chemical liquid, the controlling portion 102 controls the second moving portion 200A2 such that the second upper substrate holding portion 2A2 is moved to the facing position P1 of the rinse drying cup portion 62a and then the second upper substrate holding portion 2A2 is lowered from the facing position P1 of the rinse drying cup portion 62a to the first processing position P2. As a result, the substrate W subjected to the second chemical liquid processing moves to the inside of the rinse drying cup portion 62a. When the substrate W subjected to the second chemical liquid processing moves to the inside of the rinse drying cup portion 62a, the controlling portion 102 executes the rinse processing and the drying processing on the substrate W subjected to the second chemical liquid processing.

After end of the drying processing, the controlling portion 102 controls the second moving portion 200A2 such that the second upper substrate holding portion 2A2 that holds the substrate W subjected to the drying processing is moved to the facing position P1 of the first immersion bath 61b1. Then, the controlling portion 102 controls the transfer robot TR and the second upper substrate holding portion 2A2 such that the substrate W is carried out to the outside of the first processing block PB1.

According to Modification Example 7, the plurality of upper chuck members 31 of the second upper substrate holding portion 2A2 are not in contact with the first chemical liquid, but are in contact only with the second chemical liquid. Therefore, it is possible to reduce the possibility that another chemical liquid (first chemical liquid) adheres to the substrate W subjected to the second chemical liquid processing and the second chemical liquid and another chemical liquid are mixed on the substrate W. Therefore, the possibility that the substrate W is contaminated can be reduced.

In Modification Example 7, the placing table 7 is not provided, but the placing table 7 may be provided for each processing cup row as in the preferred embodiments described with reference to FIGS. 1 to 24.

### Modification Example 8

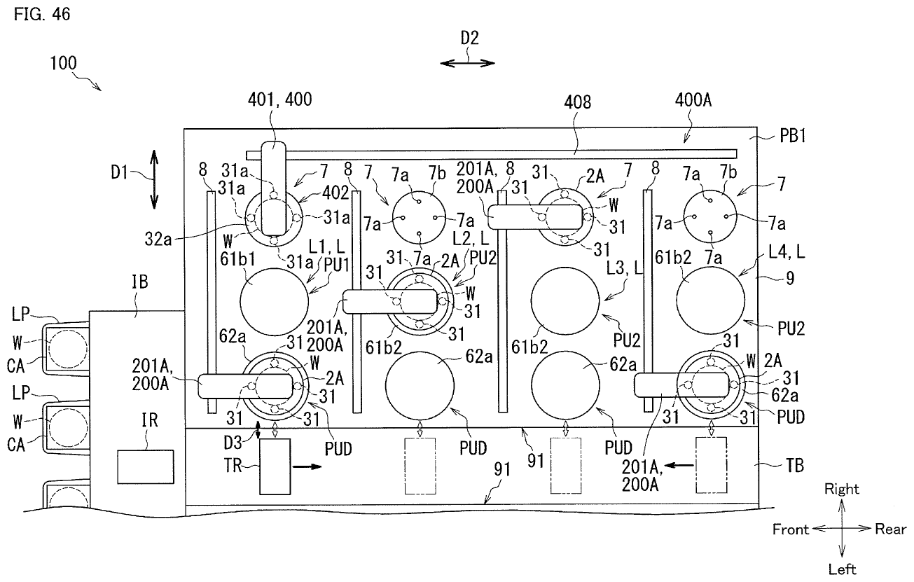

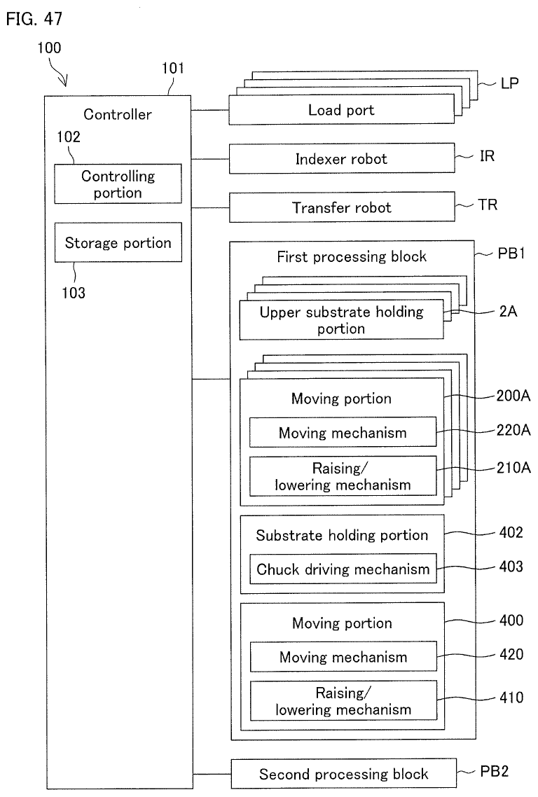

Subsequently, a substrate processing apparatus 100 according to Modification Example 8 will be described with reference to FIGS. 46 and 47. However, matters differing from the preferred embodiments described with reference to FIGS. 1 to 45 will be described, and the description of matters that are the same as in the preferred embodiments described with reference to FIGS. 1 to 45 will be omitted.

In the preferred embodiments described with reference to FIGS. 25 to 45, the substrate W is not moved between the plurality of processing cup rows L, but the substrate W may be moved between the plurality of processing cup rows L.

FIG. 46 is an enlarged schematic plan view of a portion of the substrate processing apparatus 100 according to Modification Example 8. FIG. 47 is a block diagram of the substrate processing apparatus 100 according to Modification Example 8. Specifically, FIG. 46 illustrates a configuration of the first processing block PB1 included in the substrate processing apparatus 100 according to Modification Example 8. Although not illustrated, the configuration of the second processing block PB2 is similar to the configuration of the first processing block PB1.

As illustrated in FIG. 46, the first processing block PB1 may include the processing chamber 9, the plurality of processing cup rows L (first processing cup row L1 to fourth processing cup row L4), the plurality of placing tables 7, the plurality of upper substrate holding portions 2A, the plurality of moving portions 200A, the plurality of rail members 8, and an inter-row transfer device 400A. The placing table 7, the upper substrate holding portion 2A, the moving portion 200A, and the rail member 8 are provided for each processing cup row L.

In Modification Example 8, each processing cup row L includes one immersion bath 61b and one rinse drying cup portion 62a. The first chemical liquid is stored in the immersion bath 61b (first immersion bath 61b1) of the first processing cup row L1. The second chemical liquid is stored in the immersion baths 61b (second immersion baths 61b2) of the second processing cup row L2 to the fourth processing cup row L4. That is, a chemical liquid of a type different from that of the immersion bath 61b of the first processing cup row L1 is stored in the immersion baths 61b of the second processing cup row L2 to the fourth processing cup row L4. The same type of chemical liquid is stored in the immersion baths 61b of the second processing cup row L2 to the fourth processing cup row L4.

In each processing cup row L, one immersion bath 61b and one rinse drying cup portion 62a are disposed in the order of the rinse drying cup portion 62a and the immersion bath 61b from the left side. Each placing table 7 is disposed on the right side of the corresponding processing cup row L. That is, each placing table 7 is disposed at a position farther from the transfer block TB (side wall 91) than the corresponding processing cup row L.

The inter-row transfer device 400A transfers the substrate W between the plurality of processing cup rows L. Specifically, the inter-row transfer device 400A transfers the substrate W between the plurality of placing tables 7. Specifically, the inter-row transfer device 400A has a substrate holding portion 402, a moving portion 400, and a rail member 408.

The substrate holding portion 402 has a plurality of chuck members 31a, a base member 32a, and a chuck driving mechanism 403 (FIG. 47).

The plurality of chuck members 31a are provided on the base member 32a. The base member 32a has substantially a disk shape and supports the plurality of chuck members 31a in the horizontal posture. The plurality of chuck members 31a are disposed in a peripheral edge portion of the base member 32a and protrude downward from the base member 32a. The plurality of chuck members 31a grip the substrate W under the base member 32a. When the plurality of chuck members 31a grip the substrate W, the substrate W is horizontally held.

Similarly to the upper chuck driving mechanism 50, the chuck driving mechanism 403 (FIG. 47) is controlled by the controlling portion 102 to rotate the plurality of chuck members 31a between the non-holding position and the holding position. When each of the plurality of chuck members 31a rotates from the non-holding position to the holding position, the substrate W is gripped by the plurality of chuck members 31a. Further, when each of the plurality of chuck members 31a rotates from the holding position to the non-holding position, the gripping of the substrate W by the plurality of chuck members 31a is released.

The moving portion 400 has a supporting arm 401. As illustrated in FIG. 47, the moving portion 400 further has a raising/lowering mechanism 410 and a moving mechanism 420 similarly to the moving portion 200A.

The supporting arm 401 supports the substrate holding portion 402. The rail member 408 guides the substrate holding portion 402 in the second direction D2 (front-rear direction). Specifically, similarly to the rail member 8, the rail member 408 guides the raising/lowering mechanism 410 coupled to the supporting arm 401 in the second direction D2 (front-rear direction). Since the configuration of the rail member 408 is similar to that of the rail member 8, the detailed description thereof will be omitted.

The raising/lowering mechanism 410 raises and lowers the substrate holding portion 402 by raising and lowering the supporting arm 401. The moving mechanism 420 moves the raising/lowering mechanism 410 in the second direction D2 (front-rear direction) along the rail member 408. As a result, the substrate holding portion 402 moves in the second direction D2 (front-rear direction). Since the configurations of the raising/lowering mechanism 410 and the moving mechanism 420 are similar to the configurations of the raising/lowering mechanism 210A and the moving mechanism 220A, the detailed description thereof will be omitted.

Subsequently, an example of the operation of the first processing block PB1 when one substrate W is processed will be described with reference to FIGS. 46 and 47.

The controlling portion 102 controls the transfer robot TR such that the substrate W is carried into the first processing block PB1 from the carry-in/carry-out port corresponding to the first processing cup row L1. Then, the controlling portion 102 executes the first chemical liquid processing and the rinse processing on the substrate W using the first immersion bath 61b1 and the rinse drying cup portion 62a of the first processing cup row L1. When the rinse processing ends, the controlling portion 102 controls the moving portion 200A and the upper substrate holding portion 2A which correspond to the first processing cup row L1 such that the substrate W subjected to the rinse processing is placed on the placing table 7 corresponding to the first processing cup row L1.

When the substrate W is placed on the placing table 7 corresponding to the first processing cup row L1, the controlling portion 102 controls the moving mechanism 420 such that the substrate holding portion 402 is moved to the facing position of the placing table 7 corresponding to the first processing cup row L1. Then, the controlling portion 102 controls the raising/lowering mechanism 410 and the chuck driving mechanism 403 such that the substrate holding portion 402 holds the substrate W placed on the placing table 7 corresponding to the first processing cup row L1 and then the substrate holding portion 402 that holds the substrate W is raised to the facing position of the placing table 7.

The controlling portion 102 controls the moving mechanism 420 such that the substrate holding portion 402 that holds the substrate W is moved to the facing position of one placing table 7 among the placing tables 7 corresponding to the second processing cup row L2 to the fourth processing cup row L4. For example, the controlling portion 102 moves the substrate holding portion 402 to the facing position of the placing table 7 corresponding to the fourth processing cup row L4. Then, the controlling portion 102 controls the raising/lowering mechanism 410 and the chuck driving mechanism 403 such that the substrate W is placed on the placing table 7 corresponding to the fourth processing cup row L4.

After the substrate W is placed on the placing table 7 corresponding to the fourth processing cup row L4, the controlling portion 102 controls the moving portion 200A and the upper substrate holding portion 2A which correspond to the fourth processing cup row L4 such that the upper substrate holding portion 2A corresponding to the fourth processing cup row L4 holds the substrate W. Then, the controlling portion 102 executes the second chemical liquid processing, the rinse processing, and the drying processing on the substrate W using the second immersion bath 61b2 and the rinse drying cup portion 62a of the fourth processing cup row L4. After the substrate W is dried, the controlling portion 102 carries out the substrate W from the first processing block PB1.

Modification Example 8 has been described above with reference to FIGS. 46 and 47. According to Modification Example 8, operations of the second chemical liquid processing can be executed in parallel in the plurality of processing cup rows L (second processing cup row L2 to fourth processing cup row L4).

In Modification Example 8, the same type of chemical liquid is stored in the immersion baths 61b of the second processing cup row L2 to the fourth processing cup row L4, but different chemical liquids may be stored in the immersion baths 61b of the second processing cup row L2 to the fourth processing cup row L4. Alternatively, the same type of chemical liquid may be stored in two immersion baths 61b among the immersion baths 61b of the second processing cup row L2 to the fourth processing cup row L4, and different types of chemical liquids may be stored in the remaining one immersion bath 61b.

In Modification Example 8, the chemical liquid different from that in the immersion bath 61b in the first processing cup row L1 is stored in the immersion baths 61b of the second processing cup row L2 to the fourth processing cup row L4, but the same type of chemical liquid as that in the immersion bath 61b of the first processing cup row L1 may be stored in one of the immersion baths 61b of the second processing cup row L2 to the fourth processing cup row L4.

Further, in Modification Example 8, the placing table 7 is not provided on the side wall 91 side, but the placing table 7 may be provided on the side wall 91 side.

### Modification Example 9

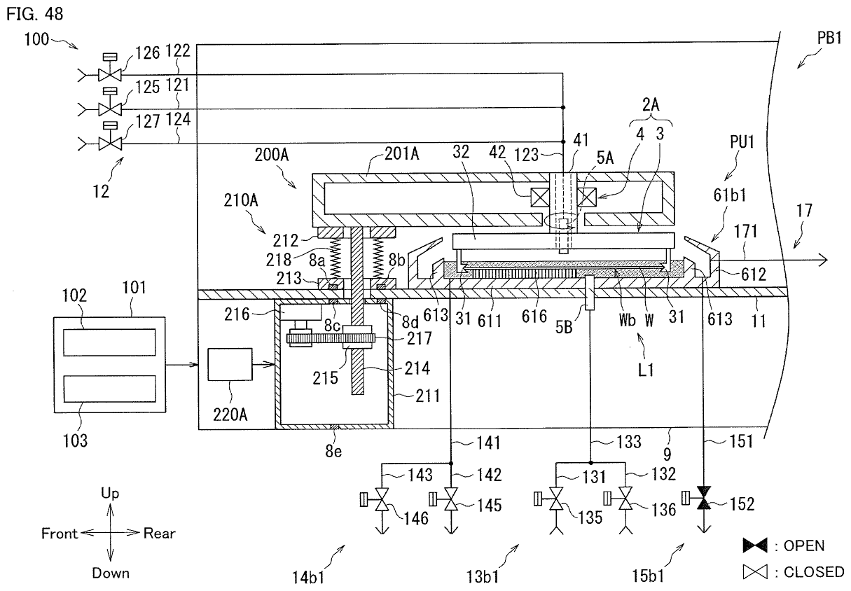

Subsequently, a substrate processing apparatus 100 according to Modification Example 9 will be described with reference to FIG. 48. However, matters differing from the preferred embodiments described with reference to FIGS. 1 to 47 will be described, and the description of matters that are the same as in the preferred embodiments described with reference to FIGS. 1 to 47 will be omitted. Modification Example 9 is different from the preferred embodiments described with reference to FIGS. 25 to 47 in that a lower brush 616 is provided in the immersion bath 61b.

FIG. 48 is a cross-sectional view schematically illustrating a portion of a configuration of the first processing block PB1 included in the substrate processing apparatus 100 according to Modification Example 9. Specifically, FIG. 48 illustrates the first liquid supplying portion 12, the upper substrate holding portion 2A, the moving portion 200A, the first chemical liquid processing unit PU1, and the first rail member 8a to the fifth rail member 8e which correspond to the first processing cup row L1 of the first processing block PB1. FIG. 48 schematically illustrates the cross sections of the moving portion 200A and the first immersion bath 61b1 as viewed from the left side.

As illustrated in FIG. 48, the first immersion bath 61b1 may have a lower brush 616. The lower brush 616 comes into contact with the lower surface Wb of the substrate W and cleans the lower surface Wb of the substrate W. The lower brush 616 is an example of a “lower brush member.”

Specifically, the lower brush 616 is fixed to an upper surface of the bottom wall portion 611 of the first immersion bath 61b1. The lower brush 616 comes into contact with the lower surface Wb of the substrate W and cleans the lower surface Wb of the substrate W in a state where the substrate W is immersed in the processing liquid stored in the first immersion bath 61b1.

The lower brush 616 may include, for example, a porous material such as sponge. Alternatively, the lower brush 616 may contain a resin such as polyvinyl alcohol (PVA). Alternatively, the lower brush 616 may be formed by combining a plurality of members. Alternatively, the lower brush 616 may include a plurality of bristles.

The shape of the lower brush 616 is not particularly limited. For example, the lower brush 616 may have a strip shape or a linear shape in a plan view. In this case, the lower brush 616 may extend from the central portion of the bottom wall portion 611 toward the radially outer side of the bottom wall portion 611. Alternatively, the lower brush 616 may have substantially a fan shape in a plan view. In this case, the main portion of the fan may be located at the central portion of the bottom wall portion 611. Alternatively, the lower brush 616 may have a circular shape in a plan view.

When the lower surface Wb of the substrate W is cleaned by the lower brush 616, the controlling portion 102 controls the raising/lowering mechanism 210A such that the upper substrate holding portion 2A is lowered to a position at which the lower surface Wb of the substrate W comes into contact with the lower brush 616. Then, the controlling portion 102 controls the upper rotating portion 4 (upper motor body 42) such that the upper spin base 32 is rotated and the substrate W is rotated. As a result, the substrate W in contact with the lower brush 616 rotates, and the lower surface Wb of the substrate W is cleaned by the lower brush 616.

The processing liquid stored in the first immersion bath 61b1 when the substrate W is cleaned by the lower brush 616 may be the first chemical liquid or the rinse liquid.

Modification Example 9 has been described above with reference to FIG. 48. According to Modification Example 9, the lower brush 616 can clean the lower surface Wb of the substrate W. The configuration in which the lower surface Wb of the substrate W is cleaned by the lower brush 616 has been described with reference to FIG. 48 using the first immersion bath 61b1 as an example, but each immersion bath 61b may be provided with the lower brush 616, or at least one of the plurality of immersion baths 61b included in each processing cup row L may be provided with the lower brush 616.

### Modification Example 10

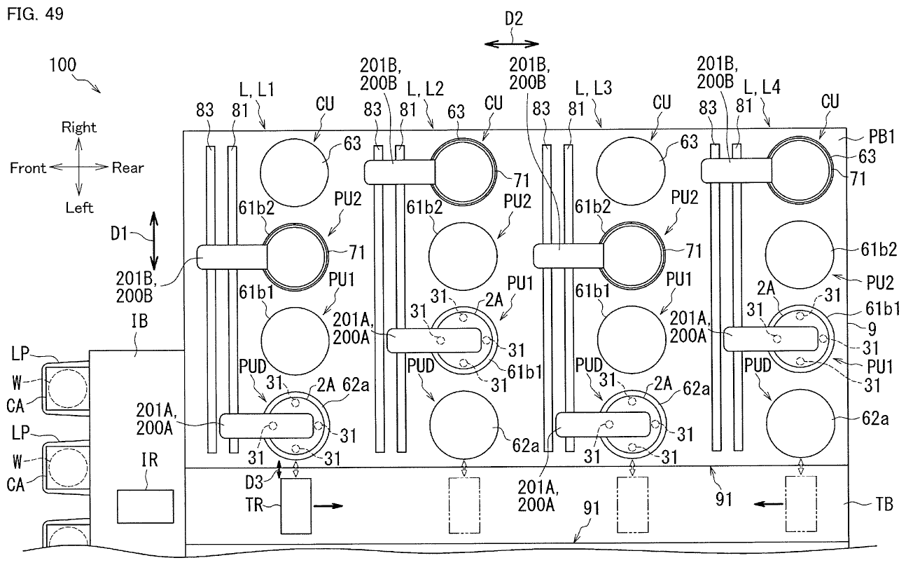

Subsequently, a substrate processing apparatus 100 according to Modification Example 10 will be described with reference to FIGS. 49 to 51. However, matters differing from the preferred embodiments described with reference to FIGS. 1 to 48 will be described, and the description of matters that are the same as in the preferred embodiments described with reference to FIGS. 1 to 48 will be omitted. Modification Example 10 is different from the preferred embodiments described with reference to FIGS. 25 to 48 in that an exhaust cutoff portion 71 is provided for each processing cup row L.

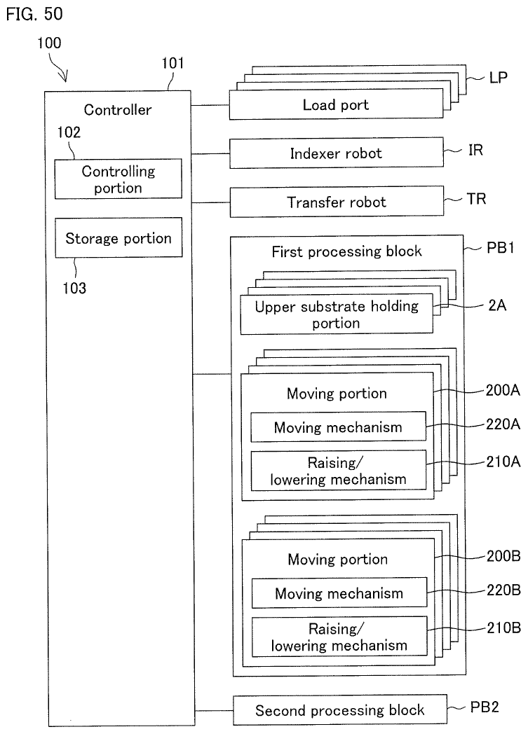

FIG. 49 is an enlarged schematic plan view of a portion of the substrate processing apparatus 100 according to Modification Example 10. FIG. 50 is a block diagram of the substrate processing apparatus 100 according to Modification Example 10. Specifically, FIG. 49 illustrates a configuration of the first processing block PB1 included in the substrate processing apparatus 100 according to Modification Example 10. Although not illustrated, the configuration of the second processing block PB2 is similar to the configuration of the first processing block PB1.

As illustrated in FIG. 49, the first processing block PB1 has the processing chamber 9, the plurality of processing cup rows L (first processing cup row L1 to fourth processing cup row L4), the plurality of upper substrate holding portions 2A, a plurality of exhaust cutoff portions 71, the plurality of moving portions 200A, a plurality of moving portion 200B, the plurality of rail members 81, and a plurality of rail members 83. The upper substrate holding portion 2A, the exhaust cutoff portion 71, the moving portion 200A, the moving portion 200B, the rail member 81, and the rail member 83 are provided for each processing cup row L.

In the example illustrated in FIG. 49, each processing cup row L includes the rinse drying cup portion 62a, the first immersion bath 61b1, the second immersion bath 61b2, and the cleaning bath 63. The rinse drying cup portion 62a, the first immersion bath 61b1, the second immersion bath 61b2, the cleaning bath 63 are disposed in the order of the rinse drying cup portion 62a, the first immersion bath 61b1, the second immersion bath 61b2, and the cleaning bath 63 from the left side.

The moving portion 200B has a supporting arm 201B. The supporting arm 201B supports the exhaust cutoff portion 71. As illustrated in FIG. 50, the moving portion 200B has a raising/lowering mechanism 210B and a moving mechanism 220B similarly to the moving portion 200A. Since the configurations of the raising/lowering mechanism 210B and the moving mechanism 220B are similar to the configurations of the raising/lowering mechanism 210A and the moving mechanism 220A, the detailed description thereof will be omitted.

The rail member 83 guides the raising/lowering mechanism 210B coupled to the supporting arm 201B in the first direction D1 (left-right direction). Since the configuration of the rail member 83 is similar to the configuration of the rail member 8 described with reference to FIGS. 1, 2, 4, and 5, the detailed description thereof will be omitted.

When the upper substrate holding portion 2A is moved in the first direction D1, the vertical positions of the upper substrate holding portion 2A and the supporting arm 201A are different from the vertical positions of the exhaust cutoff portion 71 and the supporting arm 201B. Similarly, when the exhaust cutoff portion 71 is moved in the first direction D1, the vertical positions of the upper substrate holding portion 2A and the supporting arm 201A are different from the vertical positions of the exhaust cutoff portion 71 and the supporting arm 201B. Therefore, it is possible to avoid the upper substrate holding portion 2A and the exhaust cutoff portion 71 from interfering with each other. Similarly, it is possible to avoid the supporting arm 201A and the supporting arm 201B from interfering with each other.

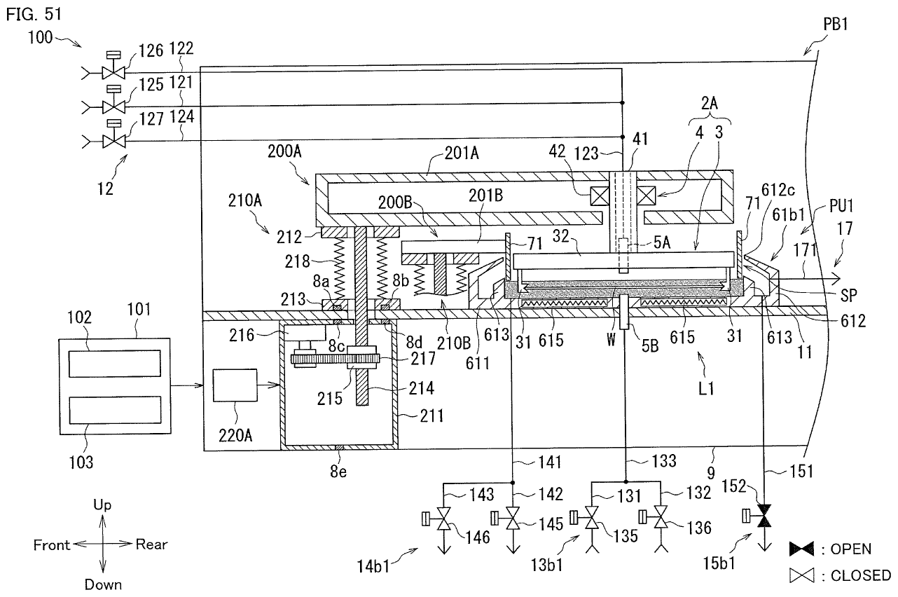

FIG. 51 is a cross-sectional view schematically illustrating a portion of the configuration of the first processing block PB1 included in the substrate processing apparatus 100 according to Modification Example 10. Specifically, FIG. 51 illustrates the first liquid supplying portion 12, the upper substrate holding portion 2A, the exhaust cutoff portion 71, the moving portion 200A, a portion of the moving portion 200B, the first chemical liquid processing unit PU1, and the first rail member 8a to the fifth rail member 8e which correspond to the first processing cup row L1 of the first processing block PB1. FIG. 51 schematically illustrates cross sections of the moving portion 200A, a portion of the moving portion 200B, the exhaust cutoff portion 71, and the first immersion bath 61b1 as viewed from the left side. Hereinafter, the exhaust cutoff portion 71 will be described using the first immersion bath 61b1 as an example.

As illustrated in FIG. 51, in Modification Example 10, the first chemical liquid processing unit PU1 further includes a heater 615 that heats the processing liquid. The heater 615 heats the first chemical liquid in the first immersion bath 61b1.

Specifically, the heater 615 may heat the first chemical liquid stored in the first immersion bath 61b1 by heating the first immersion bath 61b1. For example, the heater 615 may be disposed inside the bottom wall portion 611 of the first immersion bath 61b1. The heater 615 may be disposed such as to surround the lower nozzle portion 5B.

The controlling portion 102 controls the heater 615 such that the first chemical liquid in the first immersion bath 61b1 is heated to a predetermined temperature. Specifically, the controlling portion 102 controls on/off of the heater 615 such that the first chemical liquid in the first immersion bath 61b1 is held at a predetermined temperature.

By providing the heater 615, it is possible to suppress a decrease in the temperature of the first chemical liquid in the first immersion bath 61b1. Therefore, for example, even when the immersion processing is performed for a long time, it is possible to suppress a decrease in the temperature of the first chemical liquid. In addition, by heating the first chemical liquid in the first immersion bath 61b1 to a predetermined temperature, the substrate W can be processed with the first chemical liquid at a constant temperature, for example.

The exhaust cutoff portion 71 has a cylindrical shape. The exhaust cutoff portion 71 is an example of a “cylindrical member.” The exhaust cutoff portion 71 extends in the up-down direction. For example, the exhaust cutoff portion 71 has a circular cylindrical shape. When the substrate W is immersed in the first chemical liquid in the first immersion bath 61b1, the exhaust cutoff portion 71 is located in a gap between an inner peripheral edge portion 612c of the first immersion bath 61b1 and the upper spin base 32. The inner peripheral edge portion 612c of the first immersion bath 61b1 forms an upper surface opening of the first immersion bath 61b1. The inner peripheral edge portion 612c of the first immersion bath 61b1 is formed by the upper end of the side wall portion 612.

Before the substrate W is immersed in the first chemical liquid in the first immersion bath 61b1, the controlling portion 102 controls the moving portion 200B such that the exhaust cutoff portion 71 is moved to the inside of the first immersion bath 61b1. Thereafter, the controlling portion 102 controls the moving portion 200A such that the upper substrate holding portion 2A is moved to the first processing position P2 (see FIG. 26) and thus the substrate W is immersed in the first chemical liquid in the first immersion bath 61b1. As a result, when the substrate W is immersed in the first chemical liquid in the first immersion bath 61b1, the exhaust cutoff portion 71 is located in the gap between the inner peripheral edge portion 612c of the first immersion bath 61b1 and the upper spin base 32.

Specifically, the diameter of the exhaust cutoff portion 71 is greater than the diameter of the upper spin base 32 and smaller than the diameter of the upper end (inner peripheral edge portion 612c) of the side wall portion 612. In Modification Example 10, the diameter of the exhaust cutoff portion 71 is smaller than the diameter of the upper end of the inner wall portion 613.

The dimension of the exhaust cutoff portion 71 in the up-down direction is greater than the dimension of a gap SP formed between the upper end (inner peripheral edge portion 612c) of the side wall portion 612 and the upper end of the inner wall portion 613 in the up-down direction. The controlling portion 102 controls the moving portion 200B such that the exhaust cutoff portion 71 is moved to a position at which the exhaust cutoff portion 71 covers the gap SP.

Modification Example 10 has been described above with reference to FIGS. 49 to 51. According to Modification Example 10, since the gap SP is covered with the exhaust cutoff portion 71 during the chemical liquid processing, it is possible to suppress a decrease in the temperature of the chemical liquid stored inside the inner wall portion 613. Specifically, when the gap SP is open, the gas in the space over the liquid level of the chemical liquid stored inside the inner wall portion 613 is drawn into the gap SP by the exhaust portion 17. As a result, the temperature of the chemical liquid stored inside the inner wall portion 613 may decrease due to the airflow drawn into the gap SP. On the other hand, according to Modification Example 10, since the exhaust cutoff portion 71 covers the gap SP, the airflow drawn into the gap SP is less likely to occur. Alternatively, the flow rate of the airflow drawn into the gap SP can be reduced. Therefore, according to Modification Example 10, it is possible to suppress a decrease in the temperature of the chemical liquid stored inside the inner wall portion 613.

The configuration in which the processing liquid in the immersion bath 61b is heated has been described with reference to FIG. 51 using the configuration in which the first chemical liquid in the first immersion bath 61b1 is heated as an example, but the heater 615 may be provided for each immersion bath 61b, or the heater 615 may be provided for at least one of the plurality of immersion baths 61b included in each processing cup row L.

In Modification Example 10, the placing table 7 is not provided, but the placing table 7 may be provided for each processing cup row L as in the preferred embodiments described with reference to FIGS. 1 to 24.

In Modification Example 10, each processing cup row L includes two immersion baths 61b, one rinse drying cup portion 62a, and one cleaning bath 63, but the configuration of the processing cup row L is not particularly limited as long as the processing cup row L includes at least one first processing cup portion 61 and at least one second processing cup portion 62.

### Modification Example 11

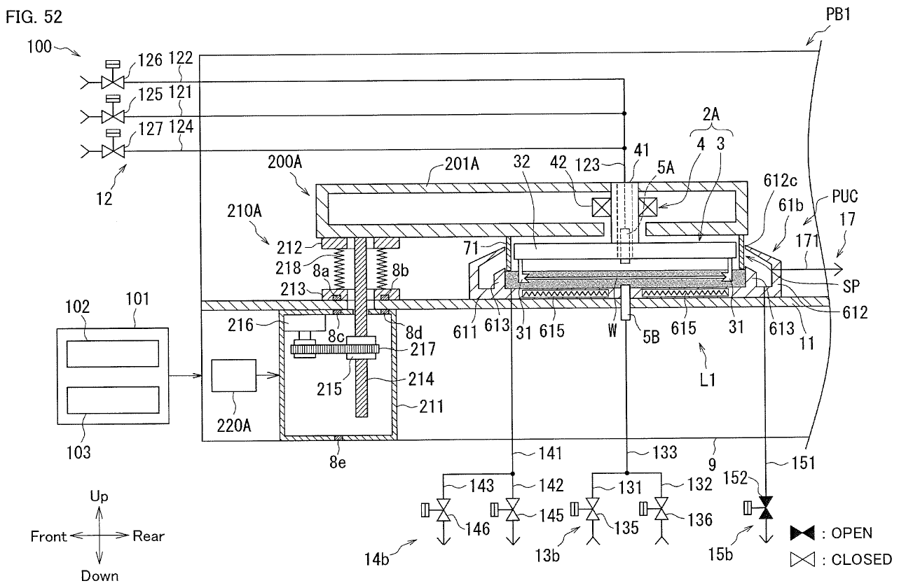

Subsequently, a substrate processing apparatus 100 according to Modification Example 11 will be described with reference to FIG. 52. However, matters differing from the preferred embodiments described with reference to FIGS. 1 to 51 will be described, and the description of matters that are the same as in the preferred embodiments described with reference to FIGS. 1 to 51 will be omitted. Modification Example 11 is different from the preferred embodiments described with reference to FIGS. 25 to 51 in that the supporting arm 201A supports the exhaust cutoff portion 71.

FIG. 52 is a cross-sectional view schematically illustrating a portion of a configuration of the first processing block PB1 included in the substrate processing apparatus 100 according to Modification Example 11. Specifically, FIG. 52 illustrates the first liquid supplying portion 12, the upper substrate holding portion 2A, the moving portion 200A, the chemical liquid processing unit PUC, the exhaust cutoff portion 71, and the first rail member 8a to the fifth rail member 8e which correspond to the first processing cup row L1 of the first processing block PB1. FIG. 52 schematically illustrates the cross sections of the moving portion 200A, the exhaust cutoff portion 71, and the immersion bath 61b as viewed from the left side.

As illustrated in FIG. 52, in Modification Example 11, the exhaust cutoff portion 71 is coupled to the supporting arm 201A. That is, the supporting arm 201A supports the exhaust cutoff portion 71. The exhaust cutoff portion 71 protrudes downward from the supporting arm 201A. The exhaust cutoff portion 71 is provided at a position at which the exhaust cutoff portion 71 surrounds the upper substrate holding portion 2A. The exhaust cutoff portion 71 covers the gap SP when the upper substrate holding portion 2A is located at the first processing position P2 (see FIG. 26). Therefore, when the substrate W is immersed in the chemical liquid in the immersion bath 61b, the gap SP is covered with the exhaust cutoff portion 71.

Modification Example 11 has been described above with reference to FIG. 52. According to Modification Example 11, similarly to Modification Example 10, since the gap SP is covered with the exhaust cutoff portion 71 during the chemical liquid processing, it is possible to suppress a decrease in the temperature of the chemical liquid stored inside the inner wall portion 613.

### Modification Example 12

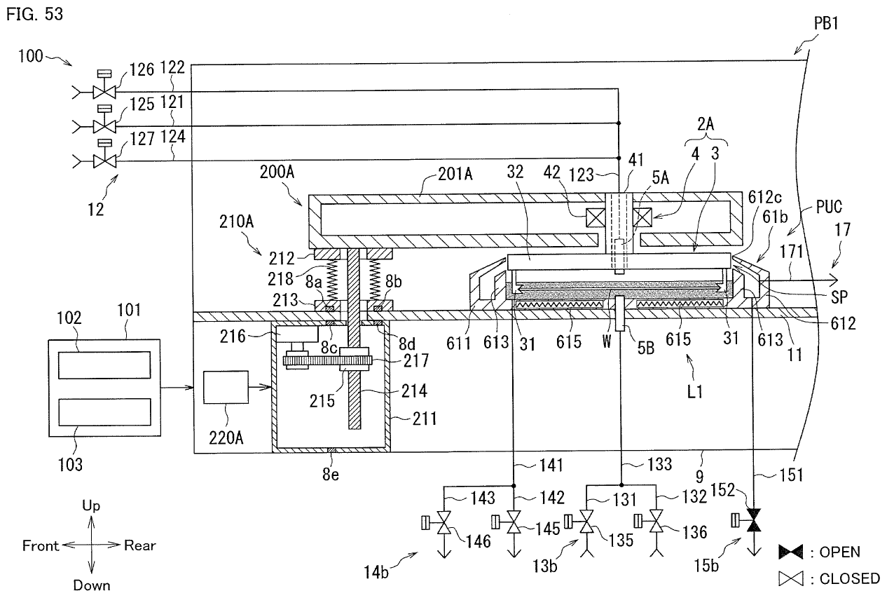

Subsequently, a substrate processing apparatus 100 according to Modification Example 12 will be described with reference to FIG. 53. However, matters differing from the preferred embodiments described with reference to FIGS. 1 to 52 will be described, and the description of matters that are the same as in the preferred embodiments described with reference to FIGS. 1 to 52 will be omitted. In Modification Example 12, the diameter of the upper spin base 32 is different from that of the preferred embodiments described with reference to FIGS. 25 to 48.

FIG. 53 is a cross-sectional view schematically illustrating a portion of a configuration of the first processing block PB1 included in the substrate processing apparatus 100 according to Modification Example 12. Specifically, FIG. 53 illustrates the first liquid supplying portion 12, the upper substrate holding portion 2A, the moving portion 200A, the chemical liquid processing unit PUC, and the first rail member 8a to the fifth rail member 8e which correspond to the first processing cup row L1 of the first processing block PB1. FIG. 53 schematically illustrates the cross sections of the moving portion 200A and the immersion bath 61b as viewed from the left side.

As illustrated in FIG. 53, in Modification Example 12, the diameter of the upper spin base 32 is slightly smaller than the diameter of the upper end (inner peripheral edge portion 612c) of the side wall portion 612. In addition, the diameter of the upper spin base 32 is slightly smaller than the diameter of the upper end of the inner wall portion 613. The dimension of the side surface of the upper spin base 32 in the up-down direction is greater than the dimension of the gap SP in the up-down direction. The side surface of the upper spin base 32 covers the gap SP when the upper substrate holding portion 2A is located at the first processing position P2 (see FIG. 26). Therefore, when the substrate W is immersed in the chemical liquid in the immersion bath 61b, the gap SP is covered with the side surface of the upper spin base 32.

Modification Example 12 has been described above with reference to FIG. 53. According to Modification Example 12, since the gap SP is covered with the side surface of the upper spin base 32 during the chemical liquid processing, it is possible to suppress a decrease in the temperature of the chemical liquid stored inside the inner wall portion 613.

### Modification Example 13

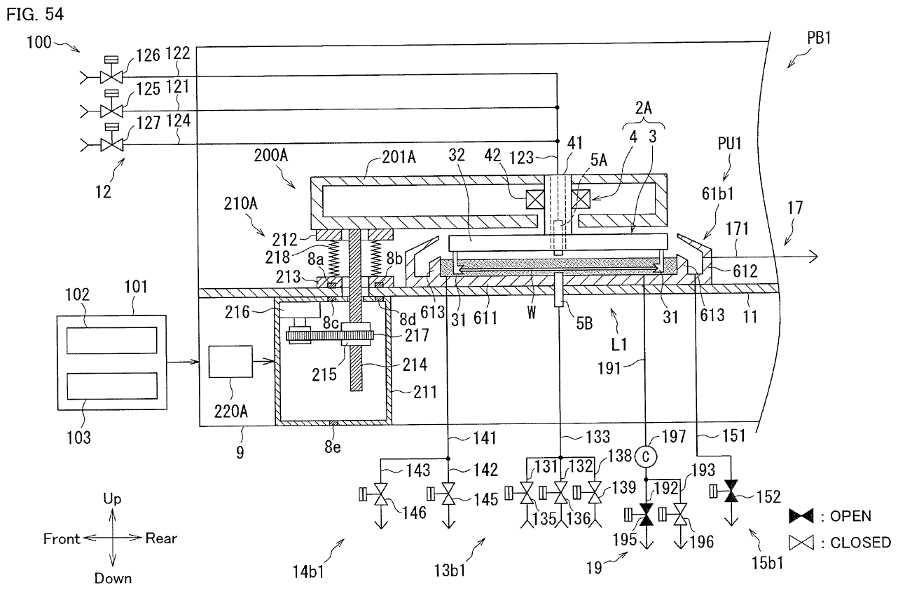

Subsequently, a substrate processing apparatus 100 according to Modification Example 13 will be described with reference to FIG. 54. However, matters differing from the preferred embodiments described with reference to FIGS. 1 to 53 will be described, and the description of matters that are the same as in the preferred embodiments described with reference to FIGS. 1 to 53 will be omitted. Modification Example 13 is different from the preferred embodiments described with reference to FIGS. 25 to 53 in that the concentration of the processing liquid stored in the immersion bath 61b is adjusted.

FIG. 54 is a cross-sectional view schematically illustrating a portion of a configuration of the first processing block PB1 included in the substrate processing apparatus 100 according to Modification Example 13. Specifically, FIG. 54 illustrates the first liquid supplying portion 12, the upper substrate holding portion 2A, the moving portion 200A, the first chemical liquid processing unit PU1, and the first rail member 8a to the fifth rail member 8e which correspond to the first processing cup row L1 of the first processing block PB1. FIG. 54 schematically illustrates the cross sections of the moving portion 200A and the first immersion bath 61b1 as viewed from the left side.

As illustrated in FIG. 54, in Modification Example 13, the second liquid supplying portion 13b1 further has an undiluted liquid pipe portion 138 and a fourth opening/closing valve 139. The undiluted liquid pipe portion 138 is a tubular member through which a fluid flows. An undiluted liquid of the first chemical liquid is supplied to the upstream end of the undiluted liquid pipe portion 138. The downstream end of the undiluted liquid pipe portion 138 is connected to the common pipe portion 133. The fourth opening/closing valve 139 is provided in the undiluted liquid pipe portion 138. Since the configuration of the fourth opening/closing valve 139 is similar to that of the first opening/closing valve 135, the detailed description thereof will be omitted.

When the concentration of the first chemical liquid in the first immersion bath 61b1 is adjusted, the controlling portion 102 switches the fourth opening/closing valve 139 from the closed state to the open state. As a result, the undiluted liquid of the first chemical liquid is supplied from the lower nozzle portion 5B into the first immersion bath 61b1, and the concentration of the first chemical liquid in the first immersion bath 61b1 is adjusted. In Modification Example 13, the second liquid supplying portion 13b1 constitutes an “undiluted liquid supplying portion.”

In Modification Example 13, the first chemical liquid processing unit PU1 further has a concentration detecting portion 19. The concentration detecting portion 19 detects the concentration of the first chemical liquid in the first immersion bath 61b1. The controlling portion 102 adjusts the concentration of the first chemical liquid in the first immersion bath 61b1 by controlling the second liquid supplying portion 13b1 on the basis of the concentration of the first chemical liquid detected by the concentration detecting portion 19.

Specifically, the concentration detecting portion 19 has a common pipe portion 191, a drainage pipe portion 192, a recovery pipe portion 193, a first opening/closing valve 195, a second opening/closing valve 196, and a concentration sensor 197. Since the configurations of the common pipe portion 191, the drainage pipe portion 192, the recovery pipe portion 193, the first opening/closing valve 195, and the second opening/closing valve 196 are the same as the configurations of the common pipe portion 141, the drainage pipe portion 142, the recovery pipe portion 143, the first opening/closing valve 145, and the second opening/closing valve 146 included in the first draining portion 14b1, the description thereof will be omitted.

The concentration sensor 197 detects the concentration of the first chemical liquid in the first immersion bath 61b1. Specifically, the concentration sensor 197 is provided in the common pipe portion 191 and detects the concentration of the first chemical liquid flowing through the common pipe portion 191. The concentration sensor 197 transmits a signal indicating the detected concentration of the first chemical liquid to the controlling portion 102. As a result, the controlling portion 102 acquires the concentration of the first chemical liquid.

The controlling portion 102 executes concentration detection processing. The concentration detecting processing indicates the processing of causing the concentration detecting portion 19 to detect the concentration of the first chemical liquid. Specifically, the controlling portion 102 switches the first opening/closing valve 195 or the second opening/closing valve 196 from the closed state to the open state. As a result, the concentration of the first chemical liquid is detected by the concentration sensor 197. For example, the controlling portion 102 may periodically execute the concentration detection processing. Alternatively, the controlling portion 102 may execute the concentration detection processing on the basis of an instruction from the worker. The time length during which the first opening/closing valve 195 or the second opening/closing valve 196 is in the open state is set to a time length during which the concentration sensor 197 can detect the concentration. For example, the time length during which the first opening/closing valve 195 or the second opening/closing valve 196 is in the open state may be set in advance.

When the concentration of the first chemical liquid in the first immersion bath 61b1 is acquired, the controlling portion 102 determines whether or not to execute the concentration adjustment processing on the basis of the acquired concentration of the first chemical liquid. When it is determined to execute the concentration adjustment processing, the controlling portion 102 controls the second liquid supplying portion 13b1.

For example, when the concentration of the first chemical liquid is lower than a predetermined range, the controlling portion 102 determines to execute the concentration adjustment processing and switches the fourth opening/closing valve 139 of the second liquid supplying portion 13b1 from the closed state to the open state. As a result, the undiluted liquid of the first chemical liquid is supplied into the first immersion bath 61b1, and the concentration of the first chemical liquid in the first immersion bath 61b1 increases. The controlling portion 102 may determine a time length during which the fourth opening/closing valve 139 of the second liquid supplying portion 13b1 is in the open state on the basis of the concentration of the first chemical liquid acquired from the concentration sensor 197 (concentration detecting portion 19).

When the concentration of the first chemical liquid is higher than a predetermined range, the controlling portion 102 determines to execute the concentration adjustment processing, switches the second opening/closing valve 136 of the second liquid supplying portion 13b1 from the closed state to the open state, and discharges DIW from the lower nozzle portion 5B. As a result, the concentration of the first chemical liquid in the first immersion bath 61b1 decreases. The controlling portion 102 may determine a time length during which the second opening/closing valve 136 of the second liquid supplying portion 13b1 is in the open state on the basis of the concentration of the first chemical liquid acquired from the concentration sensor 197 (concentration detecting portion 19).

When the concentration adjustment processing is executed in the period in which the upper substrate holding portion 2A does not hold the substrate W, the controlling portion 102 may control the moving portion 200A such that the plurality of upper chuck members 31 are immersed in the first chemical liquid and control the upper rotating portion 4 such that the plurality of upper chuck members 31 are rotated in the first chemical liquid and the first chemical liquid in the first immersion bath 61b1 is stirred.

Modification Example 13 has been described above with reference to FIG. 54. According to Modification Example 13, the concentration of the chemical liquid in the immersion bath 61b can be maintained within a predetermined range. Therefore, the substrate W can be accurately processed.

The configuration in which the concentration of the first chemical liquid in the first immersion bath 61b1 is adjusted has been described with reference to FIG. 54, but a configuration in which the concentration of the chemical liquid is adjusted may be provided for each immersion bath 61b, or a configuration in which the concentration of the chemical liquid is adjusted may be provided for at least one immersion bath 61b among the plurality of immersion baths 61b included in each processing cup row L.

### Modification Example 14

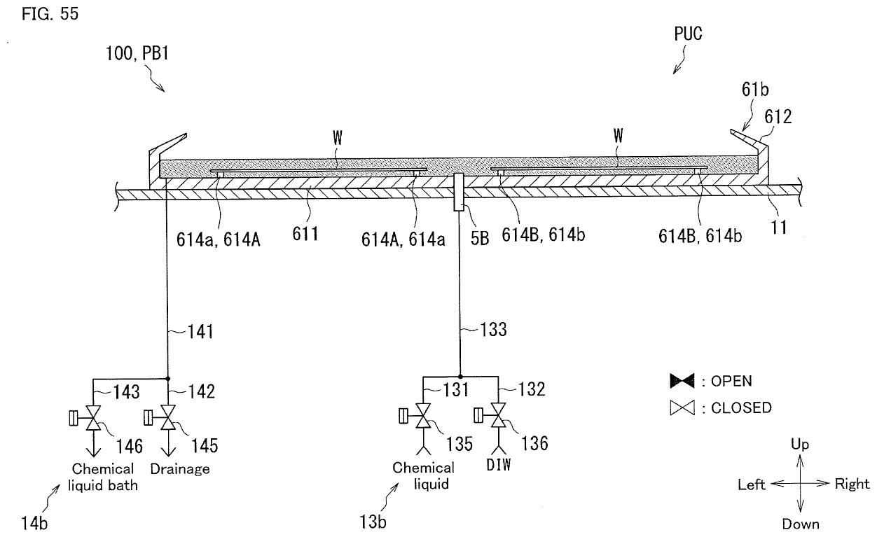

Subsequently, a substrate processing apparatus 100 according to Modification Example 14 will be described with reference to FIG. 55. However, matters differing from the preferred embodiments described with reference to FIGS. 1 to 54 will be described, and the description of matters that are the same as in the preferred embodiments described with reference to FIGS. 1 to 54 will be omitted.

In the preferred embodiments described with reference to FIGS. 25 to 54, one substrate W is immersed in the chemical liquid in the immersion bath 61b, but a plurality of substrates W may be immersed in the chemical liquid in the immersion bath 61b.

FIG. 55 is a cross-sectional view schematically illustrating a configuration of the immersion bath 61b included in the substrate processing apparatus 100 according to Modification Example 14. FIG. 55 illustrates a cross section of the immersion bath 61b as viewed from a side behind thereof.

As illustrated in FIG. 55, the immersion bath 61b may have a bottom wall portion 611, a side wall portion 612, a first supporting portion group 614A, and a second supporting portion group 614B.

The first supporting portion group 614A includes a plurality of first supporting portions 614a. The plurality of first supporting portions 614a protrude from the bottom wall portion 611. The first supporting portion 614a may have, for example, a circular columnar shape. The plurality of first supporting portions 614a horizontally support the substrate W. Specifically, the plurality of first supporting portions 614a are disposed on the same circumference and support the peripheral edge portion of the substrate W.

The upper end of each first supporting portion 614a is located at a position lower than that of the upper end of the side wall portion 612. In other words, the height of each first supporting portion 614a from the bottom wall portion 611 is lower than the height of the side wall portion 612 from the bottom wall portion 611. The substrate W supported by the plurality of first supporting portions 614a is immersed in the chemical liquid stored in the immersion bath 61b.

The second supporting portion group 614B includes a plurality of second supporting portions 614b. The plurality of second supporting portions 614b horizontally support the substrate W. Since the configuration of the second supporting portion group 614B is similar to that of the first supporting portion group 614A, the detailed description thereof will be omitted.

The second supporting portion group 614B is from that of the first disposed in a region different supporting portion group 614A. Specifically, the first supporting portion group 614A and the second supporting portion group 614B are arranged in the left-right direction. In addition, the first supporting portion group 614A and the second supporting portion group 614B are disposed at positions where the substrate W supported by the first supporting portion group 614A and the substrate W supported by the second supporting portion group 614B do not overlap. Therefore, the substrate W supported by the first supporting portion group 614A and the substrate W supported by the second supporting portion group 614B are arranged in the left-right direction.

In the example illustrated in FIG. 55, two supporting portion groups are provided in the immersion bath 61b, but three or more supporting portion groups may be provided in the immersion bath 61b. In other words, three or more substrates W may be simultaneously immersed in the chemical liquid in one immersion bath 61b.

Modification Example 14 has been described above with reference to FIG. 55. According to Modification Example 14, a plurality of substrates W can be simultaneously immersed in a chemical liquid in one immersion bath 61b. All of the immersion baths 61b included in each processing cup row L may have a structure in which a plurality of substrates W are simultaneously immersed, or some of the plurality of immersion baths 61b included in each processing cup row L may have a structure in which a plurality of substrates W are simultaneously immersed.

### Preferred Embodiment 4

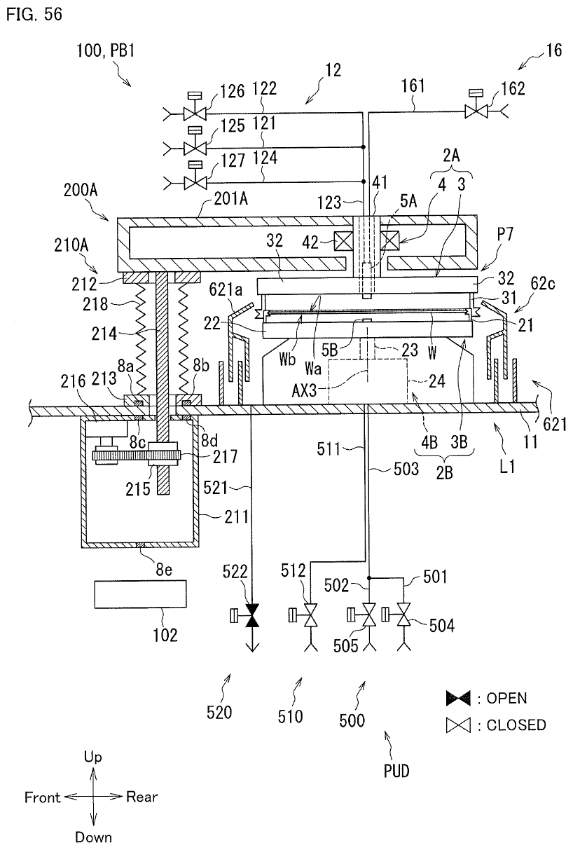

Subsequently, Preferred Embodiment 4 of the present invention will be described with reference to FIGS. 56 to 62. However, matters differing from the preferred embodiments described with reference to FIGS. 1 to 55 will be described, and the description of matters that are the same as in the preferred embodiments described with reference to FIGS. 1 to 55 will be omitted. Preferred Embodiment 4 is different from the preferred embodiments described with reference to FIGS. 25 to 55 in a configuration of the rinse drying processing unit PUD.

FIG. 56 is a cross-sectional view schematically illustrating a portion of the configuration of the first processing block PB1 included in the substrate processing apparatus 100 according to Preferred Embodiment 4. FIGS. 56 to 59 illustrate the first liquid supplying portion 12, a first gas supplying portion 16, the upper substrate holding portion 2A, a portion of the moving portion 200A, the rinse drying processing unit PUD, and the first rail member 8a to the fifth rail member 8e which correspond to the first processing cup row L1 of the first processing block PB1. FIGS. 56 to 59 schematically illustrate the cross sections of the moving portion 200A and a cup portion 621 as viewed from the left side.

As illustrated in FIG. 56, in Preferred Embodiment 4, the first processing block PB1 further has the first gas supplying portion 16. The first gas supplying portion 16 is provided for each processing cup row L. The first gas supplying portion 16 supplies gas to the corresponding upper nozzle portion 5A. The first gas supplying portion 16 is controlled by the controlling portion 102.

The gas is, for example, an inert gas. The inert gas is, for example, nitrogen gas or argon gas. When the gas is supplied from the first gas supplying portion 16 to the upper nozzle portion 5A, the gas is ejected from the upper nozzle portion 5A. Specifically, when the substrate W is dried, the controlling portion 102 ejects the gas from the upper nozzle portion 5A toward the upper surface Wa of the substrate W.

The first gas supplying portion 16 has a gas supplying pipe portion 161 and an opening/closing valve 162. The gas supplying pipe portion 161 is a tubular member through which a fluid flows. The opening/closing valve 162 is provided in the gas supplying pipe portion 161. The opening/closing valve 162 is openable and closable. The opening and closing operations of the opening/closing valve 162 are controlled by the controlling portion 102.

The gas is supplied to the upstream end of the gas supplying pipe portion 161. The downstream end of the gas supplying pipe portion 161 is connected to the upper nozzle portion 5A. The opening/closing valve 162 opens and closes a flow path in the gas supplying pipe portion 161. When the opening/closing valve 162 is opened, the gas is supplied to the upper nozzle portion 5A. As a result, the gas is ejected from the upper nozzle portion 5A. When the opening/closing valve 162 is closed, the flow of the gas through the gas supplying pipe portion 161 is stopped. As a result, the ejection of the gas from the upper nozzle portion 5A is stopped.

In Preferred Embodiment 4, the rinse drying processing unit PUD has a rinse drying cup portion 62c, a third liquid supplying portion 500, a second gas supplying portion 510, and a third draining portion 520. The rinse drying cup portion 62c has a lower substrate holding portion 2B and a cup portion 621.

The lower substrate holding portion 2B horizontally holds the substrate W. In addition, the lower substrate holding portion 2B rotates while holding the substrate W. The lower substrate holding portion 2B is controlled by the controlling portion 102.

In Preferred Embodiment 4, the lower substrate holding portion 2B has a pinching chuck mechanism. The lower substrate holding portion 2B holds the substrate W by pinching the end portion of the substrate W. Specifically, the lower substrate holding portion 2B has a lower holding portion 3B, a lower rotating portion 4B, and a lower nozzle portion 5B.

The lower holding portion 3B horizontally holds the substrate W. Specifically, the lower holding portion 3B has a plurality of lower chuck members 21 and a lower spin base 22. The lower spin base 22 is an example of a “lower base member.”

The plurality of lower chuck members 21 are provided on the lower spin base 22. Specifically, the lower spin base 22 has substantially a disk shape and supports the plurality of lower chuck members 21 in the horizontal posture. The plurality of lower chuck members 21 are disposed in a peripheral edge portion of the lower spin base 22 and protrudes upward from the lower spin base 22. The plurality of lower chuck members 21 grip the substrate W over the lower spin base 22. Therefore, the substrate W is horizontally held over the lower spin base 22.

Specifically, the plurality of lower chuck members 21 grip the peripheral edge portion of the substrate W. When the plurality of lower chuck members 21 grip the substrate W, the substrate W is horizontally held. The operation of the plurality of lower chuck members 21 is controlled by the controlling portion 102. The lower chuck member 21 is an example of a “lower gripping member.”

The lower rotating portion 4B rotates the substrate W integrally with the lower holding portion 3B. The operation of the lower rotating portion 4B is controlled by the controlling portion 102. The lower rotating portion 4B has, for example, a lower shaft 23 and a lower motor body 24.

The lower shaft 23 is a hollow shaft. The lower shaft 23 extends in the up-down direction along a third rotational axis AX3. The upper end of the lower shaft 23 is coupled to the lower spin base 22.

The lower motor body 24 rotates the lower shaft 23. As a result, the lower spin base 22 rotates. The operation of the lower motor body 24 is controlled by the controlling portion 102. The lower motor body 24 is, for example, an electric motor.

The lower nozzle portion 5B is accommodated in an inner space of the lower shaft 23. The tip end of the lower nozzle portion 5B protrudes from the upper surface of the lower spin base 22.

The cup portion 621 has an annular shape in a plan view. The outer shape of the cup portion 621 may be a circular shape in a plan view. The cup portion 621 is disposed around the lower substrate holding portion 2B and surrounds the lower substrate holding portion 2B. The cup portion 621 receives the processing liquid drained from the substrate W.

Specifically, the cup portion 621 includes a guard portion 621a that is able to be raised and lowered and a cup raising/lowering mechanism (not illustrated).

The guard portion 621a has an annular shape in a plan view. The outer shape of the guard portion 621a may be a circular shape in a plan view. The cup raising/lowering mechanism is controlled by the controlling portion 102 and raises and lowers the guard portion 621a between a liquid receiving position and a retraction position. The liquid receiving position is a higher position than the retraction position. When the guard portion 621a is located at the liquid receiving position, the guard portion 621a surrounds the substrate W and receives the processing liquid drained from the substrate W. When the guard portion 621a is located at the retraction position, the guard portion 621a is located at a position lower than that of the upper surface of the lower spin base 22.

The third liquid supplying portion 500 supplies the processing liquid to the lower nozzle portion 5B. The third liquid supplying portion 500 is controlled by the controlling portion 102. In Preferred Embodiment 4, the third liquid supplying portion 500 selectively supplies one of a fourth chemical liquid and the rinse liquid (in the present preferred embodiment, DIW) to the lower nozzle portion 5B. Specifically, liquid supplying portion 500 has a chemical liquid pipe portion 501, a rinse liquid pipe portion 502, a common pipe portion 503, a first opening/closing valve 504, and a second opening/closing valve 505. Since the configuration of the third liquid supplying portion 500 is similar to that of the second liquid supplying portion 13 illustrated in FIG. 4, the detailed description thereof will be omitted.

The second gas supplying portion 510 supplies gas to the lower nozzle portion 5B. The second gas supplying portion 510 is controlled by the controlling portion 102. The gas is, for example, an inert gas. The inert gas is, for example, nitrogen gas or argon gas.

When the gas is supplied from the second gas supplying portion 510 to the lower nozzle portion 5B, the gas is ejected from the lower nozzle portion 5B. Specifically, when the substrate W is dried, the controlling portion 102 ejects the gas from the lower nozzle portion 5B toward the lower surface Wb of the substrate W. Similarly to the first gas supplying portion 16, the second gas supplying portion 510 has a gas supplying pipe portion 511 and an opening/closing valve 512. Since the configuration of the second gas supplying portion 510 is similar to the configuration of the first gas supplying portion 16, the description thereof will be omitted.

The third draining portion 520 drains the processing liquid collected by the cup portion 621 to the outside of the cup portion 621 (rinse drying cup portion 62c). Specifically, the third draining portion 520 drains the processing liquid collected by the cup portion 621 to the outside of the first processing block PB1. Similarly to the draining portion 14c illustrated in FIG. 29, the third draining portion 520 has a drainage pipe portion 521 and an opening/closing valve 522. The upstream end of the drainage pipe portion 521 is connected to a bottom wall (not illustrated) of the cup portion 621 and communicates with an inner space of the cup portion 621. Since the configuration of the third draining portion 520 is similar to the configuration of the draining portion 14c illustrated in FIG. 29, the detailed description thereof will be omitted.

In Preferred Embodiment 4, the upper substrate holding portion 2A transfers the substrate W to and from the lower substrate holding portion 2B. Specifically, the controlling portion 102 controls the moving portion 200A such that the upper substrate holding portion 2A is moved to a transfer position P7. The transfer position P7 indicates a position at which the substrate W held by the upper substrate holding portion 2A can be gripped by the plurality of lower chuck members 21. When the upper substrate holding portion 2A is moved to the transfer position P7, the controlling portion 102 causes the plurality of lower chuck members 21 to grip the substrate W and then releases the gripping of the substrate W by the plurality of upper chuck members 31. As a result, the substrate W is horizontally held by the lower substrate holding portion 2B.

After the gripping of the substrate W by the upper substrate holding portion 2A is released, the controlling portion 102 controls the moving portion 200A (raising/lowering mechanism 210A) such that the upper substrate holding portion 2A is raised from the transfer position P7 to the facing position P1 of the rinse drying cup portion 62c.

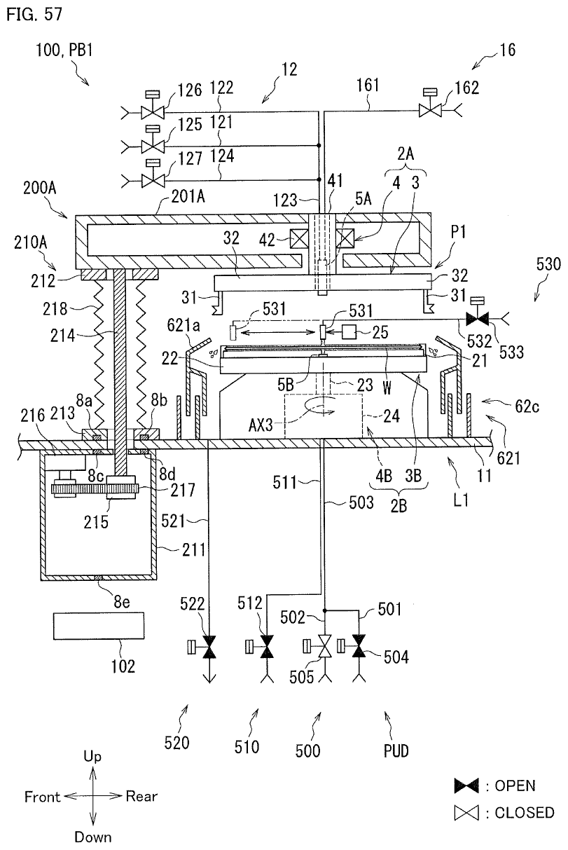

Subsequently, the substrate processing apparatus 100 according to Preferred Embodiment 4 will be described with reference to FIG. 57. FIG. 57 is another cross-sectional view schematically illustrating a portion of the configuration of the first processing block PB1 included in the substrate processing apparatus 100 according to Preferred Embodiment 4.

As illustrated in FIG. 57, the rinse drying processing unit PUD further has a fourth liquid supplying portion 530 and a first nozzle moving portion 25. The fourth liquid supplying portion 530 has a first moving nozzle 531.

The fourth liquid supplying portion 530 discharges the fourth chemical liquid from the first moving nozzle 531 toward the upper surface Wa of the substrate W held by the lower substrate holding portion 2B and supplies the fourth chemical liquid to the upper surface Wa of the substrate W (fourth chemical liquid processing). The fourth liquid supplying portion 530 is controlled by the controlling portion 102.

Specifically, the fourth liquid supplying portion 530 further has a chemical liquid pipe portion 532 and an opening/closing valve 533 in addition to the first moving nozzle 531. The chemical liquid pipe portion 532 is a tubular member through which a fluid flows. The opening/closing valve 533 is provided in the chemical liquid pipe portion 532. The opening/closing valve 533 is openable and closable. The opening and closing operations of the opening/closing valve 533 are controlled by the controlling portion 102.

The fourth chemical liquid is supplied to the upstream end of the chemical liquid pipe portion 532. The downstream end of the chemical liquid pipe portion 532 is connected to the first moving nozzle 531. The opening/closing valve 533 opens and closes a flow path in the chemical liquid pipe portion 532. When the opening/closing valve 533 is opened, the fourth chemical liquid is supplied to the first moving nozzle 531. As a result, the fourth chemical liquid is discharged from the first moving nozzle 531. When the opening/closing valve 533 is closed, the flow of the fourth chemical liquid through the chemical liquid pipe portion 532 is stopped. As a result, the discharge of the fourth chemical liquid from the first moving nozzle 531 is stopped.

The first nozzle moving portion 25 is controlled by the controlling portion 102 and moves the first moving nozzle 531 in the horizontal direction. Specifically, the first nozzle moving portion 25 moves the first moving nozzle 531 between a position over the substrate W held by the lower substrate holding portion 2B and a first retraction position. The first retraction position is a position outside the rinse drying cup portion 62c.

Specifically, the controlling portion 102 moves the first moving nozzle 531 over the substrate W when the fourth chemical liquid is discharged from the first moving nozzle 531. Therefore, the first moving nozzle 531 discharges the fourth chemical liquid toward the substrate W while moving in the space over the substrate W.

For example, the first nozzle moving portion 25 may move the first moving nozzle 531 along an arc-shaped movement trajectory. The controlling portion 102 may cause the first moving nozzle 531 to reciprocate along an arc-shaped movement trajectory when the fourth chemical liquid is discharged from the first moving nozzle 531. The first nozzle moving portion 25 may have, for example, a nozzle arm that supports the first moving nozzle 531 and a turning mechanism that turns the nozzle arm about a rotational axis extending in the up-down direction. The turning mechanism includes, for example, an electric motor capable of rotating forward and backward.

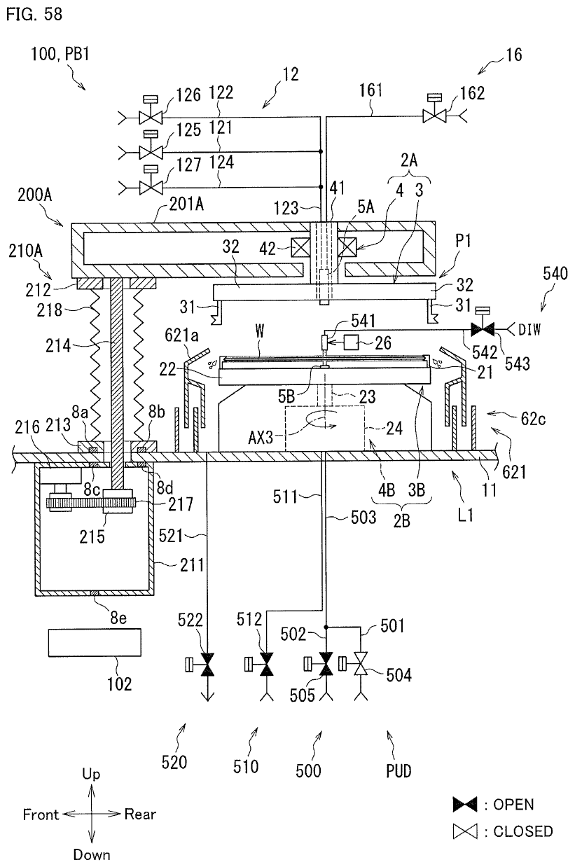

Subsequently, the substrate processing apparatus 100 according to Preferred Embodiment 4 will be described with reference to FIG. 58. FIG. 58 is still another cross-sectional view schematically illustrating a portion of the configuration of the first processing block PB1 included in the substrate processing apparatus 100 according to Preferred Embodiment 4.

As illustrated in FIG. 58, the rinse drying processing unit PUD further has a fifth liquid supplying portion 540 and a second nozzle moving portion 26. The fifth liquid supplying portion 540 has a second moving nozzle 541.

The fifth liquid supplying portion 540 discharges a rinse liquid from the second moving nozzle 541 toward the upper surface Wa of the substrate W held by the lower substrate holding portion 2B and supplies the rinse liquid to the upper surface Wa of the substrate W (rinse processing). The fifth liquid supplying portion 540 is controlled by the controlling portion 102. Specifically, the fifth liquid supplying portion 540 further has a rinse liquid pipe portion 542 and an opening/closing valve 543 in addition to the second moving nozzle 541. Since the configuration of the fifth liquid supplying portion 540 is substantially similar to the configuration of the fourth liquid supplying portion 530 described with reference to FIG. 57, the description thereof will be omitted.

The second nozzle moving portion 26 is controlled by the controlling portion 102 and moves the second moving nozzle 541 in the horizontal direction. Specifically, the second nozzle moving portion 26 moves the second moving nozzle 541 between a discharge position at which the second moving nozzle 541 faces the center of the substrate W held by the lower substrate holding portion 2B and a second retraction position. The second retraction position is a position outside the rinse drying cup portion 62c. The controlling portion 102 moves the second moving nozzle 541 from the second retraction position to the discharge position and discharges the rinse liquid from the second moving nozzle 541 located at the discharge position toward the upper surface Wa of the substrate W. Since the configuration of the second nozzle moving portion 26 is substantially similar to the configuration of the first nozzle moving portion 25 described with reference to FIG. 57, the description thereof will be omitted.

Subsequently, an example of the operation of the substrate processing apparatus 100 when the substrate W is processed in the rinse drying cup portion 62c will be described with reference to FIGS. 57 and 58.

For example, as illustrated in FIGS. 30 and 31, when the time elapsed after the substrate W is immersed in the second chemical liquid in the second immersion bath 61b2 becomes greater than or equal to a predetermined time (predetermined second chemical liquid processing time), the controlling portion 102 moves the substrate W from the second immersion bath 61b2 to the rinse drying cup portion 62c. Then, the controlling portion 102 causes the lower substrate holding portion 2B to hold the substrate W subjected to the second chemical liquid processing.

When the substrate W is moved from the second immersion bath 61b2 to the rinse drying cup portion 62c, the controlling portion 102 may execute the paddle processing as described with reference to FIGS. 35 and 36.

When the lower substrate holding portion 2B is caused to hold the substrate W subjected to the second chemical liquid processing, the controlling portion 102 raises the upper substrate holding portion 2A to the facing position P1 of the rinse drying cup portion 62c.

When the upper substrate holding portion 2A is raised to the facing position P1 of the rinse drying cup portion 62c, the controlling portion 102 controls the lower rotating portion 4B (lower motor body 24) such that the substrate W is rotated. Thereafter, the controlling portion 102 moves the second moving nozzle 541 from the second retraction position to the discharge position, discharges the rinse liquid from the second moving nozzle 541 toward the upper surface Wa of the rotating substrate W, and discharges the rinse liquid from the lower nozzle portion 5B of the rinse drying cup portion 62c toward the lower surface Wb of the rotating substrate W. As a result, the second chemical liquid is washed away from the substrate W.

When the time elapsed from the start of the rinse processing becomes greater than or equal to a predetermined time, (predetermined rinse processing time), the controlling portion 102 stops the discharge of the rinse liquid. Then, the controlling portion 102 moves the second moving nozzle 541 from the discharge position to the second retraction position and moves the first moving nozzle 531 from the first retraction position to above the substrate W. Thereafter, the controlling portion 102 discharges the fourth chemical liquid from the first moving nozzle 531 toward the upper surface Wa of the rotating substrate W and discharges the fourth chemical liquid from the lower nozzle portion 5B of the rinse drying cup portion 62c toward the lower surface Wb of the rotating substrate W. In addition, the controlling portion 102 horizontally moves the first moving nozzle 531 discharging the fourth chemical liquid. As a result, the substrate W is processed with the fourth chemical liquid (fourth chemical liquid processing).

When the time elapsed from the start of the fourth chemical liquid processing becomes greater than or equal to a predetermined time (predetermined fourth chemical liquid processing time), the controlling portion 102 stops the discharge of the fourth chemical liquid. Then, the controlling portion 102 moves the first moving nozzle 531 from above the substrate W to the first retraction position and moves the second moving nozzle 541 from the second retraction position to the discharge position. Thereafter, the controlling portion 102 executes the rinse processing. As a result, the fourth chemical liquid is washed away from the substrate W.

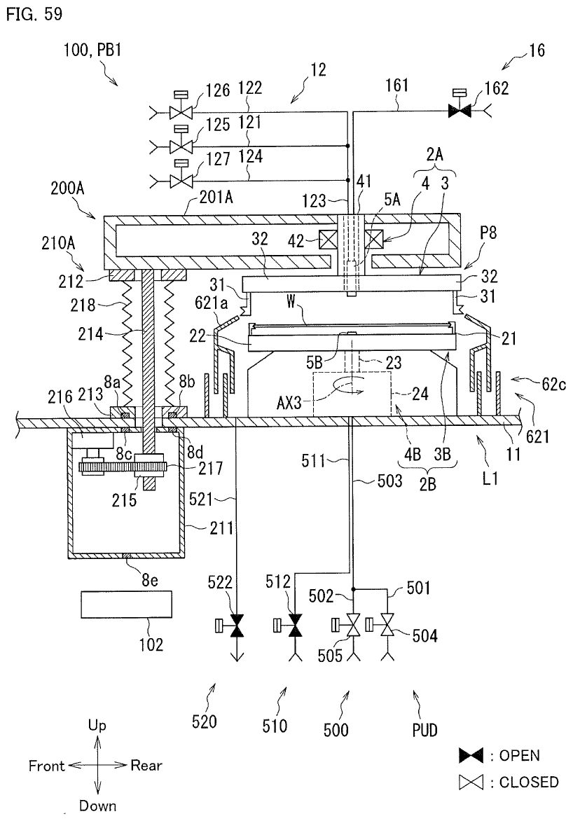

Subsequently, the drying processing executed in the rinse drying cup portion 62c will be described with reference to FIG. 59. FIG. 59 is still another cross-sectional view schematically illustrating a portion of the configuration of the first processing block PB1 included in the substrate processing apparatus 100 according to Preferred Embodiment 4.

As illustrated in FIG. 59, when the substrate W in the rinse drying cup portion 62c is dried, the controlling portion 102 lowers the upper substrate holding portion 2A from the facing position P1 of the rinse drying cup portion 62c to a drying position P8. The drying position P8 is a position between the transfer position P7 (see FIG. 56) and the facing position P1. When the upper substrate holding portion 2A is lowered to the drying position P8, the controlling portion 102 ejects the gas from the upper nozzle portion 5A and the lower nozzle portion 5B of the rinse drying cup portion 62c toward the upper surface Wa and the lower surface Wb of the rotating substrate W. As a result, the substrate W is dried.

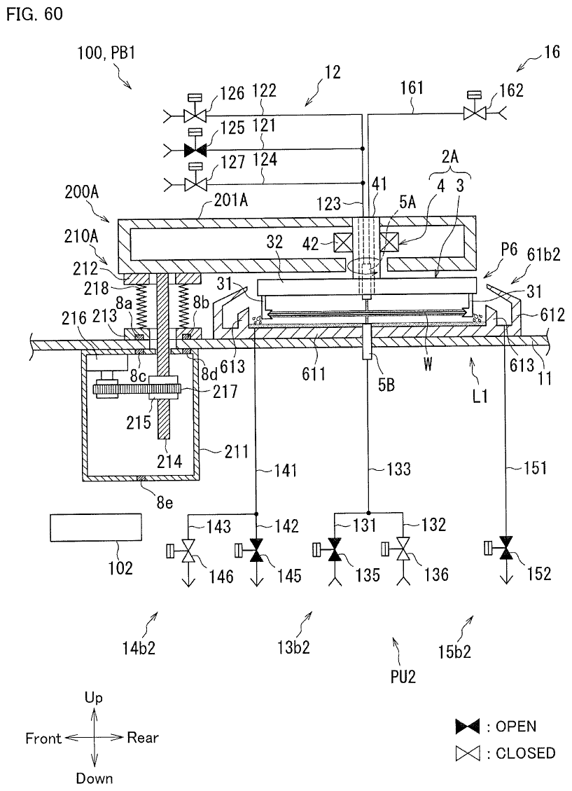

Subsequently, another example of the paddle processing executed when the substrate W is moved from the first processing cup portion 61 to the second processing cup portion 62 will be described by taking a case of moving the substrate W from the second immersion bath 61b2 to the rinse drying cup portion 62c as an example with reference to FIGS. 60 to 62. FIGS. 60 to 62 are views illustrating another example of the paddle processing.

FIGS. 60 to 62 illustrate the first liquid supplying portion 12, the first gas supplying portion 16, the upper substrate holding portion 2A, a portion of the moving portion 200A, the second chemical liquid processing unit PU2, and the first rail member 8a to the fifth rail member 8e which correspond to the first processing cup row L1 of the first processing block PB1. FIGS. 60 to 62 schematically illustrate the cross sections of the moving portion 200A and the second immersion bath 61b2 as viewed from the left side.

As illustrated in FIG. 60, the controlling portion 102 drains the second chemical liquid from the second immersion bath 61b2 before moving the substrate W from the second immersion bath 61b2 to the rinse drying cup portion 62c.

In addition, when the second chemical liquid is drained, the controlling portion 102 rotates the substrate W and discharges the second chemical liquid from the upper nozzle portion 5A and the lower nozzle portion 5B of the second immersion bath 61b2 toward the upper surface Wa and the lower surface Wb of the rotating substrate W. Through this processing, it is possible to suppress the substrate W from being dried, and thus it is possible to suppress collapse of a pattern and generation of particles.

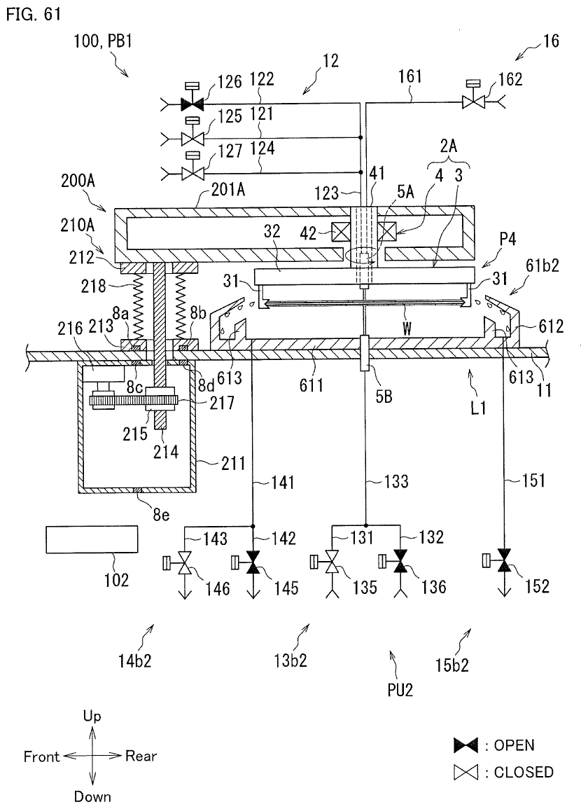

As illustrated in FIG. 61, when a predetermined time has elapsed from the start of the drainage of the second chemical liquid, the controlling portion 102 stops discharge of the second chemical liquid from the upper nozzle portion 5A and discharge of the second chemical liquid from the lower nozzle portion 5B of the second immersion bath 61b2. Thereafter, the controlling portion 102 discharges the rinse liquid from the upper nozzle portion 5A and the lower nozzle portion 5B of the second immersion bath 61b2 toward the upper surface Wa and the lower surface Wb of the rotating substrate W. As a result, the liquid film of the rinse liquid is formed on the upper surface Wa of the substrate W. That is, the upper nozzle portion 5A discharges the rinse liquid toward the substrate W subjected to the second chemical liquid processing which is located inside the second immersion bath 61b2 (first processing cup portion 61) and forms the liquid film of the rinse liquid on the upper surface Wa of the substrate W.

After the discharge of the rinse liquid is started, the controlling portion 102 raises the upper substrate holding portion 2A to the third processing position P4 while continuing the discharge of the rinse liquid and the rotation of the substrate W. Through this processing, the drying of the substrate W can be suppressed, and pattern collapse and generation of particles can be suppressed.

As described with reference to FIGS. 35 and 36, when the upper substrate holding portion 2A is raised to the third processing position P4, the controlling portion 102 stops the discharge of the rinse liquid and executes the paddle processing of supporting the liquid film of the rinse liquid on the upper surface Wa of the substrate W.

Specifically, the controlling portion 102 controls the upper rotating portion 4 (upper motor body 42) such that the rotational speed of the substrate W is reduced to a rotational speed at which the rinse liquid is not drained from the substrate W. For example, the controlling portion 102 may reduce the rotational speed of the substrate W to 10 rpm. As a result, the liquid film of the rinse liquid is supported on the upper surface Wa of the substrate W.

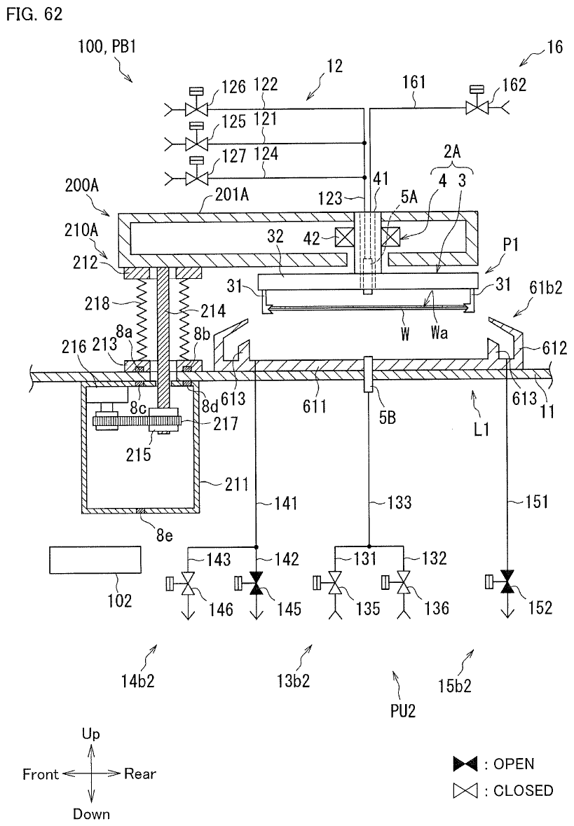

When the liquid film of the rinse liquid is supported on the upper surface Wa of the substrate W, as illustrated in FIG. 62, the controlling portion 102 moves the upper substrate holding portion 2A from the third processing position P4 to the facing position P1 of the second immersion bath 61b2 while maintaining the paddle state.

Thereafter, the controlling portion 102 moves the upper substrate holding portion 2A from the facing position P1 of the second immersion bath 61b2 to the transfer position P7 (see FIG. 56) while maintaining the paddle state.

Further, in the paddle processing described with reference to FIGS. 60 to 62, the paddle state is formed by reducing the rotational speed of the substrate W to the rotational speed at which the rinse liquid is not drained from the substrate W, but the controlling portion 102 may stop the rotation of the substrate W to support the liquid film of the rinse liquid on the upper surface Wa of the substrate W.

As described with reference to FIGS. 60 to 62, by supporting the liquid film of the rinse liquid on the upper surface Wa of the substrate W, it is possible to suppress the upper surface Wa of the substrate W from being dried while the substrate W is moved from the second immersion bath 61b2 (first processing cup portion 61) to the rinse drying cup portion 62c (second processing cup portion 62). As a result, it is possible to suppress collapse of a pattern and generation of particles.

Preferred Embodiment 4 of the present invention has been described above with reference to FIGS. 56 to 62. According to Preferred Embodiment 4, similarly to the preferred embodiments described with reference to FIGS. 1 to 55, since the substrate W in the horizontal posture is immersed in the chemical liquid stored in the immersion bath 61b and the substrate W is processed, the consumption amount of the chemical liquid can be reduced.

Furthermore, according to Preferred Embodiment 4, it is possible to process the substrate W by discharging the chemical liquid onto the substrate W while moving the first moving nozzle 531, and thus it is possible to process the substrate W with higher accuracy.

In Preferred Embodiment 4, the lower substrate holding portion 2B has the pinching chuck mechanism, but the mechanism in which the lower substrate holding portion 2B holds the substrate W is not limited to the pinching chuck mechanism. For example, the lower substrate holding portion 2B may have a vacuum chuck mechanism.

In Preferred Embodiment 4, the rinse liquid is discharged from the second moving nozzle 541 when the rinse processing is executed on the substrate W inside the rinse drying cup portion 62c, but the rinse liquid may be discharged from the upper nozzle portion 5A. In this case, the fifth liquid supplying portion 540 and the second nozzle moving portion 26 may be omitted.

In Preferred Embodiment 4, the lower substrate holding portion 2B holds the substrate W when the rinse processing is executed on the substrate W inside the rinse drying cup portion 62c, but in a case where the rinse processing is executed by discharging the rinse liquid from the upper nozzle portion 5A, the substrate W may be held by the upper substrate holding portion 2A.

In Preferred Embodiment 4, when the substrate W is dried, the lower substrate holding portion 2B holds the substrate w, but the upper substrate holding portion 2A may hold the substrate W.

In Preferred Embodiment 4, when the substrate W is dried, the gas is ejected from the upper nozzle portion 5A and the lower nozzle portion 5B of the rinse drying cup portion 62c, but the substrate W may be dried by increasing the rotation of the substrate W. In this case, the first gas supplying portion 16 and the second gas supplying portion 510 may be omitted.

In Preferred Embodiment 4, the second gas supplying portion 510 supplies the gas to the lower nozzle portion 5B, but the second gas supplying portion 510 may supply the gas to a gap on the periphery of the lower nozzle portion 5B. In this case, the gas is ejected from the periphery of the lower nozzle portion 5B toward the lower surface Wb of the substrate W.

### Preferred Embodiment 5

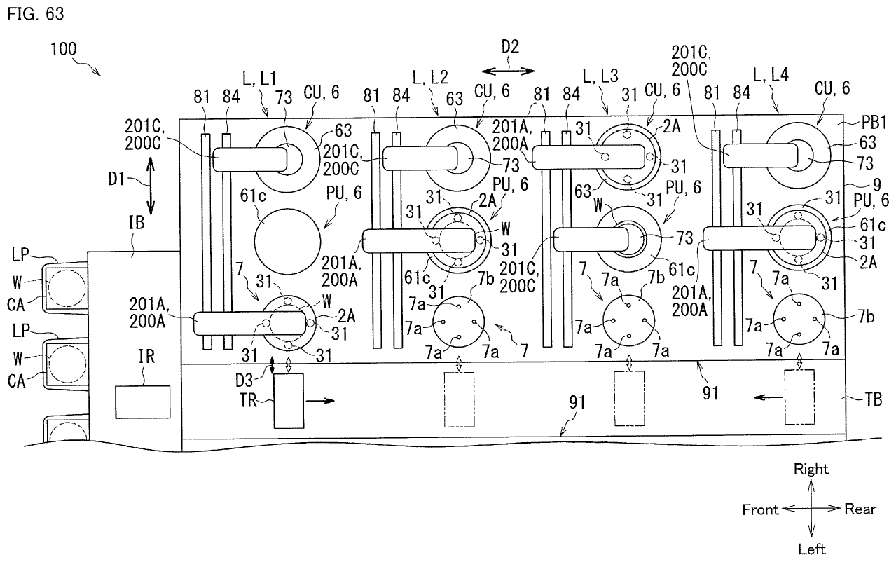

Subsequently, Preferred Embodiment 5 of the present invention will be described with reference to FIGS. 63 to 66. However, matters differing from the preferred embodiments described with reference to FIGS. 1 to 62 will be described, and the description of matters that are the same as in the preferred embodiments described with reference to FIGS. 1 to 62 will be omitted.

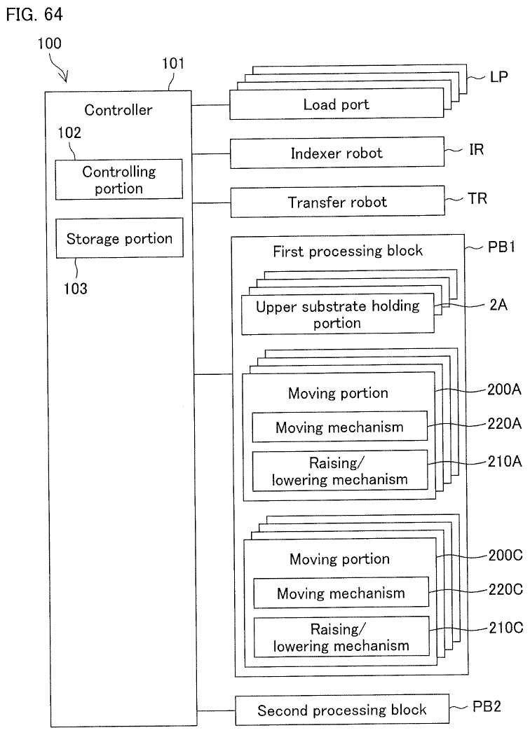

FIG. 63 is an enlarged schematic plan view of a portion of a substrate processing apparatus 100 according to Preferred Embodiment 5. FIG. 64 is a block diagram of the substrate processing apparatus 100 according to Preferred Embodiment 5. Specifically, FIG. 63 illustrates a configuration of the first processing block PB1 included in the substrate processing apparatus 100 according to Preferred Embodiment 5. Although not illustrated, the configuration of the second processing block PB2 is similar to the configuration of the first processing block PB1.

As illustrated in FIG. 63, the first processing block PB1 has the processing chamber 9, the plurality of processing cup rows L (first processing cup row L1 to fourth processing cup row L4), the plurality of placing tables 7, the plurality of upper substrate holding portions 2A, a plurality of brush processing portions 73, the plurality of moving portions 200A, a plurality of moving portion 200C, the plurality of rail members 81, and a plurality of rail members 84. The placing table 7, the upper substrate holding portion 2A, the brush processing portion 73, the moving portion 200A, the moving portion 200C, the rail member 81, and the rail member 84 are provided for each processing cup row L.

In the example illustrated in FIG. 63, each processing cup row L includes an immersion bath 61c and the cleaning bath 63. The placing table 7, the immersion bath 61c, and the cleaning bath 63 are arranged in the order of the placing table 7, the immersion bath 61c, and the cleaning bath 63 from the left side. Specifically, the first processing block PB1 has the substrate processing unit PU and the cleaning unit CU for each processing cup row L. The substrate processing unit PU has the immersion bath 61c. The immersion bath 61c stores the processing liquid. The substrate W is immersed in the processing liquid stored in the immersion bath 61c. The brush processing portion 73 performs brush processing on the upper surface Wa of the substrate W immersed in the processing liquid in the immersion bath 61c.

The moving portion 200C has a supporting arm 201C. The supporting arm 201C supports the brush processing portion 73. As illustrated in FIG. 64, the moving portion 200C has a raising/lowering mechanism 210C and a moving mechanism 220C similarly to the moving portion 200A. Since the configurations of the raising/lowering mechanism 210C and the moving mechanism 220C are similar to the configurations of the raising/lowering mechanism 210A and the moving mechanism 220A, the detailed description thereof will be omitted. The rail member 84 guides the raising/lowering mechanism 210C coupled to the supporting arm 201C in the first direction D1 (left-right direction). Since the configuration of the rail member 84 is similar to the configuration of the rail member 8 described with reference to FIGS. 1, 2, 4, and 5, the detailed description thereof will be omitted.

When the upper substrate holding portion 2A and the brush processing portion 73 are moved in the first direction D1, the vertical positions of the upper substrate holding portion 2A and the supporting arm 201A are different from the vertical positions of the brush processing portion 73 and the supporting arm 201C. Therefore, it is possible to avoid the upper substrate holding portion 2A and the brush processing portion 73 from interfering with each other. Similarly, it is possible to avoid the supporting arm 201A and the supporting arm 201C from interfering with each other.

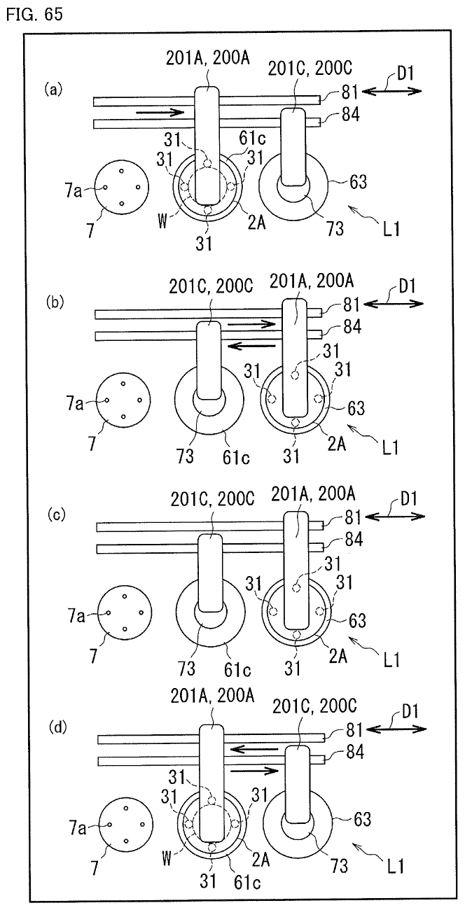

Subsequently, an example of the operation of the substrate processing apparatus 100 according to Preferred Embodiment 5 will be described with reference to FIGS. 63, 64, and 65A to 65D. FIGS. 65A to 65D are views schematically illustrating an example of the operation of the substrate processing apparatus 100 according to Preferred Embodiment 5. Specifically, FIGS. 65A to 65D illustrate an example of the operation of the first processing block PB1 when one substrate W is processed in the first processing cup row L1 of the first processing block PB1.

When the transfer robot TR is controlled such that the substrate W is placed on the placing table 7, the controlling portion 102 causes the plurality of upper chuck members 31 to grip the substrate W placed on the placing table 7. As a result, the upper substrate holding portion 2A (upper holding portion 3) horizontally holds the substrate W.

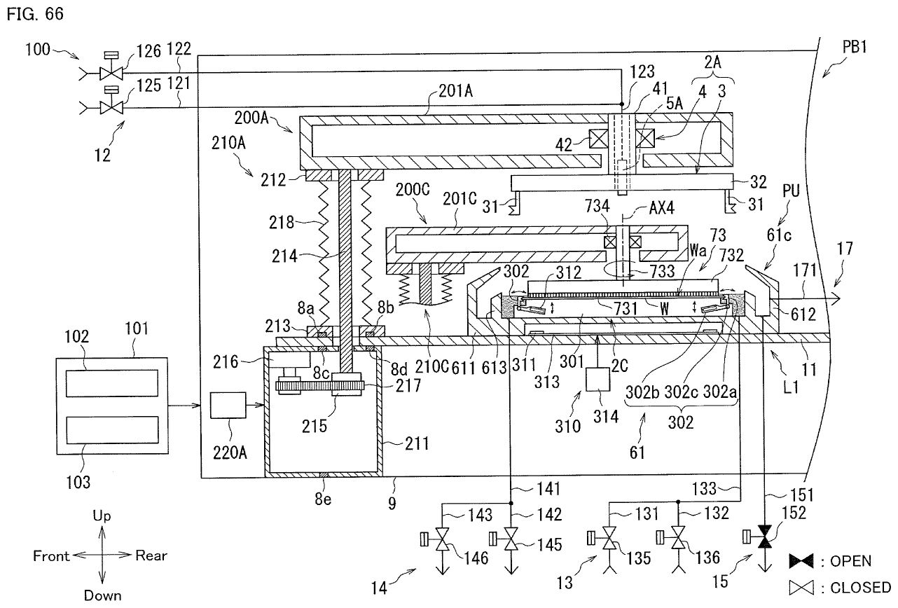

As illustrated in FIG. 65A, when the substrate W is held by the upper substrate holding portion 2A, the controlling portion 102 controls the moving portion 200A such that the substrate W is immersed in the processing liquid in the immersion bath 61c. Then, the controlling portion 102 causes the substrate W to be transferred between the upper substrate holding portion 2A and a lower substrate holding portion 2C which will be described below with reference to FIG. 66. Specifically, the controlling portion 102 causes the lower chuck members 302 which will be described below with reference to FIG. 66 to grip the substrate W. Thereafter, the controlling portion 102 controls the upper chuck driving mechanism 50 such that the gripping of the substrate W by the plurality of upper chuck members 31 is released. As a result, the substrate W immersed in the processing liquid in the immersion bath 61c is horizontally held by the lower substrate holding portion 2C.

As illustrated in FIG. 65B, when the gripping of the substrate W by the plurality of upper chuck members 31 is released, the controlling portion 102 controls the moving portion 200A such that the upper substrate holding portion 2A is retracted from the immersion bath 61c and controls the moving portion 200C such that the brush processing portion 73 is moved to a position at which the brush processing portion 73 comes into contact with the substrate W in the immersion bath 61c. For example, the controlling portion 102 may control the moving portion 200A such that the upper substrate holding portion 2A is retracted to the facing position P1 of the cleaning bath 63.

As illustrated in FIG. 65C, when the brush processing portion 73 is brought into contact with the upper surface Wa of the substrate W, the controlling portion 102 executes the brush processing such that the upper surface Wa of the substrate W is cleaned. Specifically, an upper brush 731 to be described below with reference to FIG. 66 is rotated. The controlling portion 102 may immerse the plurality of upper chuck members 31 in the rinse liquid stored in the cleaning bath 63 and execute cleaning processing of the upper chuck members 31 in parallel with the brush processing.

When the time elapsed from the start of the brush processing becomes greater than or equal to a predetermined time (predetermined brush processing time), the controlling portion 102 ends the brush processing. Specifically, the controlling portion 102 stops the rotation of the upper brush 731 which will be described later with reference to FIG. 66.

As illustrated in FIG. 65D, when the brush processing ends, the controlling portion 102 controls the moving portion 200C such that the brush processing portion 73 is retracted from the immersion bath 61c and causes the substrate W to be transferred between the upper substrate holding portion 2A and the lower substrate holding portion 2C which will be described below with reference to FIG. 66. As a result, the substrate W subjected to the brush processing is held by the upper substrate holding portion 2A. The controlling portion 102 may retract the brush processing portion 73 to the cleaning bath 63 and clean the upper brush 731 which will be described below with reference to FIG. 56.

When the substrate W subjected to the brush processing is held by the upper substrate holding portion 2A, the controlling portion 102 executes the rinse processing and the drying processing. Specifically, the rinse processing and the drying processing are performed inside the immersion bath 61c. After end of the drying processing, the controlling portion 102 controls the moving portion 200A and the upper chuck driving mechanism 50 such that the substrate W subjected to the drying processing is placed on the placing table 7.

Subsequently, the substrate processing unit PU and the brush processing portion 73 will be described with reference to FIG. 66. FIG. 66 is a cross-sectional view schematically illustrating a portion of the configuration of the first processing block PB1 included in the substrate processing apparatus 100 according to Preferred Embodiment 5. Specifically, FIG. 66 illustrates the first liquid supplying portion 12, the upper substrate holding portion 2A, the moving portion 200A, the brush processing portion 73, a portion of the moving portion 200C, the substrate processing unit PU, and the first rail member 8a to the fifth rail member 8e which correspond to the first processing cup row L1 of the first processing block PB1. FIG. 66 schematically illustrates the cross sections of the moving portion 200A, a portion of the moving portion 200C, and the immersion bath 61c as viewed from the left side.

As illustrated in FIG. 66, the substrate processing unit PU has the first processing cup portion 61, the second liquid supplying portion 13, the first draining portion 14, the second draining portion 15, and the exhaust portion 17. The first processing cup portion 61 includes the immersion bath 61c, the lower substrate holding portion 2C, and a lower chuck driving mechanism 310.

The immersion bath 61c has a bottom wall portion 611, a side wall portion 612, and an inner wall portion 613. The immersion bath 61c illustrated in FIG. 66 is not provided with the lower nozzle portion 5B. The upstream end of the common pipe portion 133 of the second liquid supplying portion 13 is connected to the bottom wall portion 611 inside the inner wall portion 613 and communicates with the inner space of the immersion bath 61c.

The lower substrate holding portion 2C is disposed inside the inner wall portion 613 and horizontally holds the substrate W immersed in the processing liquid stored inside the inner wall portion 613. The processing liquid stored in the immersion bath 61c when the substrate W is cleaned by the brush processing portion 73 may be the chemical liquid or the rinse liquid.

Specifically, the lower substrate holding portion 2C has a base 301 and a plurality of lower chuck members 302. The plurality of lower chuck members 302 are provided on the base 301. The base 301 is an example of a “lower base member.” The plurality of lower chuck members 302 grip the peripheral edge portion of the substrate W. When the plurality of lower chuck members 302 grip the substrate W, the substrate W is horizontally held. The lower chuck member 302 is an example of a “lower gripping member.”

Specifically, the base 301 has substantially a disk shape and supports the plurality of lower chuck members 302 in the horizontal posture. The base 301 is disposed inside the inner wall portion 613. The upper surface of the base 301 extends along a horizontal plane. The substrate W is placed on the upper surface of the base 301. That is, the lower surface Wb of the substrate W is in contact with the upper surface of the base 301. The height of the base 301 from the bottom wall portion 611 is lower than the height of the inner wall portion 613 from the bottom wall portion 611. The substrate W placed on the upper surface of the base 301 is immersed in the processing liquid stored inside the inner wall portion 613.

The plurality of lower chuck members 302 are disposed at the peripheral edge portion of the base 301. The plurality of lower chuck members 302 grip the substrate W placed on the upper surface of the base 301.

The substrate W may be horizontally held at a position higher than that of the upper surface of the base 301. That is, the plurality of lower chuck members 302 may grip the substrate W over the base 301. In this case, the substrate W is directly transferred between the upper chuck member 31 of the upper substrate holding portion 2A and the lower chuck member 302 of the lower substrate holding portion 2C.

The lower chuck driving mechanism 310 drives the plurality of lower chuck members 302 and causes the plurality of lower chuck members 302 to grip the substrate W. In addition, the lower chuck driving mechanism 310 drives the plurality of lower chuck members 302 and releases the gripping of the substrate W by the plurality of lower chuck members 302. The lower chuck driving mechanism 310 is controlled by the controlling portion 102. That is, the operation of the plurality of lower chuck members 302 is controlled by the controlling portion 102.

Specifically, the lower chuck member 302 has a chuck pin 302a, a driven portion 302b, and a connecting shaft 302c. The lower chuck driving mechanism 310 has a driving magnet 311, a driven magnet 312, a raising/lowering plate 313, and a raising/lowering mechanism 314.

The chuck pin 302a protrudes from the base 301. The chuck pin 302a has a pin-shaped portion and a contact portion provided at the tip end of the pin-shaped portion and being in contact with the peripheral edge portion of the substrate W.

The driven portion 302b and the connecting shaft 302c are disposed inside the base 301. An accommodation space for accommodating a plurality of driven portions 302b and a plurality of connecting shaft 302c is formed inside the base 301.

A base end of the chuck pin 302a is fixed to the connecting shaft 302c. The chuck pin 302a protrudes upward from the connecting shaft 302c. The driven portion 302b is fixed to the connecting shaft 302c. The driven portion 302b extends from the connecting shaft 302c toward the center of the base 301. The connecting shaft 302c extends in the horizontal direction.

The driven portion 302b is swingable in the up-down direction about the connecting shaft 302c. Since the driven portion 302b is fixed to the connecting shaft 302c, when the driven portion 302b swings, the connecting shaft 302c rotates. In addition, since a base end of the chuck pin 302a is fixed to the connecting shaft 302c, when the connecting shaft 302c rotates, the chuck pin 302a swings in the radial direction of the substrate W about the connecting shaft 302c. That is, the driven portion 302b and the chuck pin 302a swing integrally.

Specifically, when the driven portion 302b rotates downward about the connecting shaft 302c, the chuck pin 302a rotates radially inward of the substrate W about the connecting shaft 302c, and the contact portion of the chuck pin 302a comes into contact with the peripheral edge portion of the substrate W. When each of the plurality of chuck pins 302a rotates radially inward of the substrate W about the corresponding connecting shaft 302c, the substrate W is gripped by the plurality of chuck pins 302a.

When the driven portion 302b rotates upward about the connecting shaft 302c, the chuck pin 302a rotates radially outward of the substrate W about the connecting shaft 302c, and the contact portion of the chuck pin 302a is separated from the peripheral edge portion of the substrate W. When each of the plurality of chuck pins 302a rotates radially outward of the substrate W about the corresponding connecting shaft 302c, the gripping of the substrate W by the plurality of chuck pins 302a is released.

The lower chuck driving mechanism 310 swings the driven portion 302b about the connecting shaft 302c. Specifically, the driving magnet 311 is disposed under the driven portion 302b. The driven magnet 312 is fixed to the driven portion 302b. The raising/lowering plate 313 supports the driving magnet 311. The raising/lowering mechanism 314 is controlled by the controlling portion 102 such that the raising/lowering plate 313 is raised and lowered. When the raising/lowering mechanism 314 raises and lowers the raising/lowering plate 313, the driving magnet 311 is raised and lowered to approach the driven magnet 312 or to be separated from the driven magnet 312. As a result, the driven portion 302b swings about the connecting shaft 302c.

Specifically, the driving magnet 311 and the raising/lowering plate 313 are disposed inside the bottom wall portion 611. An accommodation space for accommodating the driving magnet 311 and the raising/lowering plate 313 is formed inside the bottom wall portion 611.

The driving magnet 311 has an annular shape in a plan view. For example, the driving magnet 311 may have a circular annular shape. The driving magnet 311 is fixed to the upper surface of the raising/lowering plate 313. The raising/lowering plate 313 may have, for example, a circular shape. An actuator of the raising/lowering mechanism 314 includes, for example, a cylinder. The raising/lowering mechanism 314 moves the raising/lowering plate 313 in the up-down direction.

The driven magnet 312 is disposed at a position directly above the driving magnet 311. The driven magnet 312 is disposed such as to repel the driving magnet 311. Specifically, the driven magnet 312 and the driving magnet 311 are disposed such that surfaces facing each other have the same polarity.

When the raising/lowering mechanism 314 raises the raising/lowering plate 313, the driving magnet 311 is raised and approaches the driven magnet 312. As a result, the driven magnet 312 repels the driving magnet 311 and is raised, and the driven portion 302b rotates upward about the connecting shaft 302c. Therefore, the chuck pin 302a rotates radially outward of the substrate W about the connecting shaft 302c. On the other hand, when the raising/lowering mechanism 314 lowers the raising/lowering plate 313, the driving magnet 311 is lowered and separated from the driven magnet 312. As a result, the driven magnet 312 is lowered by its own weight, and the driven portion 302b rotates downward about the connecting shaft 302c. Therefore, the chuck pin 302a rotates radially inward of the substrate W about the connecting shaft 302c.

Subsequently, the brush processing portion 73 will be described. As illustrated in FIG. 66, the brush processing portion 73 has the upper brush 731, a brush holder 732, a shaft 733, and a motor body 734.

The brush holder 732 holds the upper brush 731. The upper brush 731 protrudes downward from the brush holder 732. The upper brush 731 comes into contact with the upper surface Wa of the substrate W and cleans the upper surface Wa of the substrate W. The upper brush 731 is an example of an “upper brush member.” Specifically, the upper brush 731 comes into contact with the upper surface Wa of the substrate W held by the lower substrate holding portion 2C. Therefore, the upper brush 731 comes into contact with the upper surface Wa of the substrate W immersed in the processing liquid in the immersion bath 61c.

The shape of the upper brush 731 is not particularly limited. For example, the upper brush 731 may have a band shape, a linear shape, or substantially a fan shape in a plan view. Alternatively, the upper brush 731 may have a circular shape in a plan view. Since the configuration of the upper brush 731 is similar to the configuration of the lower brush 616 described with reference to FIG. 48, the detailed description thereof will be omitted.

In the present preferred embodiment, the shaft 733 and the motor body 734 constitute a “brush rotating portion.” The brush rotating portion rotates the upper brush 731. When the upper brush 731 is in contact with the upper surface Wa of the substrate W immersed in the processing liquid, the controlling portion 102 controls the brush rotating portion such that the upper brush 731 is rotated.

Specifically, the lower end of the shaft 733 is coupled to the central portion of the brush holder 732. The shaft 733 protrudes upward from the brush holder 732. The shaft 733 extends along a fourth rotational axis AX4 extending in the up-down direction. The upper end of the shaft 733 is rotatably supported by the supporting arm 201C. A portion of the shaft 733 may be accommodated inside the supporting arm 201C.

The motor body 734 rotates the shaft 733 about the fourth rotational axis AX4. As a result, the upper brush 731 rotates about the fourth rotational axis AX4. The operation of the motor body 734 is controlled by the controlling portion 102. The motor body 734 is, for example, an electric motor. The motor body 734 may be accommodated inside the supporting arm 201A.

Preferred Embodiment 5 of the present invention has been described above with reference to FIGS. 63 to 66. According to Preferred Embodiment 5, similarly to the preferred embodiments described with reference to FIGS. 1 to 62, the consumption amount of the chemical liquid can be reduced. According to Preferred Embodiment 5, the brush processing portion 73 can clean the upper surface Wa of the substrate W.

In Preferred Embodiment 5, each processing cup row L includes one immersion bath 61c, but each processing cup row L may include a plurality of immersion baths 61c.

In Preferred Embodiment 5, each processing cup row L does not include the second processing cup portion 62, but each processing cup row L may include at least one second processing cup portion 62.

In Preferred Embodiment 5, each processing cup row L includes the cleaning bath 63, but the cleaning bath 63 may be omitted. In other words, the cleaning unit CU may be omitted.

In Preferred Embodiment 5, the placing table 7 is provided for each processing cup row L, but the placing table 7 may be omitted.

In Preferred Embodiment 5, one upper substrate holding portion 2A is provided for each processing cup row L, but a plurality of upper substrate holding portions 2A may be provided for each processing cup row L. Similarly, a plurality of brush processing portions 73 may be provided for each processing cup row L.

### Preferred Embodiment 6

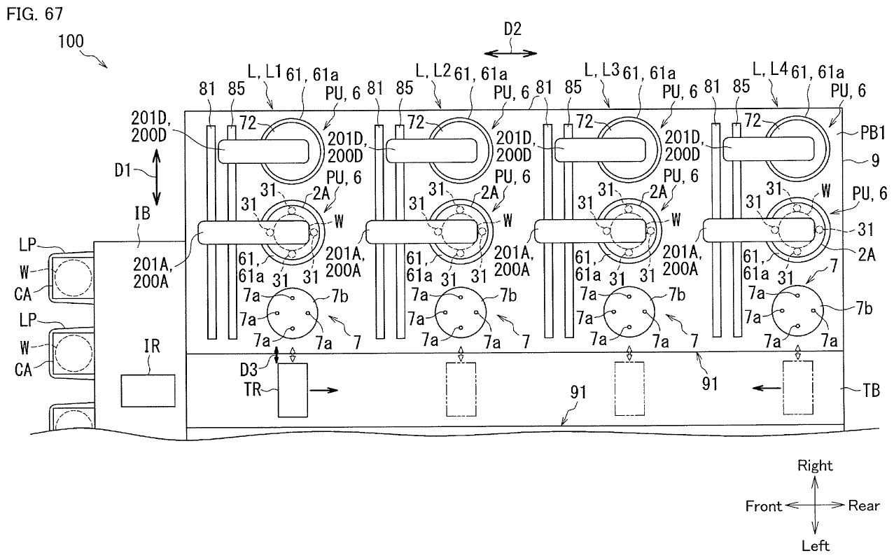

Subsequently, Preferred Embodiment 6 of the present invention will be described with reference to FIGS. 67 to 69. However, matters differing from the preferred embodiments described with reference to FIGS. 1 to 66 will be described, and the description of matters that are the same as in the preferred embodiments described with reference to FIGS. 1 to 66 will be omitted.

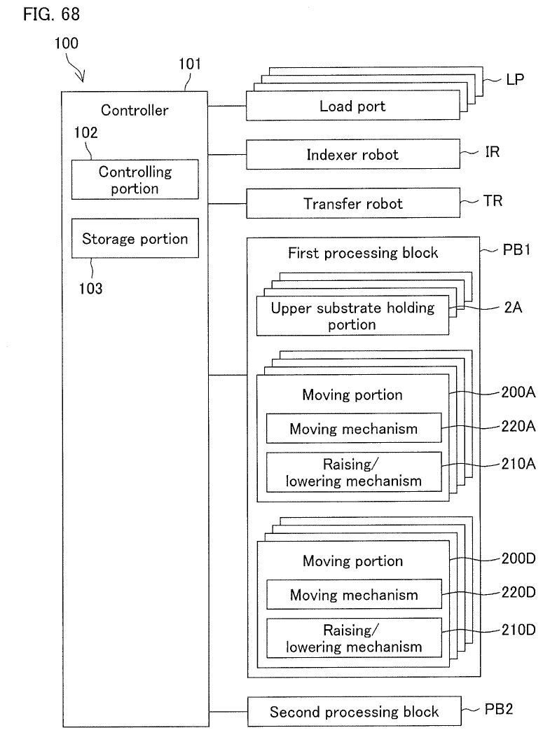

FIG. 67 is an enlarged schematic plan view of a portion of a substrate processing apparatus 100 according to Preferred Embodiment 6. FIG. 68 is a block diagram of the substrate processing apparatus 100 according to Preferred Embodiment 6. Specifically, FIG. 67 illustrates a configuration of the first processing block PB1 included in the substrate processing apparatus 100 according to Preferred Embodiment 6. Although not illustrated, the configuration of the second processing block PB2 is similar to the configuration of the first processing block PB1.

As illustrated in FIG. 67, the first processing block PB1 has the processing chamber 9, the plurality of processing cup rows L (first processing cup row L1 to fourth processing cup row L4), the plurality of placing tables 7, the plurality of upper substrate holding portions 2A, a plurality of cutoff portions 72, the plurality of moving portions 200A, a plurality of moving portion 200D, the plurality of rail members 81, and a plurality of rail members 85. The placing table 7, the upper substrate holding portion 2A, the cutoff portion 72, the moving portion 200A, the moving portion 200D, the rail member 81, and the rail member 85 are provided for each processing cup row L.

In the example illustrated in FIG. 67, each processing cup row L includes two first processing cup portions 61. Specifically, each processing cup row L includes two immersion baths 61a. The placing table 7 and the two immersion baths 61a are arranged in the order of the placing table 7, the immersion bath 61a, and the immersion bath 61a from the left side. Specifically, the first processing block PB1 has two substrate processing units PU for each processing cup row L. The substrate processing unit PU has the immersion bath 61a. The substrate W is left in the immersion bath 61a while being immersed in the processing liquid stored in the immersion bath 61a.

The moving portion 200D has a supporting arm 201D. The supporting arm 201D supports the cutoff portion 72. As illustrated in FIG. 68, the moving portion 200D has a raising/lowering mechanism 210D and a moving mechanism 220D similarly to the moving portion 200A. Since the configurations of the raising/lowering mechanism 210D and the moving mechanism 220D are similar to the configurations of the raising/lowering mechanism 210A and the moving mechanism 220A, the detailed description thereof will be omitted. The rail member 85 guides the raising/lowering mechanism 210D coupled to the supporting arm 201D in the first direction D1 (left-right direction). Since the configuration of the rail member 85 is similar to the configuration of the rail member 8 described with reference to FIGS. 1, 2, 4, and 5, the detailed description thereof will be omitted.

When the upper substrate holding portion 2A and the cutoff portion 72 are moved in the first direction D1, the vertical positions of the upper substrate holding portion 2A and the supporting arm 201A are different from the vertical positions of the cutoff portion 72 and the supporting arm 201D. Therefore, it is possible to avoid the upper substrate holding portion 2A and the cutoff portion 72 from interfering with each other. Similarly, it is possible to avoid the supporting arm 201A and the supporting arm 201D from interfering with each other.

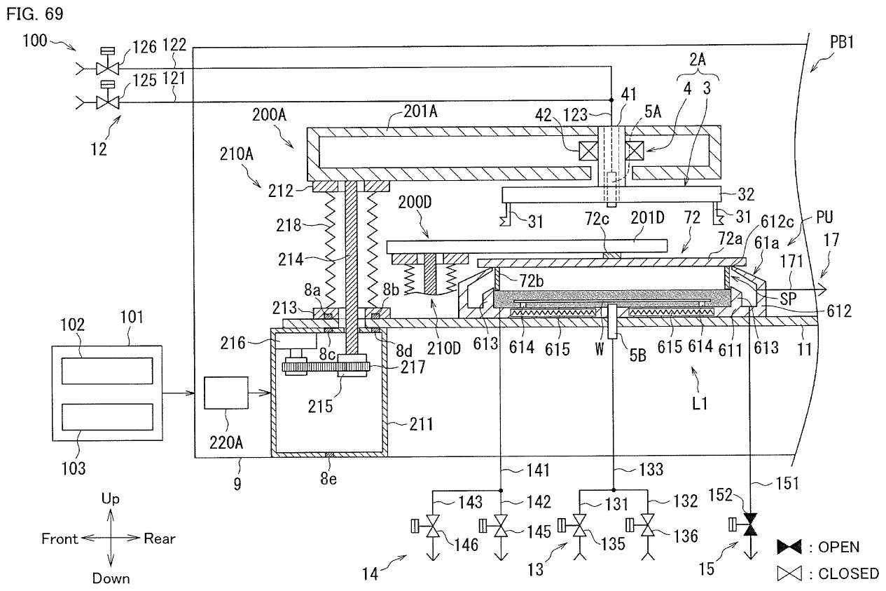

Subsequently, the substrate processing unit PU and the cutoff portion 72 will be described with reference to FIG. 69. FIG. 69 is a cross-sectional view schematically illustrating a portion of the configuration of the first processing block PB1 included in the substrate processing apparatus 100 according to Preferred Embodiment 6. Specifically, FIG. 69 illustrates the first liquid supplying portion 12, the upper substrate holding portion 2A, the moving portion 200A, the cutoff portion 72, a portion of the moving portion 200D, the substrate processing unit PU, and the first rail member 8a to the fifth rail member 8e which correspond to the first processing cup row L1 of the first processing block PB1. FIG. 69 schematically illustrates the cross sections of the moving portion 200A, a portion of the moving portion 200D, and the immersion bath 61a as viewed from the left side.

As illustrated in FIG. 69, the substrate processing unit PU has the immersion bath 61a, the heater 615, the second liquid supplying portion 13, the first draining portion 14, the second draining portion 15, and the exhaust portion 17. The cutoff portion 72 has a lid member 72a, an exhaust cutoff portion 72b, and a connecting portion 72c. The connecting portion 72c connects the lid member 72a and the supporting arm 201D. The connecting portion 72c may be, for example, a rod-shaped member.

The controlling portion 102 controls the moving portion 200A and the upper chuck driving mechanism 50 such that the substrate W is left on the plurality of supporting portions 614 of the immersion bath 61a and then controls the moving portion 200D such that the cutoff portion 72 is moved to a position at which an upper surface opening of the immersion bath 61a is covered with the lid member 72a. Therefore, when the substrate W is immersed in the chemical liquid in the immersion bath 61a, the upper surface opening of the immersion bath 61a is covered with the lid member 72a. In a state where the lid member 72a covers the upper surface opening of the immersion bath 61a, the lid member 72a may be in contact with the inner peripheral edge portion 612c (upper end of the side wall portion 612) of the immersion bath 61a, or may be slightly separated from the inner peripheral edge portion 612c (upper end of the side wall portion 612) of the immersion bath 61a.

The shape of the lid member 72a is not particularly limited as long as it is a shape that covers the upper surface opening of the immersion bath 61a. For example, the lid member 72a may have a disk shape. In this case, the diameter of the lid member 72a is greater than the diameter of the upper surface opening of the immersion bath 61a.

The exhaust cutoff portion 72b is coupled to the lid member 72a. That is, the lid member 72a supports the exhaust cutoff portion 72b. The exhaust cutoff portion 72b protrudes downward from the lid member 72a. The exhaust cutoff portion 72b covers the gap SP when the lid member 72a is located at a position at which the lid member 72a covers the upper surface opening of the immersion bath 61a. Therefore, when the substrate W is immersed in the chemical liquid in the immersion bath 61a, the gap SP is covered with the exhaust cutoff portion 72b. Since the configuration of the exhaust cutoff 72b portion is similar to the configuration of the exhaust cutoff portion 71 described with reference to FIGS. 51 and 52, the detailed description thereof will be omitted.

Preferred Embodiment 6 of the present invention has been described above with reference to FIGS. 67 to 69. According to Preferred Embodiment 6, similarly to the preferred embodiments described with reference to FIGS. 1 to 66, the consumption amount of the chemical liquid can be reduced. Further, according to Preferred Embodiment 6, the upper surface opening of the immersion bath 61a can be covered with the lid member 72a. Therefore, it is possible to suppress a decrease in the temperature of the chemical liquid stored in the immersion bath 61a.

Specifically, when the upper surface opening of the immersion bath 61a is open, the gas over the immersion bath 61a is drawn into the inside of the immersion bath 61a. As a result, the temperature of the chemical liquid in the immersion bath 61a may decrease due to the airflow drawn into the inside of the immersion bath 61a from above the immersion bath 61a. On the other hand, according to Preferred Embodiment 6, since the lid member 72a covers the upper surface opening of the immersion bath 61a, the airflow drawn into the inside of the immersion bath 61a from above the immersion bath 61a is less likely to occur. Alternatively, the flow rate of the airflow drawn into the inside of the immersion bath 61a from above the immersion bath 61a can be reduced. Therefore, according to Preferred Embodiment 6, it is possible to suppress a decrease in the temperature of the chemical liquid in the immersion bath 61a.

Further, according to Preferred Embodiment 6, as in Modification Example 10 and Modification Example 11, the gap SP is covered with the exhaust cutoff portion 72b during the chemical liquid processing. Therefore, it is possible to further suppress a decrease in the temperature of the chemical liquid in the immersion bath 61a (chemical liquid stored inside the inner wall portion 613).

In Preferred Embodiment 6, each processing cup row L does not include the cleaning bath 63, but each processing cup row L may include the cleaning bath 63. In other words, the first processing block PB1 and the second processing block PB2 may have the cleaning unit CU for each processing cup row L.

In Preferred Embodiment 6, each processing cup row L includes two first processing cup portions 61, but each processing cup row L may include one first processing cup portion 61 or may include three or more first processing cup portions 61. In other words, the first processing block PB1 and the second processing block PB2 may have one substrate processing unit PU or chemical liquid processing unit PUC for each processing cup row L or may have three or more substrate processing units PU or chemical liquid processing units PUC.

In Preferred Embodiment 6, each processing cup row L does not include the second processing cup portion 62, but each processing cup row L may include at least one second processing cup portion 62.

In Preferred Embodiment 6, the placing table 7 is provided for each processing cup row L, but the placing table 7 may be omitted.

In Preferred Embodiment 6, one upper substrate holding portion 2A is provided for each processing cup row L, but a plurality of upper substrate holding portions 2A may be provided for each processing cup row L. Similarly, a plurality of cutoff portions 72 may be provided for each processing cup row L.

### Preferred Embodiment 7

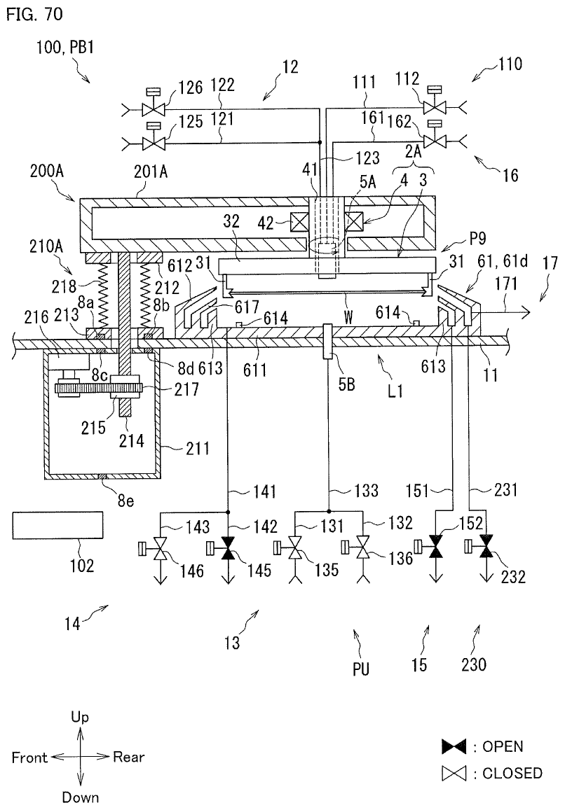

Subsequently, Preferred Embodiment 7 of the present invention will be described with reference to FIG. 70. However, matters differing from the preferred embodiments described with reference to FIGS. 1 to 69 will be described, and the description of matters that are the same as in the preferred embodiments described with reference to FIGS. 1 to 69 will be omitted. Preferred Embodiment 7 is different from the preferred embodiments described with reference to FIGS. 1 to 69 in a configuration of the first processing cup portion 61.

FIG. 70 is a cross-sectional view schematically illustrating a portion of a configuration of the first processing block PB1 included in a substrate processing apparatus 100 according to Preferred Embodiment 7. Specifically, FIG. 70 illustrates the first liquid supplying portion 12, the first gas supplying portion 16, a drying liquid supplying portion 110, the upper substrate holding portion 2A, a portion of the moving portion 200A, the substrate processing unit PU, and the first rail member 8a to the fifth rail member 8e which correspond to the first processing cup row L1 of the first processing block PB1. FIG. 70 schematically illustrates the cross sections of the moving portion 200A and an immersion bath 61d as viewed from the left side.

As illustrated in FIG. 70, in Preferred Embodiment 7, the first processing block PB1 has the upper substrate holding portion 2A, the rail member 8 (first rail member 8a to fifth rail member 8e), the supporting plate 11, the first liquid supplying portion 12, the first gas supplying portion 16, the drying liquid supplying portion 110, the moving portion 200A, and the substrate processing unit PU. The substrate processing unit PU has the immersion bath 61d, the second liquid supplying portion 13, the first draining portion 14, the second draining portion 15, and a fourth draining portion 230, and the exhaust portion 17. The upper nozzle portion 5A selectively discharges any one of a chemical liquid, a rinse liquid (here, DIW), a drying liquid, and gas.

The drying liquid supplying portion 110 is controlled by the controlling portion 102 such that the drying liquid is supplied to the upper nozzle portion 5A. When the drying liquid is supplied from the drying liquid supplying portion 110 to the upper nozzle portion 5A, the drying liquid is discharged from the upper nozzle portion 5A. The controlling portion 102 discharges the drying liquid from the upper nozzle portion 5A when the substrate W is held by the upper substrate holding portion 2A. Therefore, the drying liquid is supplied toward the upper surface Wa of the substrate W held by the upper substrate holding portion 2A. The drying liquid is, for example, isopropyl alcohol (IPA).

Specifically, the drying liquid supplying portion 110 has a drying liquid pipe portion 111 and an opening/closing valve 112. The drying liquid pipe portion 111 is a tubular member through which a fluid flows. The opening/closing valve 112 is provided in the drying liquid pipe portion 111. The opening/closing valve 112 is openable and closable. The opening and closing operations of the opening/closing valve 112 are controlled by the controlling portion 102.

The drying liquid is supplied to the upstream end of the drying liquid pipe portion 111. The downstream end of the drying liquid pipe portion 111 is connected to the upper nozzle portion 5A. The opening/closing valve 112 opens and closes a flow path in the drying liquid pipe portion 111. When the opening/closing valve 112 is opened, the drying liquid is supplied to the upper nozzle portion 5A. When the opening/closing valve 112 is closed, the supply of the drying liquid to the upper nozzle portion 5A is stopped.

The immersion bath 61d has a bottom wall portion 611, a side wall portion 612, an inner wall portion 613, a plurality of supporting portion 614, an intermediate wall portion 617, and a lower nozzle portion 5B. The immersion bath 61d is different from the immersion bath 61a described with reference to FIGS. 4 and 5 in that the immersion bath 61d has the intermediate wall portion 617.

The intermediate wall portion 617 is provided between the side wall portion 612 and the inner wall portion 613. That is, the intermediate wall portion 617 is located inside the side wall portion 612. The intermediate wall portion 617 is located outside the inner wall portion 613. The intermediate wall portion 617 is provided at a position away from the side wall portion 612 and the inner wall portion 613.

The intermediate wall portion 617 protrudes upward from the bottom wall portion 611. The intermediate wall portion 617 has an annular shape. The intermediate wall portion 617 may have, for example, a circular annular shape. The upper end of the intermediate wall portion 617 is located between the upper end of the side wall portion 612 and the upper end of the inner wall portion 613. The upper end of the intermediate wall portion 617 is located at a position lower than that of the upper end of the side wall portion 612. The upper end of the intermediate wall portion 617 is located at a position higher than that of the upper end of the inner wall portion 613.

The intermediate wall portion 617 may have a shape similar to that of the side wall portion 612. Specifically, similarly to the side wall portion 612, the intermediate wall portion 617 may include an upper wall portion (inclined portion) and a lower wall portion (see FIG. 5).

In Preferred Embodiment 7, the second draining portion 15 drains the processing liquid collected between the inner wall portion 613 and the intermediate wall portion 617 from the immersion bath 61d. Specifically, the upstream end of the drainage pipe portion 151 is connected to the bottom wall portion 611 of the immersion bath 61d between the inner wall portion 613 and the intermediate wall portion 617 and communicates with the inner space of the immersion bath 61d.

The fourth draining portion 230 drains the processing liquid collected between the intermediate wall portion 617 and the side wall portion 612 from the immersion bath 61d. Specifically, similarly to the second draining portion 15, the fourth draining portion 230 has a drainage pipe portion 231 and an opening/closing valve 232. The upstream end of the drainage pipe portion 231 is connected to the bottom wall portion 611 of the immersion bath 61d between the intermediate wall portion 617 and the side wall portion 612 and communicates with the inner space of the immersion bath 61d. Since the configuration of the fourth draining portion 230 is similar to the configuration of the second draining portion 15, the detailed description thereof will be omitted.

Subsequently, an example of the operation of the substrate processing apparatus 100 according to Preferred Embodiment 7 will be described. For example, in Preferred Embodiment 7, the chemical liquid processing is executed on the substrate W as in Preferred Embodiment 1. Specifically, the substrate W is immersed in the chemical liquid stored inside the inner wall portion 613.

When a predetermined time (predetermined chemical liquid processing time) has elapsed after the substrate W is immersed in the chemical liquid, the controlling portion 102 executes the rinse processing described with reference to FIGS. 17 to 19. In Preferred Embodiment 7, in the third step of the rinse processing, the controlling portion 102 controls the raising/lowering mechanism 210A such that the substrate W is raised to a position between the upper end of the inner wall portion 613 and the upper end of the intermediate wall portion 617 while continuing the discharge of the rinse liquid and the rotation of the substrate W.

The controlling portion 102 executes liquid film replacement processing when a predetermined time has elapsed after the substrate W is raised to a position between the upper end of the inner wall portion 613 and the upper end of the intermediate wall portion 617.

Specifically, the controlling portion 102 switches the second opening/closing valve 126 of the first liquid supplying portion 12 and the second opening/closing valve 136 of the second liquid supplying portion 13 from the open state to the closed state and switches the opening/closing valve 112 of the drying liquid supplying portion 110 from the closed state to the open state. As a result, the discharge of the rinse liquid is stopped, the drying liquid is discharged from the upper nozzle portion 5A, and the liquid film on the upper surface Wa of the substrate W is replaced from a liquid film of the rinse liquid to a liquid film of the drying liquid.

When a predetermined time has elapsed from the start of the liquid film replacement processing, the controlling portion 102 controls the raising/lowering mechanism 210A such that the upper substrate holding portion 2A is raised to a fifth processing position P9. As a result, the substrate W rises to a position between the upper end of the intermediate wall portion 617 and the upper end of the side wall portion 612. The fifth processing position P9 indicates a position in the up-down direction.

When the upper substrate holding portion 2A is raised to the fifth processing position P9, the controlling portion 102 switches the opening/closing valve 112 of the drying liquid supplying portion 110 from the open state to the closed state. As a result, the discharge of the drying liquid is stopped.

When the discharge of the drying liquid is stopped, the controlling portion 102 switches the opening/closing valve 162 of the first gas supplying portion 16 from the closed state to the open state and ejects the gas from the upper nozzle portion 5A toward the rotating substrate W. As a result, the substrate W is dried.

Preferred Embodiment 7 of the present invention has been described above with reference to FIG. 70. According to Preferred Embodiment 7, similarly to the preferred embodiments described with reference to FIGS. 1 to 69, the consumption amount of the chemical liquid can be reduced.

Furthermore, according to Preferred Embodiment 7, the chemical liquid processing is performed on the substrate W inside the inner wall portion 613. In addition, the rinse processing after the chemical liquid processing is performed on the substrate W at a position lower than the upper end of the intermediate wall portion 617. On the other hand, the drying processing on the substrate W is performed at a position between the upper end of the intermediate wall portion 617 and the upper end of the side wall portion 612. Therefore, the drying processing is performed at a higher position than a position at which the chemical liquid processing and the rinse processing are performed, a mist of the chemical liquid is less likely to adhere to the substrate W.

### Preferred Embodiment 8

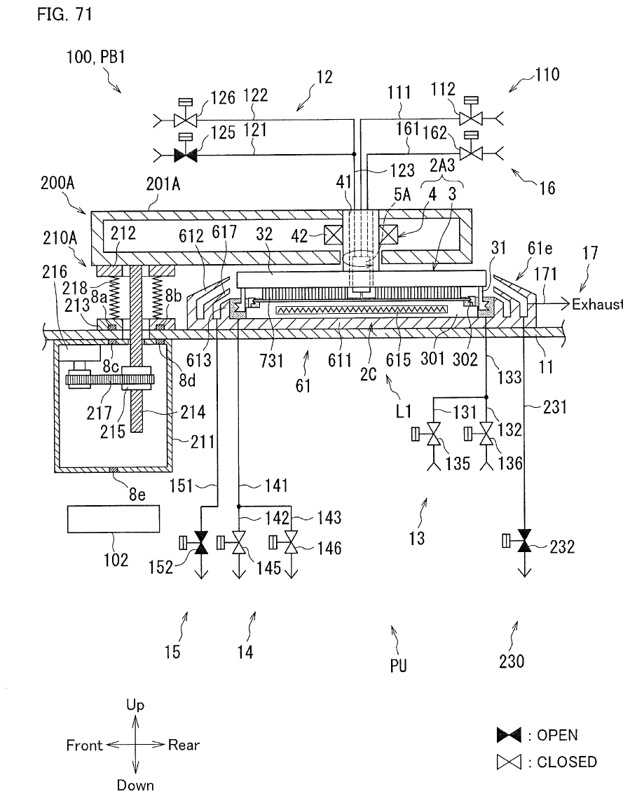

Subsequently, Preferred Embodiment 8 of the present invention will be described with reference to FIG. 71. However, matters differing from the preferred embodiments described with reference to FIGS. 1 to 70 will be described, and the description of matters that are the same as in the preferred embodiments described with reference to FIGS. 1 to 70 will be omitted.

FIG. 71 is a cross-sectional view schematically illustrating a portion of a configuration of the first processing block PB1 included in a substrate processing apparatus 100 according to Preferred Embodiment 8. Specifically, FIG. 71 illustrates the first liquid supplying portion 12, the first gas supplying portion 16, the drying liquid supplying portion 110, an upper substrate holding portion 2A3, a portion of the moving portion 200A, the substrate processing unit PU, and the first rail member 8a to the fifth rail member 8e which correspond to the first processing cup row L1 of the first processing block PB1. FIG. 71 schematically illustrates the cross sections of the moving portion 200A and an immersion bath 61e as viewed from the left side.

As illustrated in FIG. 71, in Preferred Embodiment 8, the first processing block PB1 has the supporting plate 11, the first liquid supplying portion 12, the first gas supplying portion 16, the drying liquid supplying portion 110, the upper substrate holding portion 2A3, the moving portion 200A, the substrate processing unit PU, and the rail member 8 (first rail member 8a to fifth rail member 8e). The upper substrate holding portion 2A3 has the upper holding portion 3, the upper rotating portion 4, and an upper brush 731. The substrate processing unit PU has the first processing cup portion 61, the second liquid supplying portion 13, the first draining portion 14, the second draining portion 15, the fourth draining portion 230, the exhaust portion 17, and the heater 615. The first processing cup portion 61 includes the immersion bath 61e, the lower substrate holding portion 2C, and a lower chuck driving mechanism (not illustrated).

In Preferred Embodiment 8, similarly to Preferred Embodiment 5, the substrate W is transferred between the upper substrate holding portion 2A3 and the lower substrate holding portion 2C. Similarly to Preferred Embodiment 5, the lower substrate holding portion 2C horizontally holds the substrate W immersed in the processing liquid.

In Preferred Embodiment 8, the upper spin base 32 holds the upper brush 731. The upper brush 731 protrudes downward from the upper spin base 32. Similarly to Preferred Embodiment 5, the upper brush 731 comes into contact with the upper surface Wa of the substrate W immersed in the processing liquid in the immersion bath 61e. Specifically, the upper brush 731 comes into contact with the upper surface Wa of the substrate W held by the lower substrate holding portion 2C.

The upper rotating portion 4 of the upper substrate holding portion 2A3 integrally rotates the upper holding portion 3 and the upper brush 731 with each other. When the upper surface Wa of the substrate W is cleaned by the upper brush 731, the controlling portion 102 controls the upper rotating portion 4 such that the upper spin base 32 is rotated and thus rotates the upper brush 731 in contact with the upper surface Wa of the substrate W. The processing liquid stored in the immersion bath 61e when the substrate W is cleaned through the brush processing may be the chemical liquid or the rinse liquid.

In the example illustrated in FIG. 71, the brush member is not provided at a position at which the upper spin base 32 overlaps with the upper nozzle portion 5A. In other words, the brush member is not provided at the central portion of the upper spin base 32. That is, the upper brush 731 is provided to avoid the upper nozzle portion 5A. However, the brush member may be provided at the central portion of the upper spin base 32. For example, the brush member can be provided at the central portion of the upper spin base 32 by adjusting the shape, the inner diameter, etc., of the discharge port of the upper nozzle portion 5A. In the case of a configuration in which the brush member is not provided at the central portion of the upper spin base 32, the controlling portion 102 may control the moving mechanism 220A during the brush processing such that the upper substrate holding portion 2A3 (upper brush 731) is moved in the horizontal direction. For example, the controlling portion 102 may swing the upper substrate holding portion 2A3 (upper brush 731) in the horizontal direction during the brush processing. Alternatively, another moving mechanism that moves the upper substrate holding portion 2A3 (upper brush 731) in the horizontal direction may be provided in each of the first processing block PB1 and the second processing block PB2.

The immersion bath 61e has a bottom wall portion 611, a side wall portion 612, an inner wall portion 613, and an intermediate wall portion 617. The structures of the bottom wall portion 611, the side wall portion 612, the inner wall portion 613, and the intermediate wall portion 617 are similar to the structures of the bottom wall portion 611, the side wall portion 612, the inner wall portion 613, and the intermediate wall portion 617 included in the immersion bath 61d illustrated in FIG. 70, and thus, the description thereof will be omitted. Similarly to the immersion bath 61c illustrated in FIG. 66, the immersion bath 61e illustrated in FIG. 71 is not provided with the lower nozzle portion 5B. The upstream end of the common pipe portion 133 of the second liquid supplying portion 13 is connected to the bottom wall portion 611 inside the inner wall portion 613 and communicates with the inner space of the immersion bath 61c.

The lower substrate holding portion 2C is disposed inside the inner wall portion 613. Similarly to the lower substrate holding portion 2C described with reference to FIG. 66, the lower substrate holding portion 2C has the base 301 and the plurality of lower chuck members 302. The lower chuck driving mechanism (not illustrated) drives the plurality of lower chuck members 302 and causes the plurality of lower chuck members 302 to grip the substrate W. Since the configuration of the lower chuck driving mechanism (not illustrated) is similar to the configuration of the lower chuck driving mechanism 310 described with reference to FIG. 66, the description thereof will be omitted.

Preferred Embodiment 8 of the present invention has been described above with reference to FIG. 71. According to Preferred Embodiment 8, similarly to the preferred embodiments described with reference to FIGS. 1 to 70, the consumption amount of the chemical liquid can be reduced. According to Preferred Embodiment 8, similarly to Preferred Embodiment 5, the upper brush 731 can clean the upper surface Wa of the substrate W. Furthermore, according to Preferred Embodiment 8, similarly to Preferred Embodiment 7, the drying processing can be performed at a higher position than the position at which the chemical liquid processing and the rinse processing are performed. Therefore, it is possible to suppress the mist of the chemical liquid from adhering to the substrate W.

In Preferred Embodiment 8, the intermediate wall portion 617 is provided in the first processing cup portion 61, but the intermediate wall portion 617 may be omitted. For example, the substrate processing unit PU may be provided with the immersion bath 61c described with reference to FIG. 66 as the first processing cup portion 61. In this case, the fourth draining portion 230 is omitted.

In Preferred Embodiment 8, the brush processing, the rinse processing, and the drying processing are executed in the same first processing cup portion 61, but the drying processing and the final rinse processing executed before the drying processing may be performed in the second processing cup portion 62. In this case, for example, the second upper substrate holding portion 2A2 described with reference to FIG. 45 may be provided in each of the first processing block PB1 and the second processing block PB2 in addition to the upper substrate holding portion 2A3.

### Preferred Embodiment 9

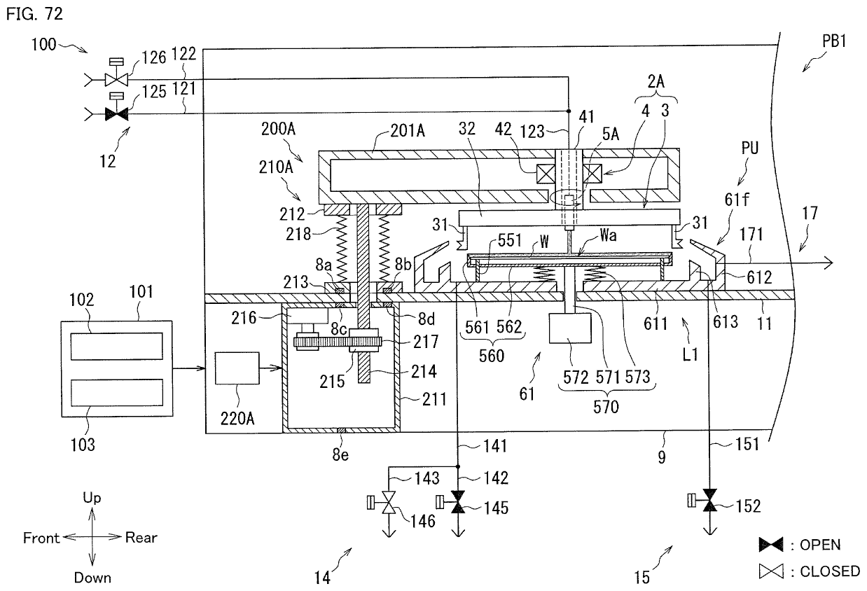

Subsequently, Preferred Embodiment 9 of the present invention will be described with reference to FIG. 72. However, matters differing from the preferred embodiments described with reference to FIGS. 1 to 71 will be described, and the description of matters that are the same as in the preferred embodiments described with reference to FIGS. 1 to 71 will be omitted. Preferred Embodiment 9 is different from the preferred embodiments described with reference to FIGS. 1 to 71 in a configuration of the first processing cup portion 61.

FIG. 72 is a cross-sectional view schematically illustrating a portion of a configuration of the first processing block PB1 included in a substrate processing apparatus 100 according to Preferred Embodiment 9. Specifically, FIG. 72 illustrates the first liquid supplying portion 12, the upper substrate holding portion 2A, the moving portion 200A, the substrate processing unit PU, and the first rail member 8a to the fifth rail member 8e which correspond to the first processing cup row L1 of the first processing block PB1. FIG. 72 schematically illustrates the cross sections of the moving portion 200A, a processing cup 61f, a supporting column 551, and a liquid film holding portion 560 as viewed from the left side.

As illustrated in FIG. 72, the first processing cup portion 61 includes the processing cup 61f, a plurality of supporting columns 551, the liquid film holding portion 560, and a raising/lowering mechanism 570. The processing cup 61f has a bottom wall portion 611, a side wall portion 612, and an inner wall portion 613. The lower nozzle portion 5B is not provided in the processing cup 61f. Therefore, the second liquid supplying portion 13 is not provided in the substrate processing unit PU.

The plurality of supporting columns 614 horizontally support the substrate W. The substrate W supported by the plurality of supporting columns 551 is located inside the processing cup 61f. Specifically, the plurality of supporting columns 551 may support the peripheral edge portion of the lower surface Wb of the substrate W. The plurality of supporting columns 551 may be disposed on the same circumference, for example. Specifically, the plurality of supporting columns 551 are provided inside the inner wall portion 613. Each supporting column 551 extends upward from the bottom wall portion 611. The supporting column 551 may have, for example, a circular columnar shape. When the substrate W is placed on the plurality of supporting columns 551, the substrate W is horizontally supported by the plurality of supporting columns 551. The upper substrate holding portion 2A transfers the substrate W to and from the plurality of supporting columns 551. The supporting column 551 is an example of a “supporting portion.”

The liquid film holding portion 560 holds the liquid film of the chemical liquid in contact with the upper surface Wa of the substrate W. Specifically, the liquid film holding portion 560 has a ring-shaped blocking portion 561 and a supporting plate 562. The blocking portion 561 blocks the chemical liquid supplied to the upper surface Wa of the substrate W. As a result, the liquid film of the chemical liquid which is formed on the upper surface Wa of the substrate W is held by the blocking portion 561. The blocking portion 561 is an example of a “ring-shaped member.”

Specifically, the supporting plate 562 supports the blocking portion 561. The supporting plate 562 is located at a position lower than that of the substrate W supported by the plurality of supporting columns 551. The blocking portion 561 protrudes upward from the supporting plate 562. The inner peripheral surface of the blocking portion 561 is in contact with the side surface of the substrate W supported by the plurality of supporting columns 551. The blocking portion 561 has, for example, a cylindrical shape.

The blocking portion 561 has a tip end portion protruding to a position higher than that of the substrate W supported by the plurality of supporting columns 551. Of the inner peripheral surface of the blocking portion 561, the inner peripheral surface of the tip end portion may include an inclined surface inclined obliquely upward toward the radially outer side of the substrate W. The chemical liquid supplied to the upper surface Wa of the substrate W is blocked by the tip end portion of the blocking portion 561, and the liquid film of the chemical liquid is held on the upper surface Wa of the substrate W. Therefore, the peripheral edge portion of the liquid film comes into contact with the tip end portion of the blocking portion 561.

The supporting plate 562 has, for example, a disk shape. The supporting plate 562 may be horizontally disposed. The supporting plate 562 may horizontally support the blocking portion 561.

The supporting plate 562 has a plurality of through holes through which the plurality of supporting columns 551 are inserted. The supporting plate 562 is guided in the up-down direction by the plurality of supporting columns 551.

The raising/lowering mechanism 570 is controlled by the controlling portion 102 such that the supporting plate 562 is raised and lowered. Specifically, the raising/lowering mechanism 570 raises and lowers the supporting plate 562 between an upper position and a lower position. The upper position is a higher position than the lower position. When the supporting plate 562 is located at the upper position, the tip end portion of the blocking portion 561 protrudes to a position higher than that of the substrate W supported by the plurality of supporting columns 551. When the supporting plate 562 is located at the lower position, the tip end portion of the blocking portion 561 is located at a position lower than that of the substrate W supported by the plurality of supporting columns 551.

The raising/lowering mechanism 570 may include, for example, a rod 571, a driving portion 572, and an elastic member 573.

The driving portion 572 is controlled by the controlling portion 102 such that the rod 571 is moved in the up-down direction. The driving portion 572 includes, for example, a cylinder. The rod 571 extends in the up-down direction. The upper end of the rod 571 is coupled to the supporting plate 562. When the rod 571 moves in the up-down direction, the supporting plate 562 is raised and lowered. For example, the driving portion 572 may be disposed under the supporting plate 11. The supporting plate 11 and the bottom wall portion 611 of the processing cup 61f may have a through hole through which the rod 571 is inserted.

The elastic member 573 is disposed inside the processing cup 61f and covers the rod 571. Specifically, a portion of the rod 571 is accommodated inside the elastic member 573. The elastic member 573 is able to be elastic in the up-down direction. The elastic member 573 is, for example, a bellows. The upper end of the elastic member 573 is fixed to the lower surface of the supporting plate 562. The lower end of the elastic member 573 is fixed to the upper surface of the bottom wall portion 611.

Subsequently, an example of the operation of the substrate processing apparatus 100 according to Preferred Embodiment 9 will be described.

When the substrate W is processed, the controlling portion 102 controls the moving portion 200A such that the upper substrate holding portion 2A that holds the substrate W is moved to a position at which the lower surface Wb of the substrate W comes into contact with the upper surfaces (tip end surfaces) of the plurality of supporting columns 551 and then controls the upper chuck driving mechanism 50 such that the gripping of the substrate W by the plurality of upper chuck members 31 is released. As a result, the substrate W is horizontally supported by the plurality of supporting columns 551. After the substrate W is supported by the plurality of supporting columns 551, the controlling portion 102 controls the moving portion 200A such that the upper substrate holding portion 2A is retracted upward.

After the upper substrate holding portion 2A is retracted, the controlling portion 102 controls the raising/lowering mechanism 570 such that the supporting plate 562 is raised from the lower position to the upper position. After the supporting plate 562 is raised from the lower position to the upper position, the controlling portion 102 controls the first liquid supplying portion 12 such that a certain amount of chemical liquid is discharged from the upper nozzle portion 5A. As a result, the chemical liquid supplied to the upper surface Wa of the substrate W is blocked by the blocking portion 561, and the liquid film of the chemical liquid in contact with the upper surface Wa of the substrate W is held by the blocking portion 561. The certain amount indicates the amount by which the liquid film of the chemical liquid is formed on the entire upper surface Wa of the substrate W.

Preferred Embodiment 9 of the present invention has been described above with reference to FIG. 72. According to Preferred Embodiment 9, similarly to the preferred embodiments described with reference to FIGS. 1 to 71, the consumption amount of the chemical liquid can be reduced. Further, according to Preferred Embodiment 9, only the upper surface Wa of the substrate W can be processed with the chemical liquid. Furthermore, according to Preferred Embodiment 9, since the liquid film is held on the upper surface Wa of the substrate W and the substrate W is processed, the consumption amount of the chemical liquid can be further reduced.

### Preferred Embodiment 10

Subsequently, Preferred Embodiment 10 of the present invention will be described with reference to FIG. 73. However, matters differing from the preferred embodiments described with reference to FIGS. 1 to 72 will be described, and the description of matters that are the same as in the preferred embodiments described with reference to FIGS. 1 to 72 will be omitted. Preferred Embodiment 10 is different from the preferred embodiments described with reference to FIGS. 1 to 72 in a configuration of the first processing cup portion 61.

FIG. 73 is a cross-sectional view schematically illustrating a portion of a configuration of the first processing block PB1 included in a substrate processing apparatus 100 according to Preferred Embodiment 10. Specifically, FIG. 73 illustrates the first liquid supplying portion 12, the upper substrate holding portion 2A, the moving portion 200A, the substrate processing unit PU, and the first rail member 8a to the fifth rail member 8e which correspond to the first processing cup row L1 of the first processing block PB1. FIG. 73 schematically illustrates the cross sections of the moving portion 200A, a processing cup 61g, and a substrate supporting table 580 as viewed from the left side.

As illustrated in FIG. 73, the first processing cup portion 61 includes the processing cup 61g, the substrate supporting table 580, and a lower nozzle portion 5B. The processing cup 61g includes a bottom wall portion 611, a side wall portion 612, and an inner wall portion 613.

The substrate supporting table 580 horizontally supports the substrate W. The substrate W supported by the substrate supporting table 580 is located inside the processing cup 61g. The upper substrate holding portion 2A transfers the substrate W to and from the substrate supporting table 580.

Specifically, the substrate supporting table 580 has a table 581 and a plurality of supporting portions 582. The table 581 is provided inside the inner wall portion 613. The plurality of supporting portion 582 are provided on the table 581 and protrude upward from an upper surface 581a of the table 581.

The plurality of supporting portions 582 horizontally support the substrate W. Specifically, the plurality of supporting portions 582 may support the peripheral edge portion of the lower surface Wb of the substrate W. The plurality of supporting portions 582 may be disposed on the same circumference, for example. When the substrate W is placed on the plurality of supporting portions 582, the substrate W is horizontally supported by the plurality of supporting portions 582. The upper substrate holding portion 2A transfers the substrate W to and from the plurality of supporting portions 582.

The upper surface 581a of the table 581 faces the lower surface Wb of the substrate W supported by the plurality of supporting portions 582. The table 581 is an example of a “lower base member.” The lower nozzle portion 5B is provided in the table 581. Specifically, the lower nozzle portion 5B passes through the table 581 in the up-down direction. The lower nozzle portion 5B discharges the chemical liquid from the upper surface 581a of the table 581. The chemical liquid discharged from the upper surface 581a of the table 581 wets and spreads in a gap between the upper surface 581a of the table 581 and the lower surface Wb of the substrate W supported by the plurality of supporting portions 582, is held in the gap between the upper surface 581a of the table 581 and the lower surface Wb of the substrate W, and comes into contact with the lower surface Wb of the substrate W. As a result, the lower surface Wb of the substrate W is processed with the chemical liquid.

Specifically, the upper surface 581a of the table 581 protrudes outward from the peripheral edge portion of the substrate W over the entire circumference of the substrate W. The upper surface 581a of the table 581 has, for example, a circular shape. In this case, the diameter of the upper surface 581a of the table 581 is greater than the diameter of the substrate W. The upper surface 581a of the table 581 may extend along a horizontal plane.

The height of the supporting portion 582 from the upper surface 581a of the table 581 indicates the height at which the chemical liquid is held in the gap between the upper surface 581a of the table 581 and the lower surface Wb of the substrate W. Specifically, the chemical liquid is held by surface tension in the gap between the upper surface 581a of the table 581 and the lower surface Wb of the substrate W. The height of the supporting portion 582 may be, for example, several hundred μm or more and several mm or less. The supporting portion 582 is, for example, a protrusion.

Subsequently, an example of the operation of the substrate processing apparatus 100 according to Preferred Embodiment 10 will be described.

When the substrate W is processed, the controlling portion 102 controls the moving portion 200A such that the upper substrate holding portion 2A that holds the substrate W is moved to a position at which the lower surface Wb of the substrate W comes into contact with the plurality of supporting portions 582 and then controls the upper chuck driving mechanism 50 such that the gripping of the substrate W by the plurality of upper chuck members 31 is released. As a result, the substrate W is horizontally supported by the plurality of supporting portions 582. After the substrate W is supported by the plurality of supporting portions 582, the controlling portion 102 controls the moving portion 200A such that the upper substrate holding portion 2A is retracted upward.

After the upper substrate holding portion 2A is retracted, the controlling portion 102 controls the second liquid supplying portion 13 such that a certain amount of chemical liquid is discharged from the lower nozzle portion 5B. As a result, the chemical liquid wets and spreads in the gap between the upper surface 581a of the table 581 and the lower surface Wb of the substrate W, and the chemical liquid is held in the gap between the upper surface 581a of the table 581 and the lower surface Wb of the substrate W. Therefore, the chemical liquid in contact with the lower surface Wb of the substrate W is held, and the lower surface Wb of the substrate W is processed with the chemical liquid. The certain amount indicates an amount by which the state in which the chemical liquid is in contact with the entire lower surface Wb of the substrate W is maintained.

Preferred Embodiment 10 of the present invention has been described above with reference to FIG. 73. According to Preferred Embodiment 10, similarly to the preferred embodiments described with reference to FIGS. 1 to 72, the consumption amount of the chemical liquid can be reduced. Further, according to Preferred Embodiment 10, only the lower surface Wb of the substrate W can be processed with the chemical liquid. Furthermore, according to Preferred Embodiment 10, since the chemical liquid in contact with the lower surface Wb of the substrate W is held thereon and the substrate W is processed, the consumption amount of the chemical liquid can be further reduced.

The preferred embodiments of the present invention have been described above with reference to the drawings (FIGS. 1 to 73). However, the present invention is not limited to the preferred embodiments described above and can be implemented in various modes within a scope not deviating from its gist. Also, it is possible to modify, as appropriate, the plurality of constituent elements disclosed in the preferred embodiments described above. For example, a certain constituent element among all constituent elements of a certain preferred embodiment may be added to the constituent elements of another preferred embodiment or some constituent elements among all constituent elements of a certain preferred embodiment may be deleted from the preferred embodiment.

The drawings mainly illustrate the respective constituent elements schematically to facilitate understanding of the invention and there are cases where thicknesses, lengths, numbers, intervals, etc., of the respective constituent elements illustrated differ from actuality due to convenience of drawing preparation. Also, the arrangements of the respective constituent elements indicated in the preferred embodiments described above are but an example, are not restricted in particular, and can obviously be changed variously within a scope of practically not deviating from the effects of the present invention.

For example, in Preferred Embodiment 1, after the substrate W is moved to the inside of the immersion bath 61a, the chemical liquid is discharged from the upper nozzle portion 5A and the lower nozzle portion 5B, the chemical liquid is stored in the immersion bath 61a, and the substrate W is immersed in the chemical liquid, but, as in Preferred Embodiment 3, the substrate W may be immersed in the chemical liquid by submerging the substrate W in the chemical liquid stored in the immersion bath 61a.

In the preferred embodiments described with reference to FIGS. 1 to 73, the opening/closing valve is not provided in the exhaust portion 17 corresponding to the first processing cup portion 61, but the exhaust portion 17 corresponding to the first processing cup portion 61 may have the opening/closing valve that opens and closes the flow path in the exhaust pipe portion 171. In this case, the controlling portion 102 may close the opening/closing valve of the exhaust portion 17 corresponding to the first processing cup portion 61 while the chemical liquid processing is executed inside the first processing cup portion 61 (inside the cup). Through this processing, it is possible to suppress a decrease in the temperature of the chemical liquid in contact with the substrate W inside the first processing cup portion 61 (inside the cup).

In the preferred embodiments described with reference to FIGS. 1 to 73, the rinse liquid is DIW, but the rinse liquid is not limited to DIW. The rinse liquid may be, for example, carbonated water, electrolyzed ion water, hydrogen water, ozone water, or hydrochloric acid water having a dilution concentration (for example, about 0.001 wt % to about 0.01 wt %).

In the preferred embodiments described with reference to FIGS. 1 to 73, the raising/lowering mechanism 210A is guided in the first direction D1 by the five rail members 8 (first rail member 8a to fifth rail member 8e), but the number of rail members 8 is not particularly limited as long as the raising/lowering mechanism 210A can be guided in the first direction D1.

In the preferred embodiments described with reference to FIGS. 1 to 73, four processing cup rows L are provided in each of the first processing block PB1 and the second processing block PB2, but the number of processing cup rows L is not limited to four. Two, three, or five or more processing cup rows L may be provided in each of the first processing block PB1 and the second processing block PB2.

In the preferred embodiments described with reference to FIGS. 1 to 73, a plurality of processing cup rows L are provided in each of the first processing block PB1 and the second processing block PB2, but one processing cup row L may be provided in each of the first processing block PB1 and the second processing block PB2 except for the preferred embodiment (Modification Example 8) that includes the inter-row transfer device 400A.

The present invention is useful for an apparatus that processes a substrate.

What is claimed is:

1. A substrate processing apparatus comprising:
a processing block that processes a substrate; and
a transfer block that is disposed adjacent to the processing block,
wherein the transfer block has a transfer device that transfers the substrate between the transfer block and the processing block,
the processing block has
an upper substrate holding portion that horizontally holds the substrate,
a moving mechanism that moves the upper substrate holding portion in a first direction that is a direction parallel to a direction in which the substrate moves between the transfer block and the processing block,
a processing cup row that includes a plurality of processing cup portions arranged in the first direction, and
a raising/lowering mechanism that raises and lowers at least one of the upper substrate holding portion and the corresponding processing cup portion such that a position of the substrate held by the upper substrate holding portion changes from one of over positions of the plurality of processing cup portions to a position inside the corresponding processing cup portion,
the plurality of processing cup portions include a first processing cup portion, and
the first processing cup portion holds a processing liquid in contact with the substrate located inside the first processing cup portion and processes the substrate.

2. The substrate processing apparatus according to claim 1,
wherein the plurality of processing cup portions include a plurality of the first processing cup portions,
each of the plurality of first processing cup portions has a supporting portion that supports the substrate, and
the upper substrate holding portion transfers the substrate to and from the supporting portion of each of the plurality of first processing cup portions.

3. The substrate processing apparatus according to claim 2,
wherein the processing liquid includes a chemical liquid,
the substrate is processed with the chemical liquid in the first processing cup portion,
the substrate processing apparatus further comprises a draining portion that drains the chemical liquid from the first processing cup portion,
the upper substrate holding portion has an upper nozzle portion that discharges a rinse liquid toward the substrate, and
the upper nozzle portion discharges the rinse liquid toward the substrate located inside the first processing cup portion from which the chemical liquid has been drained by the draining portion.

4. The substrate processing apparatus according to claim 3,
wherein the upper substrate holding portion has
an upper holding portion that horizontally holds the substrate, and
an upper rotating portion that rotates the substrate integrally with the upper holding portion, and
after the discharge of the rinse liquid is stopped, the upper rotating portion rotates the substrate located inside the first processing cup portion and dry the substrate.

5. The substrate processing apparatus according to claim 4, wherein the upper nozzle portion ejects gas toward the substrate when the substrate is dried.

6. The substrate processing apparatus according to claim 1,
wherein the processing cup portion further includes a second processing cup portion,
the second processing cup portion receives a rinse liquid drained from the substrate,
the raising/lowering mechanism changes a position of a processed substrate, which is the substrate processed in the first processing cup portion, from a position inside the first processing cup portion to an over position of the first processing cup portion,
the moving mechanism moves the upper substrate holding portion that holds the processed substrate to a facing position at which the upper substrate holding portion faces the second processing cup portion, and
the raising/lowering mechanism changes the position of the processed substrate from an over position of the second processing cup portion to a position inside the second processing cup portion.

7. The substrate processing apparatus according to claim 6,
wherein the upper substrate holding portion has an upper nozzle portion that discharges the rinse liquid, and
the upper nozzle portion discharges the rinse liquid toward the processed substrate located inside the second processing cup portion.

8. The substrate processing apparatus according to claim 7,
wherein the upper substrate holding portion has
an upper holding portion that horizontally holds the substrate, and
an upper rotating portion that rotates the substrate integrally with the upper holding portion, and
after the discharge of the rinse liquid is stopped, the upper rotating portion rotates the processed substrate located inside the second processing cup portion and dry the processed substrate.

9. The substrate processing apparatus according to claim 8, wherein the upper nozzle portion ejects gas toward the processed substrate when the processed substrate is dried.

10. The substrate processing apparatus according to claim 6,
wherein the plurality of processing cup portions include a plurality of the first processing cup portions and the one second processing cup portion,
the processing liquid includes a chemical liquid,
the substrate is processed with different types of the chemical liquids in the plurality of first processing cup portions, and
the moving mechanism moves the upper substrate holding portion according to a processing procedure indicating a procedure of processing the substrate.

11. The substrate processing apparatus according to claim 10, wherein each of the plurality of first processing cup portions has a supporting portion that supports the substrate.

12. The substrate processing apparatus according to claim 6,
wherein the plurality of processing cup portions include a plurality of the first processing cup portions and a plurality of the second processing cup portions,
the processing liquid includes a chemical liquid,
the substrate is processed with different types of the chemical liquids in the plurality of first processing cup portions, and
the plurality of first processing cup portions and the plurality of second processing cup portions are arranged according to a processing procedure indicating a procedure of processing the substrate.

13. The substrate processing apparatus according to claim 12,
wherein each of the plurality of first processing cup portions has a supporting portion that supports the substrate, and
one of the plurality of second processing cup portions disposed between two first processing cup portions has a supporting portion that supports the substrate.

14. The substrate processing apparatus according to claim 12,
wherein the processing procedure includes final rinse processing and drying processing to dry the substrate,
rinse processing indicates processing to wash away the chemical liquid from the substrate processed in the first processing cup portion,
the plurality of first processing cup portions include a third processing cup portion in which processing immediately before the final rinse processing is performed,
the plurality of second processing cup portions include a fourth processing cup portion in which the final rinse processing and the drying processing are performed,
the upper substrate holding portion includes a first upper substrate holding portion and a second upper substrate holding portion, and
the moving mechanism includes
a first moving mechanism that moves the first upper substrate holding portion such that the substrate moves between the plurality of processing cup portions other than the fourth processing cup portion, and
a second moving mechanism that moves the second upper substrate holding portion such that the substrate moves between the third processing cup portion and the fourth processing cup portion.

15. The substrate processing apparatus according to claim 6,
wherein the first processing cup portion has a supporting portion that horizontally supports a plurality of the substrates, and
the first processing cup portion holds a processing liquid in contact with the plurality of substrates located inside the first processing cup portion and processes the plurality of substrates.

16. The substrate processing apparatus according to claim 1,
wherein the processing block has
a plurality of the upper substrate holding portions,
a plurality of the moving mechanisms,
and a plurality of the raising/lowering mechanisms,
the plurality of moving mechanisms correspond to the plurality of upper substrate holding portions, and
the plurality of raising/lowering mechanisms correspond to the plurality of upper substrate holding portions and/or the plurality of processing cup portions.

17. The substrate processing apparatus according to claim 1, wherein the processing block includes
a plurality of the processing cup rows arranged in a direction orthogonal to the first direction,
a plurality of the upper substrate holding portions one of which is provided for each of the processing cup rows,
a plurality of the moving mechanisms one of which is provided for each of the processing cup rows, and
a plurality of the raising/lowering mechanisms one of which is provided for each of the processing cup rows.

18. The substrate processing apparatus according to claim 17, wherein the processing block further has an inter-row transfer device that transfers the substrate between the plurality of processing cup rows.

19. The substrate processing apparatus according to claim 1,
wherein the first processing cup portion includes an immersion bath that stores the processing liquid,
the substrate is immersed in the processing liquid in the immersion bath,
the first processing cup portion has a lower substrate holding portion that horizontally holds the substrate inside the immersion bath,
the upper substrate holding portion has
an upper base member,
an upper gripping member that is provided on the upper base member and grips the substrate,
an upper brush member that is provided on the upper base member and comes into contact with an upper surface of the substrate held by the lower substrate holding portion, and
an upper rotating portion that rotates the upper brush member and the upper gripping member integrally with the upper base member,
the upper substrate holding portion delivers the substrate from the upper gripping member to the lower substrate holding portion, and
the upper rotating portion rotates the upper brush member when the upper brush member is in contact with the upper surface of the substrate immersed in the processing liquid.
